(19) United States
(12) Patent Application Publication
(10) Pub. No.: US 2025/0169352 A1
(43) Pub. Date: May 22, 2025

(54) Organic Light Emitting Diode and Organic Light Emitting Device Having the Diode

(71) Applicant: LG Display Co., Ltd., Seoul (KR)

(72) Inventor: Ji-Ae Lee, Paju-si (KR)

(21) Appl. No.: 18/933,870

(22) Filed: Oct. 31, 2024

(30) Foreign Application Priority Data
Nov. 22, 2023 (KR) 10-2023-0163317

(51) Int. Cl. H10K 85/30; C09K 11/02; C09K 11/06; H10K 50/12; H10K 85/60

(52) U.S. Cl. CPC H10K 85/342; C09K 11/02; C09K 11/06; H10K 85/633; H10K 85/636; H10K 85/654; C09K 2211/1007; C09K 2211/1011; C09K 2211/1033; C09K 2211/185; H10K 50/12; H10K 85/615; H10K 85/626; H10K 85/6574

(57) ABSTRACT

At least one emitting material layer in an organic light emitting diode (OLED) includes a first compound of phosphorescent material having the following structure of Chemical Formula 1, Ir(L_{A})ₘ(L_{B})ₙ, a second compound of a P-type host, and optionally a third compound of an N-type host. The luminous efficiency, color purity and luminous lifespan of the OLED and the organic light emitting device can be improved.

### CROSS-REFERENCE TO RELATED APPLICATIONS

This application claims priority, under 35 U.S.C. § 119 (a), to the Republic of Korea Patent Application No. 10-2023-0163317, filed in the Republic of Korea on Nov. 22, 2023, the entire contents of which are hereby expressly incorporated by reference into the present application.

### BACKGROUND

### Technical Field

The present disclosure relates to an organic light emitting diode, and more particularly to, an organic light emitting diode (OLED) with beneficial luminous efficiency and luminous lifespan and an organic light emitting device (e.g., a display device or a lighting device) including the OLED.

### Description of the Related Art

Flat panel display devices including an organic light emitting diode (OLED), have been investigated as display devices that can replace a liquid crystal display device (LCD). The OLED can be formed as a thin organic film and the electrode configurations in the OLED can implement unidirectional or bidirectional images. Also, the OLED can be formed even on a flexible transparent substrate such as a plastic substrate so that a flexible or a foldable display device can be realized with ease using the OLED. In addition, the OLED can be driven at a lower voltage and the OLED has advantageous high color purity compared to the LCD.

Since fluorescent materials use only singlet excitons in the luminous process, the related art fluorescent material shows low luminous efficiency. Meanwhile, phosphorescent materials can show high luminous efficiency since they use triplet excitons as well as singlet excitons in the luminous process. Examples of such phosphorescent material include metal complexes, which can have a short luminous lifespan for commercial use. As such, there remains a need to develop a compound with sufficient luminous efficiency and luminous lifespan.

### SUMMARY

Accordingly, embodiments of the present disclosure are directed to an organometallic compound, an organic light emitting diode and an organic light emitting device that substantially obviate one or more of the problems due to the limitations and disadvantages of the related art.

An aspect of the present disclosure is to provide an organic light emitting diode with sufficient luminous efficiency and luminous lifespan, and an organic light emitting device including the organic light emitting diode.

Additional features and aspects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with the objects of the present disclosure, as embodied and broadly described herein, in one aspect, the present disclosure provides an organic light emitting diode that includes a first electrode; a second electrode facing the first electrode; and an emissive layer disposed between the first and second electrodes and including at least one emitting material layer, wherein the at least one emitting material layer includes a first compound and a second compound, wherein the first compound includes an organometallic compound having the following structure of Chemical Formula 1, and wherein the second compound includes an organic compound having the following structure of Chemical Formula 8:

Ir(L_{A})ₘ(L_{B})ₙ, [Chemical Formula 1]
Wherein:
L_{A} is a ligand having the structure of Chemical Formula 2:

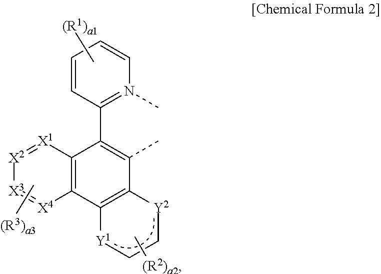

wherein:
each of X¹ to X⁴ is independently CR³ or N, wherein at least one of X¹ to X⁴ is CR³;
one of Y¹ and Y² is a single bond and the other is CR⁴R⁵, NR⁴, O or S;
each of R¹ to R⁵ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R¹ is identical to or different from each other when a1 is 2, 3, or 4, wherein each R² is identical to or different from each other when a2 is 2, and wherein each R³ is identical to or different from each other when a3 is 2, 3 or 4, or
optionally,
two adjacent R¹ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a1 is 2, 3, or 4, and/or
two adjacent R² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a2 is 2,
two adjacent R³ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a3 is 2, 3 or 4, and/or
R⁴ and R⁵ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring;
each of a1 and a3 is independently 0, 1, 2, 3, or 4;
a2 is 0, 1, or 2,
L_{B} is an auxiliary ligand;
m is 1, 2 or 3;
n is 0, 1 or 2; and
m+n is 3;

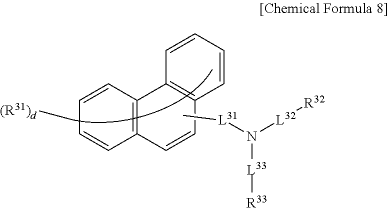

wherein:
each of R³¹ to R³³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R³¹ is identical to or different from each other when d is 2, 3, 4, 5, 6, 7, 8 or 9;
each of L³¹ and L³² is independently a single bond, an unsubstituted or substituted C₆-C₃₀ arylene group or an unsubstituted or substituted C₂-C₃₀ hetero arylene group; and
d is 0, 1, 2, 3, 4, 5, 6, 7, 8 or 9.

In one embodiment, the at least one emitting material layer can further include a third compound, and wherein the third compound includes an organic compound having the structure of Chemical Formula 11:

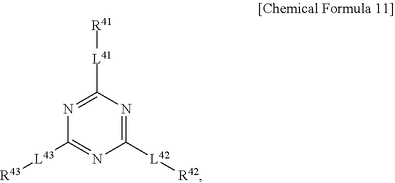

wherein:
each of R⁴¹ to R⁴³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group; and
each of L⁴¹ to L⁴³ is independently a single bond, an unsubstituted or substituted C₆-C₃₀ arylene group or an unsubstituted or substituted C₂-C₃₀ hetero arylene group.

In another embodiment, the L_{A} in Chemical Formula 1 can have the structure of Chemical Formula 3:

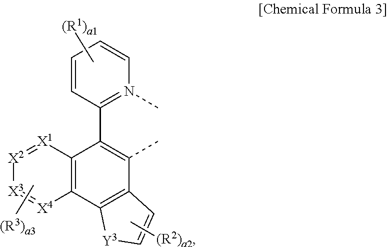

wherein:
Y³ is CR+R⁵, NR⁴, O or S; and
each of X¹ to X⁴, R¹ to R⁵, a1, a2 and a3 is as defined in Chemical Formula 2.

In another embodiment, the L_{A} in Chemical Formula 1 can have the structure of Chemical Formula 4:

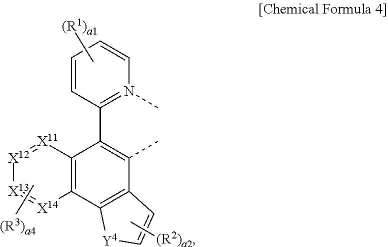

wherein:
each of X¹¹ to X¹⁴ is independently CR³ or N, wherein at least two of X¹¹ to X¹⁴ are CR³, and at least one of X¹¹ to X¹⁴ is N;
Y⁴ is NR⁴, O or S;
a4 is 0, 1, 2, or 3; and
each of R¹ to R⁴, a1 and a2 is as defined in Chemical Formula 2.

In another embodiment, the L_{A} in Chemical Formula 1 can have the structure of Chemical Formula 5:

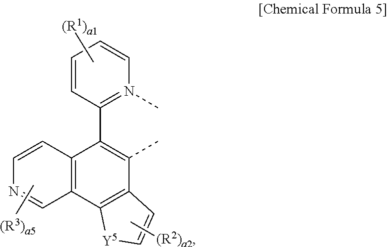

wherein:
Y⁵ is O or S;
a5 is 0, 1, 2 or 3; and
each of R¹ to R³, a1 and a2 is as defined in Chemical Formula 2.

As an example, each R¹ in Chemical Formula 2 can be independently hydrogen, an unsubstituted or substituted C₁-C₂₀ alkyl group, an unsubstituted or substituted C₆-C₃₀ aryl group or an unsubstituted or substituted C₇-C₃₀ aralkyl group.

Each of R² and R³ in Chemical Formula 2 can be independently hydrogen, or an unsubstituted or substituted C₁-C₂₀ alkyl group.

One of X¹ to X⁴ can be N and three of X¹ to X⁴ can be CR³ in Chemical Formula 2.

Y¹ can be O or S, and Y² can be the single bond in Chemical Formula 2.

As an example, the L_{B} in Chemical Formula 1 can have the structure of Chemical Formula 6A or Chemical Formula 6B:

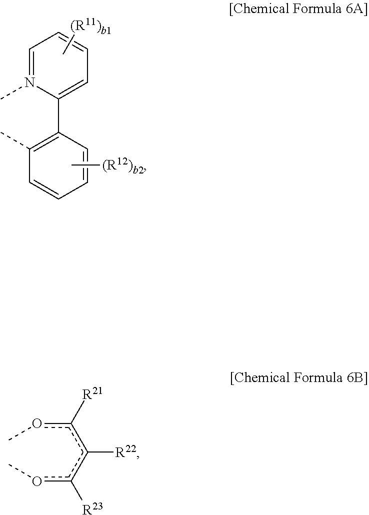

wherein:
each of R¹¹, R¹² and R²¹ to R²³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R¹¹ is identical to or different from each other when b1 is 2, 3 or 4, and wherein each R¹² is identical to or different from each other when b2 is 2, 3 or 4, or
optionally,
two adjacent R¹¹ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when b1 is 2, 3 or 4, and/or
two adjacent R¹² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when b2 is 2, 3 or 4, and/or
two adjacent groups among R²¹ to R²³ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring; and
each of b1 and b2 is independently 0, 1, 2, 3 or 4.

As an example, the second compound can have the structure of Chemical Formula 9:

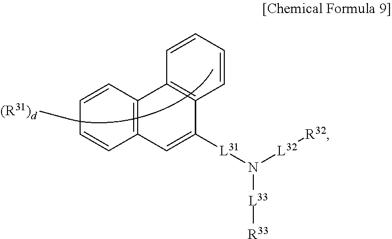

wherein:
each of R³¹ to R³³, L³¹ to L³³ and d is as defined in Chemical Formula 8.

In some embodiments, R³¹ can be hydrogen or a C₁-C₁₀ alkyl group. In some embodiments, each of R³² and R³³ can be independently selected from phenyl, biphenyl, terphenyl, naphthyl, phenanthrenyl, dibenzofuranyl and dibenzothiophenyl each of which is independently unsubstituted or substituted with at least one of C₁-C₁₀ alkyl and C₆-C₃₀ aryl. In some embodiments, each of L³¹ to L³³ can be independently the single bond, a phenylene group, a biphenylene group, a terphenylene group or a naphthylene group in Chemical Formula 8.

In another embodiment, R⁴¹ can be selected from phenyl, naphthyl, dibenzofuranyl and dibenzothiophenyl each of which is independently unsubstituted or substituted with at least one of C₁-C₁₀ alkyl and C₆-C₂₀ aryl, each of R⁴² and R⁴³ can be independently selected from phenyl, biphenyl, terphenyl and naphthyl, each of which is independently unsubstituted or substituted with at least one of C₁-C₁₀ alkyl and C₆-C₂₀ aryl, and/or each of L⁴¹ to L⁴³ is independently a single bond, a phenylene group, a biphenylene group, a terphenylene group or a naphthylene group in Chemical Formula 11.

The emissive layer can have a single emitting part, or multiple emitting parts to form a tandem structure.

In one embodiment, the emissive layer can include a first emitting part disposed between the first and second electrodes and including a first emitting material layer; a second emitting part disposed between the first emitting part and the second electrode and including a second emitting material layer; and a first charge generation layer disposed between the first emitting part and the second emitting part, and wherein at least one of the first emitting material layer and the second emitting material layer can include the first compound, the second compound, and optionally the third compound.

For example, the second emitting material layer can include a first layer disposed between the first charge generation layer and the second electrode; and a second layer disposed between the first layer and the second electrode, and wherein one of the first layer and the second layer includes the first compound, the second compound, and optionally the third compound.

In another embodiment, the emissive layer can further include a third emitting part disposed between the second emitting part and the second electrode and including a third emitting material layer; and a second charge generation layer disposed between the second emitting part and the third emitting part.

In another aspect, the present disclosure provides an organic light emitting device, for example, an organic light emitting display device or an organic light emitting illumination device, includes a substrate and the organic light emitting diode over the substrate.

In one or more embodiments, the at least one emitting material layer includes the first compound of phosphorescent material that can be an iridium-containing organometallic compound, the second compound of the first host, and optionally the third compound of the second host.

In one or more embodiments, the first compound as the organometallic compound includes a metal atom linked to multiple fused aromatic rings or fused hetero aromatic rings through a covalent bond or a coordination bond. The organometallic compound has very narrow full-width at half maximum, and thus shows beneficial color purity in emitting.

In one or more embodiments, the organometallic compound can be a heteroleptic metal complex wherein two or more different bidentate ligands are coordinated to the metal atom, so that the photoluminescence color purity and emission colors of the organometallic compound can be controlled by combining two different bidentate ligands.

The second compound has beneficial hole affinity property and/or hole transporting property, and the third compound has beneficial electron affinity property and/or electron transporting property. The first compound can be a phosphorescent material emitting red to green range light. As the at least one emitting material layer includes the first compound as the dopant, the second compound as the first host, and optionally the third compound as the second host, the luminescent color purity, luminous efficiency and/or luminous lifetime of the organic light emitting diode and the organic light emitting device can be improved.

In addition, the driving voltages of the organic light emitting diode and the organic light emitting device can be lowered by applying the first compound, the second compound, and optionally the third compound into an emissive layer. It is possible to realize and implement an environment-friendly organic light emitting diode and an organic light emitting device with lower power consumption by applying the first compound, the second compound, and optionally the third compound. It is possible to manufacture an organic light emitting diode and an organic light emitting device with realizing ESG (environmental, social and Governance) ideology using the first compound, the second compound, and optionally the third compound.

It is to be understood that both the foregoing general description and the following detailed description are merely by way of example, and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a cross-sectional view of an organic light emitting display device as an example of an organic light emitting device in accordance with an embodiment of the present disclosure.

FIG. 3 illustrates a cross-sectional view of an organic light emitting diode having a single emitting part in accordance with an embodiment of the present disclosure.

FIG. 4 illustrates a cross-sectional view of an organic light emitting display device in accordance with another embodiment of the present disclosure.

FIG. 5 illustrates a cross-sectional view of an organic light emitting diode with two emitting parts forming a tandem structure in accordance with another embodiment of the present disclosure.

FIG. 6 illustrates a cross-sectional view of an organic light emitting diode with three emitting parts forming a tandem structure in accordance with another embodiment of the present disclosure.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

The luminous efficiency and/or the luminous lifespan of an organic light emitting diode where a first compound of phosphorescent material and second and/or third compounds of host is applied to an emissive layer can be improved. As an example, the emissive layer including the first compound, the second compound, and optionally the third compound can be applied to an organic light emitting diode with a single emitting part in a red pixel region, a green pixel region and/or a blue pixel region. Alternatively, the emissive layer including the first compound, the second compound, and optionally the third compound can be applied to an organic light emitting diode of having a tandem structure where at least two emitting parts are stacked.

The organic light emitting diode where an emissive layer includes the first compound, the second compound, and optionally the third compound can be applied to an organic light emitting device such as an organic light emitting display device or an organic light emitting illumination device. As an example, an organic light emitting display device will be described.

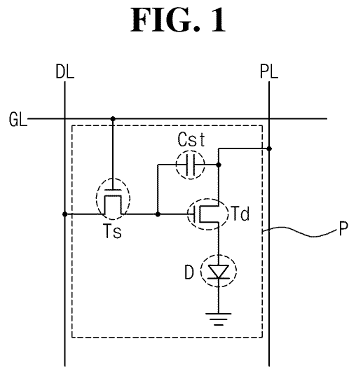

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

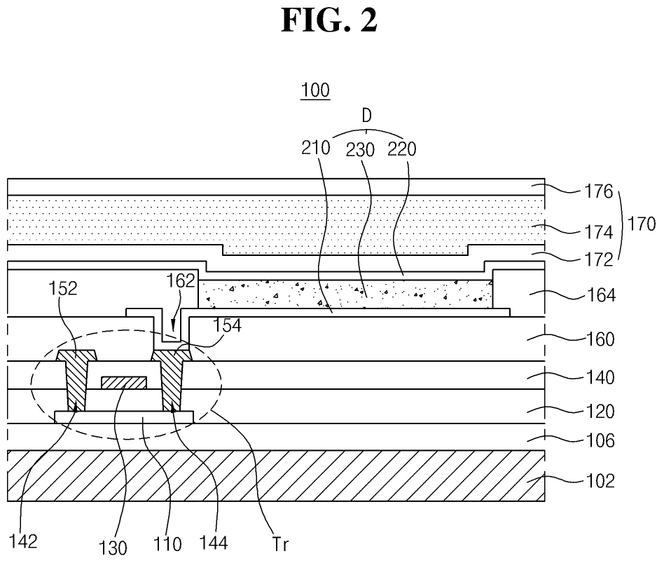

The driving thin film transistor Td is turned on by the data signal applied to the gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 includes a substrate 102, a thin-film transistor Tr disposed on the substrate 102, and an organic light emitting diode D connected to the thin film transistor Tr.

As an example, the substrate 102 can include a red pixel region, a green pixel region and a blue pixel region and an organic light emitting diode D can be located in each pixel region. Each of the organic light emitting diodes D emitting red, green and blue light, respectively, is located correspondingly in the red pixel region, the green pixel region and the blue pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can include, but is not limited to, oxide semiconductor materials. In this case, a light-shield pattern may be disposed under the semiconductor layer 110, and the light-shield pattern can prevent light from being incident toward the semiconductor layer 110, and thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on an entire area of the substrate 102 as shown in FIG. 2, the gate insulating layer 120 may be patterned identically as the gate electrode 130.

An interlayer insulating layer 140 including an insulating material is disposed on the gate electrode 130 with and covers an entire surface of the substrate 102. The interlayer insulating layer 140 can include, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface closer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr may further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

One of the first electrode 210 and the second electrode 220 can be an anode, and the other of the first electrode 210 and the second electrode 220 can be a cathode. One of the first electrode 210 and the second electrode 220 can be a reflective electrode, and the other of the first electrode 210 and the second electrode 220 can be a transmissive electrode.

The first electrode 210 is disposed in each pixel region. As an example, the first electrode 210 can be an anode. The first electrode 210 can include conductive material having relatively high work function value. For example, the first electrode 210 can include a transparent conductive oxide (TCO).

In one embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer may be disposed under the first electrode 210. For example, the reflective electrode or the reflective layer can include, but is not limited to, silver (Ag) or aluminum-palladium-copper (APC) alloy. As an example, in the OLED D of the top-emission type, the first electrode 210 can have, but is not limited to, a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. In certain embodiments, the bank layer 164 can be omitted.

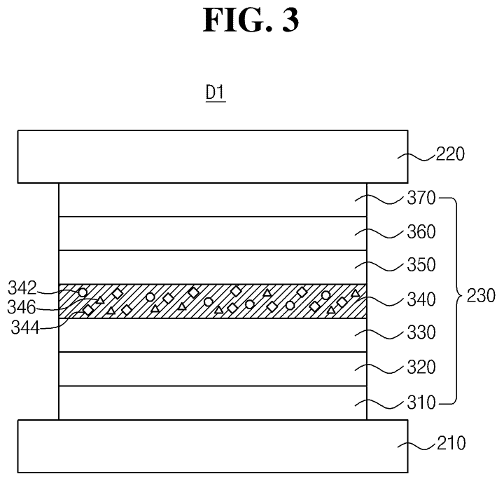

An emissive layer 230 is disposed on the first electrode 210. In one embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3).

In one embodiment, the emissive layer 230 can have a single emitting part. Alternatively, the emissive layer 230 can have multiple emitting parts to form a tandem structure. For example, the emissive layer 230 can be applied to an OLED with a single emitting part located each of the red pixel region, the green pixel region and the blue pixel region. Alternatively, the emissive layer 230 can be applied to a tandem-type OLED where at least two emitting parts are stacked.

The emissive layer 230 can include a first compound 342 (FIG. 3) of phosphorescent material, a second compound 344 (FIG. 3) of a first host, and optionally a third compound 346 (FIG. 3) of a second host. The luminous efficiency and the luminous lifespan of the OLED D and the organic light emitting display device 100 can be improved by including the first compound 342, the second compound 344, and optionally the third compound 346.

The second electrode 220 is disposed on the substrate 102 above which the emissive layer 230 is disposed. The second electrode 220 can be disposed on an entire display area. The second electrode 220 can include a conductive material with a relatively low work function value compared to the first electrode 210. The second electrode 220 can be a cathode providing electrons. When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. In certain embodiments, the encapsulation film 170 can be omitted.

A polarizing plate can be attached onto the encapsulation film 170 to reduce reflection of external light. For example, the polarizing plate may be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window may have a flexible property, thus the organic light emitting display device 100 may be a flexible display device.

The OLED D is described in more detail. FIG. 3 illustrates a schematic cross-sectional view of an organic light emitting diode having a single emitting part in accordance with an embodiment of the present disclosure.

As illustrated in FIG. 3, the organic light emitting diode (OLED) D1 in accordance with the present disclosure includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region and/or the green pixel region.

In an embodiment, the emissive layer 230 includes an emitting material layer (EML) 340 disposed between the first and second electrodes 210 and 220. Also, the emissive layer 230 can include at least one of an HTL 320 disposed between the first electrode 210 and the EML 340 and an ETL 360 disposed between the second electrode 220 and the EML 340. In addition, the emissive layer 230 can further include at least one of an HIL 310 disposed between the first electrode 210 and the HTL 320 and an EIL 370 disposed between the second electrode 220 and the ETL 360. Alternatively or additionally, the emissive layer 230 can further comprise a first exciton blocking layer, i.e. an EBL 330 disposed between the HTL 320 and the EML 340 and/or a second exciton blocking layer, i.e. a HBL 350 disposed between the EML 340 and the ETL 360.

The first electrode 210 can be an anode proving holes to the EML 340. The first electrode 210 can include conductive material having relatively high work function value. For example, the first electrode 210 can include a TCO. As an example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or the like.

The second electrode 220 can be a cathode proving electrons to the EML 340. For example, the second electrode 220 can include at least one of, but is not limited to, aluminum (Al), magnesium (Mg), calcium (Ca), silver (Ag), alloy thereof and/or combinations thereof such as aluminum-magnesium alloy (Al—Mg).

The HIL 310 is disposed between the first electrode 210 and the HTL 320 and can improve an interface property between the inorganic first electrode 210 and the organic HTL 320. In one embodiment, hole injecting material in the HIL 310 can include, but is not limited to, 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB; NPD), N,N′-bis{4-[bis(3-methylphenyl)amino]phenyl}-N,N′ diphenyl-4,4′-biphenyldiamine (DNTPD), 1,4,5,8,9,11-hexaazatriphenylenchexacarbonitrile (dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracaynonaphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and/or combinations thereof.

In another embodiment, the HIL 310 can include a hole injection host chosen from the following hole transporting material and a hole injection dopant chosen from the above hole injecting material (e.g., HAT-CN, F4-TCNQ and/or F6-TCNNQ). In this case, the contents of the hole injection dopant in the HIL 310 can be, but is not limited to, about 1 wt. % to about 10 wt. %. In certain embodiments, the HIL 310 can be omitted in compliance of the OLED D1 property.

The HTL 320 is disposed adjacently to the EML 340 between the first electrode 210 and the EML 340. In one embodiment, hole transporting material in the HTL 320 can include, but is not limited to, N,N′-diphenyl-N,N′-bis(3-methylphenyl)-1,1′-biphenyl-4,4′-diamine (TPD), NPB (NPD), DNTPD, 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl) biphenyl-4-amine), N-([1,1′-biphenyl]-4-yl)-9,9-dimethyl-N-(4-(9-phenyl-9H-carbazol-3-yl)phenyl)-9H-fluoren-2-amine and/or combinations thereof.

The EML 340 can include the first compound 342, the second compound 344, and optionally the third compound 346. The first compound can be a dopant (emitter) where ultimate light emission occurs, and each of the second compound 344 and the third compound 346 can be a host.

The first compound 342 can be phosphorescent material of an organometallic compound that can emit red to green color light. The first compound 342 has a rigid chemical configuration so as to improve the luminous efficiency and luminous lifespan of the organic light emitting diode D1 and the organic light emitting device 100. The first compound 342 can have the structure of Chemical Formula 1:

Ir(L_{A})ₘ(L_{B})ₙ. [Chemical Formula 1]
wherein:
L_{A} is a ligand having the structure of Chemical Formula 2:

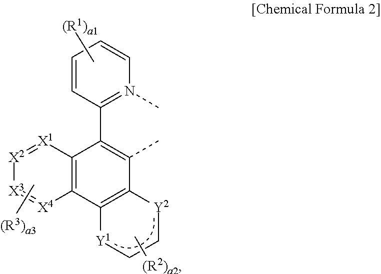

wherein:
each of X¹ to X⁴ is independently CR³ or N, wherein at least one of X¹ to X⁴ is CR³;
one of Y¹ and Y² is a single bond and the other is CR⁴R⁵, NR⁴, O or S;
each of R¹ to R⁵ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R¹ is identical to or different from each other when a1 is 2, 3, or 4, wherein each R² is identical to or different from each other when a2 is 2, and wherein each R³ is identical to or different from each other when a3 is 2, 3 or 4, or
optionally,
two adjacent R¹ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a1 is 2, 3, or 4, and/or
two adjacent R² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a2 is 2,
two adjacent R³ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a3 is 2, 3 or 4, and/or
R⁴ and R⁵ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring;
each of a1 and a3 is independently 0, 1, 2, 3, or 4;
a2 is 0, 1, or 2;
L_{B} is an auxiliary ligand;
m is 1, 2 or 3;
n is 0, 1 or 2; and
m+n is 3.

As used herein, the term “unsubstituted” means that hydrogen is directly linked to an atom. “Hydrogen”, as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy group, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, an unsubstituted or halogen-substituted C₁-C₁₀ alkyl silyl group, an unsubstituted or halogen-substituted C₁-C₁₀ alkoxy silyl group, an unsubstituted or halogen-substituted C₃-C₂₀ cyclo alkyl silyl group, an unsubstituted or halogen-substituted C₆-C₃₀ aryl silyl group, a C₃-C₃₀ hetero aryl silyl group, an unsubstituted or halogen- or C₁-C₂₀ alkyl-substituted C₆-C₃₀ aryl group, an unsubstituted or halogen- or C₁-C₂₀ alkyl-substituted C₂-C₃₀ hetero aryl group.

As used herein, the term “hetero” in terms such as “a hetero aromatic group”, “a hetero cyclo alkylene group”, “a hetero arylene group”, “a hetero aralkylene group”, “a hetero aryl oxylene group”, “a hetero cyclo alkyl group”, “a hetero aryl group”, “a hetero aralkyl group”, “a hetero aryloxy group”, “a hetero aryl amino group” and the likes means that at least one carbon atom, for example 1 to 5 carbons atoms, constituting an aliphatic chain, an alicyclic group or ring or an aromatic group or ring is substituted with at least one heteroatom selected from the group consisting of N, O, S and P.

As used herein, the C₆-C₃₀ aryl group can comprise, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

As used herein, the C₂-C₃₀ hetero aryl group can comprise, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

Each of the C₆-C₃₀ arylene group and the C₂-C₃₀ hetero arylene group can be a bivalent organic group corresponding to each of the C₆-C₃₀ aryl group and the C₂-C₃₀ hetero aryl group. For example, the C₆-C₃₀ arylene group can be selected from, but is not limited to, the group consisting of phenylene, biphenylene, terphenylene, tetraphenylene, indenylene, naphthylene, azulenylene, indacenylene, acenaphthylene, fluorenylene, spiro-fluorenylene, phenalenylene, phenanthrenylene, anthracenylene, fluoranthrenylene, triphenylenylene, pyrenylene, chrysenylene, naphthacenylene, picenylene, perylenylene, pentaphenylene and hexacenylene. For example, the C₂-C₃₀ hetero arylene group can be selected from, but is not limited to, the group consisting of pyrrolylene, imidazolylene, pyrazolylene, pyridinylene, pyrazinylene, pyrimidinylene, pyridazinylene, isoindolylene, indolylene, indazolylene, purinylene, quinolinylene, isoquinolinylene, phthalazinylene, naphthyridinylene, quinoxalinylene, quinazolinylene, benzo-quinolinylene, benzo-isoquinolinylene, benzo-quinoxalinylene, benzo-quinoxalinylene, benzo-quinazolinylene, cinnolinylene, phenanthridinylene, acridinylene, phenanthrolinylene, phenazinylene, benzoxazolylene, benzimidazolylene, furanylene, benzo-furanylene, thiophenylene, benzo-thiophenylene, thiazolylene, isothiazolylene, benzo-thiazolylene, isoxazolylene, oxazolylene, triazolylene, tetrazolylene, oxadiazolylene, triazinylene, dibenzo-furanylene, dibenzo-thiophenylene, carbazolylene, benzo-carbazolylene, dibenzo-carbazolylene, indolo-carbazolylene, indeno-carbazolylene, imidazo-pyrimidinylene and imidazopyridinylene.

As an example, each of the aryl group or aromatic group, or the hetero aryl group or hetero aromatic group of R¹ to R³ in Chemical Formula 2 can consist of one to three aromatic and/or hetero aromatic rings. With the increase of the number of the aromatic and/or hetero aromatic rings of R¹ to R³, conjugated structure within the whole molecule becomes elongates, thus, endowing the organometallic compound with narrow energy bandgap. For example, each of the aryl group or the hetero aryl group of R¹ to R³ can comprise independently, but not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

Alternatively, two adjacent R¹ when a1 is 2, 3 or 4, two adjacent R² when a2 is 2, two adjacent R³ when a3 is 2, 3 or 4, and/or R⁴ and R⁵ can be further linked together to form an unsubstituted or substituted C₄-C₃₀ alicyclic ring (e.g., a C₅-C₁₀ alicyclic ring), an unsubstituted or substituted C₃-C₃₀ hetero alicyclic ring (e.g. a C₃-C₁₀ hetero alicyclic ring), an unsubstituted or substituted C₆-C₂₀ aromatic ring (e.g. a C₆-C₁₀ aromatic ring) and/or an unsubstituted or substituted C₃-C₂₀ hetero aromatic ring (e.g. a C₃-C₁₀ hetero aromatic ring).

The alicyclic ring, the hetero alicyclic ring, the aromatic ring and the hetero aromatic ring formed by two adjacent R¹, two adjacent R², two adjacent R³ and/or R⁴ and R⁵ are not limited to specific rings. For example, the aromatic ring or the hetero aromatic ring formed by those groups can comprise, but is not limited to, a benzene ring, a pyridine ring, an indene ring, an indole ring, a pyran ring, a furan ring, a thiophene ring, a benzofuran ring, a benzothiophene ring, or a fluorene ring, each can be unsubstituted or substituted with at least one of a C₁-C₁₀ alkyl group, a C₆-C₂₀ aryl group and a C₂-C₂₀ hetero aryl group.

The first compound 342 having the structure of Chemical Formula 1 has at least one ligand of fused system with multiple aromatic and/or hetero aromatic rings. The organometallic compound having the structure of Chemical Formula 1 can have a narrow FWHM (Full-width at half maximum) in the luminescence spectrum. In addition, the organometallic compound having the structure of Chemical Formula 1 has a rigid chemical configuration, so that it is difficult to change its conformation in the luminous process, and therefore, the organometallic compound can maintain adequate luminous lifespan. The organometallic compound can have specific ranges of photoluminescence emissions, so that its color purity can be improved.

In one embodiment, each of m (the number of the main ligands L_{A}) and n (the number of the auxiliary ligands L_{B}) in the first compound 342 having the structure of Chemical Formula 1 can be 1 or 2, respectively. In this case, the first compound 342 having the structure of Chemical Formula 1 can be a heteroleptic metal complex including two different bidentate ligands coordinated to the central metal atom. The photoluminescence color purity and emission colors of the first compound 342 can be controlled by combining two different bidentate ligands. In addition, it is possible to control the color purity and emission peaks of the first compound 342 by introducing various substituents to each of the ligands. As an example, the first compound 342 having the structure of Chemical Formula 1 can emit green to red colors, for example, yellow green to green color and can improve luminous efficiency of the organic light emitting diode D1.

In another embodiment, each R¹ in Chemical Formula 2 can independently comprise, but is not limited to, hydrogen, an unsubstituted or substituted C₁-C₂₀ alkyl group (e.g., methyl, ethyl, iso-propyl or tert-butyl), an unsubstituted or substituted C₆-C₃₀ aryl group (e.g., phenyl, naphthyl), or an unsubstituted or substituted C₇-C₃₀ aralkyl group (e.g., methyl-phenyl or ethyl-phenyl). For example, each R¹ in Chemical Formula 2 can be independently, but is not limited to, hydrogen, a C₁-C₂₀ alkyl group, a C₆-C₃₀ aryl group or a C₇-C₃₀ aralkyl group, where each of the C₆-C₃₀ aryl group and the C₇-C₃₀ aralkyl group can be unsubstituted or further substituted with at least one of a C₁-C₁₀ alkyl group (e.g., methyl, ethyl or tert-butyl) and a C₆-C₂₀ aryl group (e.g., phenyl).

In another embodiment, each of R² and R³ in the Chemical Formula 2 can independently comprise, but is not limited to, hydrogen or an unsubstituted or substituted C₁-C₂₀ alkyl group (e.g., methyl, ethyl, iso-propyl, or tert-butyl). For example, each of R² and R³ in the Chemical Formula 2 can be independently, but is not limited to, hydrogen or a C₁-C₂₀ alkyl group.

In another embodiment, Y² can be a single bond and Y¹ can be CR⁴R⁵, NR⁴, O or S in the Chemical Formula 2 that can be the L_{A} in the Chemical Formula 1. The main ligand L_{A} with such a configuration can have the structure of Chemical Formula 3:

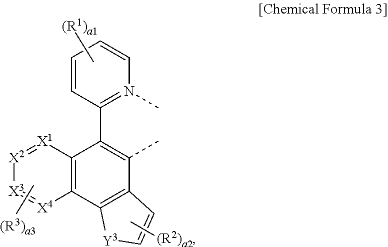

wherein:
Y³ is CR⁴R⁵, NR⁴, O or S; and
each of X¹ to X⁴, R¹ to R⁵, a1, a2 and a3 is as defined in Chemical Formula 2.

In another embodiment, Y² can be a single bond, Y¹ can be NR⁴, O or S, and/or at least two of X¹ to X⁴ can be CR³ and at least one of X¹ to X⁴ can be N in the Chemical Formula 2 that can be the L_{A} in the Chemical Formula 1. As an example, three of X¹ to X⁴ can be CR³ and one of X¹ to X⁴ can be N in the Chemical Formula 2. The main ligand L_{A} with such a conformation can have the structure of Chemical Formula 4:

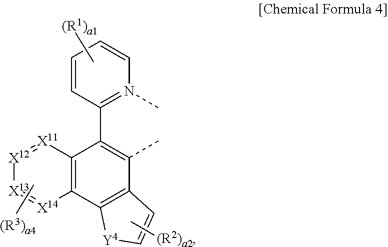

wherein:
each of X¹¹ to X¹⁴ is independently CR³ or N, wherein at least two of X¹¹ to X¹⁴ are CR³, and at least one of X¹¹ to X¹⁴ is N;
Y⁴ is NR⁴, O or S;
a4 is 0, 1, 2, or 3; and
each of R¹ to R⁴, a1 and a2 is as defined in Chemical Formula 2.

In another embodiment, Y² can be a single bond, Y¹ can be O or S, and/or three of X¹ to X⁴ can be CR³ and one of X¹ to X⁴ can be N in the Chemical Formula 2 that can be the L_{A} in the Chemical Formula 1. As an example, the main ligand L_{A} with such a configuration can have the structure of Chemical Formula 5:

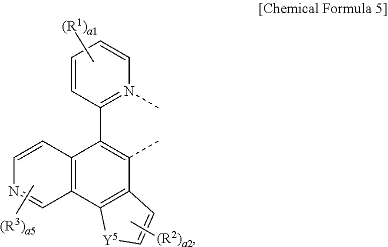

wherein:
Y⁵ is O or S;
a5 is 0, 1, 2 or 3; and
each of R¹ to R³, a1 and a2 is as defined in Chemical Formula 2.

The L_{B} in Chemical Formula 1 can be any auxiliary ligand. In one embodiment, the L_{B} as the auxiliary ligand in Chemical Formula 1 can be a phenyl-pyridino-containing ligand or an acetylacetonate-containing ligand. The auxiliary ligand L_{B} with such a moiety can have the structure of Chemical Formula 6A or Chemical Formula 6B:

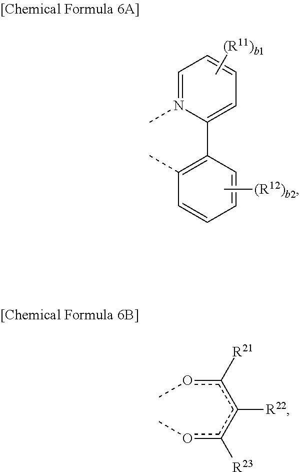

wherein:
each of R¹¹, R¹² and R²¹ to R²³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R¹¹ is identical to or different from each other when b1 is 2, 3 or 4, and wherein each R¹² is identical to or different from each other when b2 is 2, 3 or 4, or
optionally,
two adjacent R¹¹ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when b1 is 2, 3 or 4, and/or
two adjacent R¹² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when b2 is 2, 3 or 4, and/or
two adjacent groups among R²¹ to R²³ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring; and
each of b1 and b2 is independently 0, 1, 2, 3 or 4.

The substituents of R¹¹, R¹² and R²¹ to R²³ or the ring formed by R¹¹ to R¹², R²¹ and R²² and R²² and R²³, for example, the C₁-C₂₀ alkyl group, the C₆-C₃₀ aryl group, the C₂-C₃₀ hetero aryl group, the C₆-C₂₀ aromatic ring and the C₂-C₂₀ hetero aromatic ring, in the Chemical Formulae 6A and 6B can be identical to the substituents or the ring as described in Chemical Formulae 2 to 5. In one embodiment, each of R¹¹, R¹² and R²¹ to R²³ in Chemical Formulae 11A and 11B can be, but is not limited to, hydrogen or a C₁-C₂₀ alkyl group (e.g., C₁-C₁₀ alkyl group). In some embodiments, L_{A} in Chemical Formula 1 is chosen from:

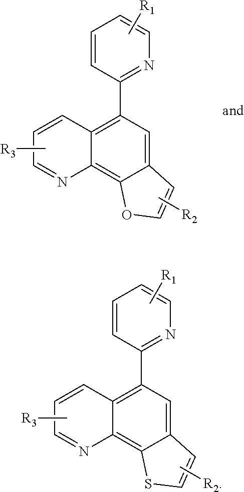

In some embodiments, R₁ in Chemical Formula 1 is chosen from:
H, CH₃, C₂H₅,

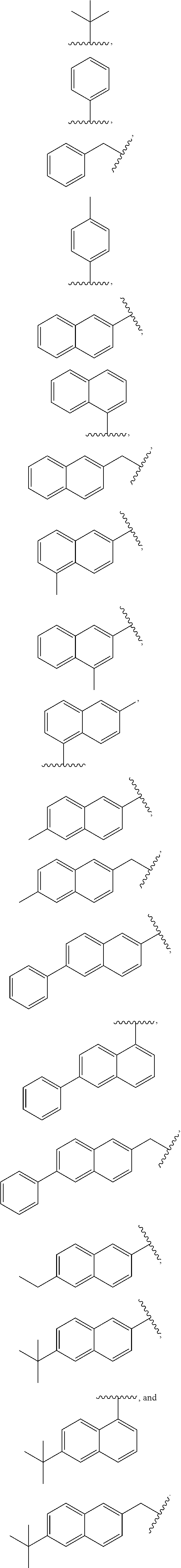

In some embodiments, R₂ in Chemical Formula 1 is hydrogen.

In some embodiments, R₃ in Chemical Formula 1 is chosen from:
H, CH₃,

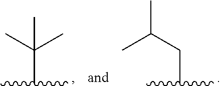

In some embodiments, L_{B} in Chemical Formula 1 is chosen from:

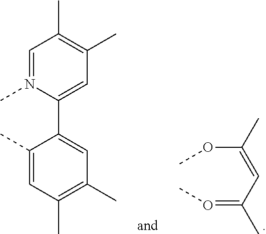

For example, the first compound 342 having the structure of Chemical Formula 1 can be at least one of or selected from, but is not limited to, the following organometallic compounds of Chemical Formula 7:

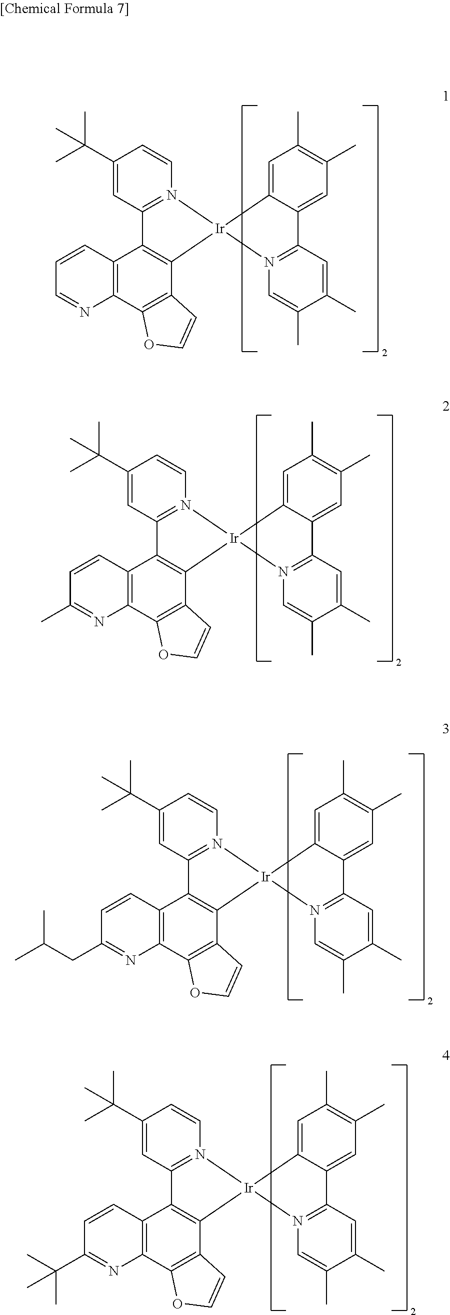

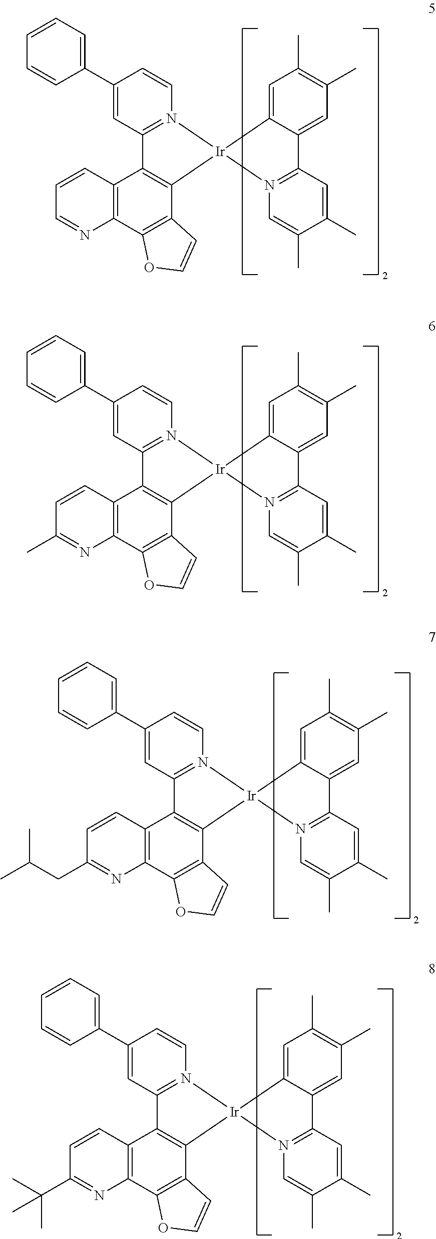

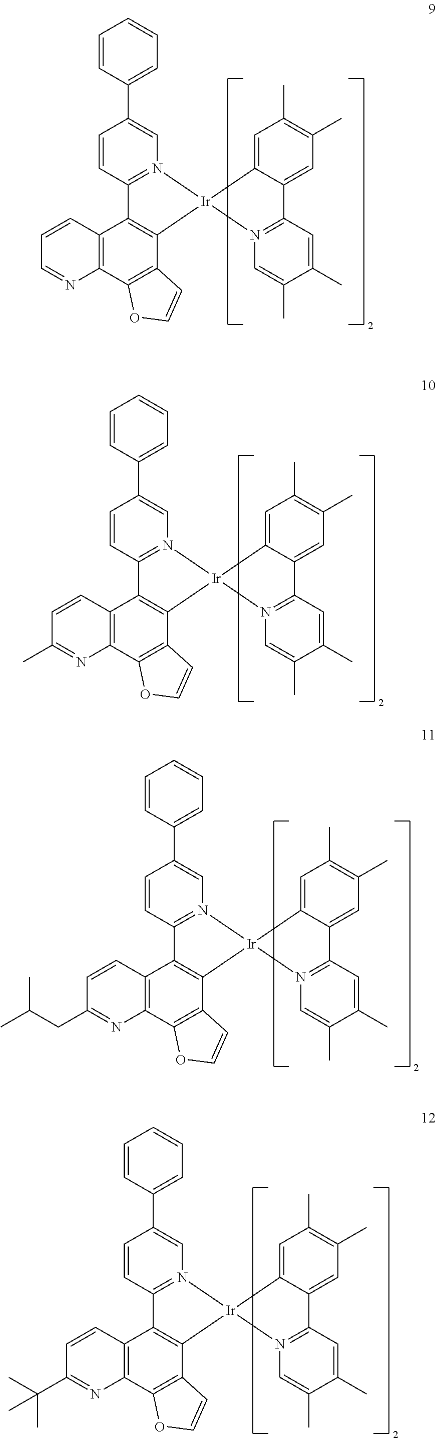

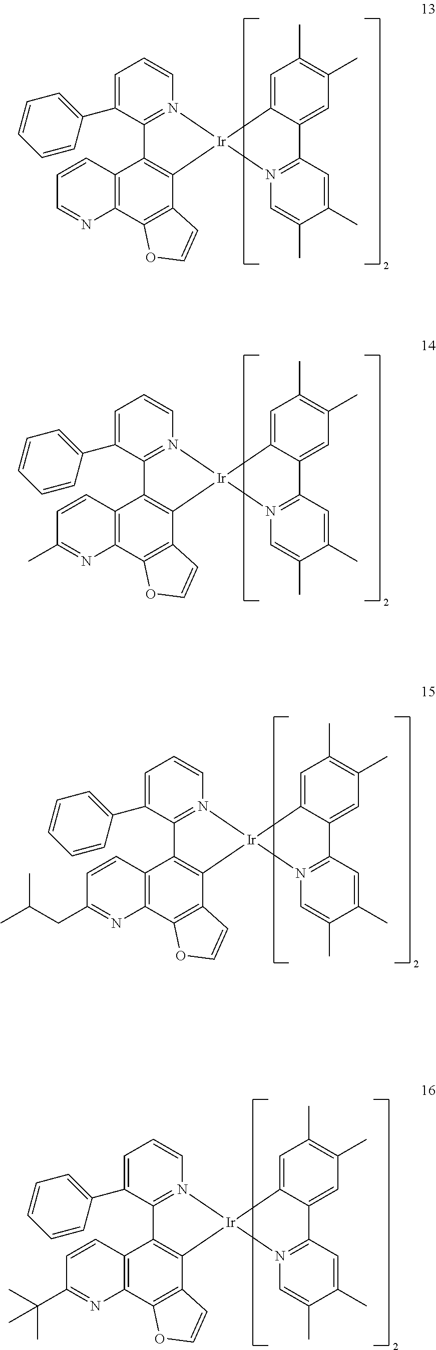

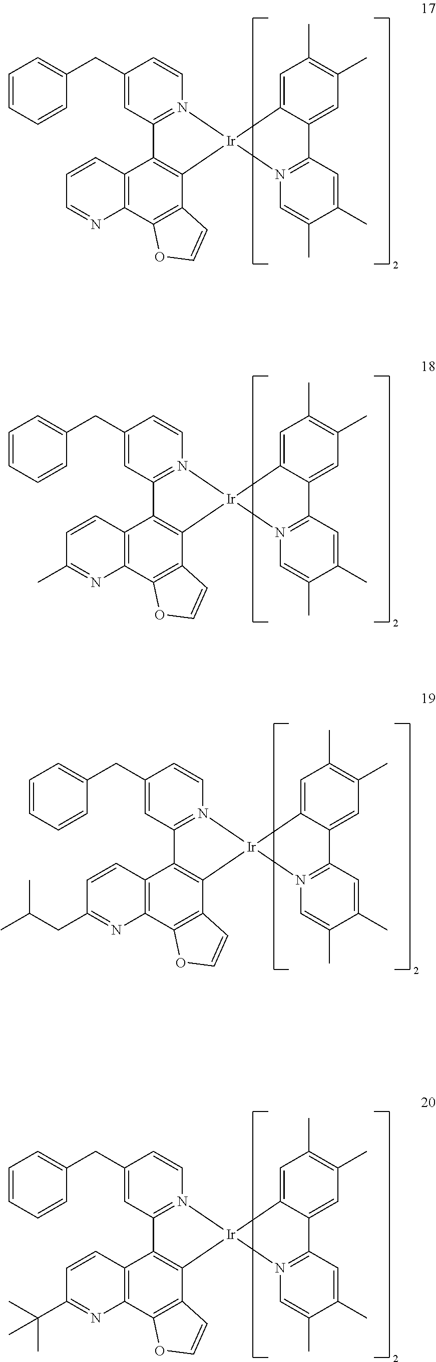

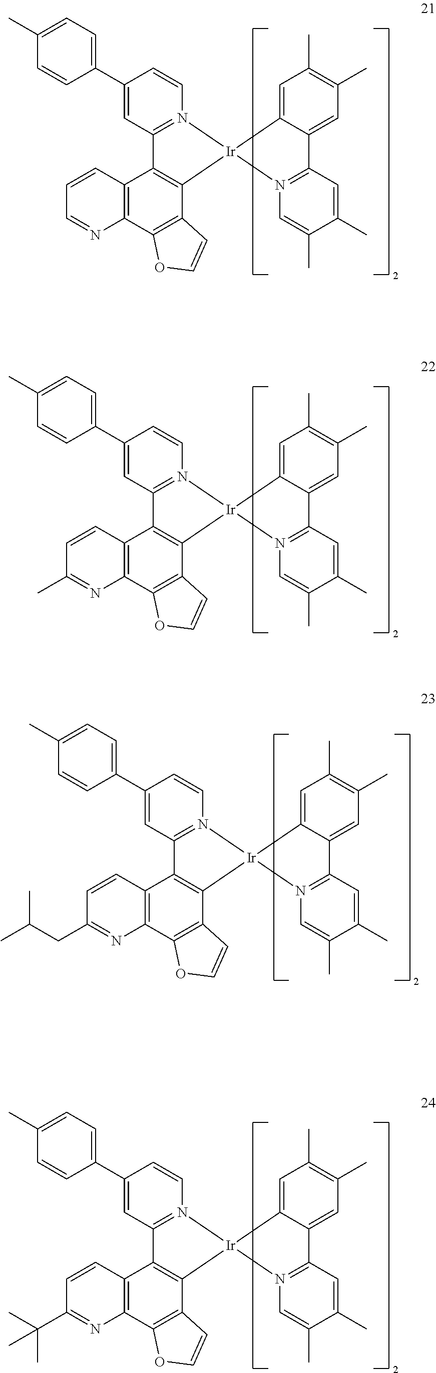

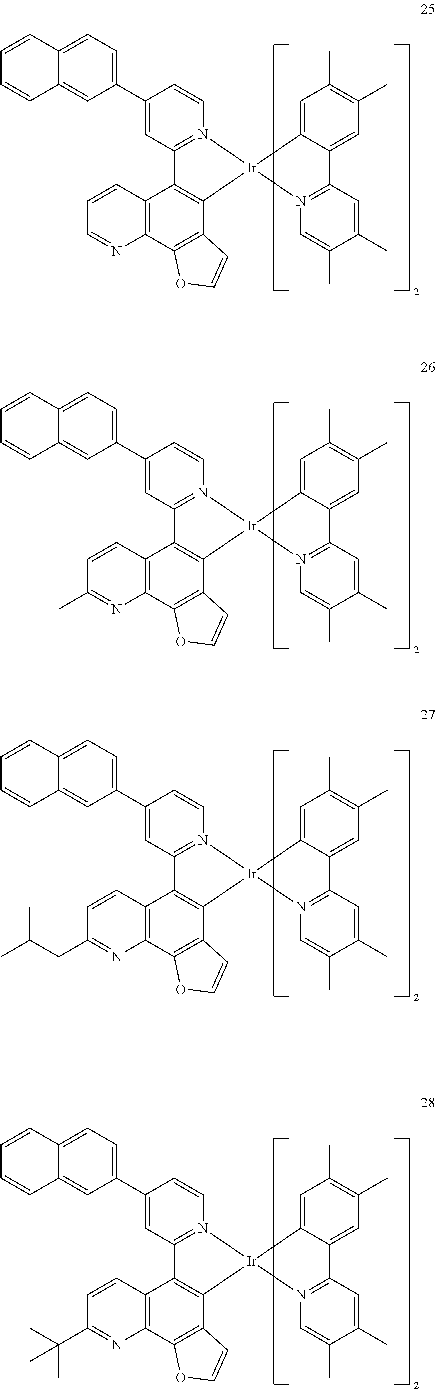

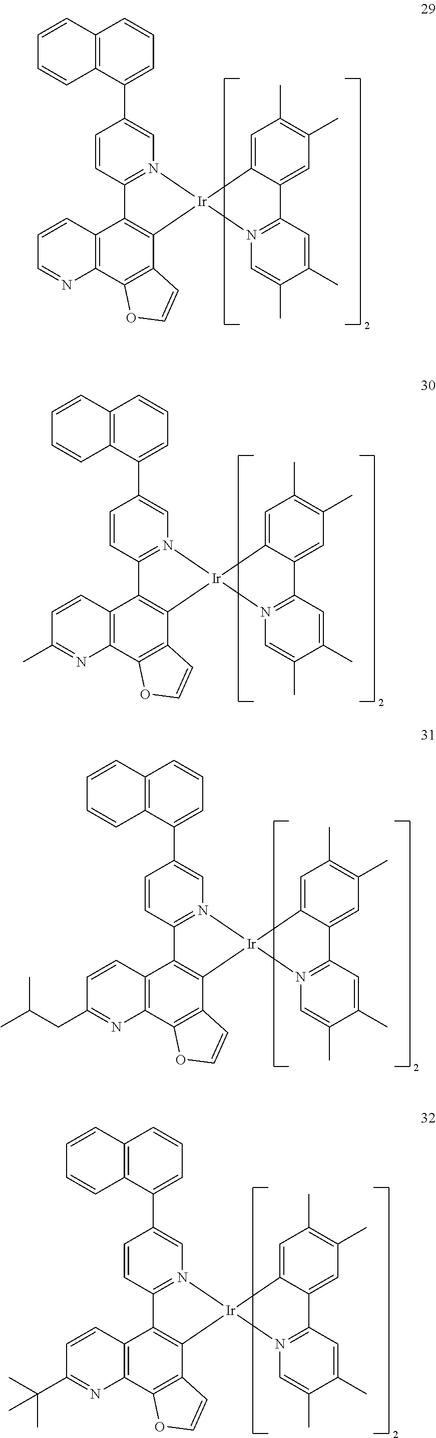

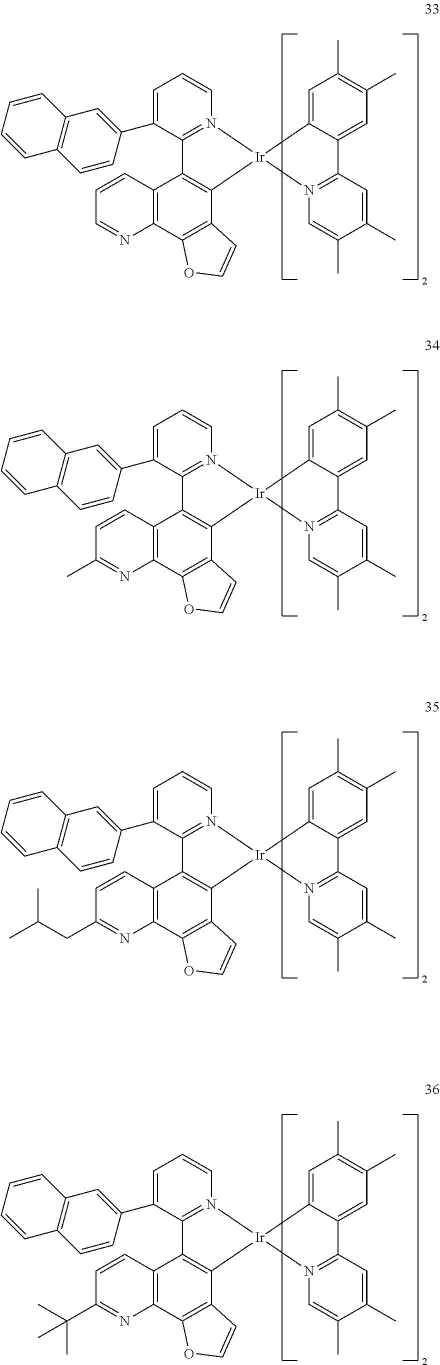

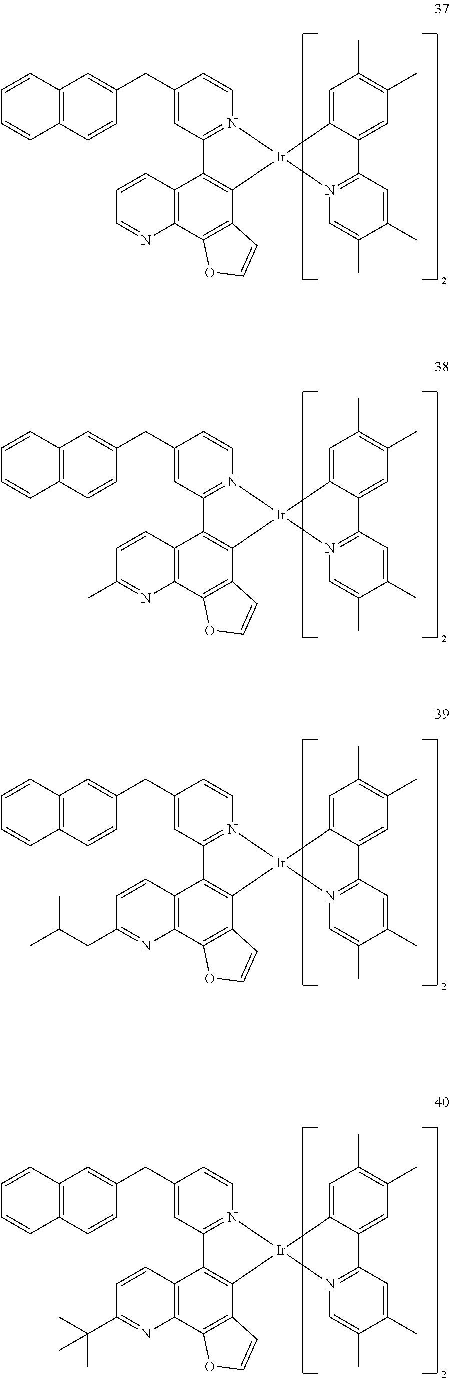

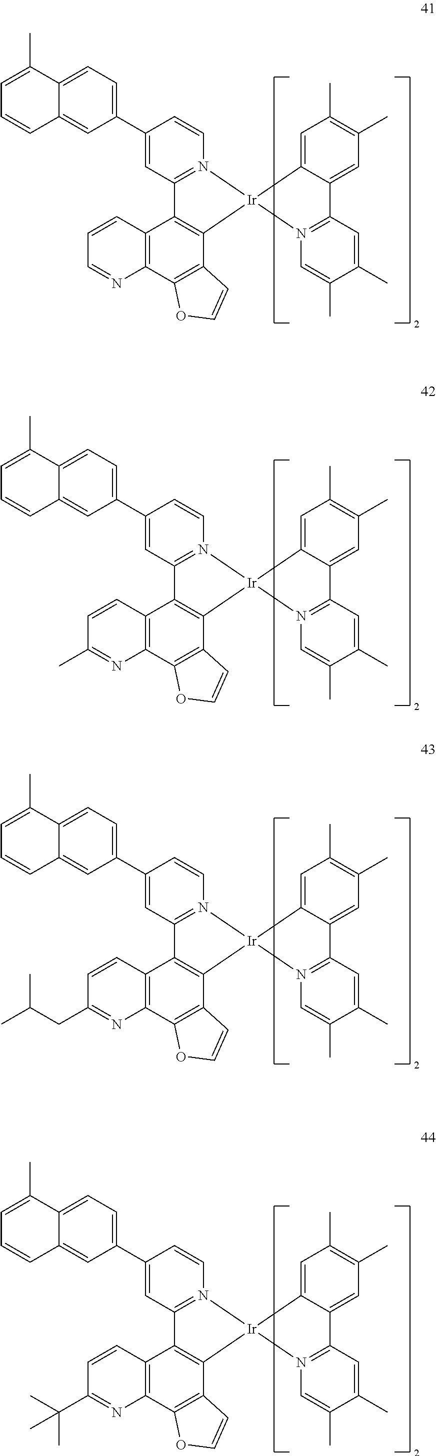

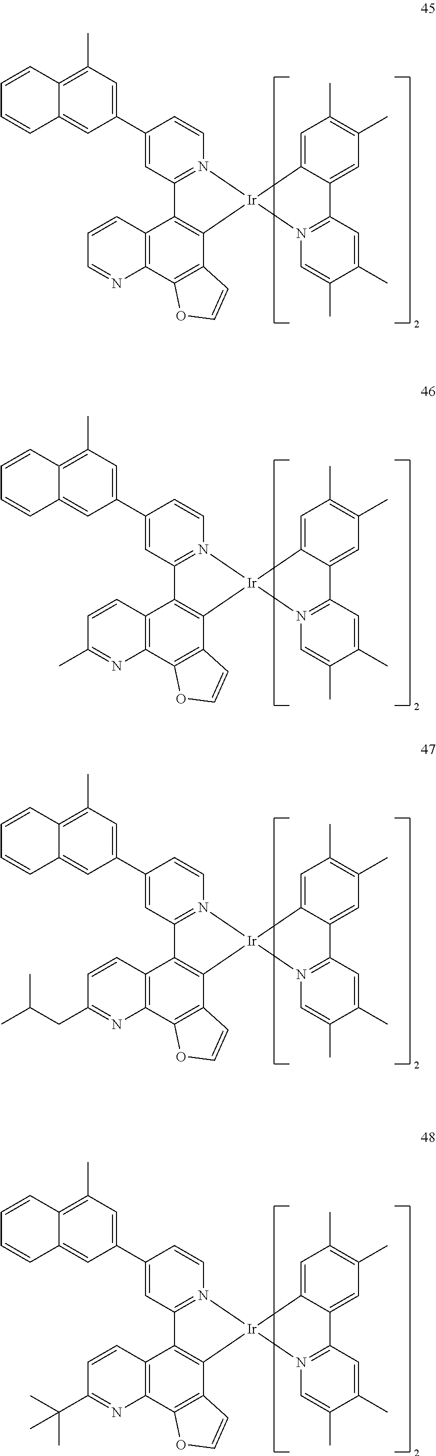

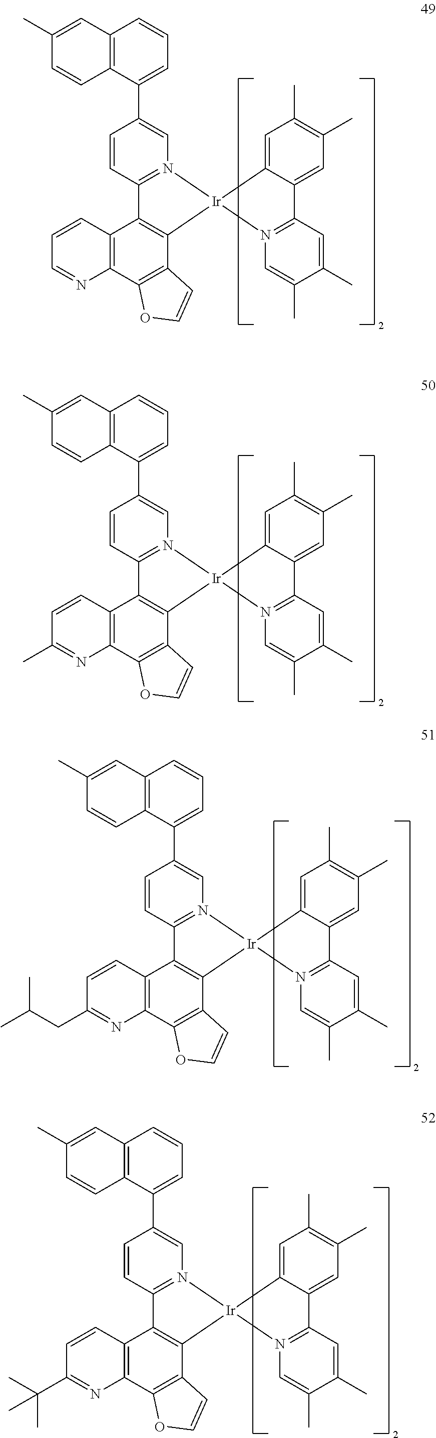

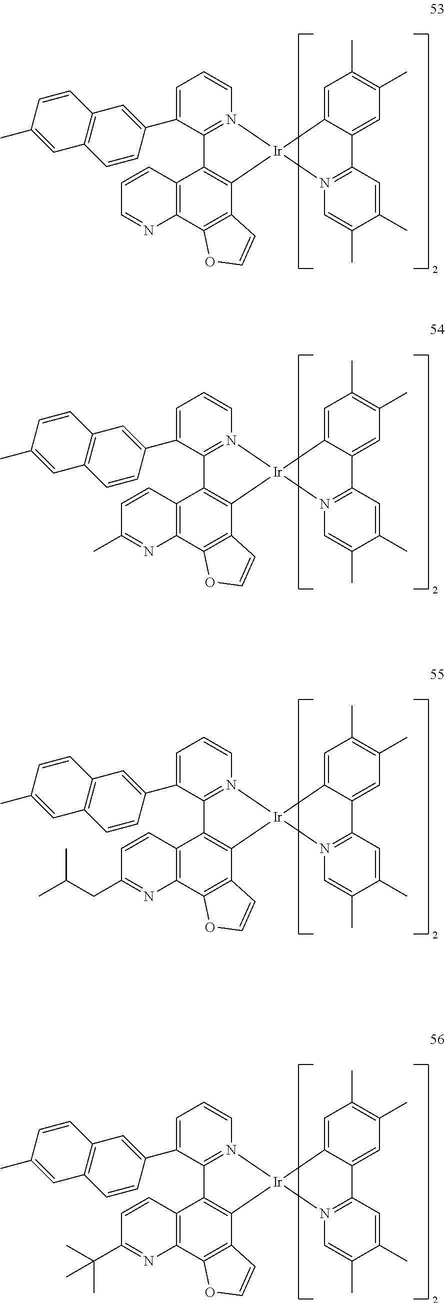

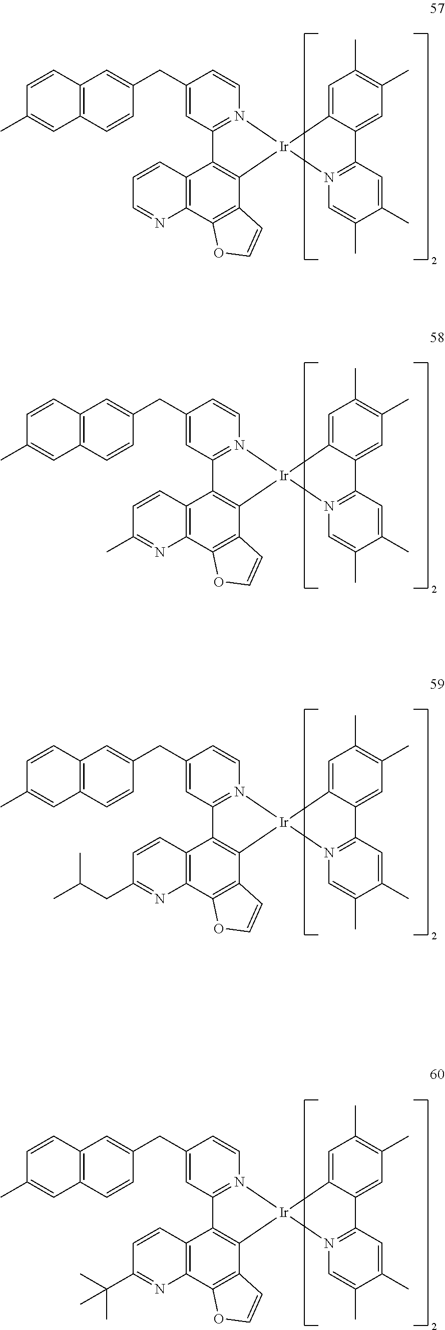

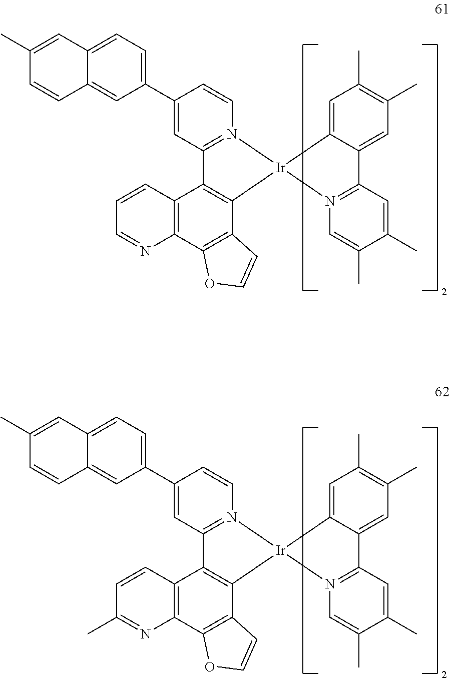

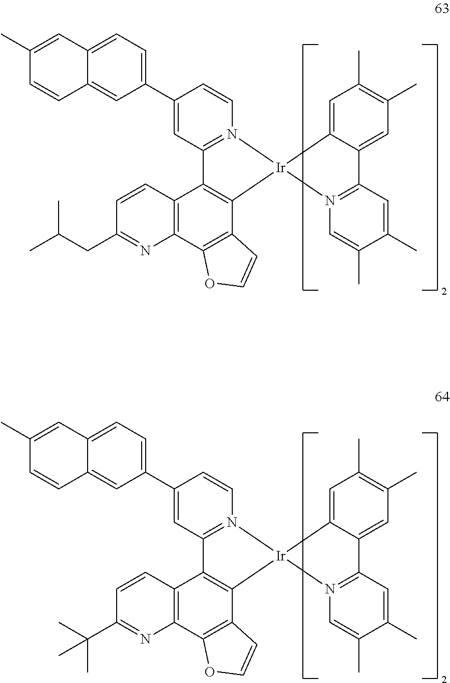

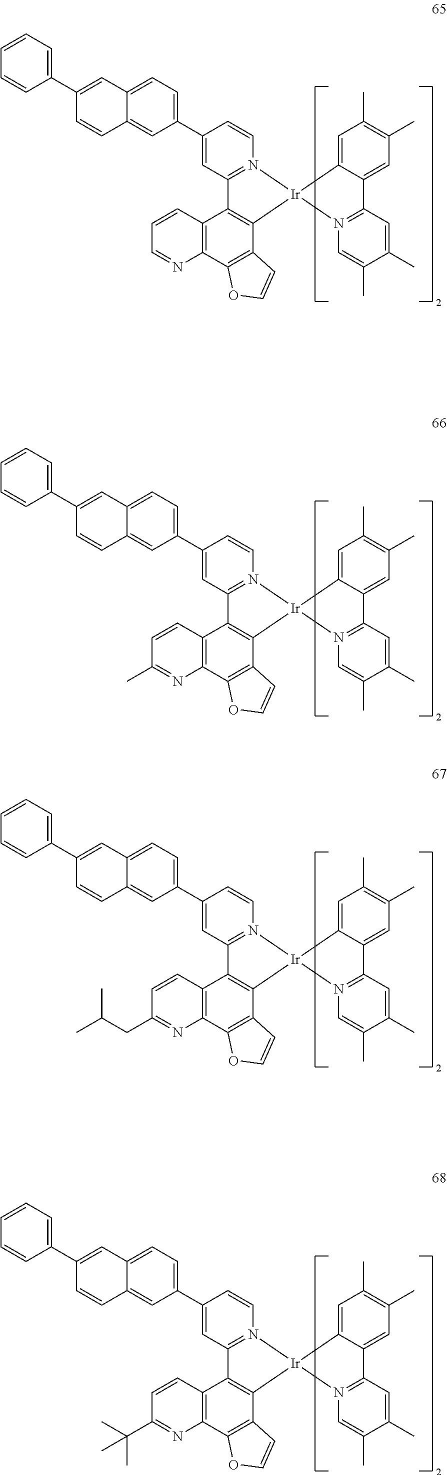

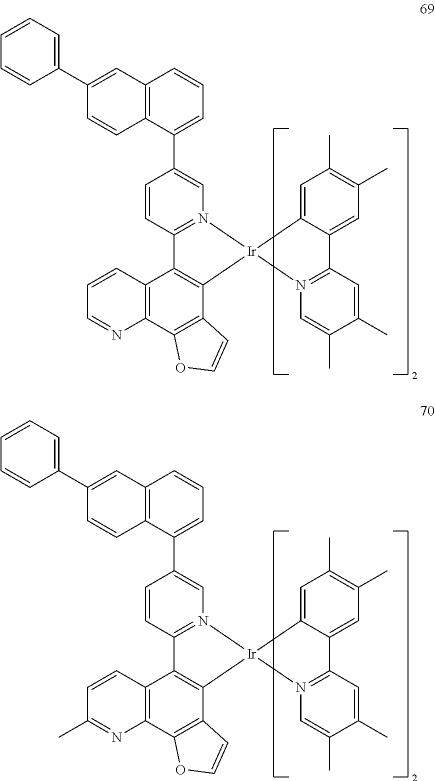

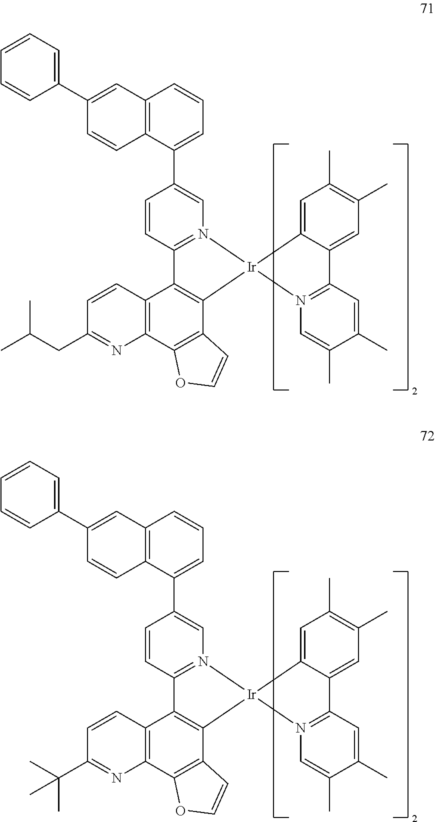

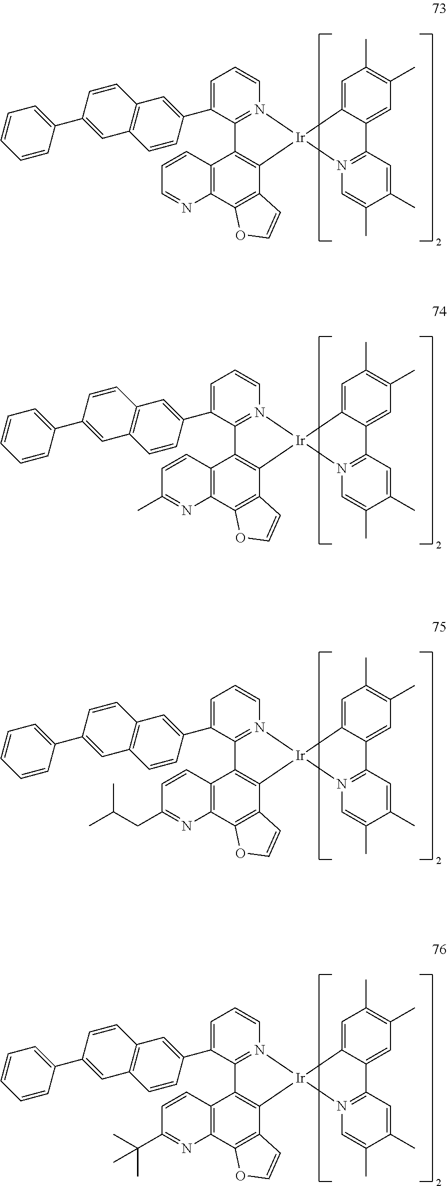

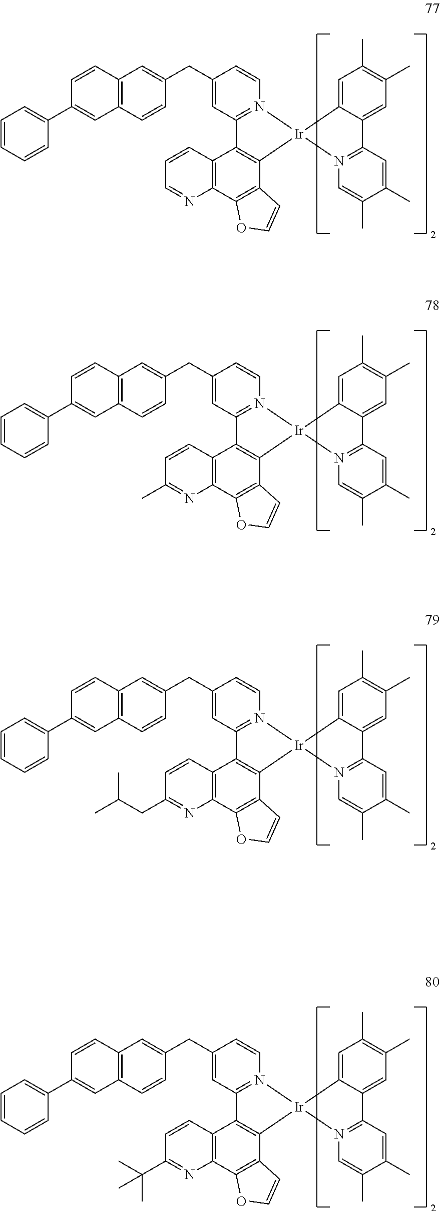

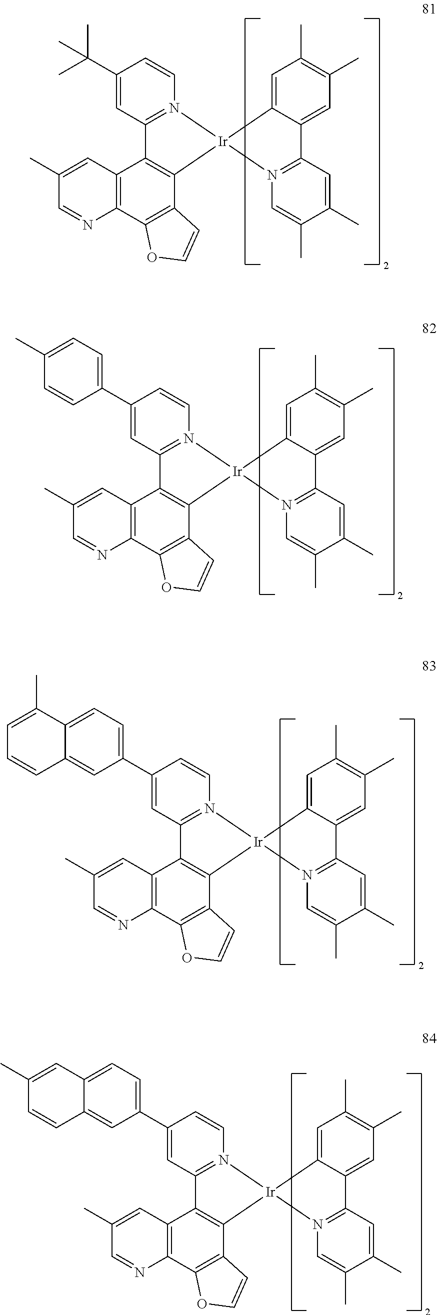

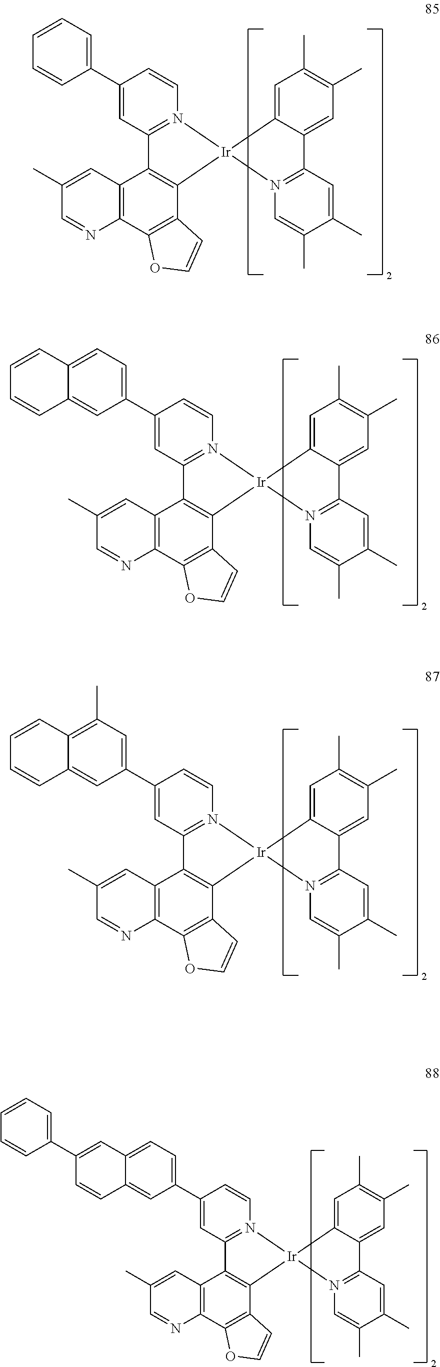

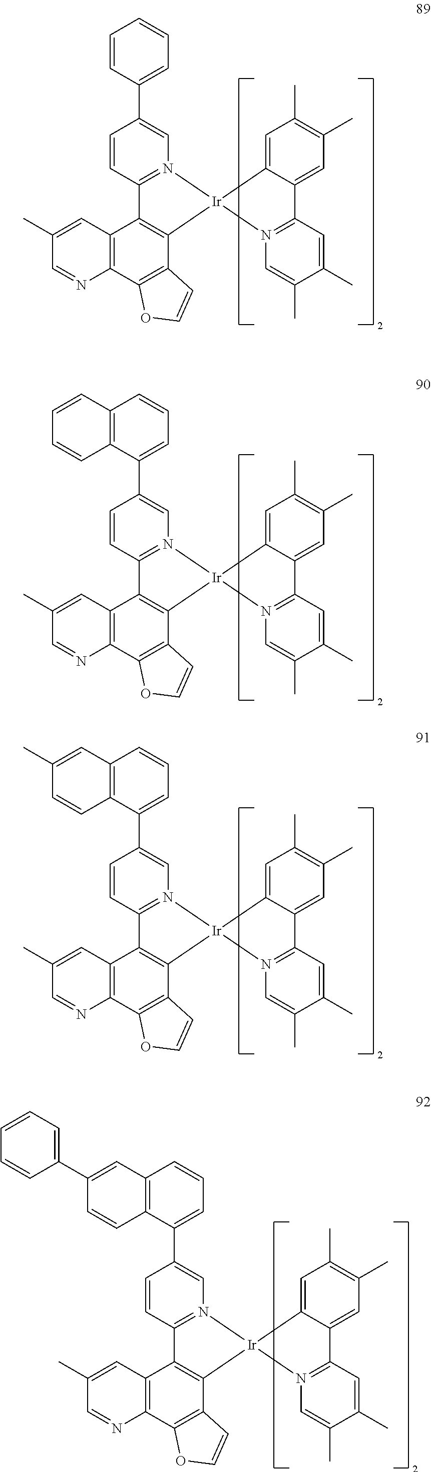

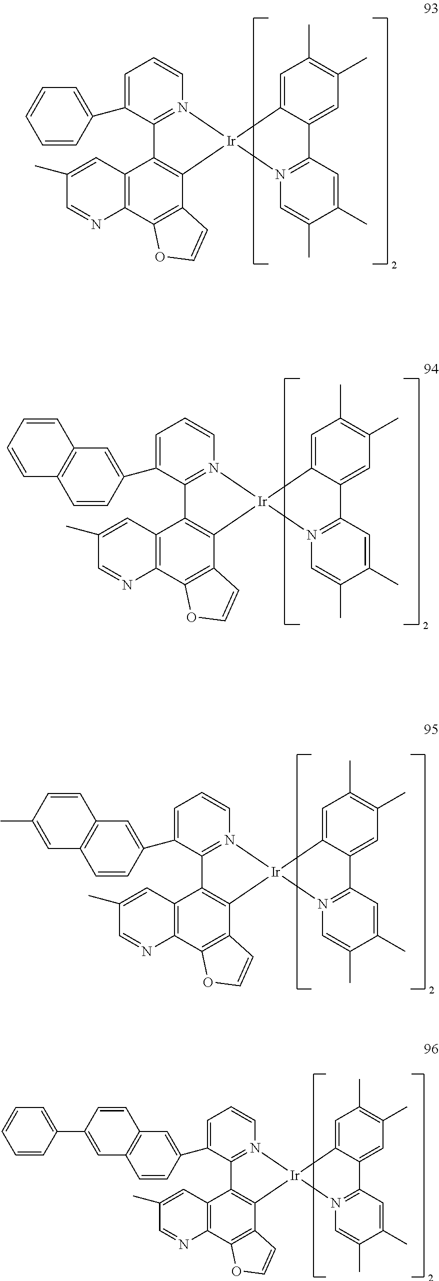

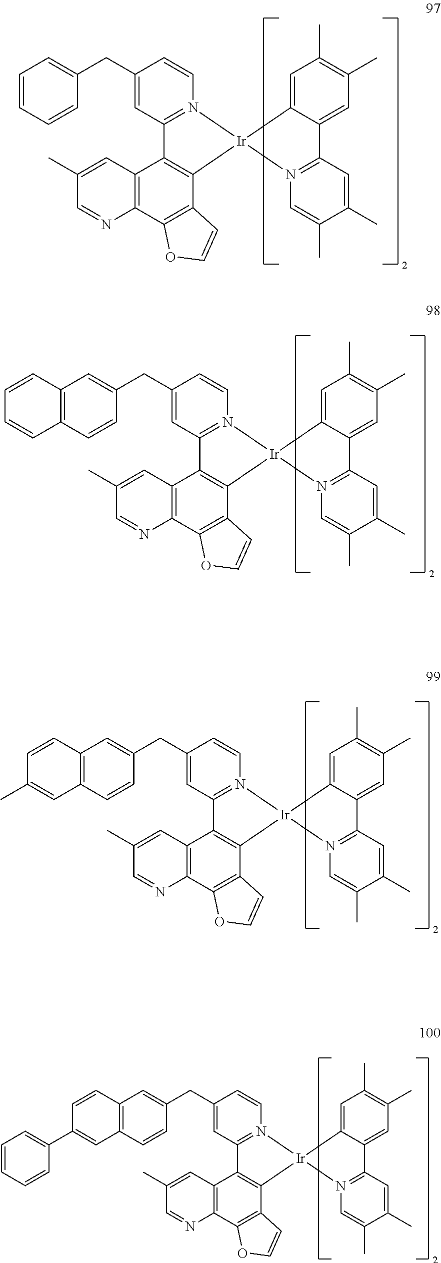

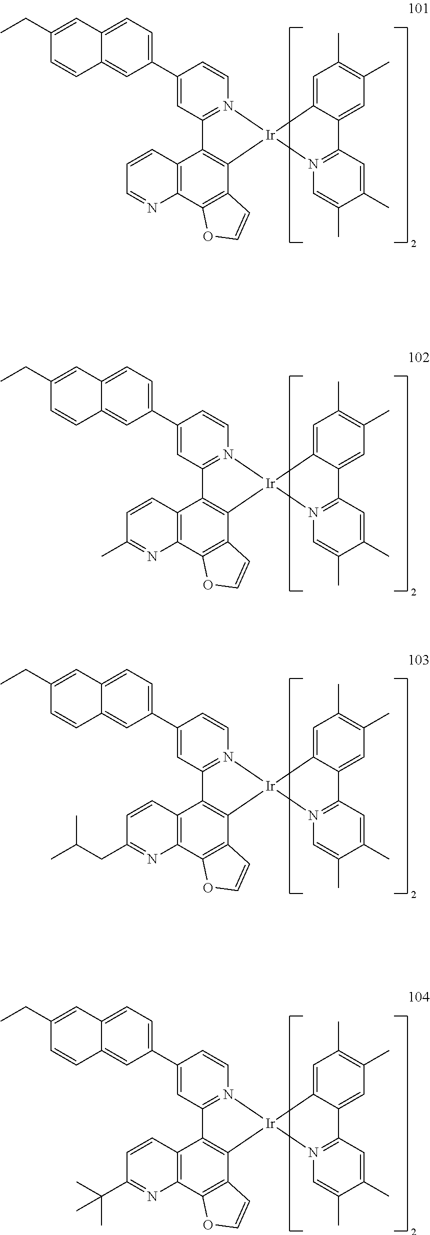

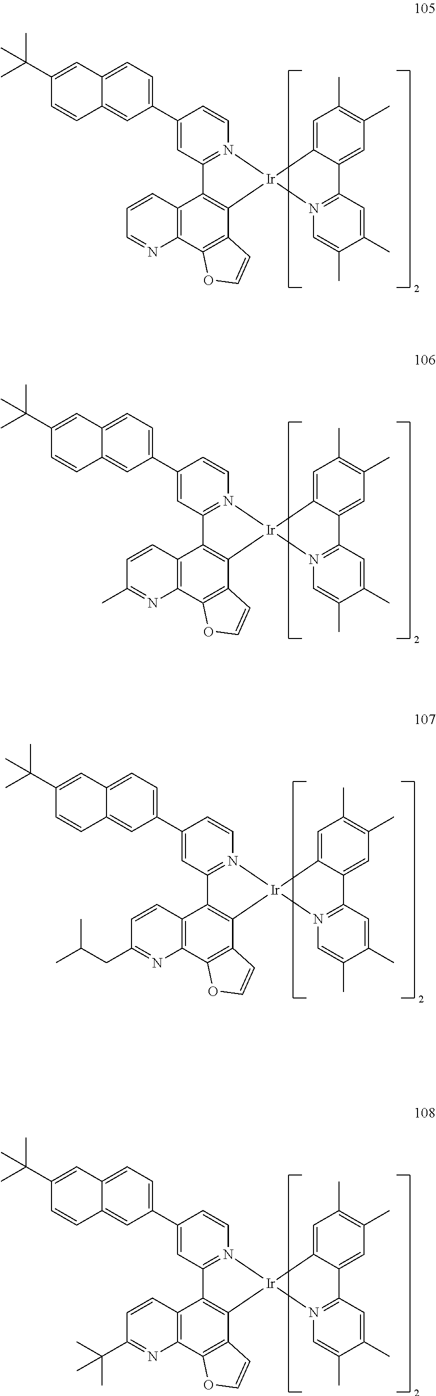

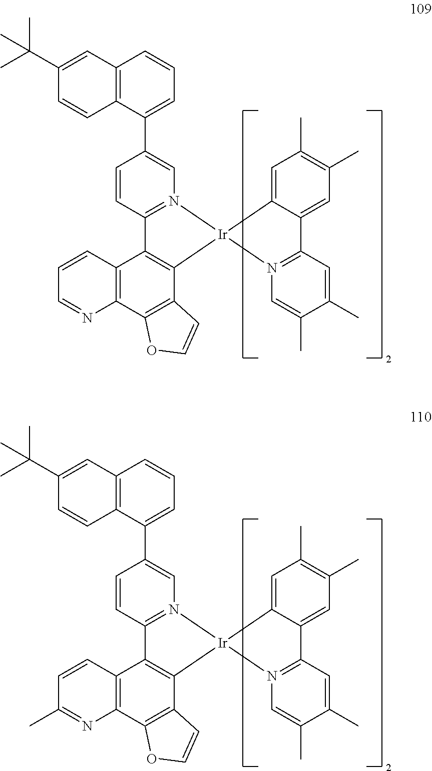

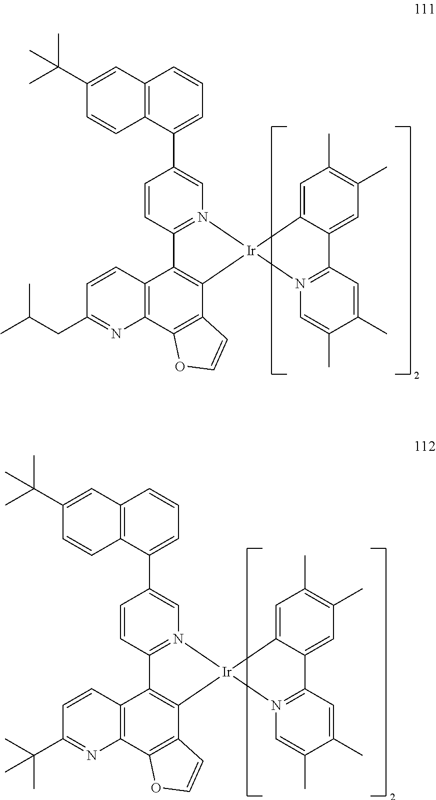

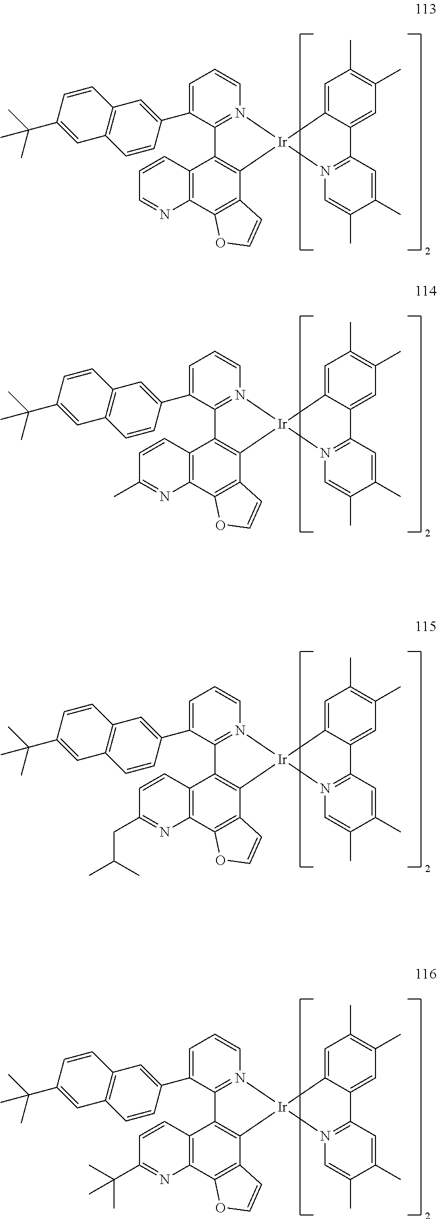

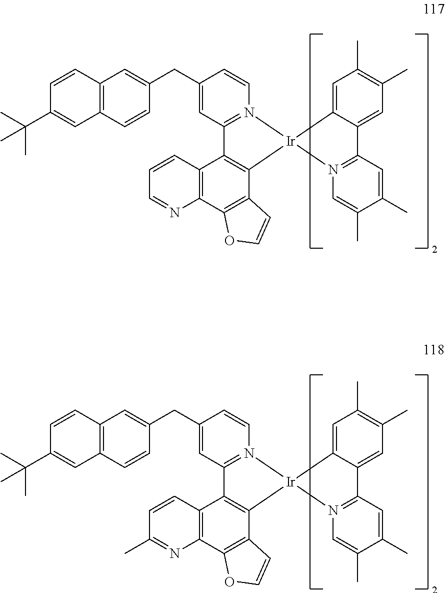

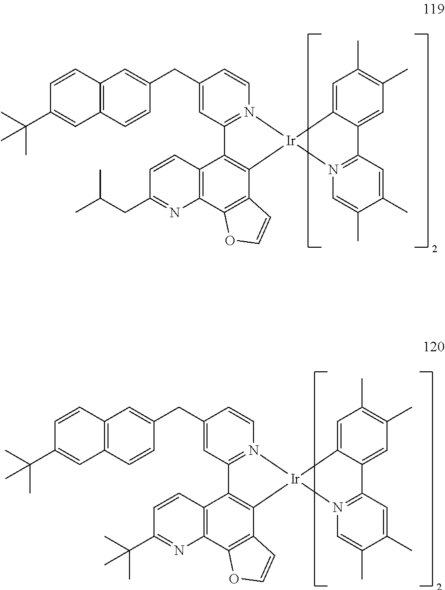

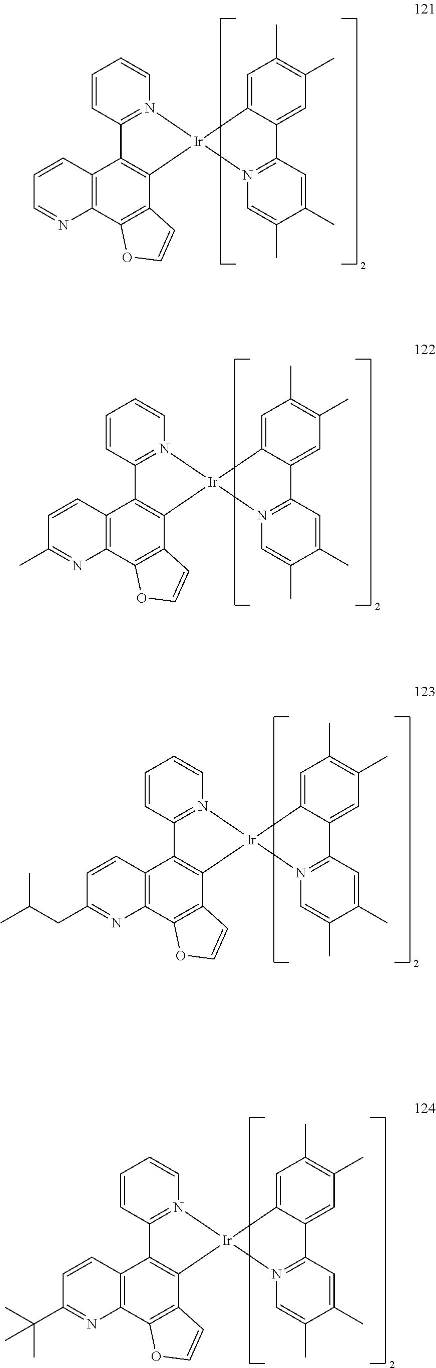

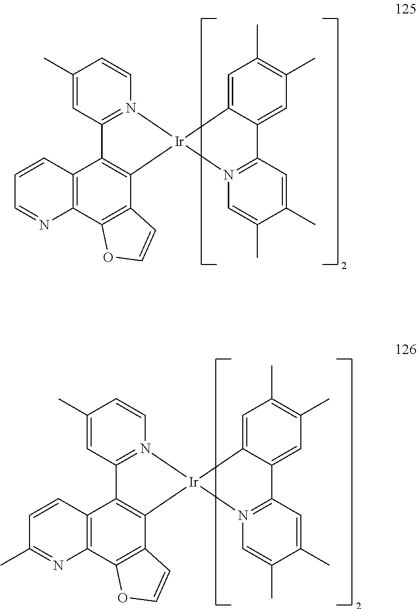

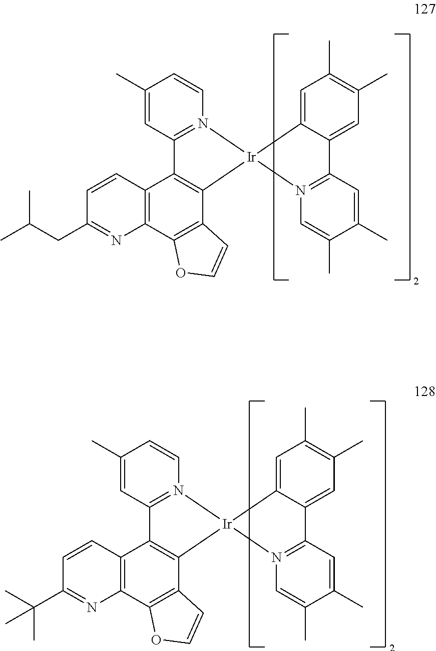

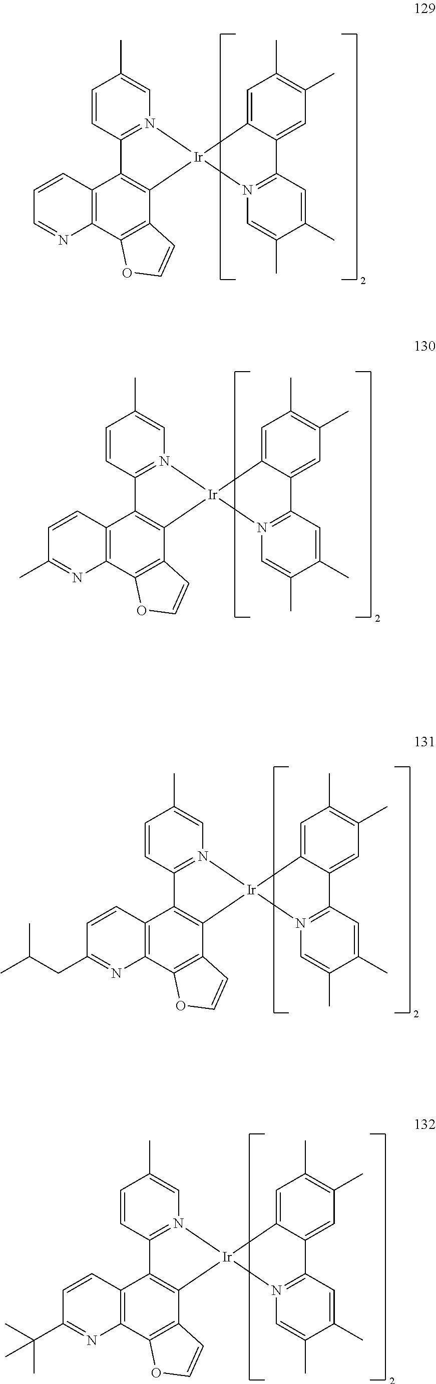

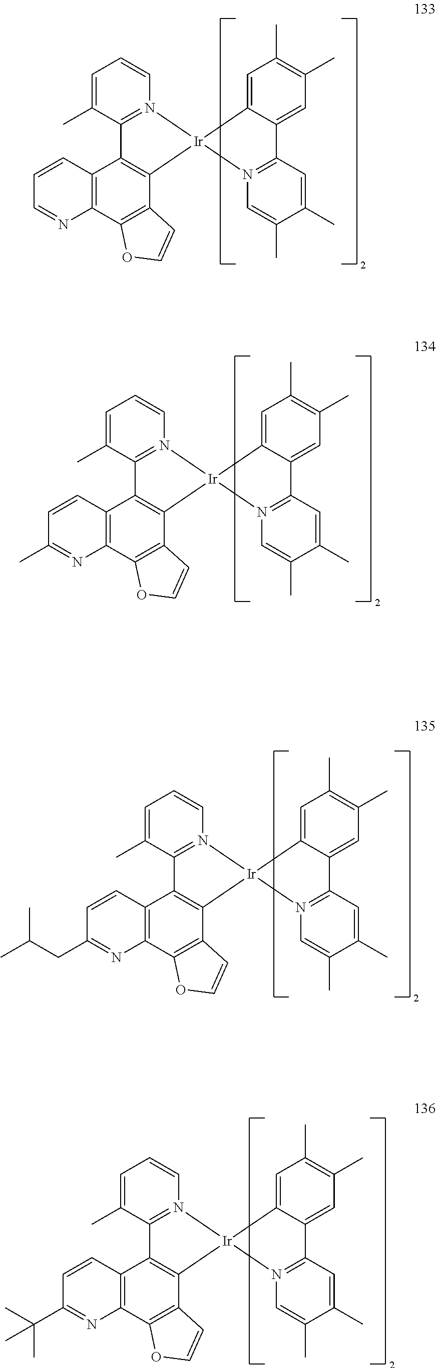

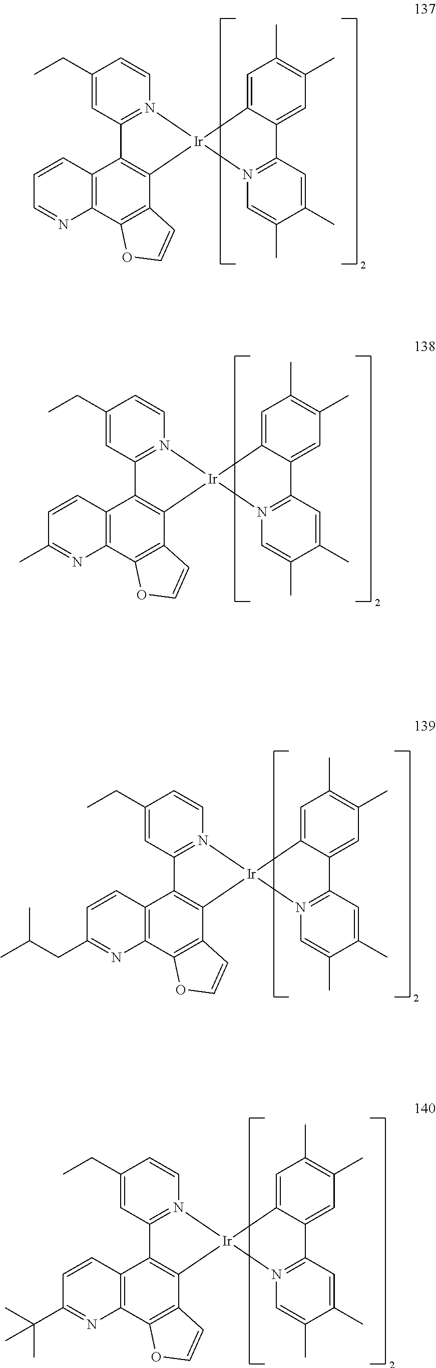

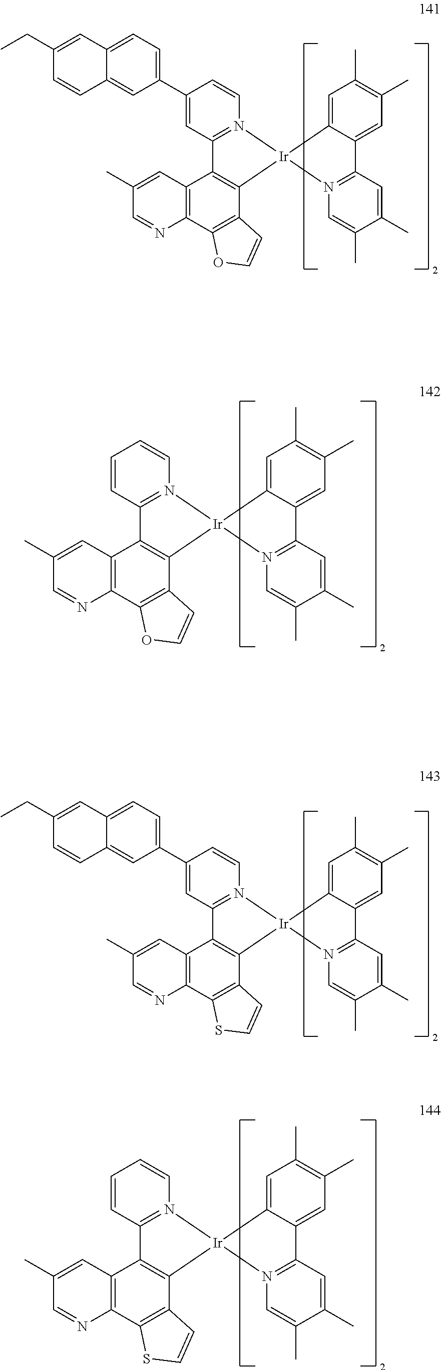

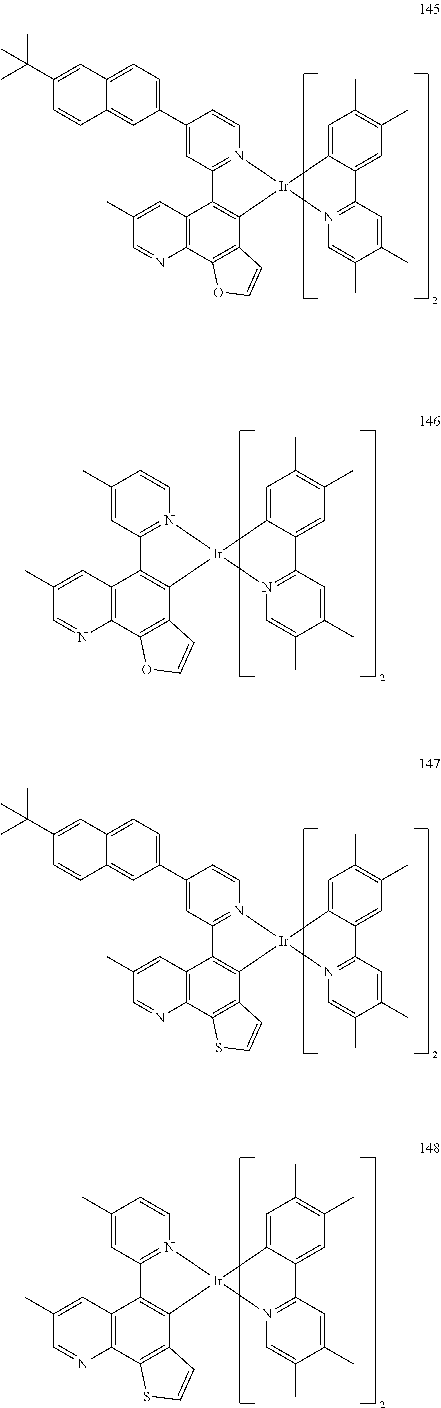

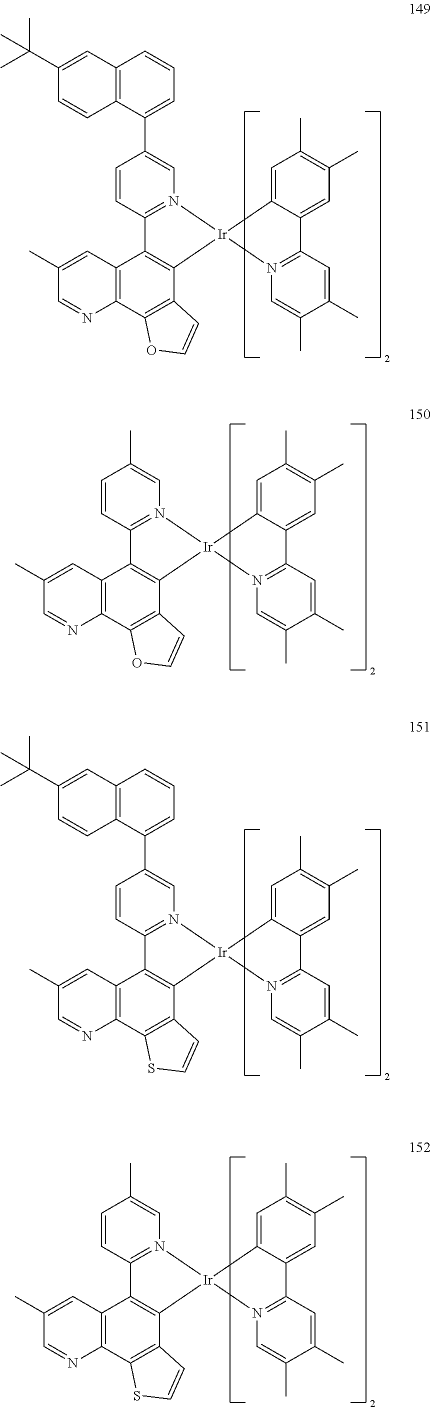

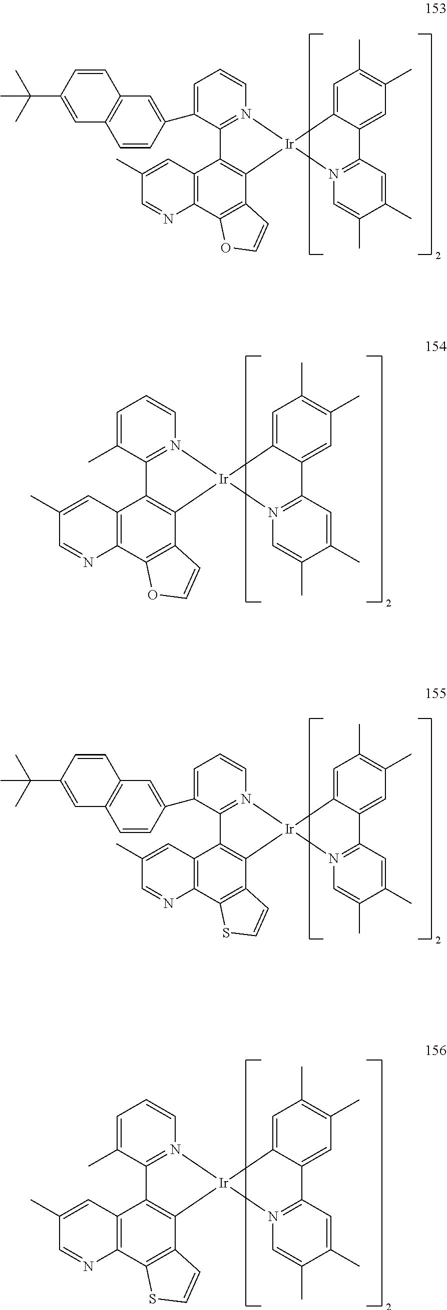

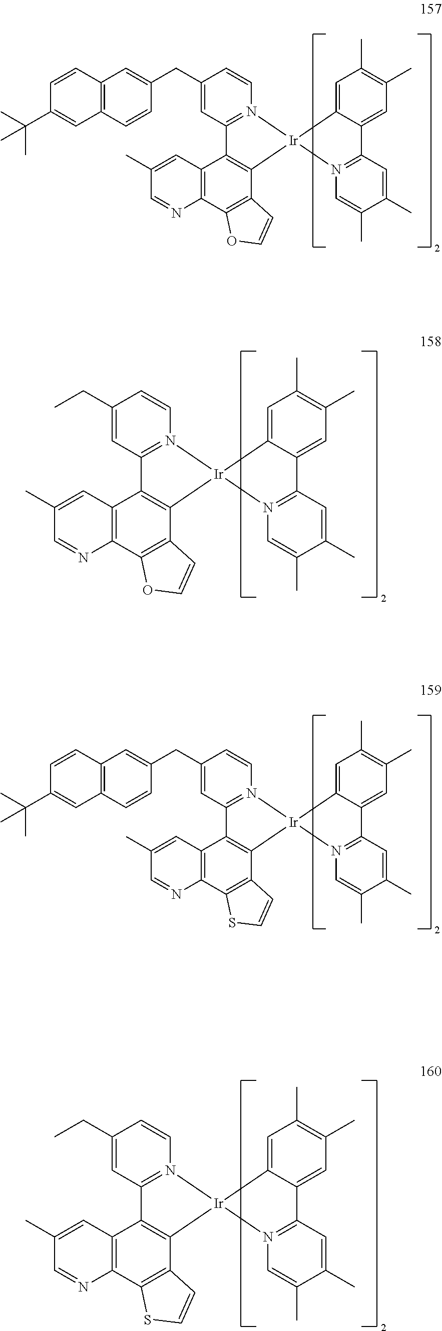

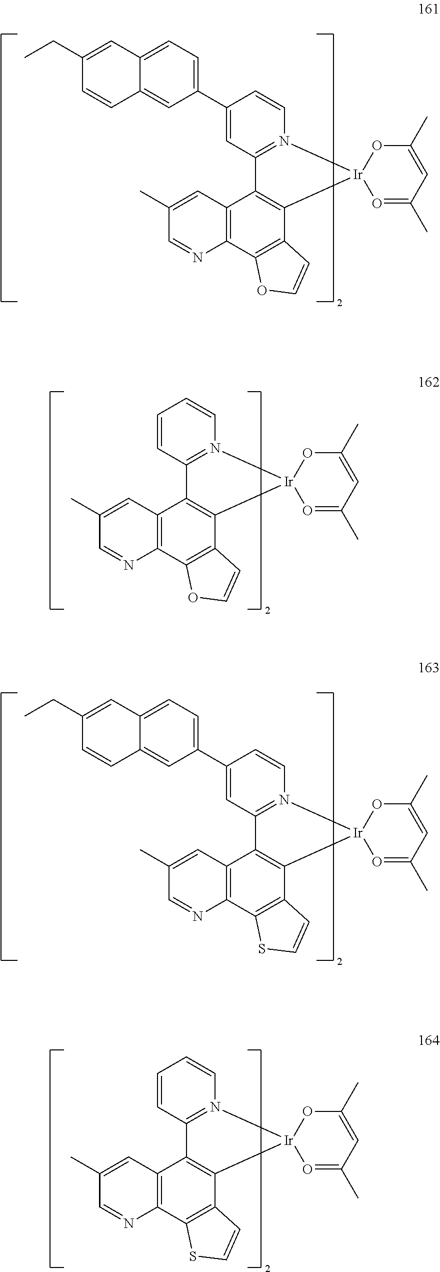

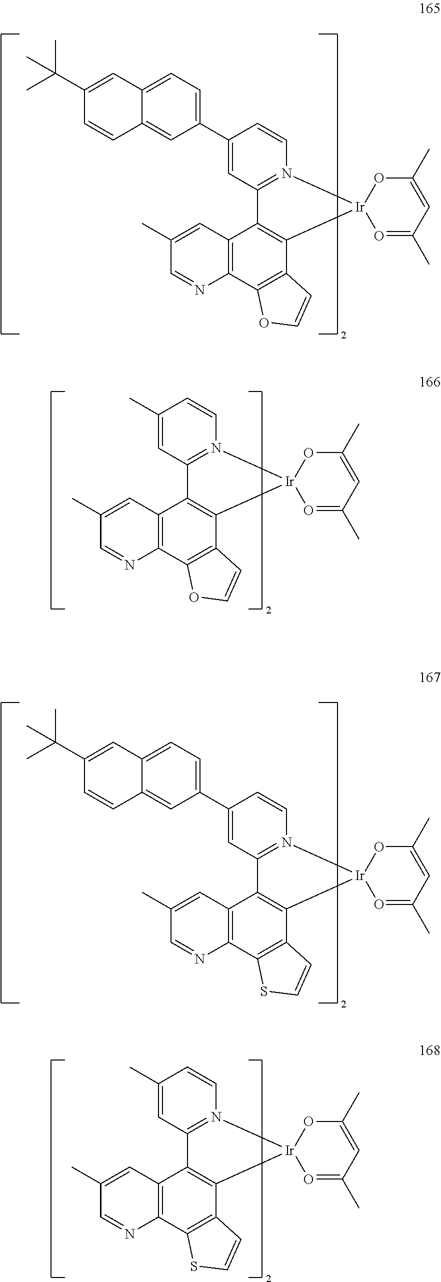

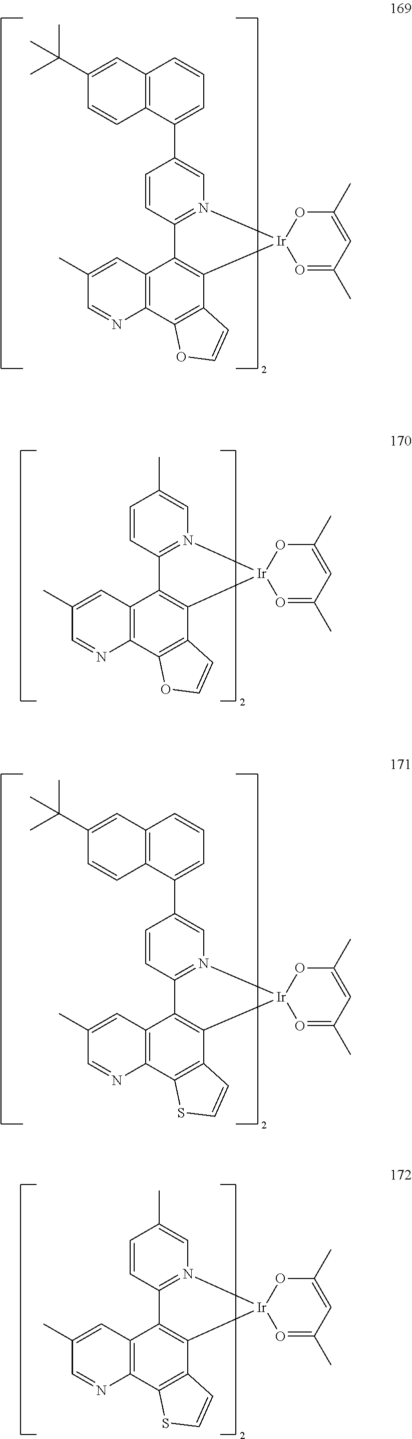

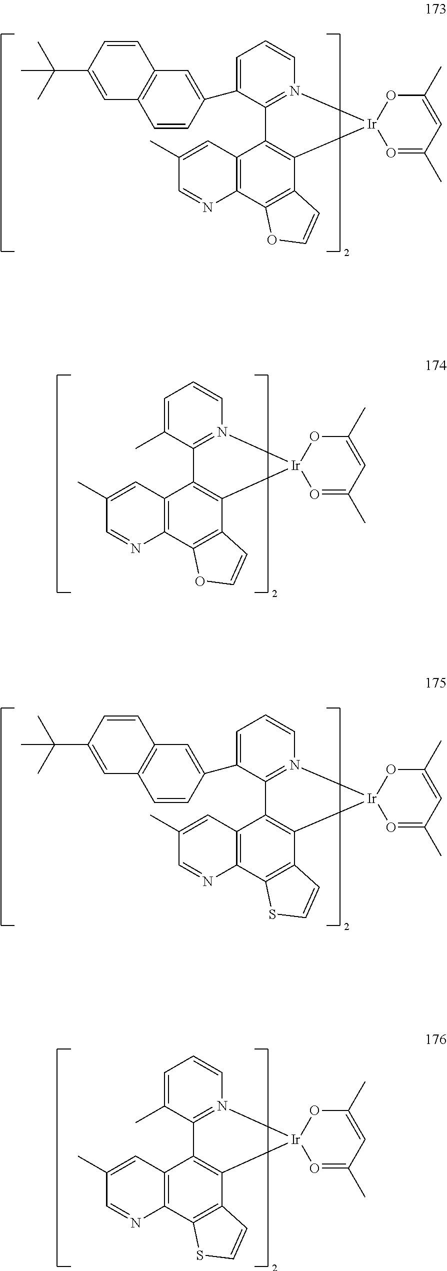

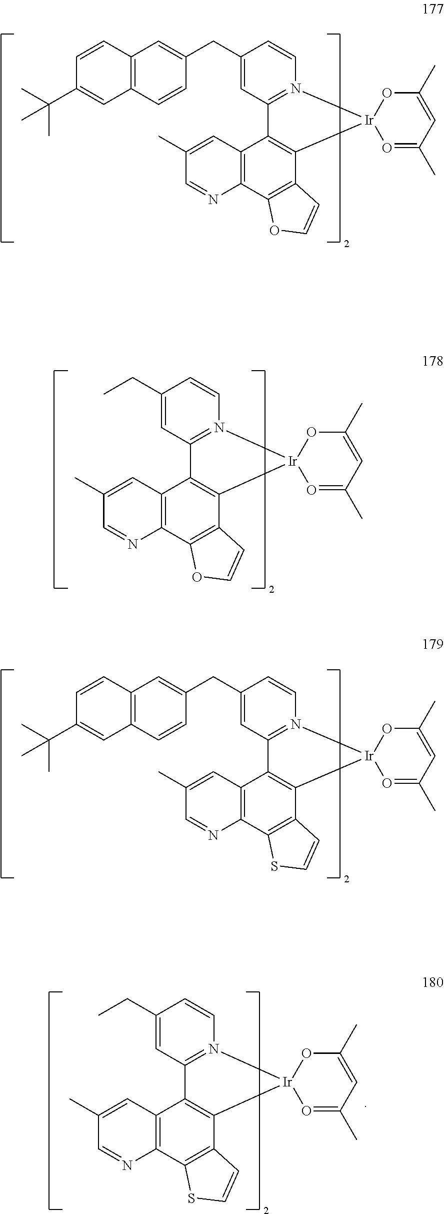

The first compound 342 having any one of the structures of Chemical Formulae 1 to 7 includes at least one ligand fused with aromatic rings and/or fused hetero aromatic rings so that the compound has a rigid chemical conformation. The first compound 342 can improve its color purity and luminous lifespan because the first compound 342 has a narrow FWHM and can maintain its stable chemical conformation in the emission process. In addition, since the first compound 342 can be a metal complex with bidentate ligands, it is possible to control the emission color purity and emission colors. The organic light emitting diode D1 can have beneficial luminous efficiency by applying the first compound 342 having the structure of Chemical Formulae 1 to 7 into the EML 340.

Each of the second compound 344 and the third compound 346 can be the first host and the second host, respectively. The second compound 344 can be a P-type (or hole-type) host with relatively beneficial hole affinity property and/or hole transporting affinity. The third compound 346 can be an N-type (or electron-type) host with relatively beneficial electron affinity property and/or electron transporting property.

The second compound 344 can be an amino-containing organic compound wherein at least one of an aromatic ring and/or a hetero aromatic ring is substituted with a nitrogen atom. As an example, the second compound 344 can have the structure of Chemical Formula 8:

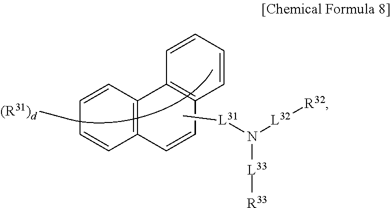

wherein:
each of R³¹ to R³³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, where each R³¹ is identical to or different from each other when d is 2, 3, 4, 5, 6, 7, 8 or 9;
each of L³¹ and L³² is independently a single bond, an unsubstituted or substituted C₆-C₃₀ arylene group or an unsubstituted or substituted C₂-C₃₀ hetero arylene group; and
d is 0, 1, 2, 3, 4, 5, 6, 7, 8 or 9.

In one embodiment, the nitrogen atom constituting the amino group in the second compound 344 can be linked to a 9-position of the phenanthrene ring directly or via the linker group L³¹ in a molecular configuration of the second compound 344. As an example, the second compound 344 with such a configuration can have the structure of Chemical Formula 9:

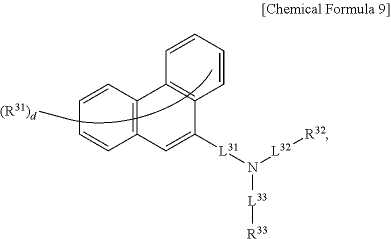

wherein:
each of R³¹ to R³³, L³¹ to L³³ and d is as defined in Chemical Formula 8.

In one embodiment, R³¹ can be hydrogen or a C₁-C₁₀ alkyl group, each of R³² and R³³ can be independently selected from phenyl, biphenyl, terphenyl, naphthyl, phenanthrenyl, dibenzofuranyl and dibenzothiophenyl each of which is independently unsubstituted or substituted with at least one of C₁-C₁₀ alkyl and C₆-C₃₀ aryl, and/or each of L³¹ to L³³ can be independently the single bond, a phenylene group, a biphenylene group, a terphenylene group or a naphthylene group in Chemical Formulae 8 and 9.

In another embodiment, R³² can be selected from phenyl, biphenyl, terphenyl, naphthyl, phenanthrenyl and dibenzo-furanyl each of which can be independently unsubstituted or substituted with at least one of C₁-C₁₀ alkyl and C₆-C₃₀ aryl in Chemical Formulae 8 and 9. In another embodiment, R³³ can selected from phenyl, biphenyl and terphenyl each of which can be independently unsubstituted or substituted with at least one of C₁-C₁₀ alkyl and C₆-C₃₀ aryl in Chemical Formulae 8 and 9.

In some embodiments, R³¹ is hydrogen.

In some embodiments, R³² is chosen from:
H, CH₃,

[chemical structure]

In some embodiments. R³³ is chosen from:

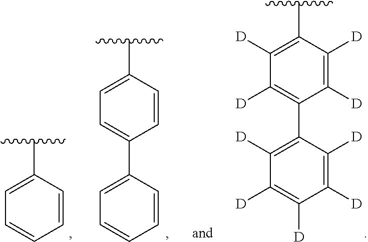

In some embodiments, each of L³¹, L³², and L³³ is independently chosen from a single bond,

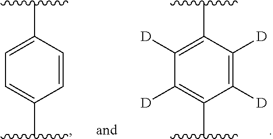 [SMILES: *c1ccc(*)cc1 ; *c1c([2H])c([2H])c(*)c([2H])c1[2H]]

For example, the second compound 344 having the structure of Chemical Formula 8 or Chemical Formula 9 can be at least one of or selected from, but is not limited to, the following organic compounds of Chemical Formula 10:

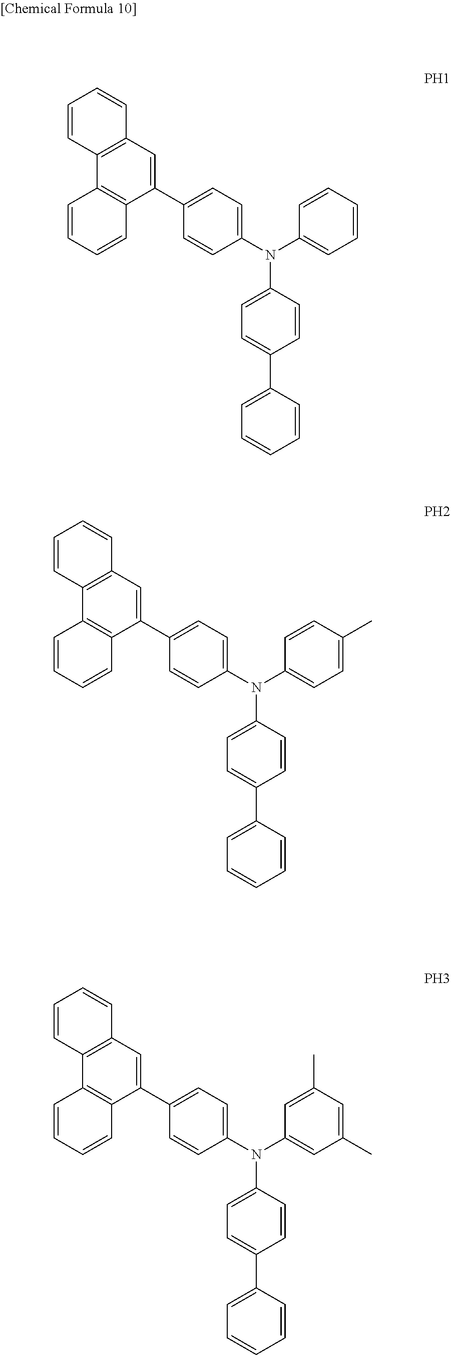 [SMILES: c1ccc(-c2ccc(N(c3ccccc3)c3ccc(-c4cc5ccccc5c5ccccc45)cc3)cc2)cc1 ; Cc1ccc(N(c2ccc(-c3ccccc3)cc2)c2ccc(-c3cc4ccccc4c4ccccc34)cc2)cc1 ; Cc1cc(C)cc(N(c2ccc(-c3ccccc3)cc2)c2ccc(-c3cc4ccccc4c4ccccc34)cc2)c1]

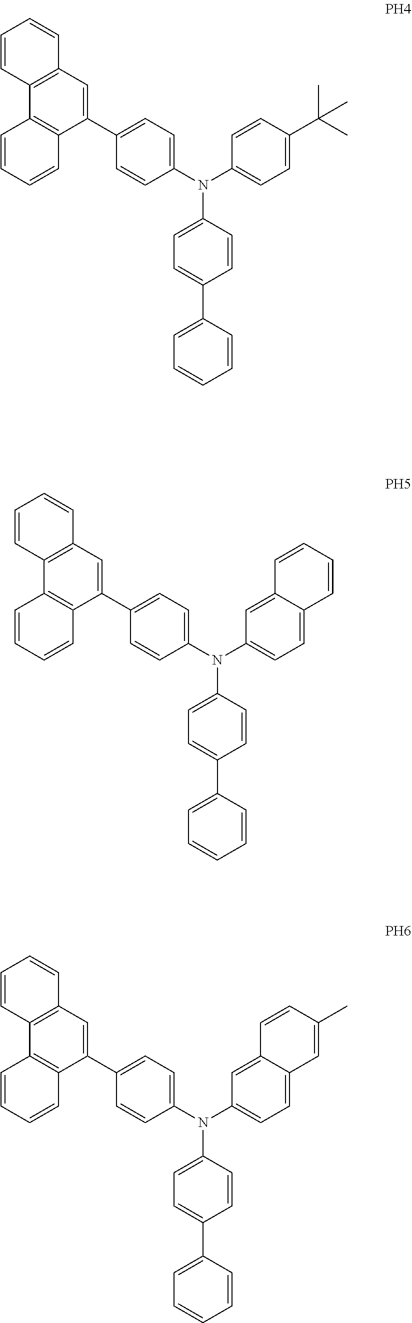 [SMILES: CC(C)(C)c1ccc(N(c2ccc(-c3ccccc3)cc2)c2ccc(-c3cc4ccccc4c4ccccc34)cc2)cc1 ; c1ccc(-c2ccc(N(c3ccc(-c4cc5ccccc5c5ccccc45)cc3)c3ccc4ccccc4c3)cc2)cc1 ; Cc1ccc2cc(N(c3ccc(-c4ccccc4)cc3)c3ccc(-c4cc5ccccc5c5ccccc45)cc3)ccc2c1]

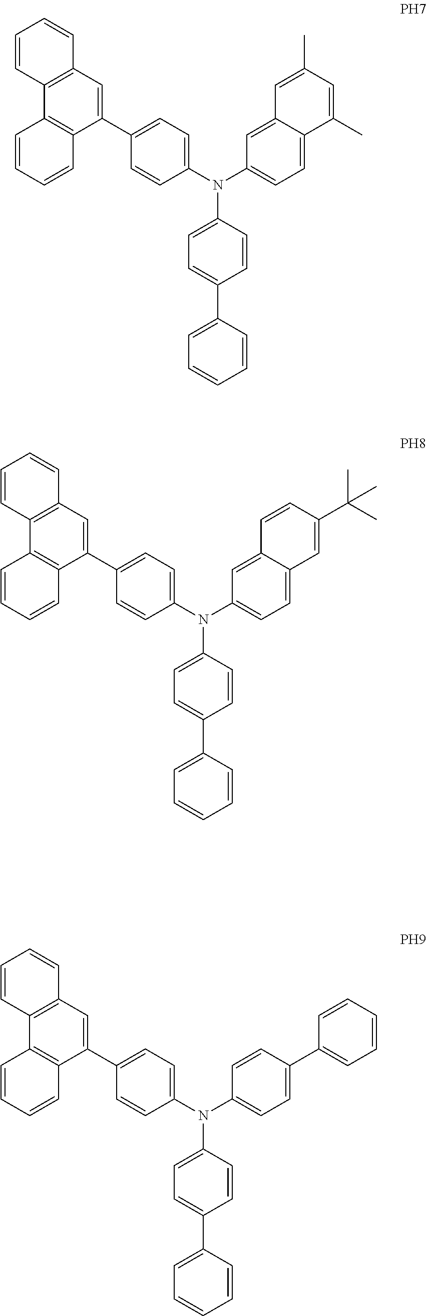 [SMILES: Cc1cc(C)c2ccc(N(c3ccc(-c4ccccc4)cc3)c3ccc(-c4cc5ccccc5c5ccccc45)cc3)cc2c1 ; CC(C)(C)c1ccc2cc(N(c3ccc(-c4ccccc4)cc3)c3ccc(-c4cc5ccccc5c5ccccc45)cc3)ccc2c1 ; c1ccc(-c2ccc(N(c3ccc(-c4ccccc4)cc3)c3ccc(-c4cc5ccccc5c5ccccc45)cc3)cc2)cc1]

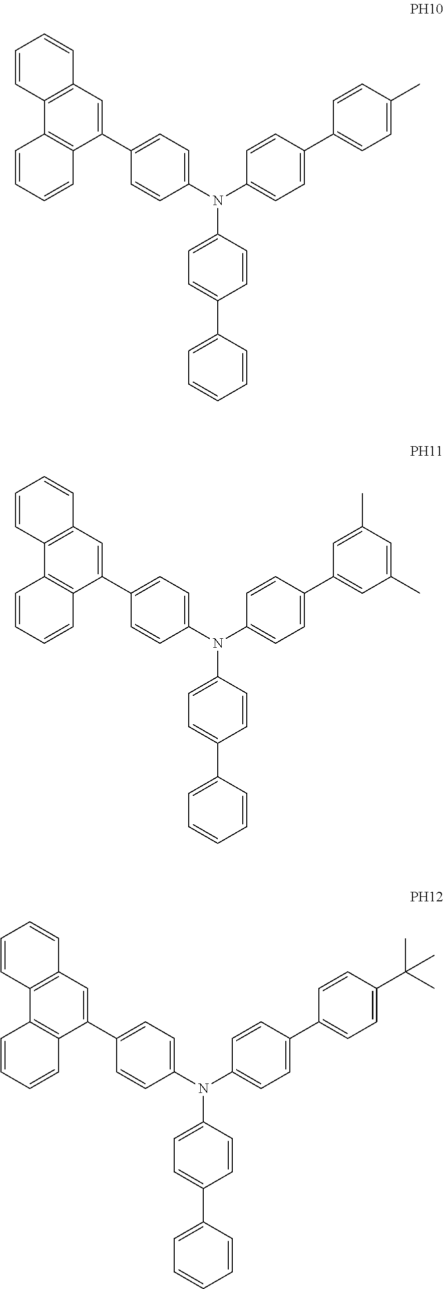 [SMILES: Cc1ccc(-c2ccc(N(c3ccc(-c4ccccc4)cc3)c3ccc(-c4cc5ccccc5c5ccccc45)cc3)cc2)cc1 ; Cc1cc(C)cc(-c2ccc(N(c3ccc(-c4ccccc4)cc3)c3ccc(-c4cc5ccccc5c5ccccc45)cc3)cc2)c1 ; CC(C)(C)c1ccc(-c2ccc(N(c3ccc(-c4ccccc4)cc3)c3ccc(-c4cc5ccccc5c5ccccc45)cc3)cc2)cc1]

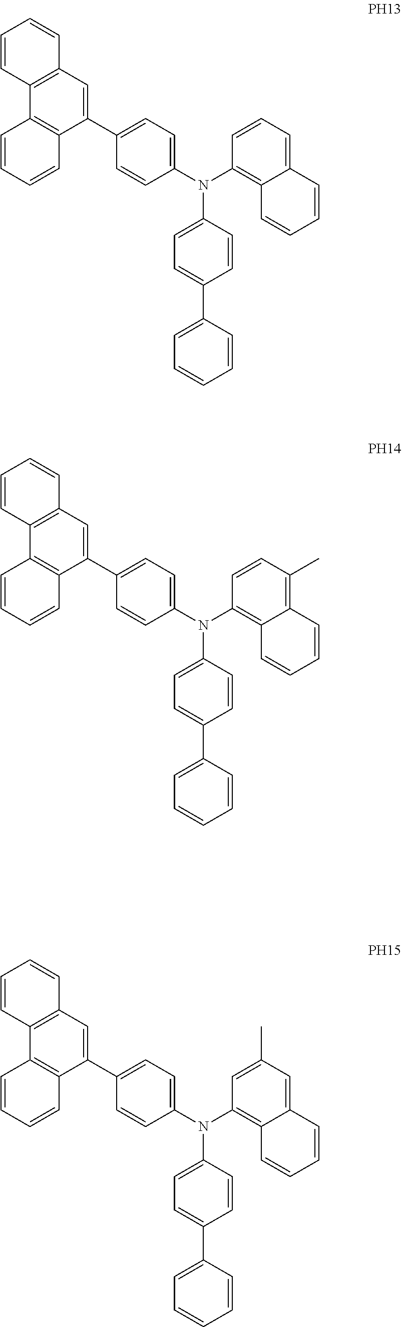 [SMILES: c1ccc(-c2ccc(N(c3ccc(-c4cc5ccccc5c5ccccc45)cc3)c3cccc4ccccc34)cc2)cc1 ; Cc1ccc(N(c2ccc(-c3ccccc3)cc2)c2ccc(-c3cc4ccccc4c4ccccc34)cc2)c2ccccc12 ; Cc1cc(N(c2ccc(-c3ccccc3)cc2)c2ccc(-c3cc4ccccc4c4ccccc34)cc2)c2ccccc2c1]

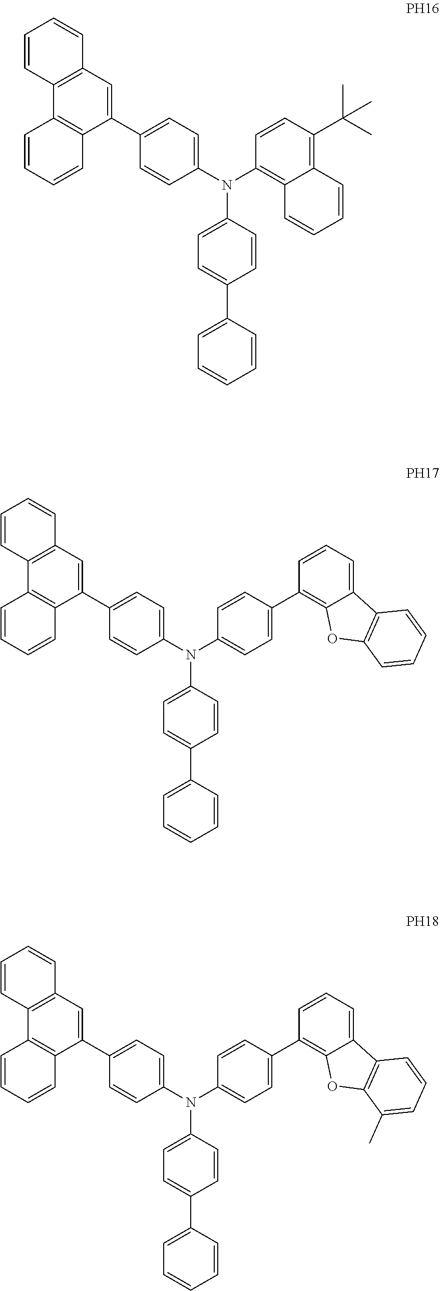 [SMILES: CC(C)(C)c1ccc(N(c2ccc(-c3ccccc3)cc2)c2ccc(-c3cc4ccccc4c4ccccc34)cc2)c2ccccc12 ; c1ccc(-c2ccc(N(c3ccc(-c4cc5ccccc5c5ccccc45)cc3)c3ccc(-c4cccc5c4oc4ccccc45)cc3)cc2)cc1 ; Cc1cccc2c1oc1c(-c3ccc(N(c4ccc(-c5ccccc5)cc4)c4ccc(-c5cc6ccccc6c6ccccc56)cc4)cc3)cccc12]

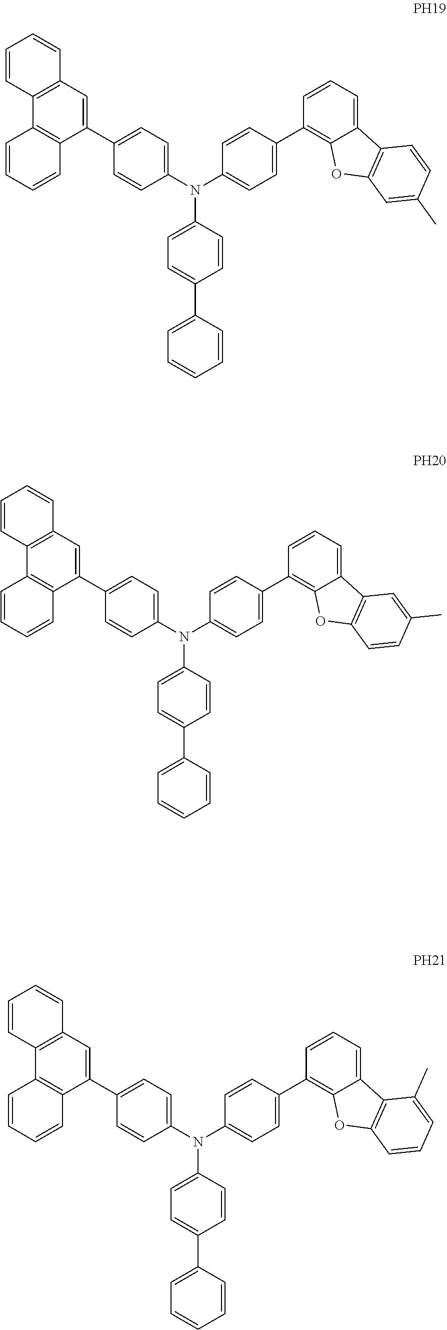 [SMILES: Cc1ccc2c(c1)oc1c(-c3ccc(N(c4ccc(-c5ccccc5)cc4)c4ccc(-c5cc6ccccc6c6ccccc56)cc4)cc3)cccc12 ; Cc1ccc2oc3c(-c4ccc(N(c5ccc(-c6ccccc6)cc5)c5ccc(-c6cc7ccccc7c7ccccc67)cc5)cc4)cccc3c2c1 ; Cc1cccc2oc3c(-c4ccc(N(c5ccc(-c6ccccc6)cc5)c5ccc(-c6cc7ccccc7c7ccccc67)cc5)cc4)cccc3c12]

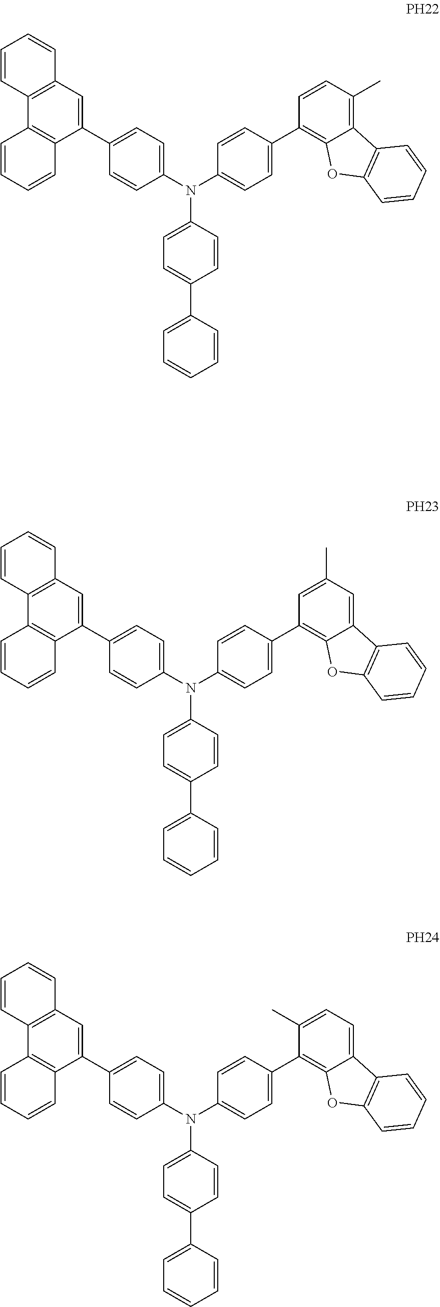 [SMILES: Cc1ccc(-c2ccc(N(c3ccc(-c4ccccc4)cc3)c3ccc(-c4cc5ccccc5c5ccccc45)cc3)cc2)c2oc3ccccc3c12 ; Cc1cc(-c2ccc(N(c3ccc(-c4ccccc4)cc3)c3ccc(-c4cc5ccccc5c5ccccc45)cc3)cc2)c2oc3ccccc3c2c1 ; Cc1ccc2c(oc3ccccc32)c1-c1ccc(N(c2ccc(-c3ccccc3)cc2)c2ccc(-c3cc4ccccc4c4ccccc34)cc2)cc1]

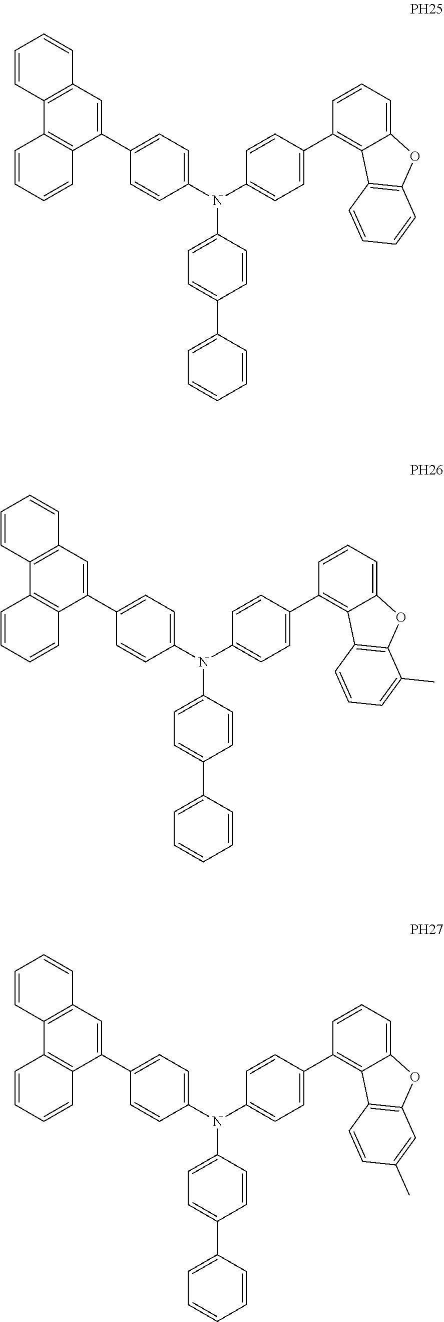 [SMILES: c1ccc(-c2ccc(N(c3ccc(-c4cc5ccccc5c5ccccc45)cc3)c3ccc(-c4cccc5oc6ccccc6c45)cc3)cc2)cc1 ; Cc1cccc2c1oc1cccc(-c3ccc(N(c4ccc(-c5ccccc5)cc4)c4ccc(-c5cc6ccccc6c6ccccc56)cc4)cc3)c12 ; Cc1ccc2c(c1)oc1cccc(-c3ccc(N(c4ccc(-c5ccccc5)cc4)c4ccc(-c5cc6ccccc6c6ccccc56)cc4)cc3)c12]

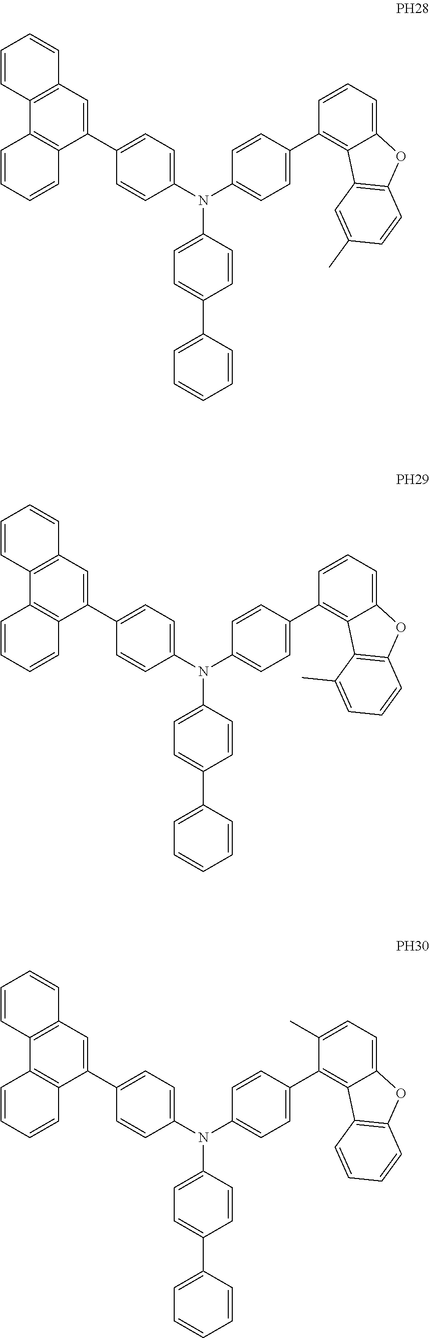 [SMILES: Cc1ccc2oc3cccc(-c4ccc(N(c5ccc(-c6ccccc6)cc5)c5ccc(-c6cc7ccccc7c7ccccc67)cc5)cc4)c3c2c1 ; Cc1cccc2oc3cccc(-c4ccc(N(c5ccc(-c6ccccc6)cc5)c5ccc(-c6cc7ccccc7c7ccccc67)cc5)cc4)c3c12 ; Cc1ccc2oc3ccccc3c2c1-c1ccc(N(c2ccc(-c3ccccc3)cc2)c2ccc(-c3cc4ccccc4c4ccccc34)cc2)cc1]

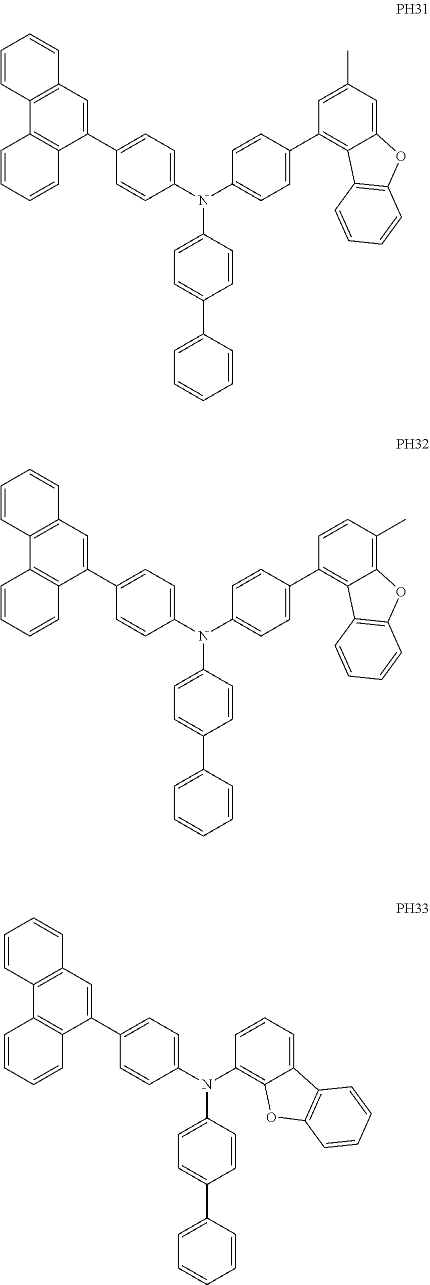 [SMILES: Cc1cc(-c2ccc(N(c3ccc(-c4ccccc4)cc3)c3ccc(-c4cc5ccccc5c5ccccc45)cc3)cc2)c2c(c1)oc1ccccc12 ; Cc1ccc(-c2ccc(N(c3ccc(-c4ccccc4)cc3)c3ccc(-c4cc5ccccc5c5ccccc45)cc3)cc2)c2c1oc1ccccc12 ; c1ccc(-c2ccc(N(c3ccc(-c4cc5ccccc5c5ccccc45)cc3)c3cccc4c3oc3ccccc34)cc2)cc1]

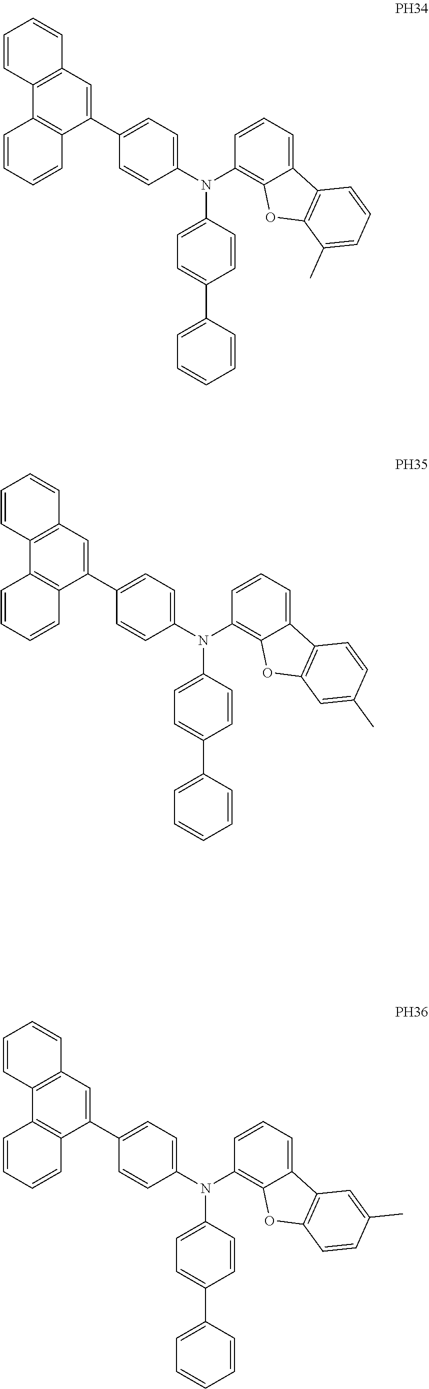 [SMILES: Cc1cccc2c1oc1c(N(c3ccc(-c4ccccc4)cc3)c3ccc(-c4cc5ccccc5c5ccccc45)cc3)cccc12 ; Cc1ccc2c(c1)oc1c(N(c3ccc(-c4ccccc4)cc3)c3ccc(-c4cc5ccccc5c5ccccc45)cc3)cccc12 ; Cc1ccc2oc3c(N(c4ccc(-c5ccccc5)cc4)c4ccc(-c5cc6ccccc6c6ccccc56)cc4)cccc3c2c1]

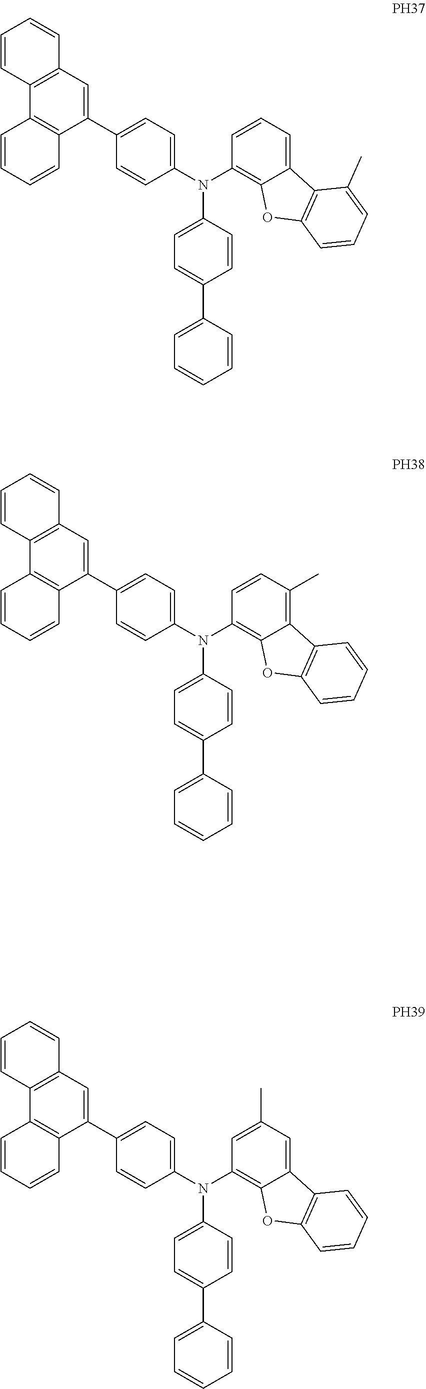 [SMILES: Cc1cccc2oc3c(N(c4ccc(-c5ccccc5)cc4)c4ccc(-c5cc6ccccc6c6ccccc56)cc4)cccc3c12 ; Cc1ccc(N(c2ccc(-c3ccccc3)cc2)c2ccc(-c3cc4ccccc4c4ccccc34)cc2)c2oc3ccccc3c12 ; Cc1cc(N(c2ccc(-c3ccccc3)cc2)c2ccc(-c3cc4ccccc4c4ccccc34)cc2)c2oc3ccccc3c2c1]

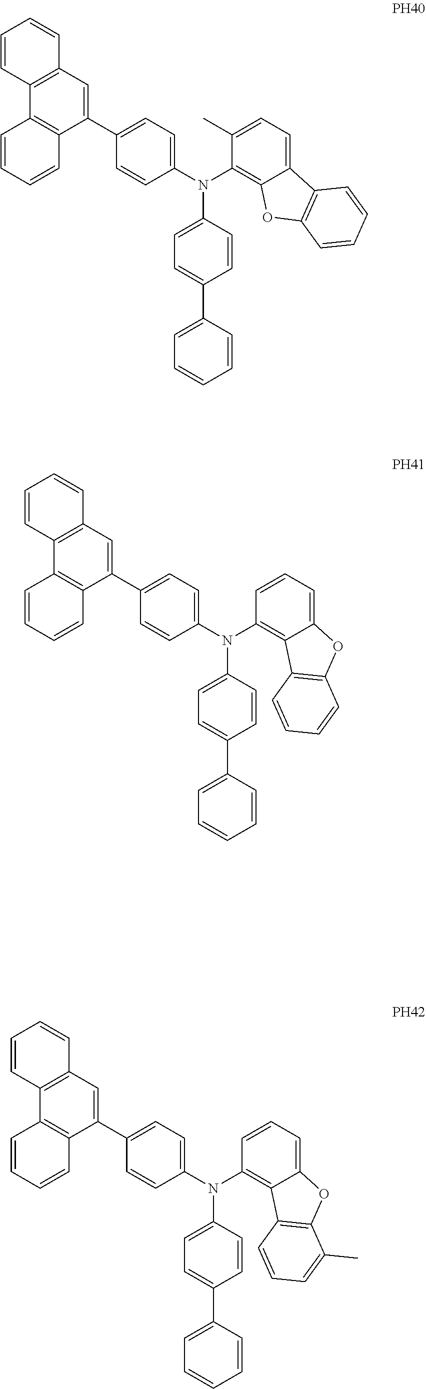 [SMILES: Cc1ccc2c(oc3ccccc32)c1N(c1ccc(-c2ccccc2)cc1)c1ccc(-c2cc3ccccc3c3ccccc23)cc1 ; c1ccc(-c2ccc(N(c3ccc(-c4cc5ccccc5c5ccccc45)cc3)c3cccc4oc5ccccc5c34)cc2)cc1 ; Cc1cccc2c1oc1cccc(N(c3ccc(-c4ccccc4)cc3)c3ccc(-c4cc5ccccc5c5ccccc45)cc3)c12]

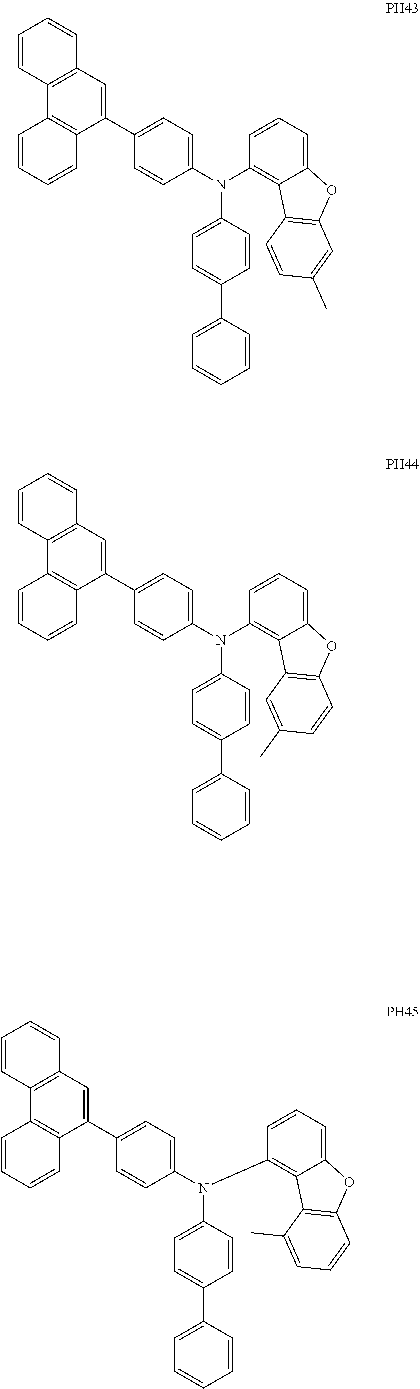 [SMILES: Cc1ccc2c(c1)oc1cccc(N(c3ccc(-c4ccccc4)cc3)c3ccc(-c4cc5ccccc5c5ccccc45)cc3)c12 ; Cc1ccc2oc3cccc(N(c4ccc(-c5ccccc5)cc4)c4ccc(-c5cc6ccccc6c6ccccc56)cc4)c3c2c1 ; Cc1cccc2oc3cccc(N(c4ccc(-c5ccccc5)cc4)c4ccc(-c5cc6ccccc6c6ccccc56)cc4)c3c12]

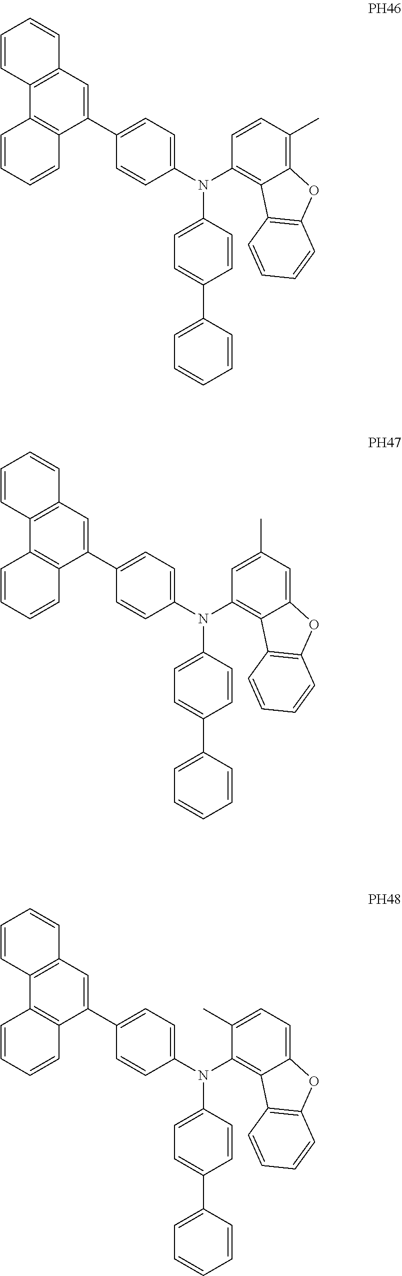 [SMILES: Cc1ccc(N(c2ccc(-c3ccccc3)cc2)c2ccc(-c3cc4ccccc4c4ccccc34)cc2)c2c1oc1ccccc12 ; Cc1cc(N(c2ccc(-c3ccccc3)cc2)c2ccc(-c3cc4ccccc4c4ccccc34)cc2)c2c(c1)oc1ccccc12 ; Cc1ccc2oc3ccccc3c2c1N(c1ccc(-c2ccccc2)cc1)c1ccc(-c2cc3ccccc3c3ccccc23)cc1]

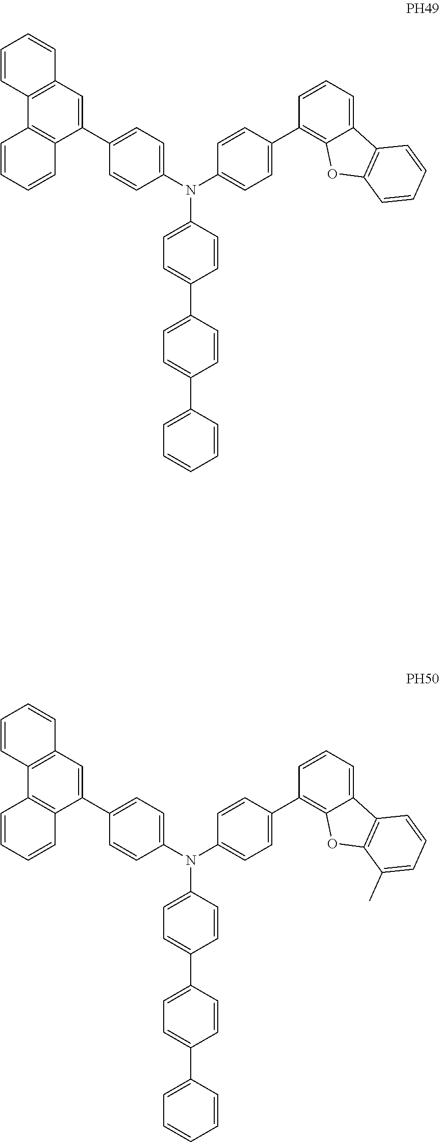 [SMILES: c1ccc(-c2ccc(-c3ccc(N(c4ccc(-c5cc6ccccc6c6ccccc56)cc4)c4ccc(-c5cccc6c5oc5ccccc56)cc4)cc3)cc2)cc1 ; Cc1cccc2c1oc1c(-c3ccc(N(c4ccc(-c5ccc(-c6ccccc6)cc5)cc4)c4ccc(-c5cc6ccccc6c6ccccc56)cc4)cc3)cccc12]

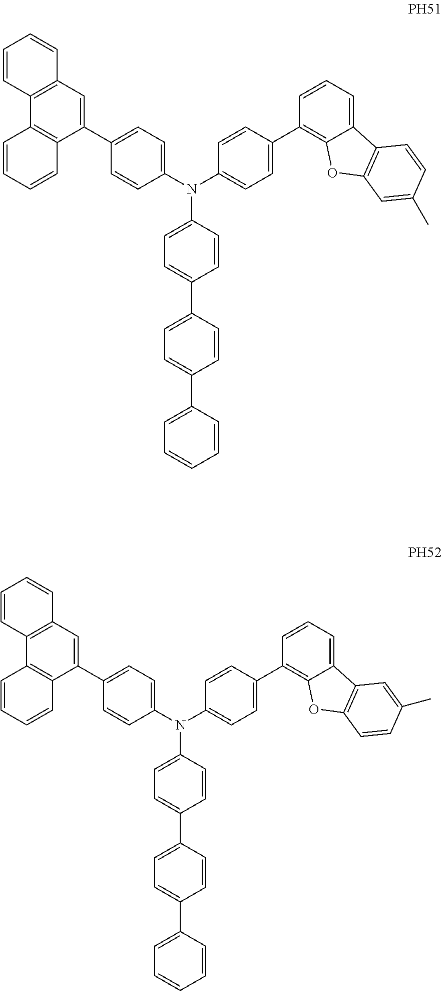 [SMILES: Cc1ccc2c(c1)oc1c(-c3ccc(N(c4ccc(-c5ccc(-c6ccccc6)cc5)cc4)c4ccc(-c5cc6ccccc6c6ccccc56)cc4)cc3)cccc12 ; Cc1ccc2oc3c(-c4ccc(N(c5ccc(-c6ccc(-c7ccccc7)cc6)cc5)c5ccc(-c6cc7ccccc7c7ccccc67)cc5)cc4)cccc3c2c1]

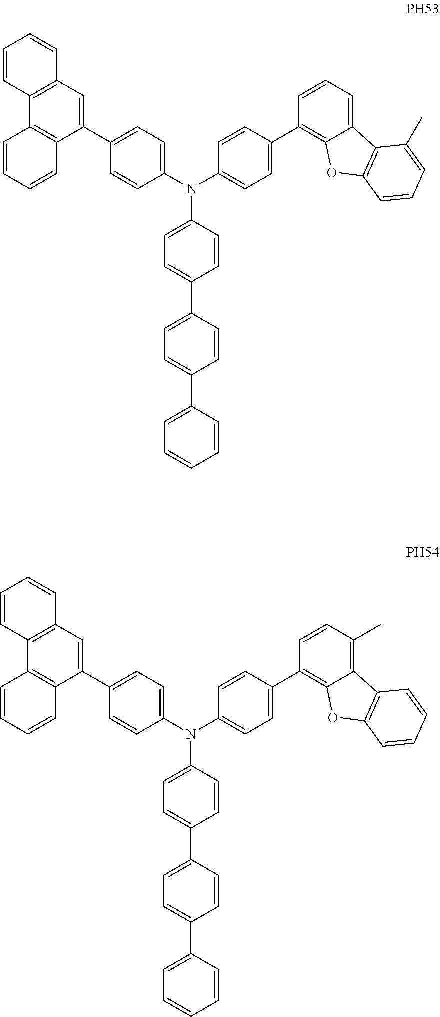 [SMILES: Cc1cccc2oc3c(-c4ccc(N(c5ccc(-c6ccc(-c7ccccc7)cc6)cc5)c5ccc(-c6cc7ccccc7c7ccccc67)cc5)cc4)cccc3c12 ; Cc1ccc(-c2ccc(N(c3ccc(-c4ccc(-c5ccccc5)cc4)cc3)c3ccc(-c4cc5ccccc5c5ccccc45)cc3)cc2)c2oc3ccccc3c12]

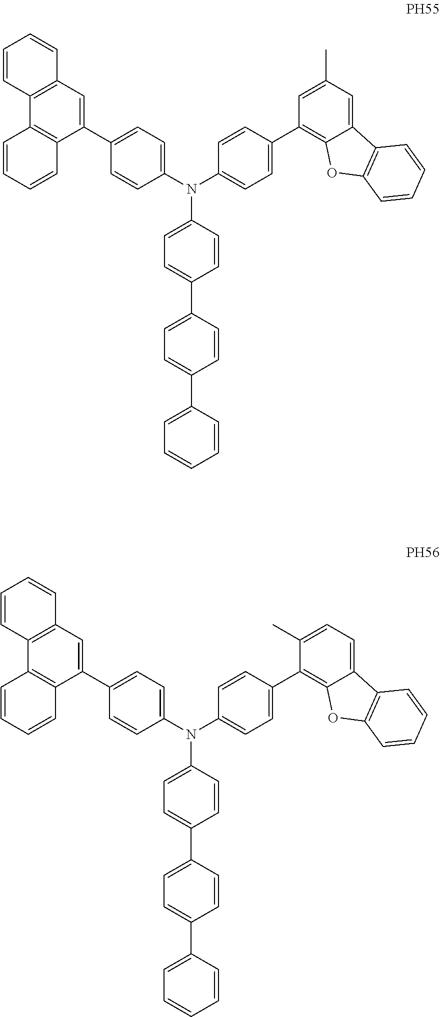 [SMILES: Cc1cc(-c2ccc(N(c3ccc(-c4ccc(-c5ccccc5)cc4)cc3)c3ccc(-c4cc5ccccc5c5ccccc45)cc3)cc2)c2oc3ccccc3c2c1 ; Cc1ccc2c(oc3ccccc32)c1-c1ccc(N(c2ccc(-c3ccc(-c4ccccc4)cc3)cc2)c2ccc(-c3cc4ccccc4c4ccccc34)cc2)cc1]

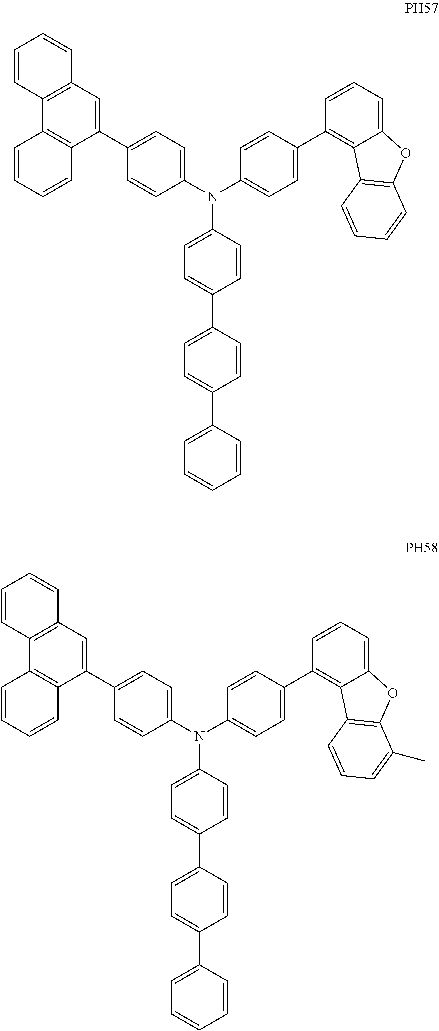 [SMILES: c1ccc(-c2ccc(-c3ccc(N(c4ccc(-c5cc6ccccc6c6ccccc56)cc4)c4ccc(-c5cccc6oc7ccccc7c56)cc4)cc3)cc2)cc1 ; Cc1cccc2c1oc1cccc(-c3ccc(N(c4ccc(-c5ccc(-c6ccccc6)cc5)cc4)c4ccc(-c5cc6ccccc6c6ccccc56)cc4)cc3)c12]

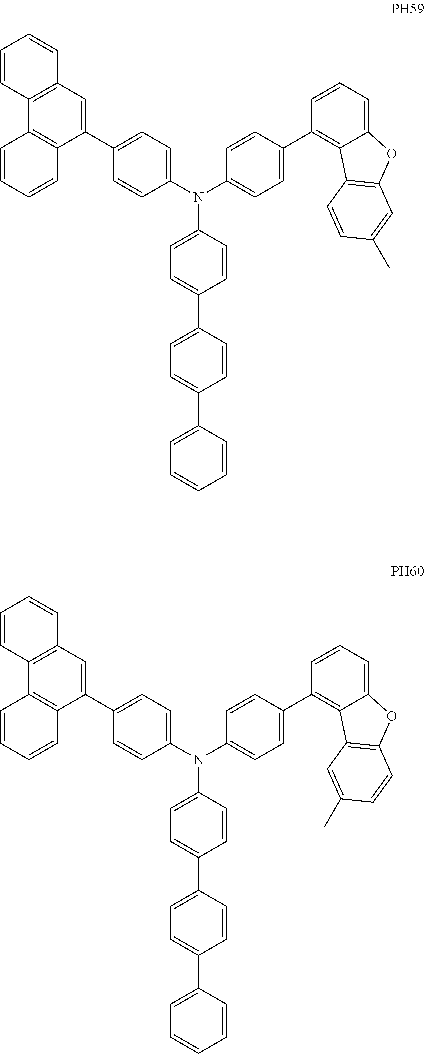 [SMILES: Cc1ccc2c(c1)oc1cccc(-c3ccc(N(c4ccc(-c5ccc(-c6ccccc6)cc5)cc4)c4ccc(-c5cc6ccccc6c6ccccc56)cc4)cc3)c12 ; Cc1ccc2oc3cccc(-c4ccc(N(c5ccc(-c6ccc(-c7ccccc7)cc6)cc5)c5ccc(-c6cc7ccccc7c7ccccc67)cc5)cc4)c3c2c1]

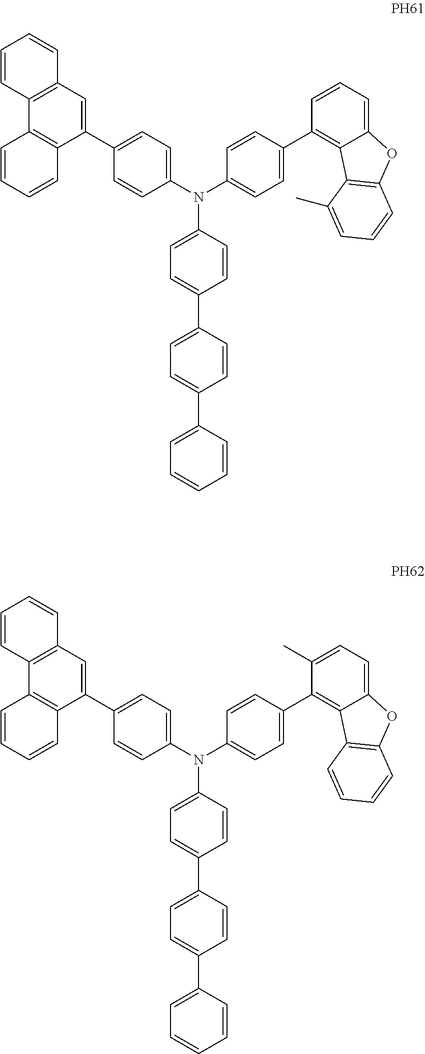 [SMILES: Cc1cccc2oc3cccc(-c4ccc(N(c5ccc(-c6ccc(-c7ccccc7)cc6)cc5)c5ccc(-c6cc7ccccc7c7ccccc67)cc5)cc4)c3c12 ; Cc1ccc2oc3ccccc3c2c1-c1ccc(N(c2ccc(-c3ccc(-c4ccccc4)cc3)cc2)c2ccc(-c3cc4ccccc4c4ccccc34)cc2)cc1]

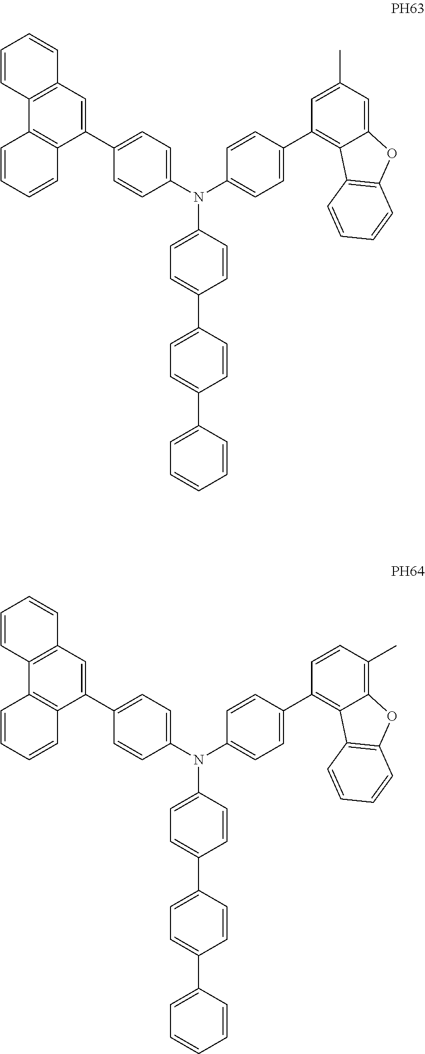 [SMILES: Cc1cc(-c2ccc(N(c3ccc(-c4ccc(-c5ccccc5)cc4)cc3)c3ccc(-c4cc5ccccc5c5ccccc45)cc3)cc2)c2c(c1)oc1ccccc12 ; Cc1ccc(-c2ccc(N(c3ccc(-c4ccc(-c5ccccc5)cc4)cc3)c3ccc(-c4cc5ccccc5c5ccccc45)cc3)cc2)c2c1oc1ccccc12]

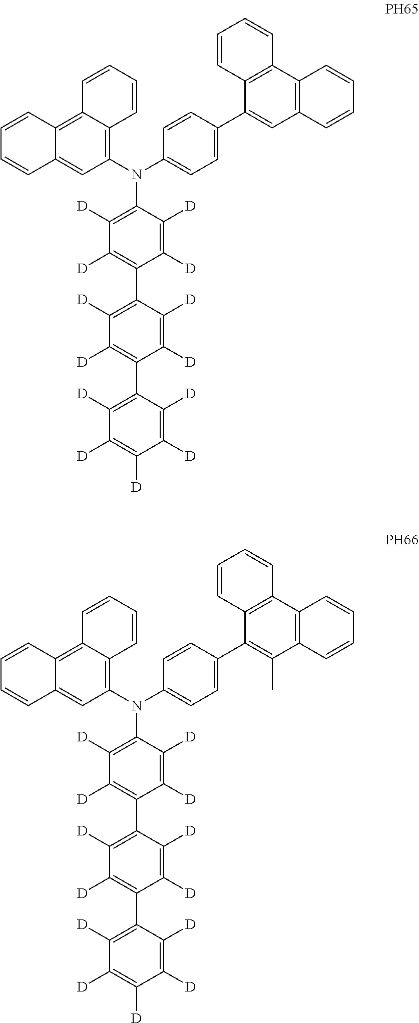 [SMILES: [2H]c1c([2H])c([2H])c(-c2c([2H])c([2H])c(-c3c([2H])c([2H])c(N(c4ccc(-c5cc6ccccc6c6ccccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5c(C)c6ccccc6c6ccccc56)cc4)c4cc5ccccc5c5ccccc45)c([2H])c3[2H])c([2H])c2[2H])c([2H])c1[2H]]

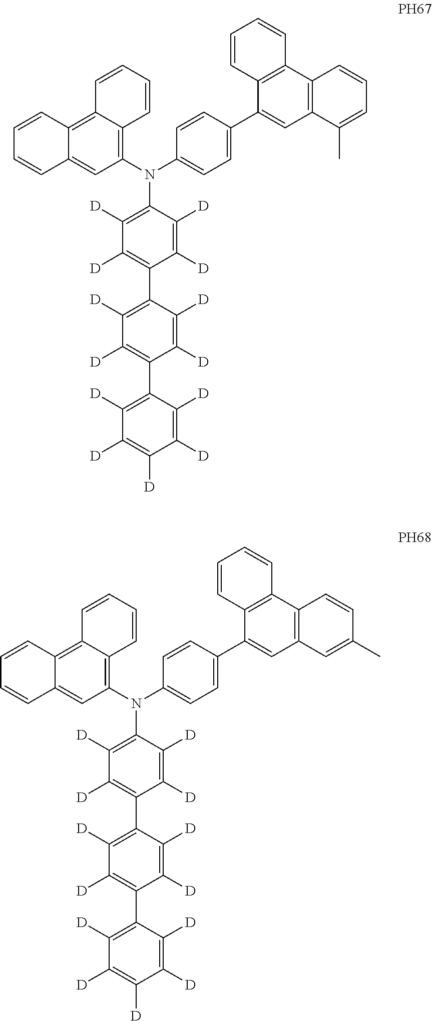 [SMILES: [2H]c1c([2H])c([2H])c(-c2c([2H])c([2H])c(-c3c([2H])c([2H])c(N(c4ccc(-c5cc6c(C)cccc6c6ccccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5cc6cc(C)ccc6c6ccccc56)cc4)c4cc5ccccc5c5ccccc45)c([2H])c3[2H])c([2H])c2[2H])c([2H])c1[2H]]

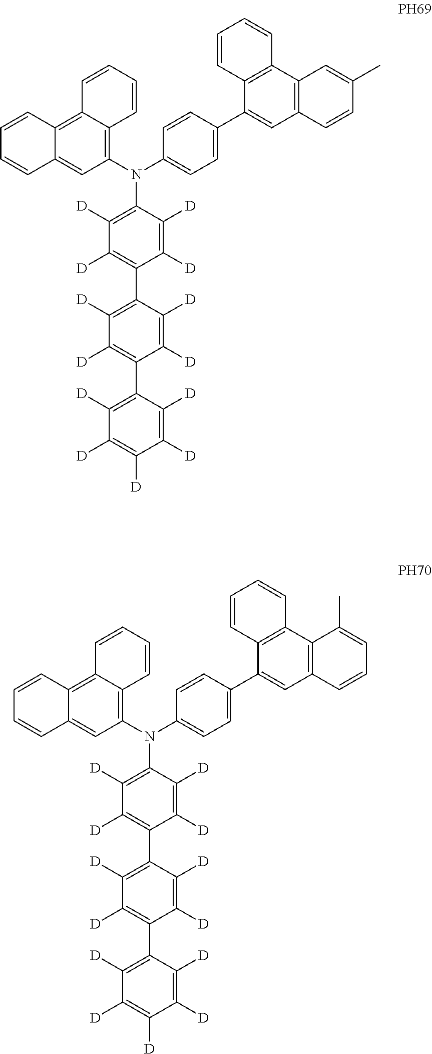 [SMILES: [2H]c1c([2H])c([2H])c(-c2c([2H])c([2H])c(-c3c([2H])c([2H])c(N(c4ccc(-c5cc6ccc(C)cc6c6ccccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5cc6cccc(C)c6c6ccccc56)cc4)c4cc5ccccc5c5ccccc45)c([2H])c3[2H])c([2H])c2[2H])c([2H])c1[2H]]

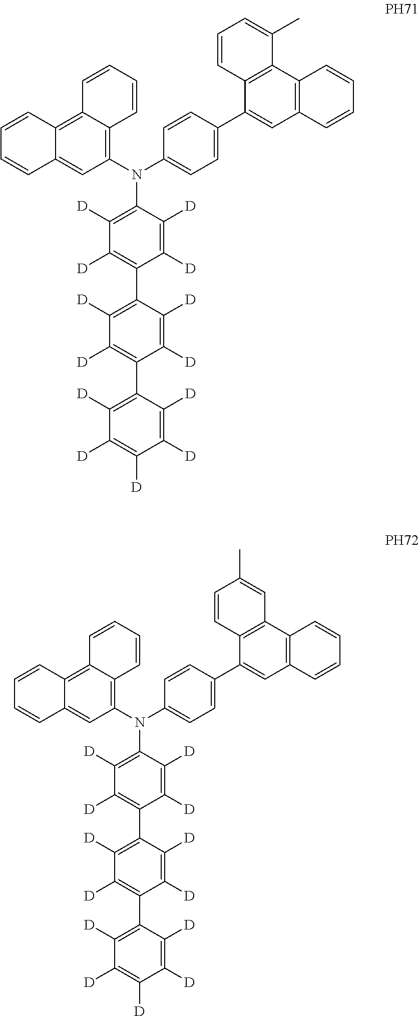 [SMILES: [2H]c1c([2H])c([2H])c(-c2c([2H])c([2H])c(-c3c([2H])c([2H])c(N(c4ccc(-c5cc6ccccc6c6c(C)cccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5cc6ccccc6c6cc(C)ccc56)cc4)c4cc5ccccc5c5ccccc45)c([2H])c3[2H])c([2H])c2[2H])c([2H])c1[2H]]

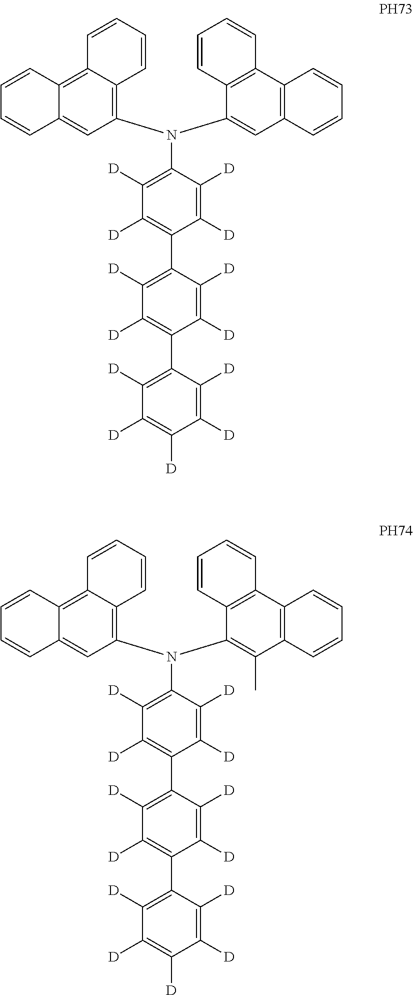 [SMILES: [2H]c1c([2H])c([2H])c(-c2c([2H])c([2H])c(-c3c([2H])c([2H])c(N(c4cc5ccccc5c5ccccc45)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4c(C)c5ccccc5c5ccccc45)c([2H])c3[2H])c([2H])c2[2H])c([2H])c1[2H]]

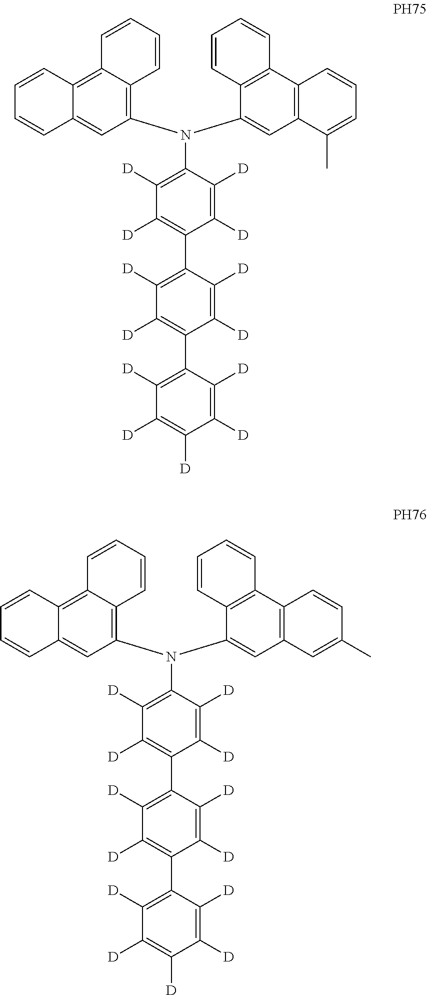 [SMILES: [2H]c1c([2H])c([2H])c(-c2c([2H])c([2H])c(-c3c([2H])c([2H])c(N(c4cc5ccccc5c5ccccc45)c4cc5c(C)cccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4cc5cc(C)ccc5c5ccccc45)c([2H])c3[2H])c([2H])c2[2H])c([2H])c1[2H]]

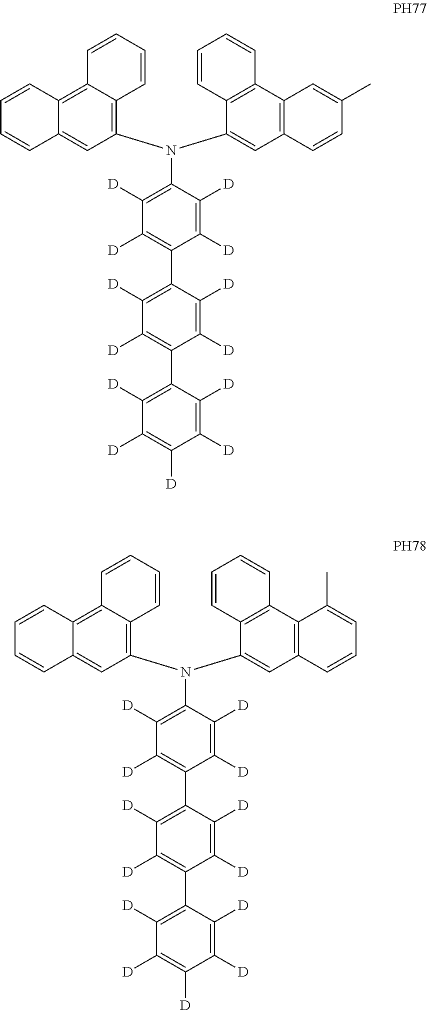 [SMILES: [2H]c1c([2H])c([2H])c(-c2c([2H])c([2H])c(-c3c([2H])c([2H])c(N(c4cc5ccccc5c5ccccc45)c4cc5ccc(C)cc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4cc5cccc(C)c5c5ccccc45)c([2H])c3[2H])c([2H])c2[2H])c([2H])c1[2H]]

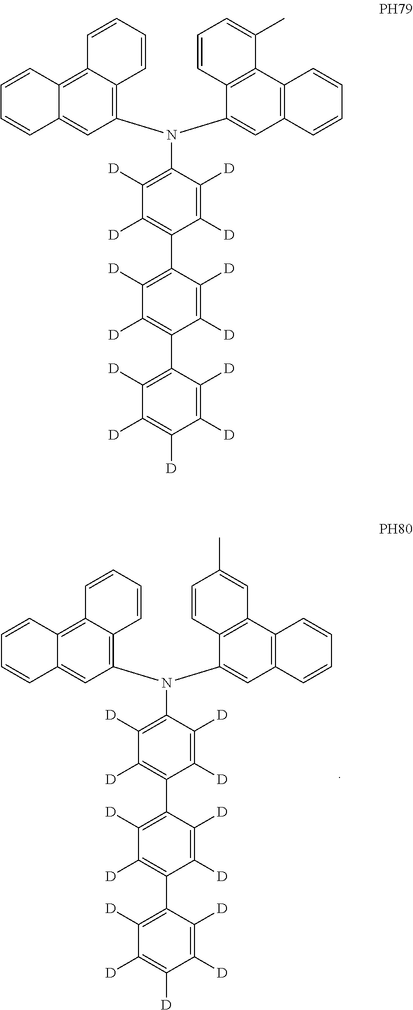 [SMILES: [2H]c1c([2H])c([2H])c(-c2c([2H])c([2H])c(-c3c([2H])c([2H])c(N(c4cc5ccccc5c5ccccc45)c4cc5ccccc5c5c(C)cccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4cc5ccccc5c5cc(C)ccc45)c([2H])c3[2H])c([2H])c2[2H])c([2H])c1[2H]]

The third compound 346 can be an organic compound with an azine moiety, for example, a triazine moiety, with a beneficial electron donor property. As an example, the third compound 346 can have the structure of Chemical Formula 11:

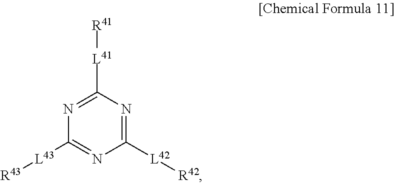

wherein:
each of R⁴¹ to R⁴³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group; and
each of L⁴¹ to L⁴³ is independently a single bond, an unsubstituted or substituted C₆-C₃₀ arylene group or an unsubstituted or substituted C₂-C₃₀ hetero arylene group.

As an example, R⁴¹ can be selected from phenyl, naphthyl, dibenzofuranyl and dibenzothiophenyl each of which is independently unsubstituted or substituted with at least one of C₁-C₁₀ alkyl and C₆-C₂₀ aryl, each of R⁴² and R⁴³ can be independently selected from phenyl, biphenyl, terphenyl and naphthyl each of which is independently unsubstituted or substituted with at least one of C₁-C₁₀ alkyl and C₆-C₂₀ aryl, and/or each of L⁴¹ to L⁴³ is independently the single bond, a phenylene group, a biphenylene group, a terphenylene group or a naphthylene group in Chemical Formula 11.

In some embodiments, each of L⁴¹, L⁴², and L⁴³ is independently chosen from a single bond,

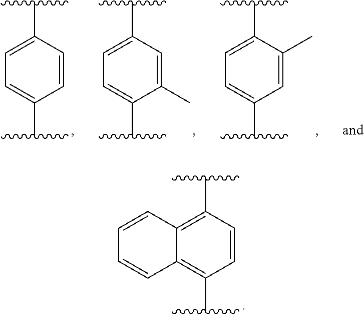

In some embodiments, R⁴¹ is chosen from:

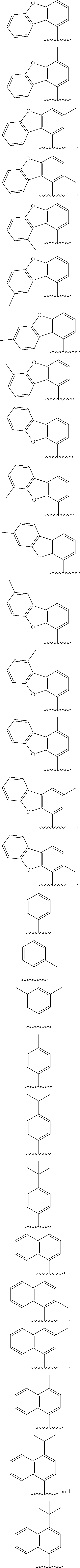

In some embodiments, each of R⁴² and R⁴³ is independently chosen from:

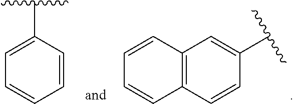 [SMILES: *c1ccccc1 ; *c1ccc2ccccc2c1]

For example, the third compound 346 having the structure of Chemical Formula 11 can be at least one of or selected from, but is not limited to, the following organic compounds of Chemical Formula 12:

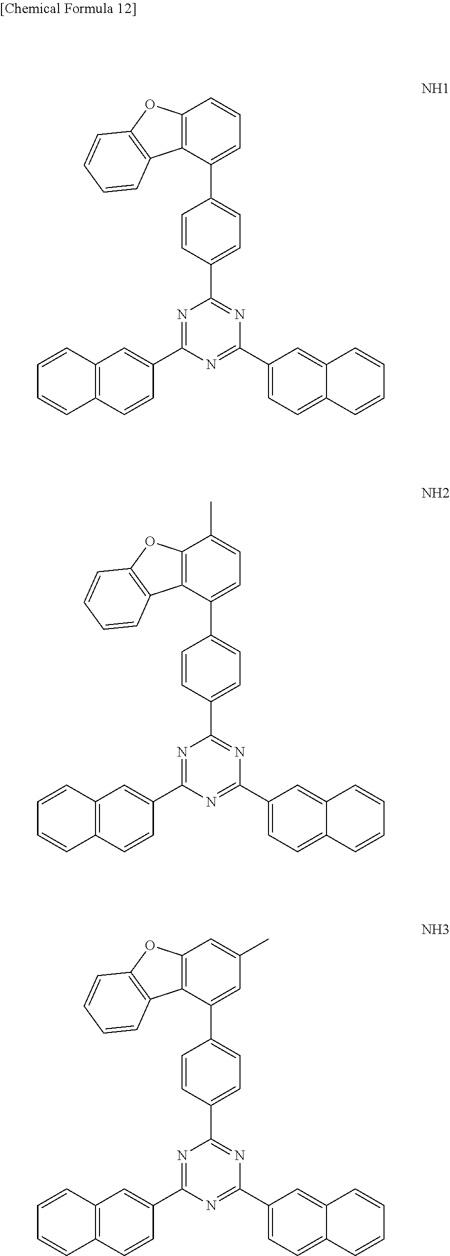 [SMILES: c1ccc2cc(-c3nc(-c4ccc(-c5cccc6oc7ccccc7c56)cc4)nc(-c4ccc5ccccc5c4)n3)ccc2c1 ; Cc1ccc(-c2ccc(-c3nc(-c4ccc5ccccc5c4)nc(-c4ccc5ccccc5c4)n3)cc2)c2c1oc1ccccc12 ; Cc1cc(-c2ccc(-c3nc(-c4ccc5ccccc5c4)nc(-c4ccc5ccccc5c4)n3)cc2)c2c(c1)oc1ccccc12]

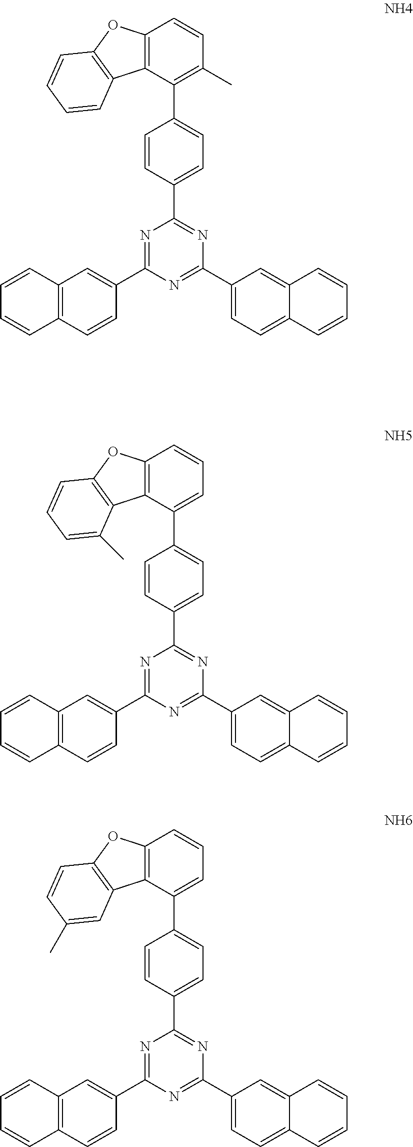 [SMILES: Cc1ccc2oc3ccccc3c2c1-c1ccc(-c2nc(-c3ccc4ccccc4c3)nc(-c3ccc4ccccc4c3)n2)cc1 ; Cc1cccc2oc3cccc(-c4ccc(-c5nc(-c6ccc7ccccc7c6)nc(-c6ccc7ccccc7c6)n5)cc4)c3c12 ; Cc1ccc2oc3cccc(-c4ccc(-c5nc(-c6ccc7ccccc7c6)nc(-c6ccc7ccccc7c6)n5)cc4)c3c2c1]

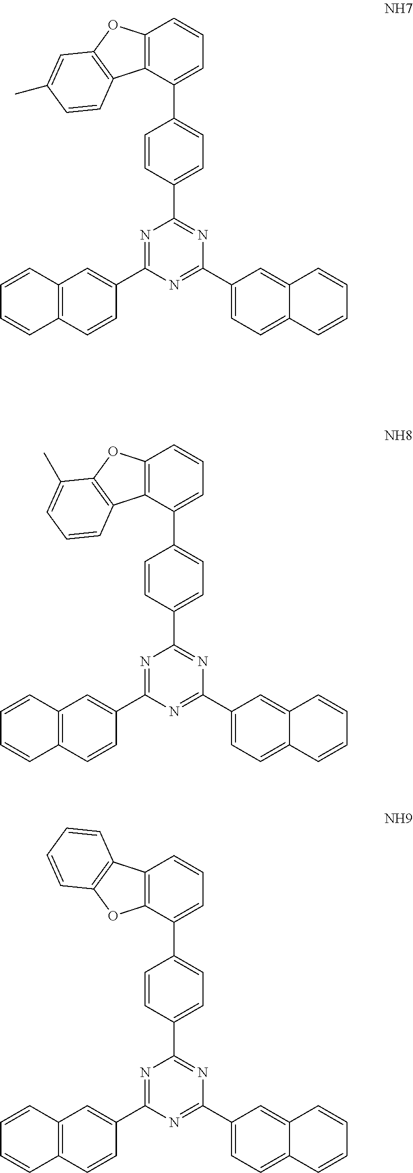 [SMILES: Cc1ccc2c(c1)oc1cccc(-c3ccc(-c4nc(-c5ccc6ccccc6c5)nc(-c5ccc6ccccc6c5)n4)cc3)c12 ; Cc1cccc2c1oc1cccc(-c3ccc(-c4nc(-c5ccc6ccccc6c5)nc(-c5ccc6ccccc6c5)n4)cc3)c12 ; c1ccc2cc(-c3nc(-c4ccc(-c5cccc6c5oc5ccccc56)cc4)nc(-c4ccc5ccccc5c4)n3)ccc2c1]

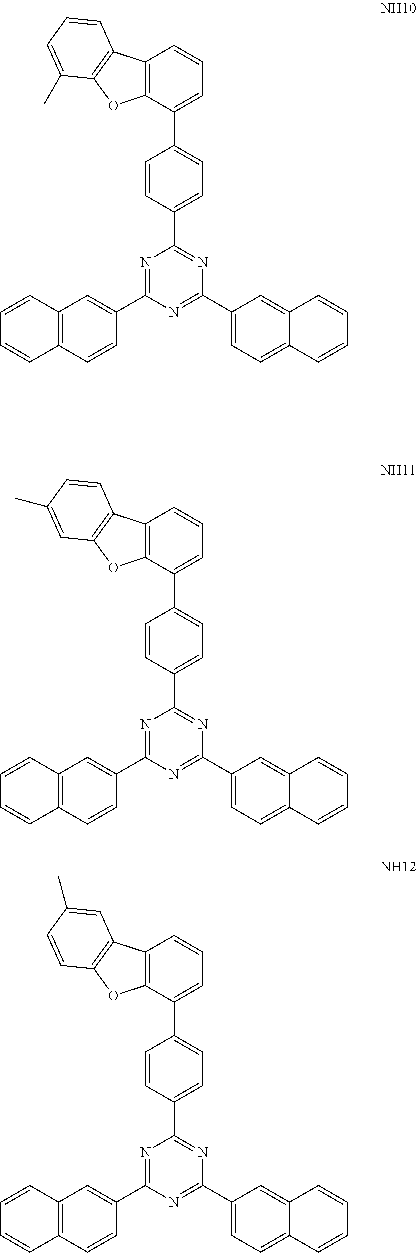 [SMILES: Cc1cccc2c1oc1c(-c3ccc(-c4nc(-c5ccc6ccccc6c5)nc(-c5ccc6ccccc6c5)n4)cc3)cccc12 ; Cc1ccc2c(c1)oc1c(-c3ccc(-c4nc(-c5ccc6ccccc6c5)nc(-c5ccc6ccccc6c5)n4)cc3)cccc12 ; Cc1ccc2oc3c(-c4ccc(-c5nc(-c6ccc7ccccc7c6)nc(-c6ccc7ccccc7c6)n5)cc4)cccc3c2c1]

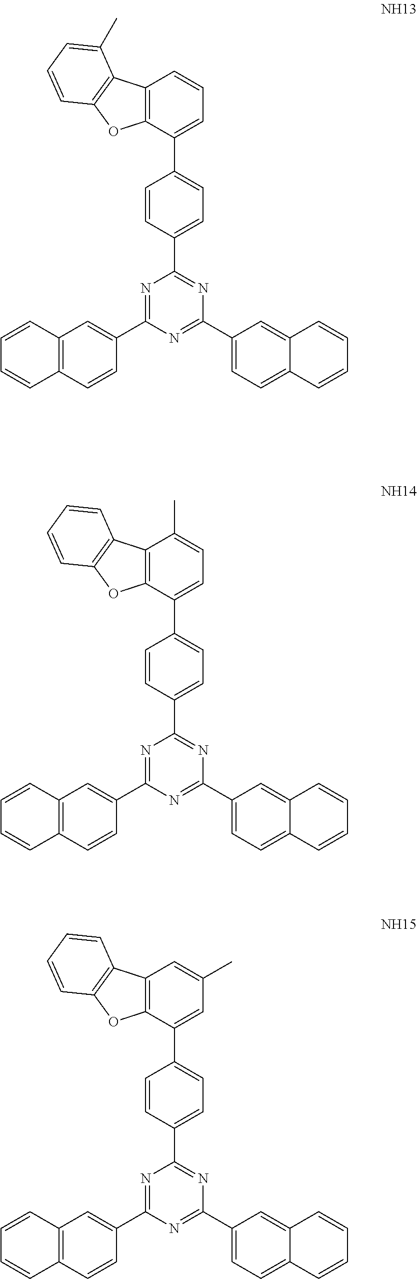 [SMILES: Cc1cccc2oc3c(-c4ccc(-c5nc(-c6ccc7ccccc7c6)nc(-c6ccc7ccccc7c6)n5)cc4)cccc3c12 ; Cc1ccc(-c2ccc(-c3nc(-c4ccc5ccccc5c4)nc(-c4ccc5ccccc5c4)n3)cc2)c2oc3ccccc3c12 ; Cc1cc(-c2ccc(-c3nc(-c4ccc5ccccc5c4)nc(-c4ccc5ccccc5c4)n3)cc2)c2oc3ccccc3c2c1]

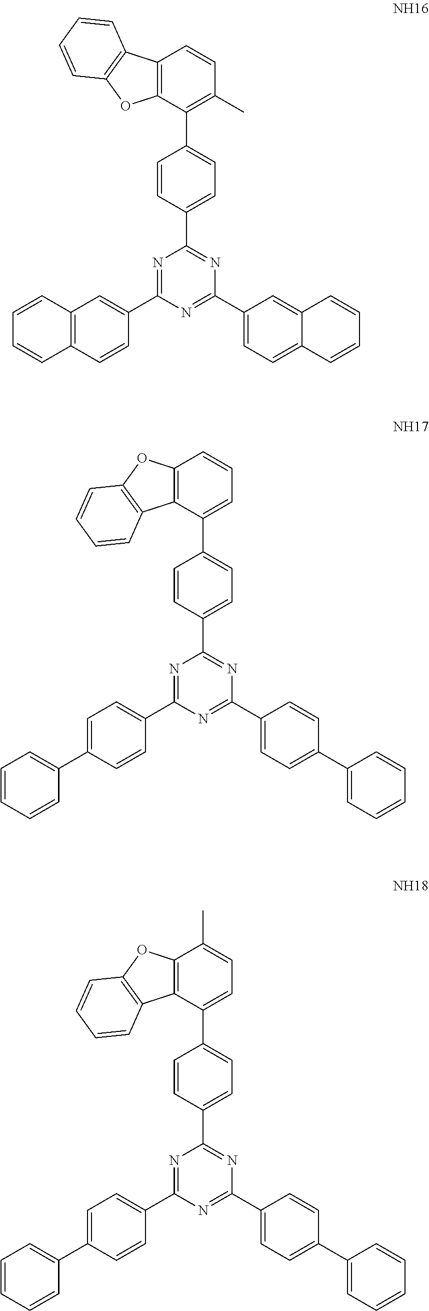 [SMILES: Cc1ccc2c(oc3ccccc32)c1-c1ccc(-c2nc(-c3ccc4ccccc4c3)nc(-c3ccc4ccccc4c3)n2)cc1 ; c1ccc(-c2ccc(-c3nc(-c4ccc(-c5ccccc5)cc4)nc(-c4ccc(-c5cccc6oc7ccccc7c56)cc4)n3)cc2)cc1 ; Cc1ccc(-c2ccc(-c3nc(-c4ccc(-c5ccccc5)cc4)nc(-c4ccc(-c5ccccc5)cc4)n3)cc2)c2c1oc1ccccc12]

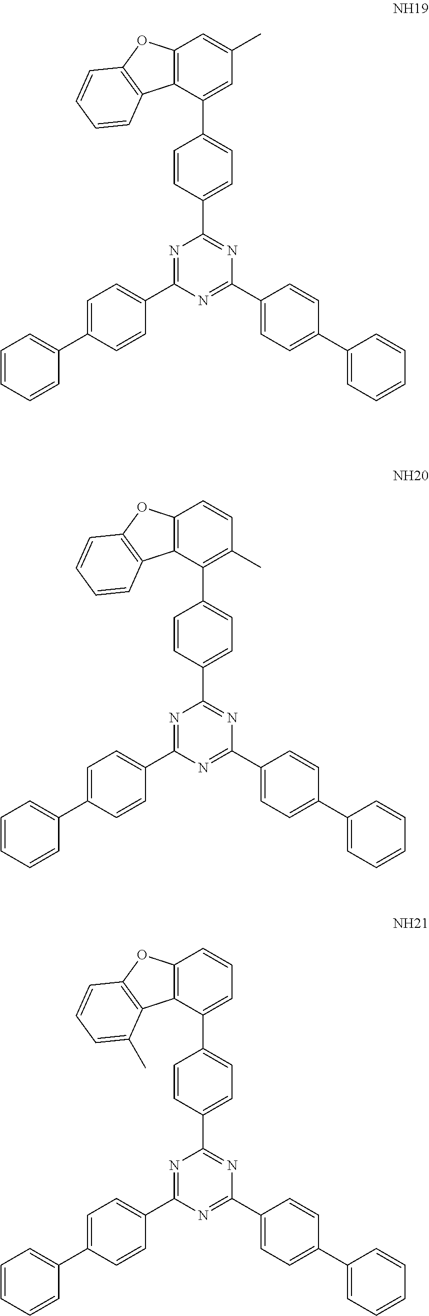 [SMILES: Cc1cc(-c2ccc(-c3nc(-c4ccc(-c5ccccc5)cc4)nc(-c4ccc(-c5ccccc5)cc4)n3)cc2)c2c(c1)oc1ccccc12 ; Cc1ccc2oc3ccccc3c2c1-c1ccc(-c2nc(-c3ccc(-c4ccccc4)cc3)nc(-c3ccc(-c4ccccc4)cc3)n2)cc1 ; Cc1cccc2oc3cccc(-c4ccc(-c5nc(-c6ccc(-c7ccccc7)cc6)nc(-c6ccc(-c7ccccc7)cc6)n5)cc4)c3c12]

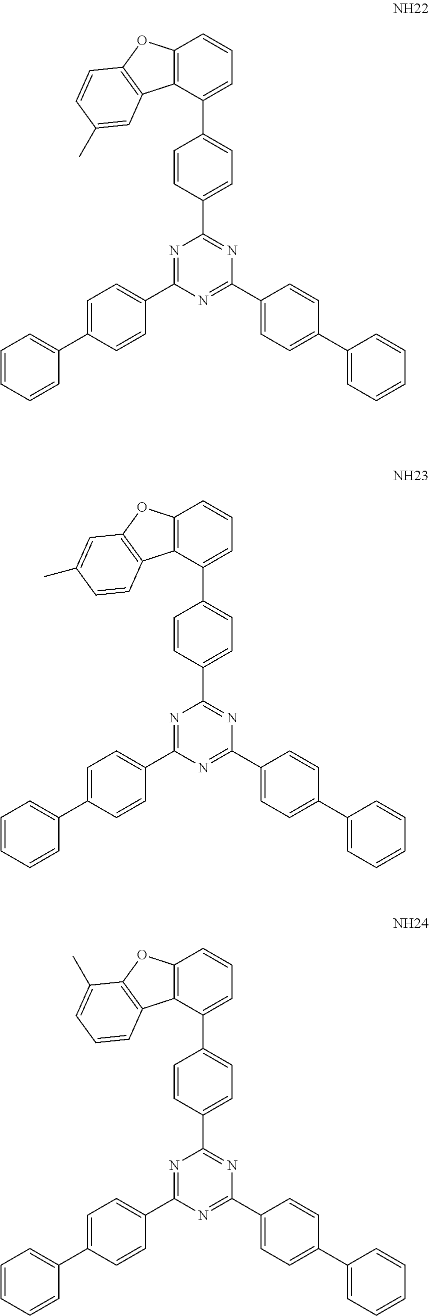 [SMILES: Cc1ccc2oc3cccc(-c4ccc(-c5nc(-c6ccc(-c7ccccc7)cc6)nc(-c6ccc(-c7ccccc7)cc6)n5)cc4)c3c2c1 ; Cc1ccc2c(c1)oc1cccc(-c3ccc(-c4nc(-c5ccc(-c6ccccc6)cc5)nc(-c5ccc(-c6ccccc6)cc5)n4)cc3)c12 ; Cc1cccc2c1oc1cccc(-c3ccc(-c4nc(-c5ccc(-c6ccccc6)cc5)nc(-c5ccc(-c6ccccc6)cc5)n4)cc3)c12]

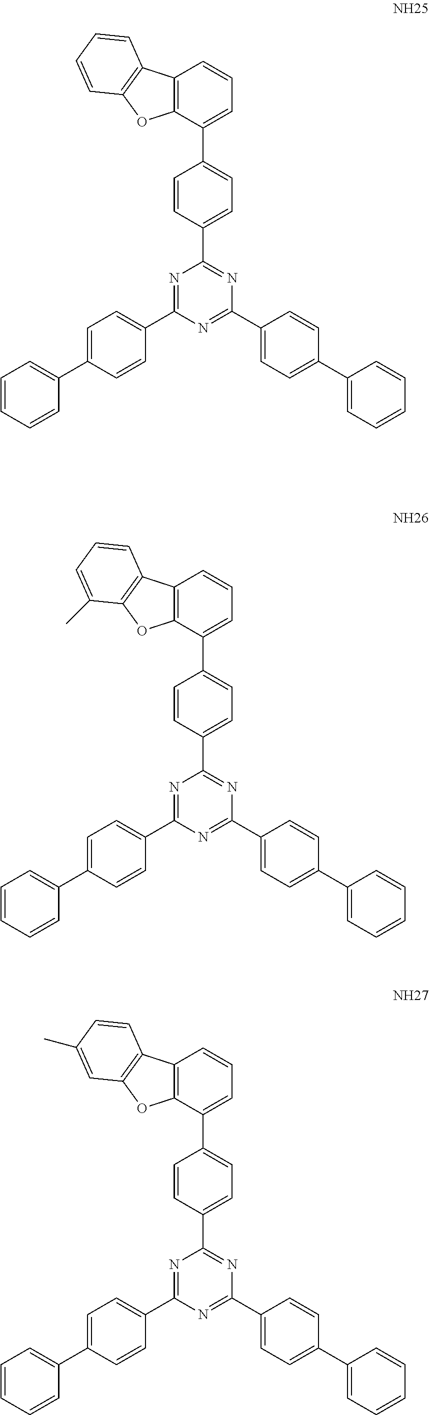 [SMILES: c1ccc(-c2ccc(-c3nc(-c4ccc(-c5ccccc5)cc4)nc(-c4ccc(-c5cccc6c5oc5ccccc56)cc4)n3)cc2)cc1 ; Cc1cccc2c1oc1c(-c3ccc(-c4nc(-c5ccc(-c6ccccc6)cc5)nc(-c5ccc(-c6ccccc6)cc5)n4)cc3)cccc12 ; Cc1ccc2c(c1)oc1c(-c3ccc(-c4nc(-c5ccc(-c6ccccc6)cc5)nc(-c5ccc(-c6ccccc6)cc5)n4)cc3)cccc12]

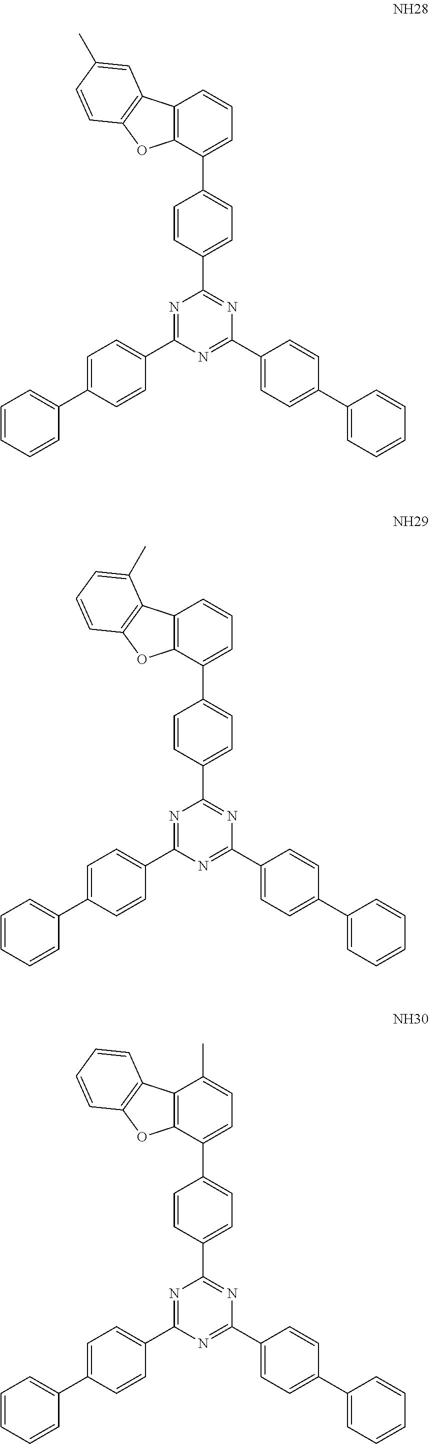 [SMILES: Cc1ccc2oc3c(-c4ccc(-c5nc(-c6ccc(-c7ccccc7)cc6)nc(-c6ccc(-c7ccccc7)cc6)n5)cc4)cccc3c2c1 ; Cc1cccc2oc3c(-c4ccc(-c5nc(-c6ccc(-c7ccccc7)cc6)nc(-c6ccc(-c7ccccc7)cc6)n5)cc4)cccc3c12 ; Cc1ccc(-c2ccc(-c3nc(-c4ccc(-c5ccccc5)cc4)nc(-c4ccc(-c5ccccc5)cc4)n3)cc2)c2oc3ccccc3c12]

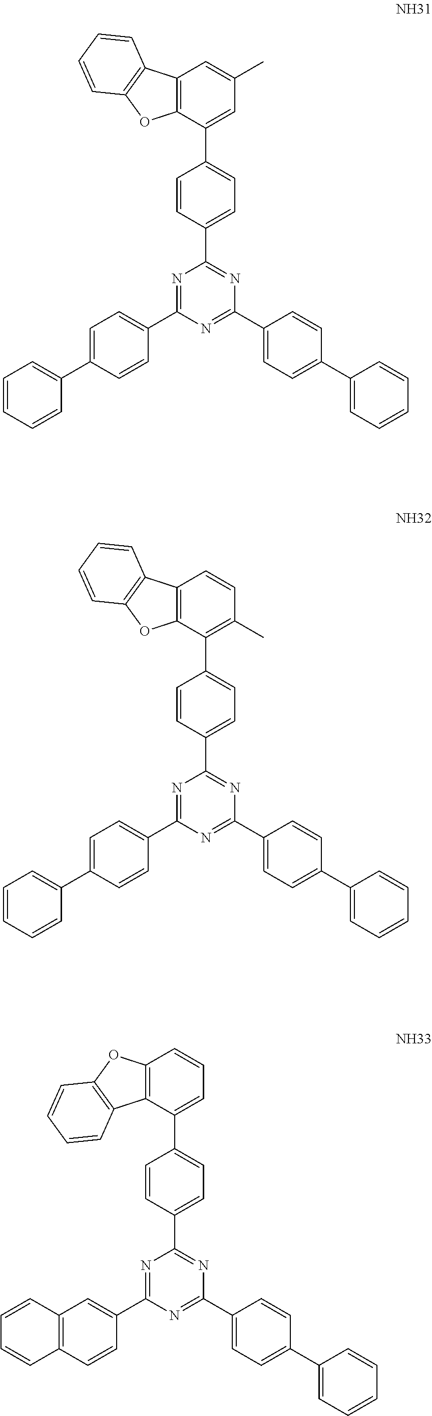 [SMILES: Cc1cc(-c2ccc(-c3nc(-c4ccc(-c5ccccc5)cc4)nc(-c4ccc(-c5ccccc5)cc4)n3)cc2)c2oc3ccccc3c2c1 ; Cc1ccc2c(oc3ccccc32)c1-c1ccc(-c2nc(-c3ccc(-c4ccccc4)cc3)nc(-c3ccc(-c4ccccc4)cc3)n2)cc1 ; c1ccc(-c2ccc(-c3nc(-c4ccc(-c5cccc6oc7ccccc7c56)cc4)nc(-c4ccc5ccccc5c4)n3)cc2)cc1]

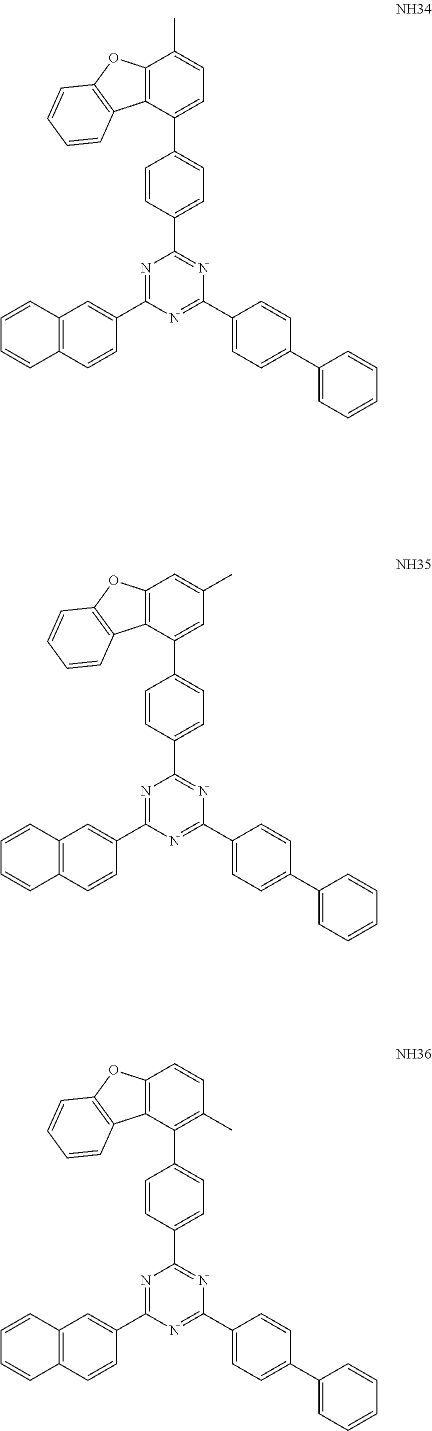 [SMILES: Cc1ccc(-c2ccc(-c3nc(-c4ccc(-c5ccccc5)cc4)nc(-c4ccc5ccccc5c4)n3)cc2)c2c1oc1ccccc12 ; Cc1cc(-c2ccc(-c3nc(-c4ccc(-c5ccccc5)cc4)nc(-c4ccc5ccccc5c4)n3)cc2)c2c(c1)oc1ccccc12 ; Cc1ccc2oc3ccccc3c2c1-c1ccc(-c2nc(-c3ccc(-c4ccccc4)cc3)nc(-c3ccc4ccccc4c3)n2)cc1]

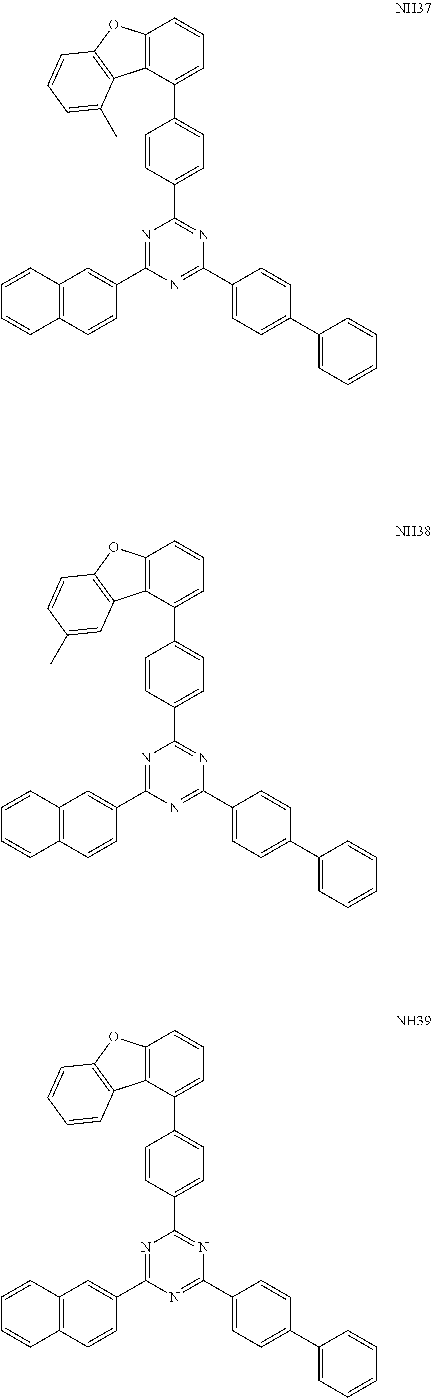 [SMILES: Cc1cccc2oc3cccc(-c4ccc(-c5nc(-c6ccc(-c7ccccc7)cc6)nc(-c6ccc7ccccc7c6)n5)cc4)c3c12 ; Cc1ccc2oc3cccc(-c4ccc(-c5nc(-c6ccc(-c7ccccc7)cc6)nc(-c6ccc7ccccc7c6)n5)cc4)c3c2c1 ; c1ccc(-c2ccc(-c3nc(-c4ccc(-c5cccc6oc7ccccc7c56)cc4)nc(-c4ccc5ccccc5c4)n3)cc2)cc1]

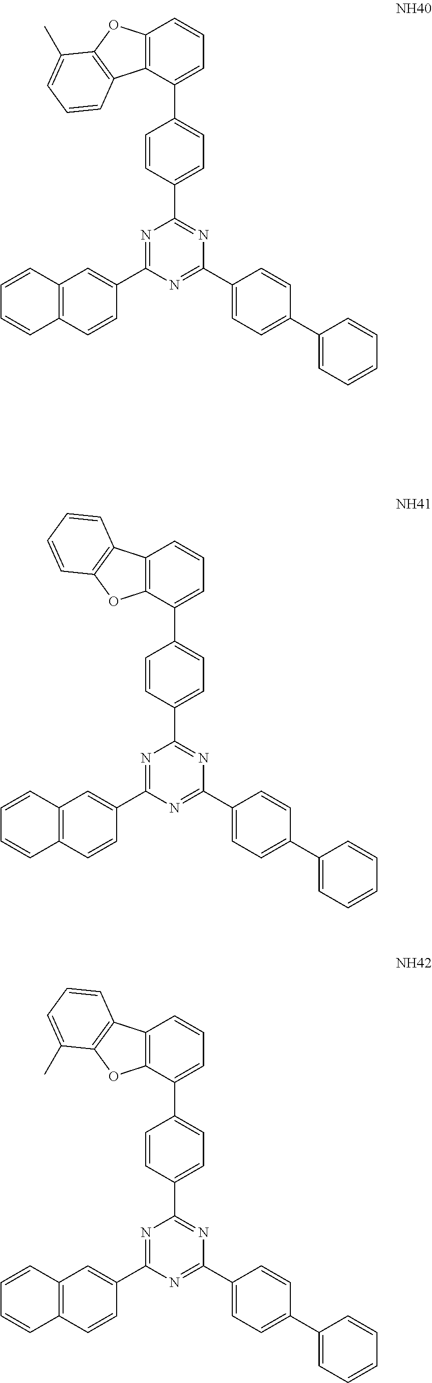 [SMILES: Cc1cccc2c1oc1cccc(-c3ccc(-c4nc(-c5ccc(-c6ccccc6)cc5)nc(-c5ccc6ccccc6c5)n4)cc3)c12 ; c1ccc(-c2ccc(-c3nc(-c4ccc(-c5cccc6c5oc5ccccc56)cc4)nc(-c4ccc5ccccc5c4)n3)cc2)cc1 ; Cc1cccc2c1oc1c(-c3ccc(-c4nc(-c5ccc(-c6ccccc6)cc5)nc(-c5ccc6ccccc6c5)n4)cc3)cccc12]

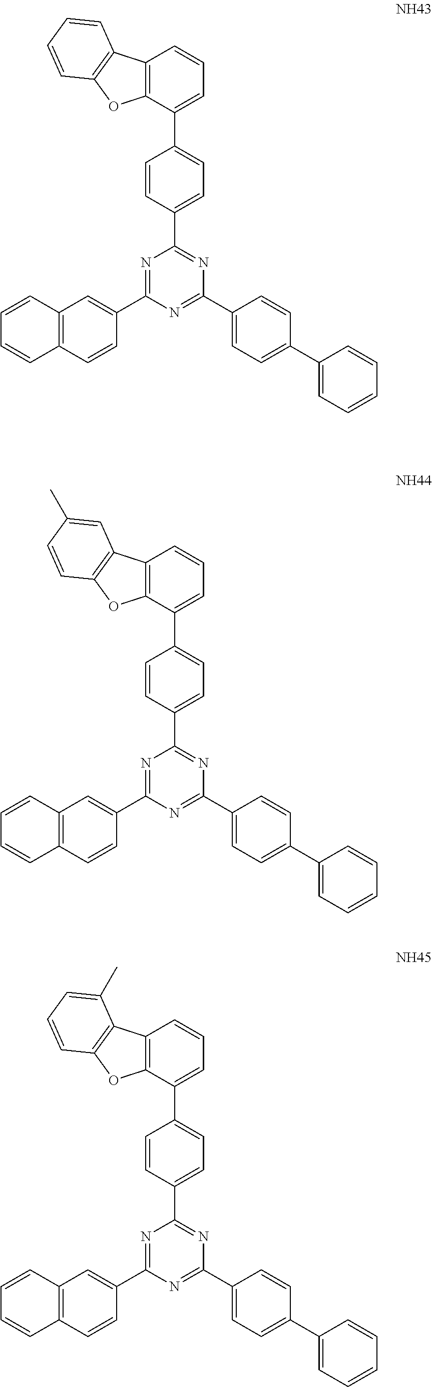 [SMILES: c1ccc(-c2ccc(-c3nc(-c4ccc(-c5cccc6c5oc5ccccc56)cc4)nc(-c4ccc5ccccc5c4)n3)cc2)cc1 ; Cc1ccc2oc3c(-c4ccc(-c5nc(-c6ccc(-c7ccccc7)cc6)nc(-c6ccc7ccccc7c6)n5)cc4)cccc3c2c1 ; Cc1cccc2oc3c(-c4ccc(-c5nc(-c6ccc(-c7ccccc7)cc6)nc(-c6ccc7ccccc7c6)n5)cc4)cccc3c12]

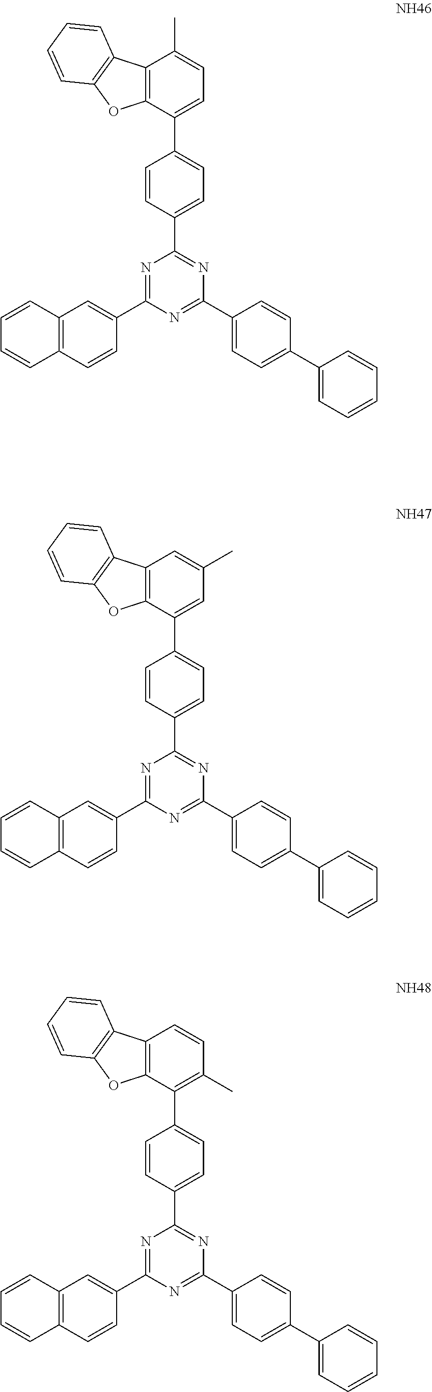 [SMILES: Cc1ccc(-c2ccc(-c3nc(-c4ccc(-c5ccccc5)cc4)nc(-c4ccc5ccccc5c4)n3)cc2)c2oc3ccccc3c12 ; Cc1cc(-c2ccc(-c3nc(-c4ccc(-c5ccccc5)cc4)nc(-c4ccc5ccccc5c4)n3)cc2)c2oc3ccccc3c2c1 ; Cc1ccc2c(oc3ccccc32)c1-c1ccc(-c2nc(-c3ccc(-c4ccccc4)cc3)nc(-c3ccc4ccccc4c3)n2)cc1]

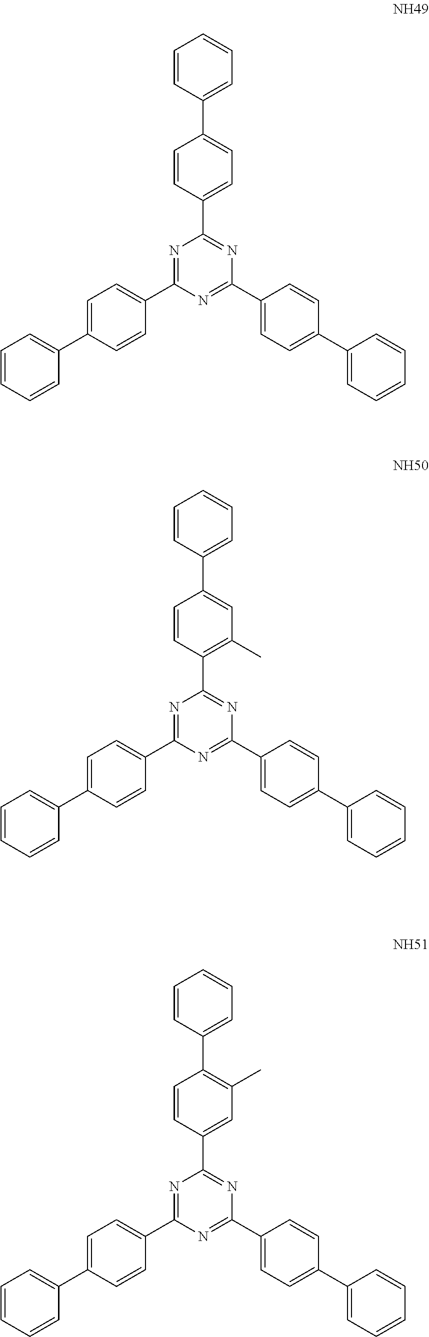 [SMILES: c1ccc(-c2ccc(-c3nc(-c4ccc(-c5ccccc5)cc4)nc(-c4ccc(-c5ccccc5)cc4)n3)cc2)cc1 ; Cc1cc(-c2ccccc2)ccc1-c1nc(-c2ccc(-c3ccccc3)cc2)nc(-c2ccc(-c3ccccc3)cc2)n1 ; Cc1cc(-c2nc(-c3ccc(-c4ccccc4)cc3)nc(-c3ccc(-c4ccccc4)cc3)n2)ccc1-c1ccccc1]

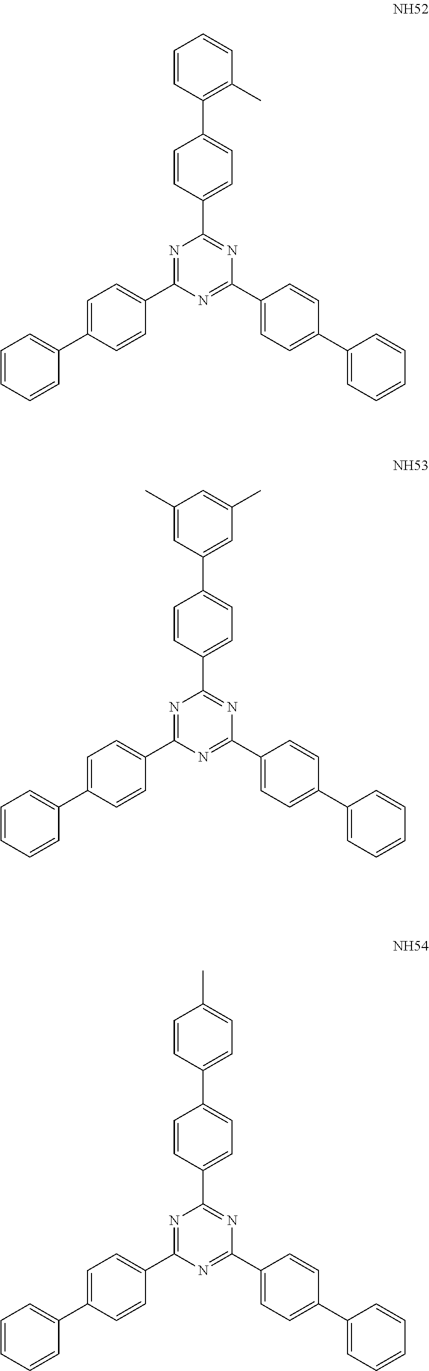 [SMILES: Cc1ccccc1-c1ccc(-c2nc(-c3ccc(-c4ccccc4)cc3)nc(-c3ccc(-c4ccccc4)cc3)n2)cc1 ; Cc1cc(C)cc(-c2ccc(-c3nc(-c4ccc(-c5ccccc5)cc4)nc(-c4ccc(-c5ccccc5)cc4)n3)cc2)c1 ; Cc1ccc(-c2ccc(-c3nc(-c4ccc(-c5ccccc5)cc4)nc(-c4ccc(-c5ccccc5)cc4)n3)cc2)cc1]

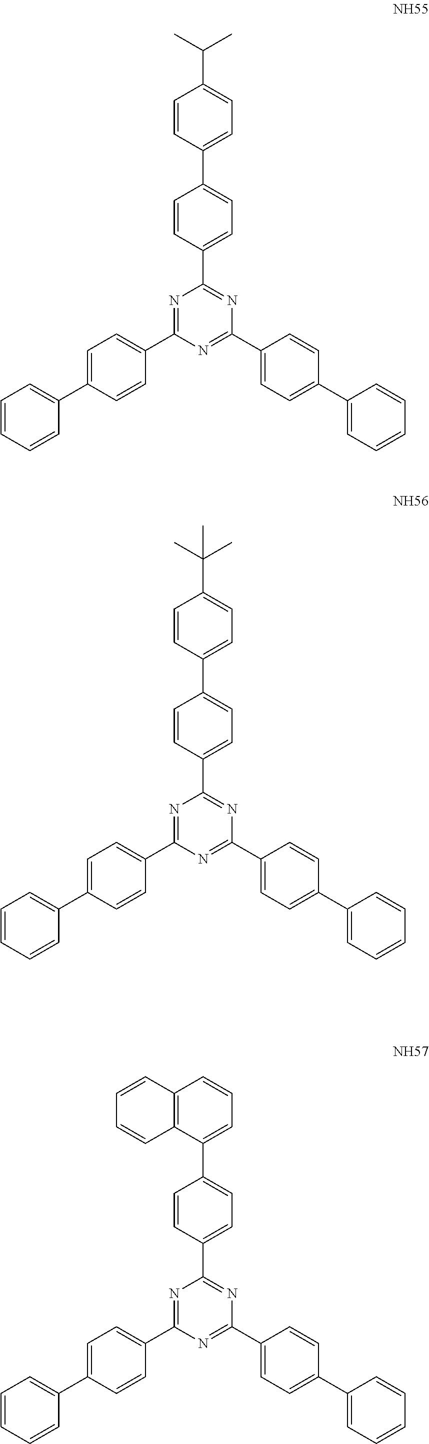 [SMILES: CC(C)c1ccc(-c2ccc(-c3nc(-c4ccc(-c5ccccc5)cc4)nc(-c4ccc(-c5ccccc5)cc4)n3)cc2)cc1 ; CC(C)(C)c1ccc(-c2ccc(-c3nc(-c4ccc(-c5ccccc5)cc4)nc(-c4ccc(-c5ccccc5)cc4)n3)cc2)cc1 ; c1ccc(-c2ccc(-c3nc(-c4ccc(-c5ccccc5)cc4)nc(-c4ccc(-c5cccc6ccccc56)cc4)n3)cc2)cc1]

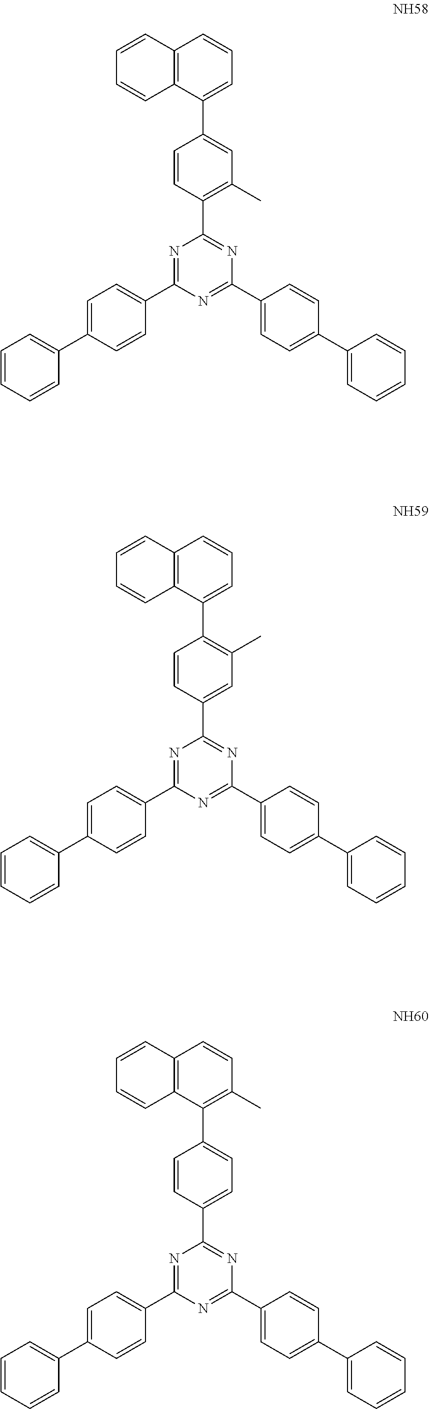 [SMILES: Cc1cc(-c2cccc3ccccc23)ccc1-c1nc(-c2ccc(-c3ccccc3)cc2)nc(-c2ccc(-c3ccccc3)cc2)n1 ; Cc1cc(-c2nc(-c3ccc(-c4ccccc4)cc3)nc(-c3ccc(-c4ccccc4)cc3)n2)ccc1-c1cccc2ccccc12 ; Cc1ccc2ccccc2c1-c1ccc(-c2nc(-c3ccc(-c4ccccc4)cc3)nc(-c3ccc(-c4ccccc4)cc3)n2)cc1]

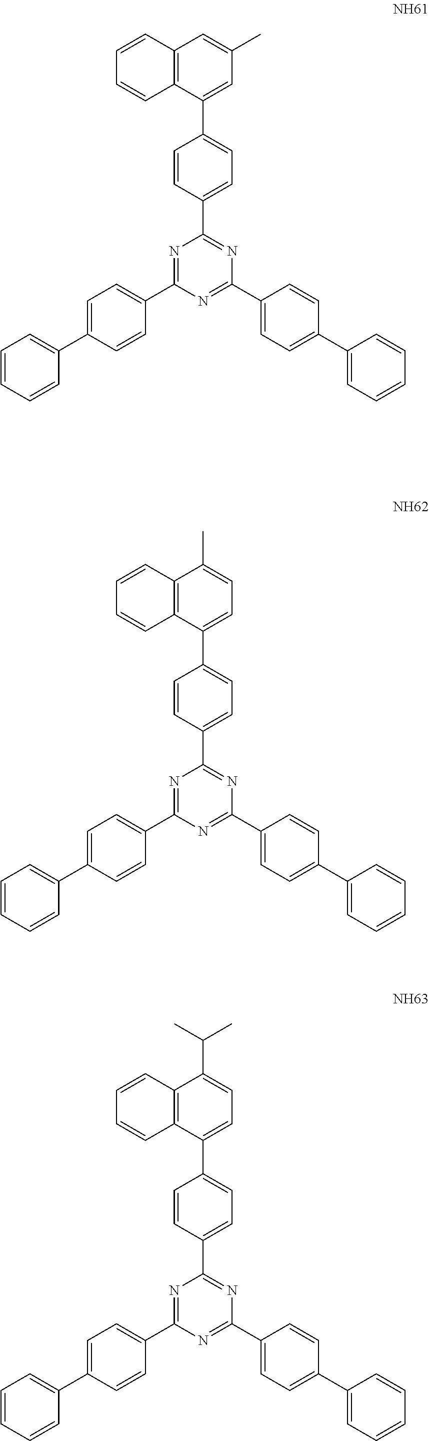 [SMILES: Cc1cc(-c2ccc(-c3nc(-c4ccc(-c5ccccc5)cc4)nc(-c4ccc(-c5ccccc5)cc4)n3)cc2)c2ccccc2c1 ; Cc1ccc(-c2ccc(-c3nc(-c4ccc(-c5ccccc5)cc4)nc(-c4ccc(-c5ccccc5)cc4)n3)cc2)c2ccccc12 ; CC(C)c1ccc(-c2ccc(-c3nc(-c4ccc(-c5ccccc5)cc4)nc(-c4ccc(-c5ccccc5)cc4)n3)cc2)c2ccccc12]

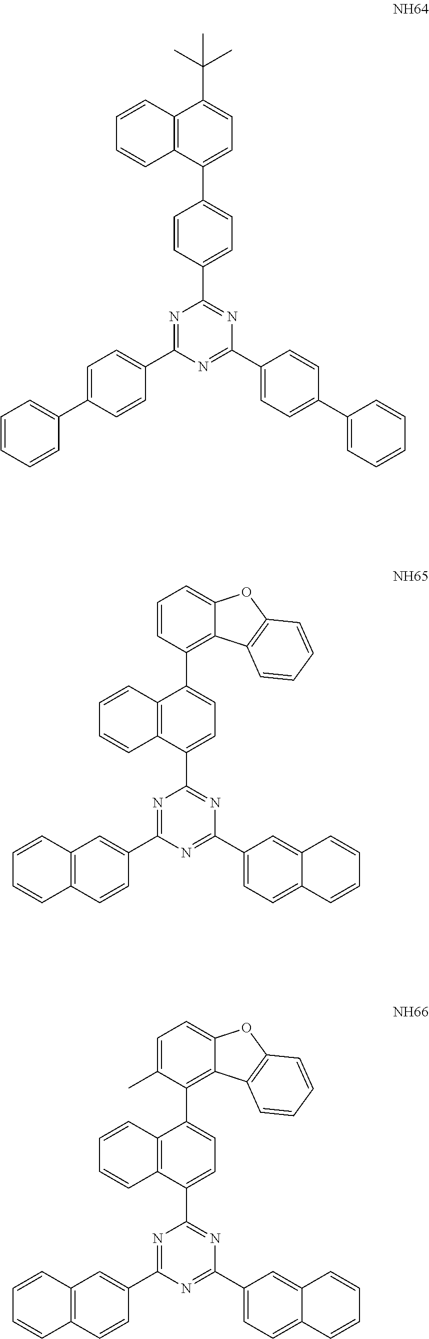 [SMILES: CC(C)(C)c1ccc(-c2ccc(-c3nc(-c4ccc(-c5ccccc5)cc4)nc(-c4ccc(-c5ccccc5)cc4)n3)cc2)c2ccccc12 ; c1ccc2cc(-c3nc(-c4ccc5ccccc5c4)nc(-c4ccc(-c5cccc6oc7ccccc7c56)c5ccccc45)n3)ccc2c1 ; Cc1ccc2oc3ccccc3c2c1-c1ccc(-c2nc(-c3ccc4ccccc4c3)nc(-c3ccc4ccccc4c3)n2)c2ccccc12]

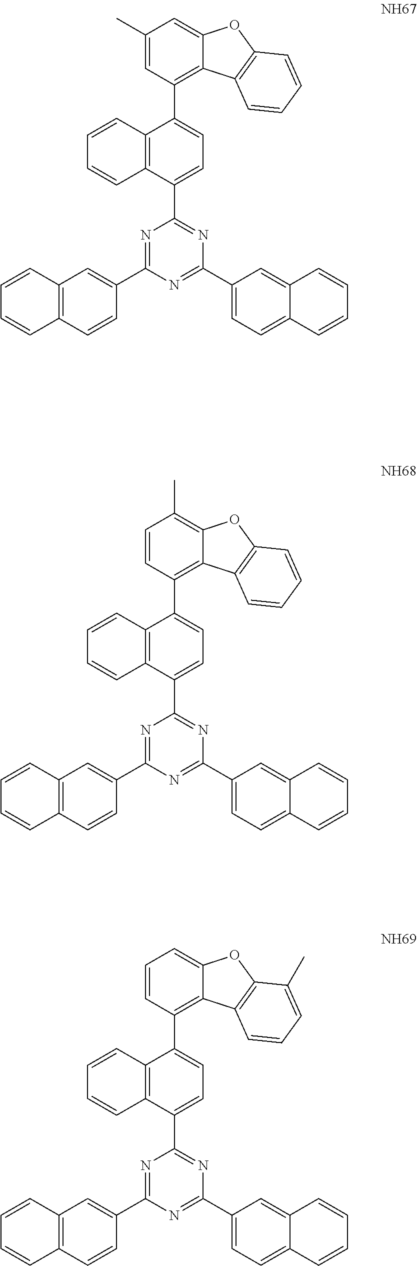 [SMILES: Cc1cc(-c2ccc(-c3nc(-c4ccc5ccccc5c4)nc(-c4ccc5ccccc5c4)n3)c3ccccc23)c2c(c1)oc1ccccc12 ; Cc1ccc(-c2ccc(-c3nc(-c4ccc5ccccc5c4)nc(-c4ccc5ccccc5c4)n3)c3ccccc23)c2c1oc1ccccc12 ; Cc1cccc2c1oc1cccc(-c3ccc(-c4nc(-c5ccc6ccccc6c5)nc(-c5ccc6ccccc6c5)n4)c4ccccc34)c12]

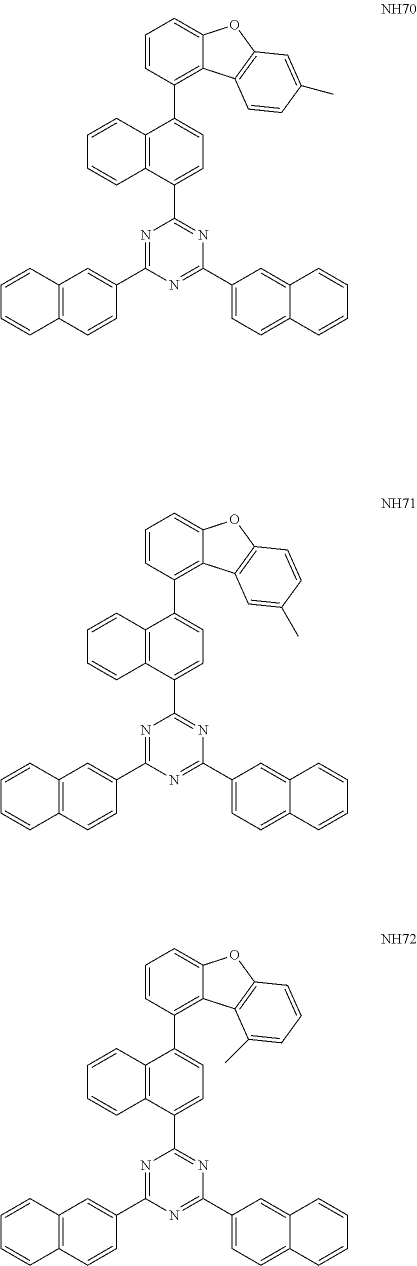 [SMILES: Cc1ccc2c(c1)oc1cccc(-c3ccc(-c4nc(-c5ccc6ccccc6c5)nc(-c5ccc6ccccc6c5)n4)c4ccccc34)c12 ; Cc1ccc2oc3cccc(-c4ccc(-c5nc(-c6ccc7ccccc7c6)nc(-c6ccc7ccccc7c6)n5)c5ccccc45)c3c2c1 ; Cc1cccc2oc3cccc(-c4ccc(-c5nc(-c6ccc7ccccc7c6)nc(-c6ccc7ccccc7c6)n5)c5ccccc45)c3c12]

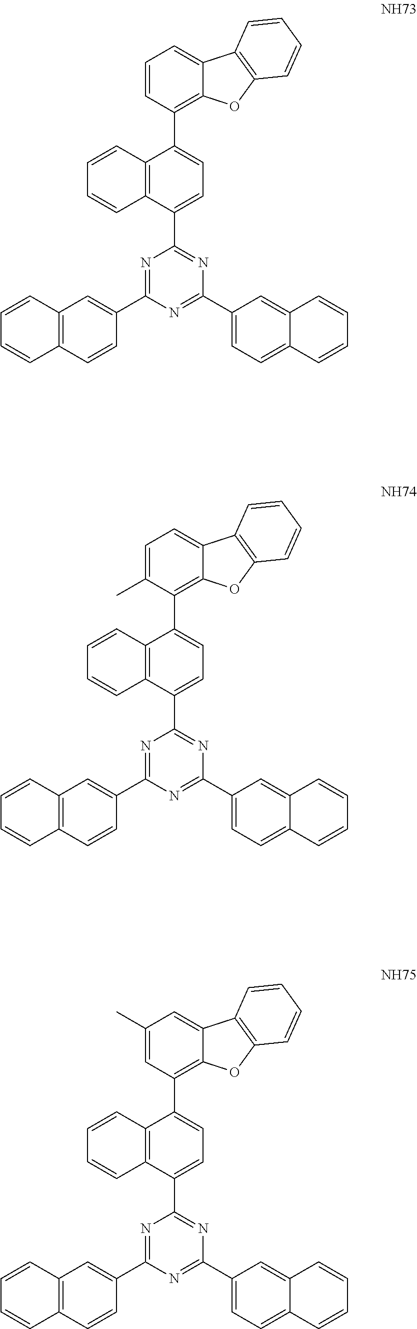 [SMILES: c1ccc2cc(-c3nc(-c4ccc5ccccc5c4)nc(-c4ccc(-c5cccc6c5oc5ccccc56)c5ccccc45)n3)ccc2c1 ; Cc1ccc2c(oc3ccccc32)c1-c1ccc(-c2nc(-c3ccc4ccccc4c3)nc(-c3ccc4ccccc4c3)n2)c2ccccc12 ; Cc1cc(-c2ccc(-c3nc(-c4ccc5ccccc5c4)nc(-c4ccc5ccccc5c4)n3)c3ccccc23)c2oc3ccccc3c2c1]

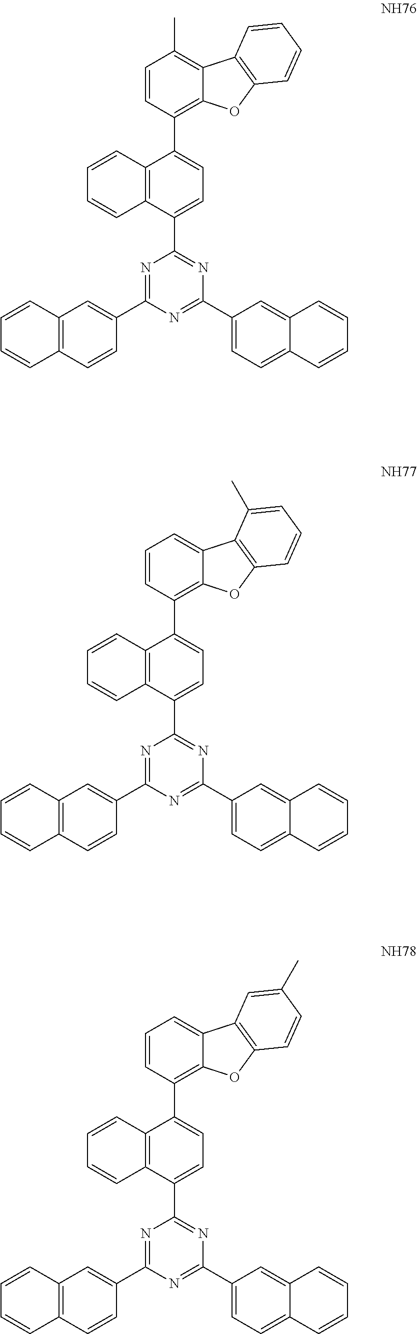 [SMILES: Cc1ccc(-c2ccc(-c3nc(-c4ccc5ccccc5c4)nc(-c4ccc5ccccc5c4)n3)c3ccccc23)c2oc3ccccc3c12 ; Cc1cccc2oc3c(-c4ccc(-c5nc(-c6ccc7ccccc7c6)nc(-c6ccc7ccccc7c6)n5)c5ccccc45)cccc3c12 ; Cc1ccc2oc3c(-c4ccc(-c5nc(-c6ccc7ccccc7c6)nc(-c6ccc7ccccc7c6)n5)c5ccccc45)cccc3c2c1]

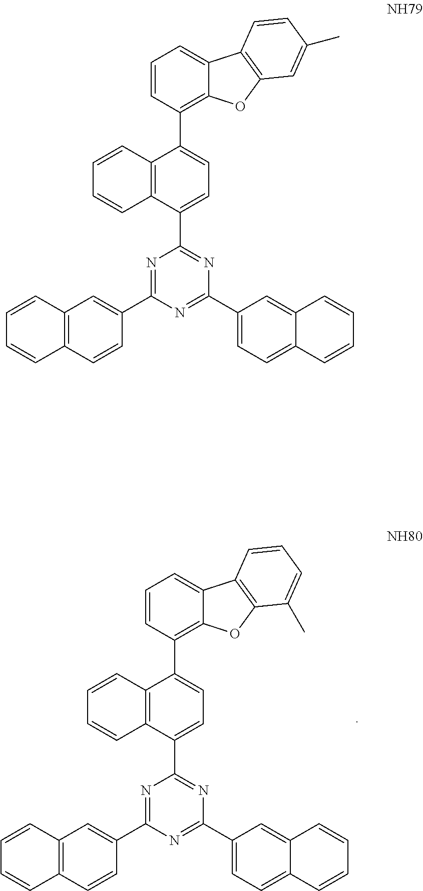 [SMILES: Cc1ccc2c(c1)oc1c(-c3ccc(-c4nc(-c5ccc6ccccc6c5)nc(-c5ccc6ccccc6c5)n4)c4ccccc34)cccc12 ; Cc1cccc2c1oc1c(-c3ccc(-c4nc(-c5ccc6ccccc6c5)nc(-c5ccc6ccccc6c5)n4)c4ccccc34)cccc12]

In one embodiment, the contents of the host including the second host 344, and optionally the third compound 346 in the EML 340 can be about 50 wt. % to about 99 wt. %, for example, about 80 wt. % to about 95 wt. %, and the contents of the first compound 342 in the EML 340 can be about 1 wt. % to about 50 wt. %, for example, about 5 wt. % to about 20 wt. %, but is not limited thereto. When the EML 340 includes both the second compound 344 of the first host and the third compound 346 of the second host, the second compound 344 and the third compound 346 can be mixed, but is not limited to, with a weight ratio of about 4:1 to about 1:4, for example about 3:1 to about 1:3. As an example, the EML 340 can have a thickness, but is not limited to, about 100 Å to about 500 Å.

The ETL 360 and the EIL 370 can be laminated sequentially between the EML 340 and the second electrode 220. An electron transporting material included in the ETL 360 has high electron mobility so as to provide electrons stably with the EML 340 by fast electron transportation.

In one embodiment, the electron transporting material in the ETL 360 can include at least one of oxadiazole-containing compounds, triazole-containing compounds, phenanthroline-containing compounds, benzoxazole-containing compounds, benzothiazole-containing compounds, benzimidazole-containing compounds and triazine-containing compounds.

For example, the electron transporting material in the ETL 360 can include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl) 4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), diphenyl-4-triphenylsilyl-phenylphosphine oxide (TSPO1), 2-[4-(9,10-Di-2-naphthalen2-yl-2-anthracen-2-yl)phenyl]-1-phenyl-1H-benzimidazole (ZADN) and/or combinations thereof.

The EIL 370 is disposed between the second electrode 220 and the ETL 360, and can improve physical properties of the second electrode 220 and therefore, can enhance the lifespan of the OLED D1. In one embodiment, electron injecting material in the EIL 370 can include, but is not limited to, an alkali metal halide or an alkaline earth metal halide such as LiF, CsF, NaF, BaF₂ and the like, and/or an organometallic compound such as Liq, lithium benzoate, sodium stearate, and the like. In certain embodiments, the EIL 370 can be omitted.

In another embodiment, the ETL 360 and the EIL 370 can have a single layered structure. In this case, the above electron transporting material and/or the electron injecting material can be mixed with each other. As an example, the ETL/EIL with a single layered structure can include two or more different electron transporting materials. For example, two electron transporting materials in the ETL/EIL are mixed with a weight ratio of about 3:7 to about 7:3, but is not limited thereto.

When holes are transferred to the second electrode 220 via the EML 340 and/or electrons are transferred to the first electrode 210 via the EML 340, the OLED D1 can have short lifespan and reduced luminous efficiency. In order to prevent those phenomena, the OLED D1 in accordance with this aspect of the present disclosure can have at least one exciton blocking layer adjacent to the EML 340.

As an example, the OLED D1 can include the EBL 330 between the HTL 320 and the EML 340 so as to control and prevent electron transfer. In one embodiment, electron blocking material in the EBL 330 can include, but is not limited to, TCTA, tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof.

In addition, the OLED D1 can further include the HBL 350 as a second exciton blocking layer between the EML 340 and the ETL 360 so that holes cannot be transferred from the EML 340 to the ETL 360. In one embodiment, hole blocking material in the HBL 350 can include, but is not limited to, at least one of oxadiazole-containing compounds, triazole-containing compounds, phenanthroline-containing compounds, benzoxazole-containing compounds, benzothiazole-containing compounds, benzimidazole-containing compounds, and triazine-containing compounds.

As an example, the hole blocking material in the HBL 350 can include material having a relatively low HOMO energy level compared to the luminescent materials in EML 340. For example, the hole blocking material in the HBL 350 can include, but is not limited to, BCP, BAlq, Alq₃, PBD, spiro-PBD, Liq, bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

As described above, the EML 340 includes the first compound 342 of a phosphorescent dopant, the second compound 344, and optionally the third compound 346 of the host. The first compound 342 has a narrow FWHM. The first compound 342 has a rigid chemical configuration, so that its chemical conformation can be maintained in the luminous process, and therefore, its color purity and luminous lifespan can be improved. It is possible to adjust luminous colors by modifying the structure of the ligand and/or the groups substituted to the ligands in the first compound 342. The second compound 344 has beneficial hole affinity property and/or hole transporting affinity, and the third compound 346 has beneficial electron affinity property and/or electron transporting affinity. Accordingly, the OLED D1 including the first compound 342, the second compound 344, and optionally the third compound 346 can have beneficial luminous efficiency and luminous lifespan.

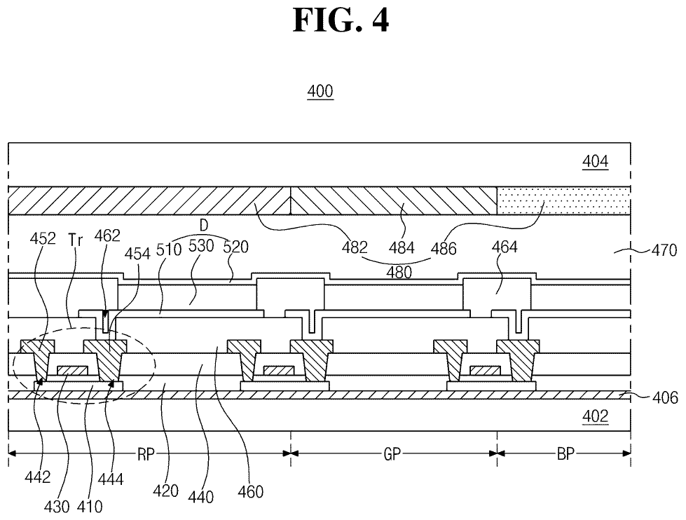

The organic light emitting device and the OLED D1 with a single emitting part and emitting red to green color light is shown in FIGS. 2 and 3. In another embodiment, an organic light emitting display device can implement full-color including white color. FIG. 4 illustrates a schematic cross-sectional view of an organic light emitting display device in accordance with another embodiment of the present disclosure.

As illustrated in FIG. 4, the organic light emitting display device 400 includes a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the second substrate 404.

Each of the first and second substrates 402 and 404 can include, but is not limited to, glass, flexible material and/or polymer plastics. For example, each of the first and second substrates 402 and 404 can be made of PI, PES, PEN, PET, PC and/or combinations thereof. In certain embodiments, the second substrate 404 can be omitted. The first substrate 402, on which a thin film transistor Tr and the OLED D are arranged, forms an array substrate.

A buffer layer 406 can be disposed on the first substrate 402. The thin film transistor Tr is disposed on the buffer layer 406 correspondingly to each of the red pixel region RP, the green pixel region GP and the blue pixel region BP. In certain embodiments, the buffer layer 406 can be omitted.

A semiconductor layer 410 is disposed on the buffer layer 406. The semiconductor layer 410 can be made of or include an oxide semiconductor material or polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 including an insulating material, for example, inorganic insulating material such as SiOₓ (wherein 0<x≤2) or SiNₓ (wherein 0<x≤2), or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 4, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the entire first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP can be an anode and can include a conductive material having relatively high work function value. Alternatively, a reflective electrode or a reflective layer can be disposed under the first electrode 510. For example, the reflective electrode or the reflective layer can include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel RP, the green pixel GP and the blue pixel BP. In certain embodiments, the bank layer 464 can be omitted.

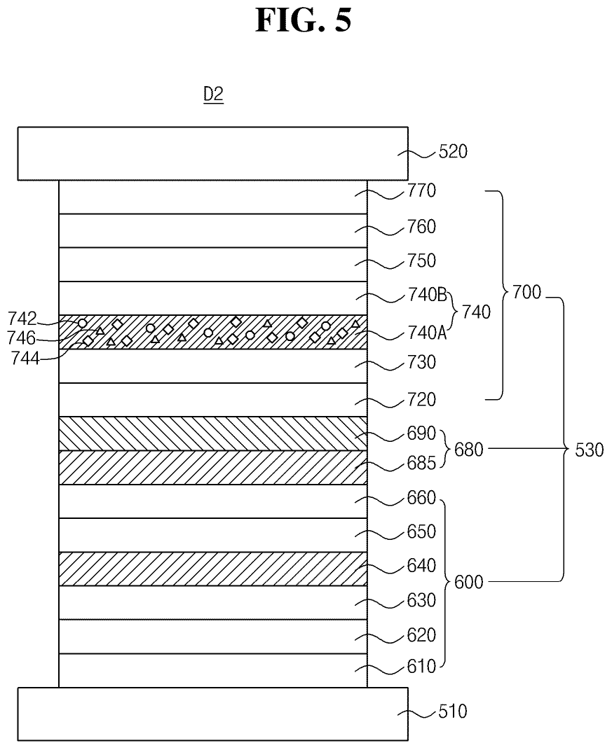

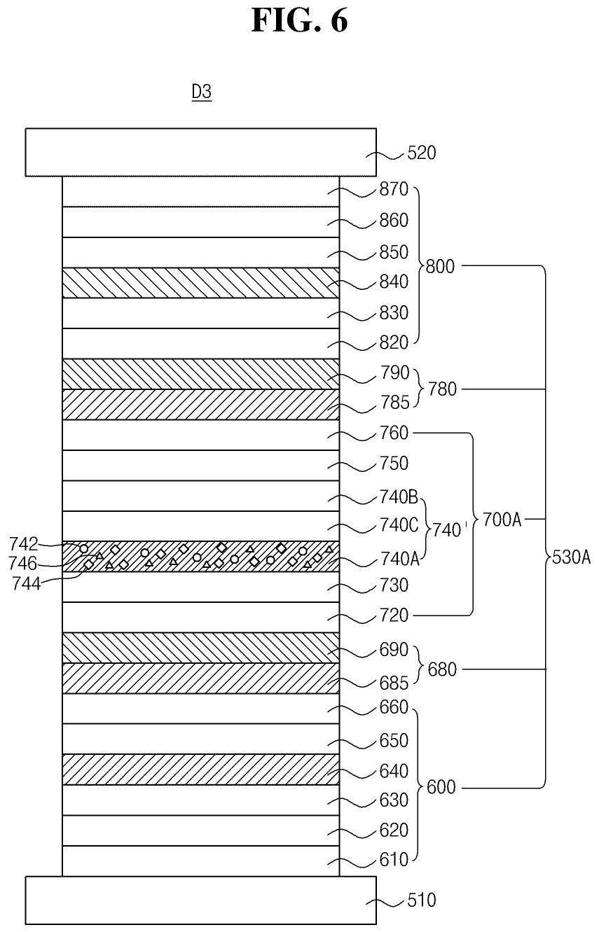

An emissive layer 530 that can include multiple emitting parts is disposed on the first electrode 510. As illustrated in FIGS. 5 and 6, the emissive layer 530 can include multiple emitting parts 600, 700, 700A, and 800 and at least one charge generation layer 680 and 780. Each of the emitting parts 600, 700, 700A and 800 includes at least one emitting material layer and can further include an HIL, an HTL, an EBL, an HBL, an ETL and/or an EIL.

The second electrode 520 can be disposed on the first substrate 402 above which the emissive layer 530 can be disposed. The second electrode 520 can be disposed over an entire display area, can include a conductive material with a relatively low work function value compared to the first electrode 510, and can be a cathode. Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light can be transmitted.

The color filter layer 480 is disposed on the OLED D and includes a red color filter pattern 482, a green color filter pattern 484 and a blue color filter pattern 486 each of which is disposed correspondingly to the red pixel RP, the green pixel GP and the blue pixel BP, respectively. Although not shown in FIG. 4, the color filter layer 480 can be attached to the OLED D through an adhesive layer. Alternatively, the color filter layer 480 can be disposed directly on the OLED D.

In addition, an encapsulation film 470 can be disposed on the second electrode 520 in order to prevent or reduce outer moisture from penetrating into the OLED D. The encapsulation film 470 can have, but is not limited to, a laminated structure including a first inorganic insulating film, an organic insulating film and a second inorganic insulating film (170 in FIG. 2). In addition, a polarizing plate can be attached onto the second substrate 404 to reduce reflection of external light. For example, the polarizing plate can be a circular polarizing plate.

In FIG. 4, the light emitted from the OLED D is transmitted through the second electrode 520 and the color filter layer 480 is disposed on the OLED D. In this case, the organic light emitting display device 400 can be a top-emission type. Alternatively, when the organic light emitting display device 400 is a bottom-emission type, the light emitted from the OLED D is transmitted through the first electrode 510 and the color filter layer 480 can be disposed between the OLED D and the first substrate 402.

In addition, a color conversion layer may be formed or disposed between the OLED D and the color filter layer 480. The color conversion layer may include a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 can comprise the color conversion layer instead of the color filter layer 480.

As described above, the white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will be described in more detail. FIG. 5 illustrates a schematic cross-sectional view of an organic light emitting diode having a tandem structure of two emitting parts.

As illustrated in FIG. 5, the OLED D2 in accordance with the embodiment of the present disclosure includes first and second electrodes 510 and 520 and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

The first electrode 510 can be an anode and can include a conductive material having a relatively high work function value such as TCO. For example, the first electrode 510 can include, but is not limited to, ITO, IZO, ITZO, SnO, ZnO, ICO, AZO, and/or the like. The second electrode 520 can be a cathode and can include a conductive material with a relatively low work function value. For example, the second electrode 520 can include, but is not limited to, highly reflective material such as Al, Mg, Ca, Ag, alloy thereof and/or combination thereof such as Al—Mg.

The first emitting part 600 includes a first EML (EML1) 640. The first emitting part 600 can further include at least one of a hole injection layer (HIL) 610 disposed between the first electrode 510 and the EML1 640, a first hole transport layer (HTL1) 620 disposed between the HIL 610 and the EML1 640, and a first electron transport layer (ETL1) 660 disposed between the EML1 640 and the CGL 680. Alternatively or additionally, the first emitting part 600 can further include a first electron blocking layer (EBL1) 630 disposed between the HTL1 620 and the EML1 640 and/or a first hole blocking layer (HBL1) 650 disposed between the EML1 640 and the ETL1 660.

The second emitting part 700 includes a second EML (EML2) 740. The second emitting part 700 can further include at least one of a second hole transport layer (HTL2) 720 disposed between the CGL 680 and the EML2 740, an second electron transport layer (ETL2) 760 disposed between the second electrode 520 and the EML2 740 and an electron injection layer (EIL) 770 disposed between the second electrode 520 and the ETL2 760. Alternatively or additionally, the second emitting part 700 can further include a second electron blocking layer (EBL2) 730 disposed between the HTL2 720 and the EML2 740 and/or a second hole blocking layer (HBL2) 750 disposed between the EML2 740 and the ETL2 760.

One of the EML1 640 and the EML2 740 can include a first compound 742, a second compound 744, and optionally a third compound 746 so that it can emit red to green color light, the other of the EML1 640 and the EM2 740 can emit blue color light, so that the OLED D2 can realize white (W) emission. Hereinafter, the OLED D2 where the EML2 740 includes the first compound 742, the second compound 744, and optionally the third compound 746 will be described in detail.

The HIL 610 is disposed between the first electrode 510 and the HTL1 620 and may improve an interface property between the inorganic first electrode 510 and the organic HTL1 620. In one exemplary embodiment, hole injecting material in the HIL 610 can include, but is not limited to, MTDATA, NATA, 1T-NATA, 2T-NATA, CuPc, TCTA, NPB (NPD), DNDPT, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB and/or combinations thereof. In another embodiment, the HIL 610 can include hole injection host of hole transporting material and hole injection dopant of the hole injecting material. In certain embodiments, the HIL 610 can be omitted in compliance with the OLED D2 property.

In one embodiment, hole transporting material in each of the HTL1 620 and the HTL2 720 can independently include, but is not limited to, TPD, NPB (NPD), DNTPD, CBP, poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl) biphenyl-4-amine, N-([1,1′-biphenyl]-4-yl)-9,9-dimethyl-N-(4-(9-phenyl-9H-carbazol-3-yl)phenyl)-9H-fluoren-2-amine and/or combinations thereof.

Each of the ETL1 660 and the ETL2 760 facilitates electron transportation in each of the first emitting part 600 and the second emitting part 700, respectively. As an example, each of electron transporting materials in the ETL1 660 and the ETL2 760 can independently include at least one of oxadiazole-containing compounds, triazole-containing compounds, phenanthroline-containing compounds, benzoxazole-containing compounds, benzothiazole-containing compounds, benzimidazole-containing compound and triazine-containing compounds. For example, each of the electron transporting materials in the ETL1 660 and the ETL2 760 can include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EIL 770 is disposed between the second electrode 520 and the ETL2 760, and can improve physical properties of the second electrode 520 and therefore, can enhance the lifespan of the OLED D2. In one embodiment, electron injecting material in the EIL 770 can include, but is not limited to, an alkali metal halide or an alkaline earth metal halide such as LiF, CsF, NaF, BaF₂ and the like, and/or an organometallic compound such as Liq, lithium benzoate, sodium stearate, and the like.

Each of electron blocking materials in the EBL1 630 and the EBL2 730 can independently include, but are not limited to, TCTA, tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Each of hole blocking materials in the HBL1 650 and the HBL2 750 can include, but are not limited to, at least one of oxadiazole-containing compounds, triazole-containing compounds, phenanthroline-containing compounds, benzoxazole-containing compounds, benzothiazole-containing compounds, benzimidazole-containing compounds, and triazine-containing compounds. For example, each of the hole blocking materials in the HBL1 650 and the HBL2 750 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL 680 is disposed between the first emitting part 600 and the second emitting part 700. The CGL 680 includes an N-type CGL (N-CGL) 685 disposed adjacently to the first emitting part 600 and a P-type CGL (P-CGL) 690 disposed adjacently to the second emitting part 700. The N-CGL 685 injects electrons to the EML1 640 of the first emitting part 600 and the P-CGL 690 injects holes to the EML2 740 of the second emitting part 700.

The N-CGL 685 can be an organic layer doped with an alkali metal such as Li, Na, K and Cs and/or an alkaline earth metal such as Mg, Sr, Ba and Ra. For example, the host in the N-CGL 685 can include, but is not limited to, Bphen and MTDATA. The contents of the alkali metal or the alkaline earth metal in the N-CGL 685 can be, but is not limited to, between about 0.01 wt. % and about 30 wt. %.

The P-CGL 690 can include, but is not limited to, inorganic material selected from the group consisting of tungsten oxide (WOₓ), molybdenum oxide (MoOₓ), beryllium oxide (Be₂O₃), vanadium oxide (V₂O₅) and/or combinations thereof, and/or organic material selected from the group consisting of NPD, DNTPD, HAT-CN, F4-TCNQ, F6-TCNNQ, TPD, N,N,N′,N′-tetranaphthalenyl-benzidine (TNB), TCTA, N,N′-dioctyl-3,4,9,10-perylenedicarboximide (PTCDI-C8) and/or combinations thereof.

The EML1 640 can be a blue EML. In this case, the EML1 640 can be a blue EML, a sky-blue EML or a deep-blue EML. The EML1 640 can include at least one blue host and at least one blue dopant.

For example, the blue host can include, but is not limited to, mCP, mCP-CN, mCBP, CBP-CN, 9-(3-(9H-carbazol-9-yl)phenyl)-3-(diphenylphosphoryl)-9H-carbazole (mCPPO1) 3,5-di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spirobifluoren-2-yl-diphenyl-phosphine oxide (SPPO1), 9,9′-(5-(triphenylsilyl)-1,3-phenylene)bis(9H-carbazole) (SimCP) and/or combinations thereof.

The blue dopant can include at least one of blue phosphorescent material, blue fluorescent material and blue delayed fluorescent material. As an example, the blue dopant can include, but is not limited to, perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino) styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-tetra-tert-butylperylene (TBPe), bis(2-hydroxylphenyl)-pyridine)beryllium (Bcpp2), 9-(9-phenylcarbazole-3-yl)-10-(naphthalene-1-yl)anthracene (PCAN), mer-tris(1-phenyl-3-methylimidazolin-2-ylidene-C,C(2)′iridium(III) (mer-Ir(pmi)₃), fac-tris(1,3-diphenyl-benzimidazolin-2-ylidene-C,C(2)′iridium(III) (fac-Ir(dpbic)₃), bis(3,4,5-trifluoro-2-(2-pyridyl)phenyl-(2-carboxypyridyl)iridium (III) (Ir(tfpd)₂pic), tris(2-(4,6-difluorophenyl)pyridine))iridium(III) (Ir(Fppy)₃), bis[2-(4,6-difluorophenyl)pyridinato-C₂,N](picolinato)iridium (III) (FIrpic) and/or combinations thereof.

When the EML1 640 includes at least one blue host, the contents of the blue host in the EML1 640 can be about 50 wt. % to about 99 wt. %, for example, about 80 wt. % to about 95 wt. %, and the contents of the blue dopant in the EML1 640 can be about 1 wt. % to about 50 wt. %, for example, about 5 wt. % to about 20 wt. %, but is not limited thereto. When the EML1 640 includes a first blue host of a P-type blue host and a second blue host of an N-type blue host, the first blue host and the second blue host can be mixed, but is not limited to, with a weight ratio of about 4:1 to about 1:4, for example about 3:1 to about 1:3.

The EML2 740 can include a lower emitting material layer (lower EML, first layer) 740A disposed between the EBL2 730 and the HBL2 750 and an upper emitting material layer (upper EML, second layer) 740B disposed between the lower EML 740A and the HBL2 750. One of the first layer 740A and the second layer 740B can emit red to yellow color light and the other of the first layer 740A and the second layer 740B can emitting green color light. Hereinafter, the EML2 740 where the first layer 740A emits a red to yellow color light and the second layer 740B emits a green color light will be described in detail.

The first layer 740A can include the first compound 742, the second compound 744, and optionally the third compound 746. The first compound 742 can include the organometallic compound having the structure of Chemical Formulae 1 to 7 to emit red to yellow color light. The second compound 744 can include the amine-containing organic compound having the structure of any one of Chemical Formulae 8 to 10 and can be the P-type host. The third compound 746 can include the triazine-containing organic compound having the structure of any one of Chemical Formulae 11 to 12 and can be the N-type host.

In another embodiment, the first compound can include at least one of another red phosphorescent material, red fluorescent material and red delayed fluorescent material. For example, the first compound 742 can include, but is not limited to, bis[2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)₂(acac)), tris[2-(4-n-hexylphenyl)quinoline]iridium(III) (Hex-Ir(phq)₃), tris[2-phenyl-4-methylquinoline]iridium(III) (Ir(Mphq)₃), bis(2-phenylquinoline)(2,2,6,6-tetramethylheptene-3,5-dionate)iridium(III) (Ir(dpm)PQ₂), bis(phenylisoquinoline)(2,2,6,6-tetramethylheptene-3,5-dionate)iridium(III) (Ir(dpm)(piq)₂), bis(1-phenylisoquinoline)(acetylacetonate)iridium(III) (Ir(piq)₂(acac)), bis[(4-n-hexylphenyl)isoquinoline](acetylacetonate)iridium(III) (Hex-Ir(piq)₂(acac)), tris[₂-(4-n-hexylphenyl)quinoline]iridium(III) (Hex-Ir(piq)₃), tris(2-(3-methylphenyl)-7-methyl-quinolato)iridium (Ir(dmpq)₃), bis[2-(2-methylphenyl)-7-methyl-quinoline](acetylacetonate)iridium(III) (Ir(dmpq)₂(acac)), bis[2-(3,5-dimethylphenyl)-4-methyl-quinoline](acetylacetonate)iridium(III) (Ir(mphmq)₂(acac)), tris(dibenzoylmethane)mono(1,10-phenanthroline)europium(III) (Eu(dbm)₃(phen)) and/or combinations thereof.

In another embodiment, the second compound 744 of the first host can include, but is not limited to, a biscarbazole-containing organic compound, an aryl amine- or a hetero aryl amine-containing organic compound with at least one fused aromatic and/or fused hetero aromatic moiety, and/or an aryl amine- or a hetero aryl amine-containing organic compound with a spirofluorene moiety. In another embodiment, the third compound 746 of the second host can include, but is not limited to, an azine-containing organic compound, a benzimidazole-containing organic compound and/or a quinazoline-containing organic compound.

As an example, the second compound 744 and/or the third compound 746 can include, but is not limited to, mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl) pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbiphenyl (CDBP), (2,7-bis(carbazole-9-yl)-9,9-dimethylfluorene (DMFL-CBP), 2,2′,7,7′-tetrakis(carbazole-9-yl)-9,9-spirofluorene (Spiro-CBP), 3,6-bis(carbazole-9-yl)-9-(2-ethyl-hexyl)-9H-carbazole (TCz1) and/or combinations thereof.

As an example, the contents of the host including the second host 744, and optionally the third compound 746 in the first layer 740A can be about 50 wt. % to about 99 wt. %, for example, about 80 wt. % to about 95 wt. %, and the contents of the first compound 742 in the first layer 740A can be about 1 wt. % to about 50 wt. %, for example, about 5 wt. % to about 20 wt. %, but is not limited thereto. When the first layer 740A includes both the second compound 744 of the first host and the third compound 746 of the second host, the second compound 744 and the third compound 746 can be mixed, but not limited to, with a weight ratio of about 4:1 to about 1:4, for example about 3:1 to about 1:3.

The second layer 740B can include a green host, and a green dopant or a green emitter. For example, the second layer 740B can include at least one green host and a green dopant. The green host can be identical to the second compound 744 and/or the third compound 746. The green dopant can include at least one of green phosphorescent material, green fluorescent material and green delayed fluorescent material.

As an example, the green dopant can include, but is not limited to, [bis(2-phenylpyridine)](pyridyl-2-benzofuro[2,3-b]pyridine)iridium, tris[2-phenylpyridine]iridium(III) (Ir(ppy)₃), fac-tris(2-phenylpyridine)iridium(III) (fac-Ir(ppy)₃), bis(2-phenylpyridine)(acetylacetonate)iridium(III) (Ir(ppy)₂(acac)), Tris[2-(p-tolyl)pyridine]iridium(III); Ir(mppy)₃), bis(2-(naphthalene-2-yl)pyridine)(acetylacetonate)iridium(III) (Ir(npy)₂acac), tris(2-phenyl-3-methyl-pyridine)iidium (Ir(3mppy)₃), fac-tris(2-(3-p-xylyl)phenyl)pyridine iridium(III) (TEG) and/or combinations thereof. In another embodiment, the green dopan can include the first compound 742 having the structure of Chemical Formulae 1 to 7.

The contents of the green host in the second layer 740B can be about 50 wt. % to about 99 wt. %, for example, about 80 wt. % to about 95 wt. %, and the contents of the green dopant in the second layer 740B can be about 1 wt. % to about 50 wt. %, for example, about 5 wt. % to about 20 wt. %, but is not limited thereto. When the second layer 740B includes a first green host of a P-type green host and a second green host of an N-type green host, the first green host and the second green host can be mixed, but not limited to, with a weight ratio of about 4:1 to about 1:4, for example about 3:1 to about 1:3.

Optionally, the EML2 740 can further include a third layer (740C in FIG. 6) that can emit yellow-green color light disposed between the first layer 740A of the red EML and the second layer 740B of the green EML.

The OLED D2 in accordance with this embodiment has a tandem structure and includes the first compound 742, the second compound 744, and optionally the third compound 746. The luminous efficiency and the luminous lifespan of the OLED D2, which includes the first compound 742 having a rigid chemical configuration and enabling its luminous color with ease, the second compound 744 and optionally the third compound 746 having a beneficial charge affinity property and/or charge transporting affinity, can be improved.

An OLED can have three or more emitting parts to form a tandem structure. FIG. 6 is a schematic cross-sectional view illustrating an organic light emitting diode in accordance with yet another embodiment of the present disclosure.

As illustrated in FIG. 6, the OLED D3 includes first and second electrodes 510 and 520 facing each other and an emissive layer 530A disposed between the first and second electrodes 510 and 520. The emissive layer 530A includes a first emitting part 600 disposed between the first and second electrodes 510 and 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

The first emitting part 600 includes a first emitting material layer (EML1) 640. The first emitting part 600 can further include at least one of a hole injection layer (HIL) 610 disposed between the first electrode 510 and the EML1 640, a first hole transport layer (HTL1) 620 disposed between the HIL 610 and the EML1 640, a first electron transport layer (ETL1) 660 disposed between the EML1 640 and the CGL1 680. Alternatively or additionally, the first emitting part 600 can further comprise a first electron blocking layer (EBL1) 630 disposed between the HTL1 620 and the EML1 640 and/or a first hole blocking layer (HBL1) 650 disposed between the EML1 640 and the ETL1 660.

The second emitting part 700A includes a second emitting material layer (EML2) 740′. The second emitting part 700A can further include at least one of a second hole transport layer (HTL2) 720 disposed between the CGL1 680 and the EML2 740′ and a second electron transport layer (ETL2) 760 disposed between the EML2 740′ and the CGL2 780. Alternatively or additionally, the second emitting part 700A can further include a second electron blocking layer (EBL2) 730 disposed between the HTL2 720 and the EML2 740′ and/or a second hole blocking layer (HBL2) 750 disposed between the EML2 740′ and the ETL2 760.

The third emitting part 800 includes a third emitting material layer (EML3) 840. The third emitting part 800 can further include at least one of a third hole transport layer (HTL3) 820 disposed between the CGL2 780 and the EML3 840, a third electron transport layer (ETL3) 860 disposed between the second electrode 520 and the EML3 840 and an electron injection layer (EIL) 870 disposed between the second electrode 520 and the ETL3 860. Alternatively or additionally, the third emitting part 800 can further comprise a third electron blocking layer (EBL3) 830 disposed between the HTL3 820 and the EML3 840 and/or a third hole blocking layer (HBL3) 850 disposed between the EML3 840 and the ETL3 860.

The CGL1 680 is disposed between the first emitting part 600 and the second emitting part 700A and the CGL2 780 is disposed between the second emitting part 700A and the third emitting part 800. The CGL1 680 includes a first N-type charge generation layer (N-CGL1) 685 disposed adjacently to the first emitting part 600 and a first P-type charge generation layer (P-CGL1) 690 disposed adjacently to the second emitting part 700A. The CGL2 780 includes a second N-type charge generation layer (N-CGL2) 785 disposed adjacently to the second emitting part 700A and a second P-type charge generation layer (P-CGL2) 790 disposed adjacently to the third emitting part 800. Each of the N-CGL1 685 and the N-CGL2 785 injects electrons to the EML1 640 of the first emitting part 600 and the EML2 740′ of the second emitting part 700A, respectively, and each of the P-CGL1 690 and the P-CGL2 790 injects holes to the EML2 740′ of the second emitting part 700A and the EML3 840 of the third emitting part 800, respectively.

The materials included in the HIL 610, the HTL1 to the HTL3 620, 720 and 820, the EBL1 to the EBL3 630, 730 and 830, the HBL1 to the HBL3 650, 750 and 850, the ETL1 to the ETL3 660, 760 and 860, the EIL 870, the CGL1 680, and the CGL2 780 can be identical to the materials with referring to FIGS. 3 and 5.

In one embodiment, at least one of the EML1 640, the EML2 740′ and the EML3 840 can include the first compound 742, the second compound 744, and optionally the third compound 746. For example, one of the EML1 640, the EML2 740′ and the EML3 840 can emit red to green color light, and the other of the EML1 640, the EML2 740′ and the EML3 840 can emit blue color light so that the OLED D3 can realize white (W) emission. Hereinafter, the OLED where the EML2 740′ includes the first compound 742, the second compound 744, and optionally the third compound 746 and emits red to green color light, and each of the EML1 640 and the EML3 840 emits blue color light will be described in detail.

Each of the EML1 640 and the EML3 840 can be independently a blue EML. In this case, each of the EML1 640 and the EML3 840 can be independently a blue EML, a sky-blue EML or a deep-blue EML. Each of the EML1 640 and the EML3 840 can independently include at least one blue host and at least one blue dopant. Each of the blue host and the blue dopant can be identical to the blue host and the blue dopant with referring to FIG. 5. For example, the blue dopant can include at least one of blue phosphorescent material, blue fluorescent material and blue delayed fluorescent material. Alternatively or additionally, the blue dopant in the EML1 640 can be identical to or different from the blue dopant in the EML3 840 in terms of color and/or luminous efficiency.

When each of the EML1 640 and the EML3 840 includes at least one blue host, the contents of the blue host in the EML1 640 and/or the EML3 840 can be about 50 wt. % to about 99 wt. %, for example, about 80 wt. % to about 95 wt. %, and the contents of the blue dopant in the EML1 640 and/or the EML3 840 can be about 1 wt. % to about 50 wt. %, for example, about 5 wt. % to about 20 wt. %, but is not limited thereto. When the EML1 640 and/or the EML3 840 include a first blue host and a second blue host, the first blue host and the second blue host can be mixed, but is not limited to, with a weight ratio of about 4:1 to about 1:4, for example about 3:1 to about 1:3.

The EML2 740′ can include a lower emitting material layer (first layer) 740A disposed between the EBL2 730 and the HBL2 750, an upper emitting material layer (second layer) 740B disposed between the first layer 740A and the HBL2 750, and a middle emitting material layer (third layer) 740C disposed between the first layer 740A and the second layer 740B. One of the first layer 740A and the second layer 740B can emit red color and the other of the first layer 740A and the second layer 740B can emit green color. Hereinafter, the EML2 740′ where the first layer 740A emits a red color and the second layer 740B emits a green color will be described in detail.

The first layer 740A can include the first compound 742, the second compound 744, and optionally the third compound 746. The first compound 742 can include the organometallic compound having the structure of Chemical Formulae 1 to 7 to emit red to yellow color light. The second compound 744 can include the amine-containing organic compound having the structure of any one of Chemical Formulae 8 to 10 and can be the P-type host. The third compound 746 can include the triazine-containing organic compound having the structure of any one of Chemical Formulae 11 to 12 and can be the N-type host. Alternatively, the first compound 742 can include other red dopant with referring to FIG. 5, and the second compound 744 and/or the third compound can include other host with referring to FIG. 5. The contents of the first compound 742, the second compound 744 and the third compound 746 in the first layer 740A can be identical to the contents of the corresponding materials with referring to FIG. 5.

The second layer 740B can include a green host and a green dopant. For example, the second layer 740B can include at least one green host and a green dopant. In one embodiment, the green host can be identical to the second compound 744 and/or the third compound 746 described above. The green dopant can include at least one of green phosphorescent material, green fluorescent material and green delayed fluorescent material. The green dopant identical to materials with referring to FIG. 5. In another embodiment, the green dopant can include the organometallic compound having the structure of Chemical Formulae 1 to 7.

The third layer 740C can be a yellow green EML. The third layer 740C can include a yellow green host and a yellow green dopant. For example, the third layer 740C can include at least one yellow green host and at least one yellow green dopant. As an example, the yellow green host can be identical to the second compound 744 and/or the third compound 746. The yellow green dopant can include at least one of yellow green phosphorescent material, yellow green fluorescent material and yellow green delayed fluorescent material.

For example, the yellow green dopant can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethytl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof. In another embodiment, the yellow green dopant can include the first compound 742 having the structure of Chemical Formulae 1 to 7. In certain embodiments, the third layer 740C can be omitted.

When the third layer 740C includes at least one yellow-green host, the contents of the yellow-green host in the third layer 740C can be about 50 wt. % to about 99 wt. %, for example, about 80 wt. % to about 95 wt. %, and the contents of the yellow-green dopant in the third layer 740C can be about 1 wt. % to about 50 wt. %, for example, about 5 wt. % to about 20 wt. %, but is not limited thereto. When the third layer 740C includes two hosts, each of the hosts can be mixed, but is not limited to, with a weight ratio of about 4:1 to about 1:4, for example about 3:1 to about 1:3.

The OLED D3 in accordance with this embodiment includes the first compound 742, the second compound 744, and optionally the third compound 746 in at least one EML. The first compound 742 has narrow luminous FWHM and can maintain its stable chemical conformation in emitting process. The second compound 744 has beneficial hole affinity property and/or hole transporting property, and the third compound 746 has beneficial electron affinity property and/or electron transporting affinity. The OLED D3, which includes the first compound 742, the second compound 744, and optionally the third compound 746, and three or more emitting part, enables its luminous efficiency, color purity and luminous lifespan to be improved with white emission.

In FIG. 6, the OLED having three emitting parts is illustrated. If necessary, an organic light emitting diode can have four or more emitting parts. As an example, when the OLED has four emitting parts, two emitting part can emit blue color light, another emitting part can emit red color light, and another emitting part can emit green color light, so that the OLED can implement white (W) emission.

### Synthesis Example 1: Synthesis of Compound 5

### (1) Synthesis of Intermediate DM-1

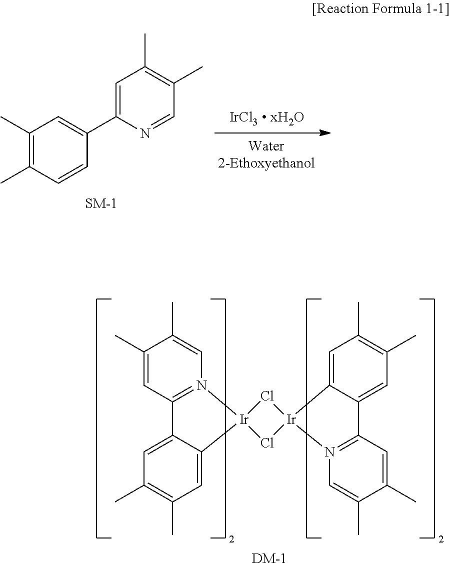

Compound SM-1 (3.0 g, 14.2 mmol), IrCl₃ (1.7 g, 5.7 mmol) and a mixed solvent of 2-ethoxyethanol (90 ml) and distilled water (30 ml) were put into a 250 ml round bottom flask under nitrogen atmosphere, then the solution was refluxed with stirring for 24 hours. After the reaction was complete, the solution was cooled to room temperature, then obtained solid was filtered under reduced pressure to be separated. The filtered solid was washed sufficiently with water and cold methanol, and was filtered under reduced pressure several times to give a solid Intermediate DM-1 (15.6 g, 84%).

### (2) Synthesis of Intermediate L-1

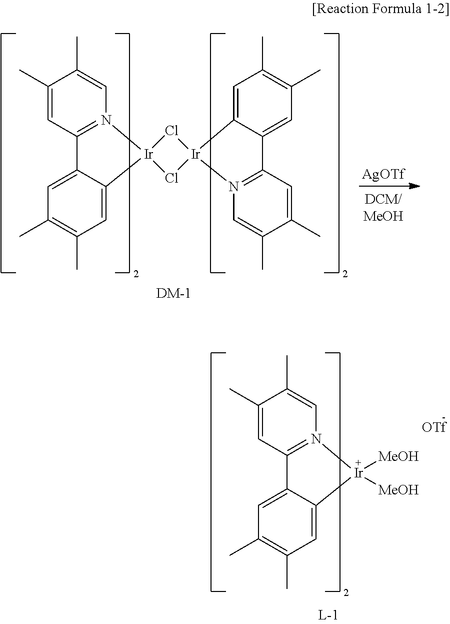

A solution of the Intermediate DM-1 (5.2 g, 4 mmol) and silver trifluoromethansulfonate (AgOTf, 3.08 g, 12 mmol) dissolved in dichloromethane (DCM) was put into a 250 ml round bottom flask, then the solution was stirred at room temperature for 24 hours. After the reaction was complete, the solution was filtered through Celite to remove a precipitate. The filtrate was distilled under reduced pressure to remove the solvent and to give a solid Compound L-1 (2.7 g, 88%).

### (3) Synthesis of Compound 5

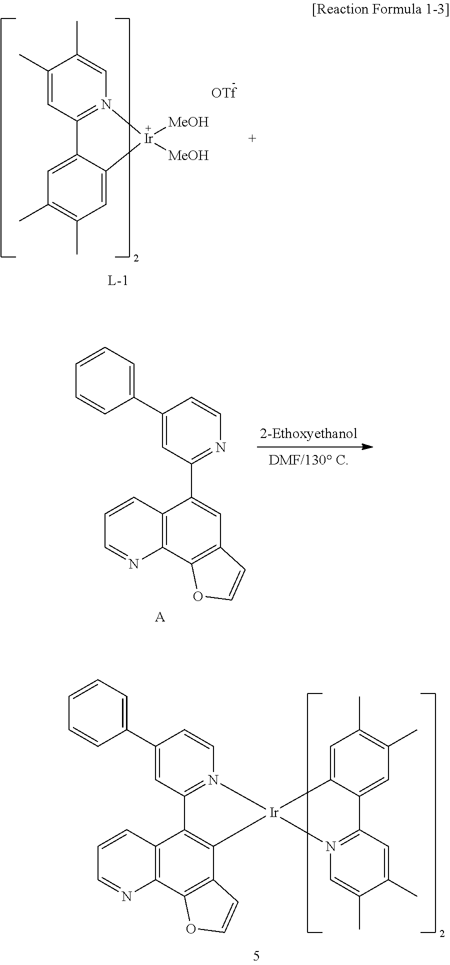

The iridium precursor compound L-1 (1.2 g, 1.6 mmol) and ligand precursor A (1.0 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 5 (0.7 g, 51%).

### Synthesis Example 2: Synthesis of Compound 25

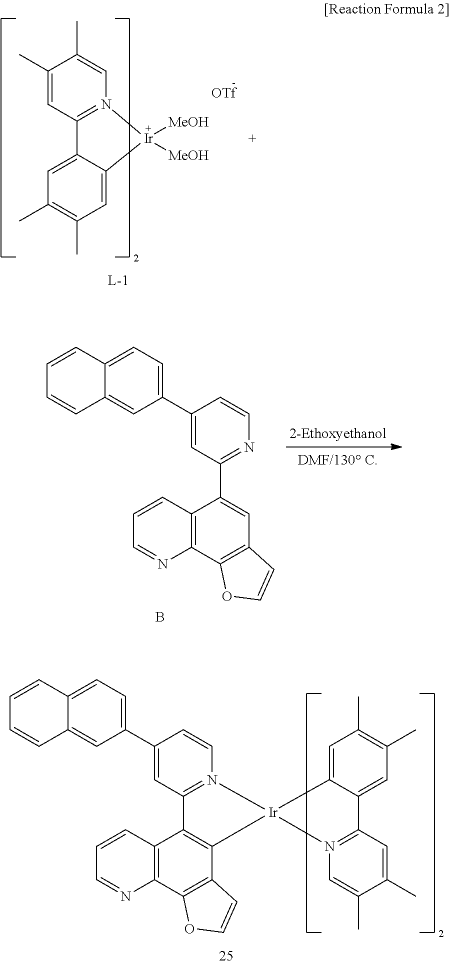

The iridium precursor compound L-1 (1.2 g, 1.5 mmol) and ligand precursor B (1.2 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 25 (0.7 g, 46%).

### Synthesis Example 3: Synthesis of Compound 26

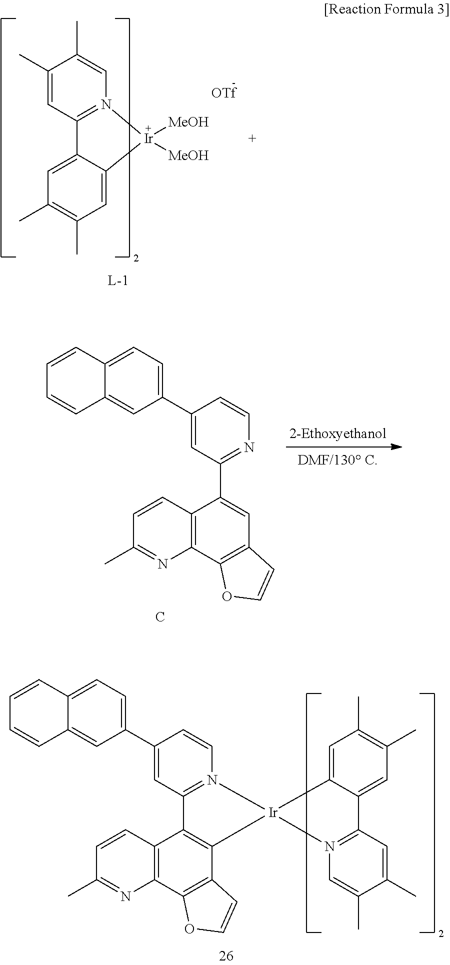

The iridium precursor compound L-1 (1.2 g, 1.6 mmol) and ligand precursor C (1.2 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 26 (0.6 g, 41%).

### Synthesis Example 4: Synthesis of Compound 27

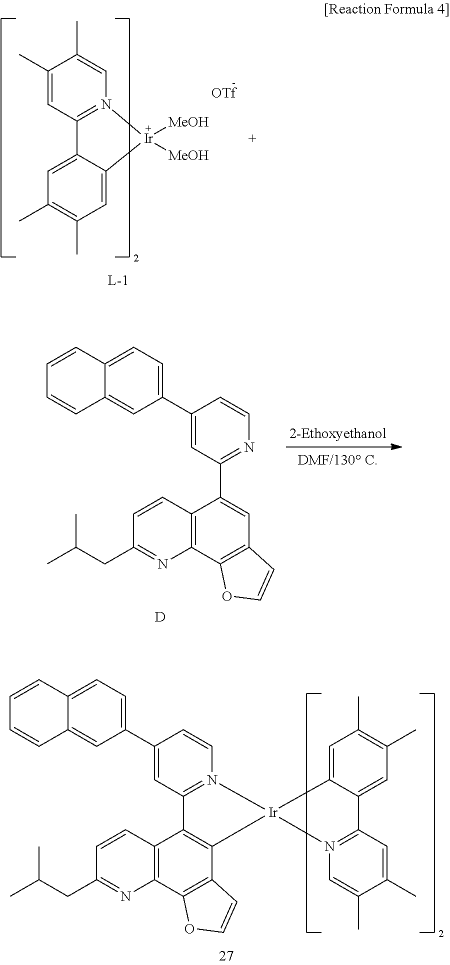

The iridium precursor compound L-1 (1.2 g, 1.6 mmol) and ligand precursor D (1.3 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 27 (0.5 g, 34%).

### Synthesis Example 5: Synthesis of Compound 45

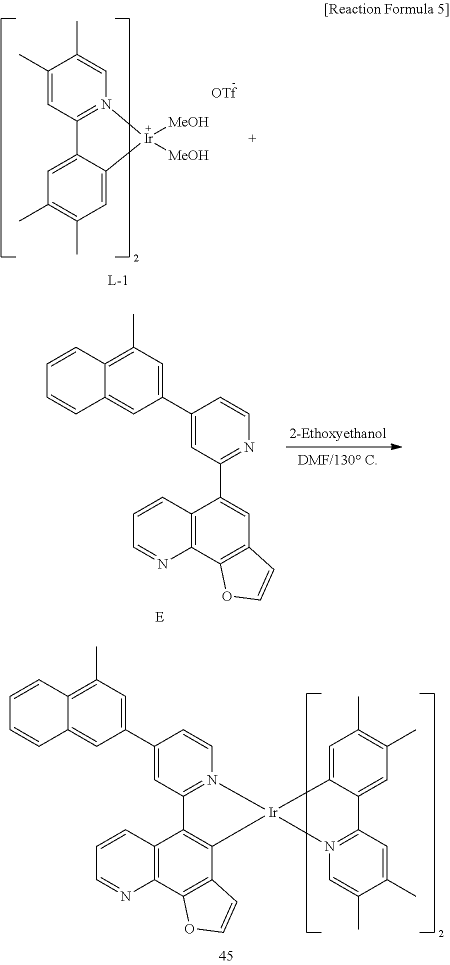

The iridium precursor compound L-1 (1.2 g, 1.5 mmol) and ligand precursor E (1.2 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 45 (0.6 g, 38%).

### Synthesis Example 6: Synthesis of Compound 65

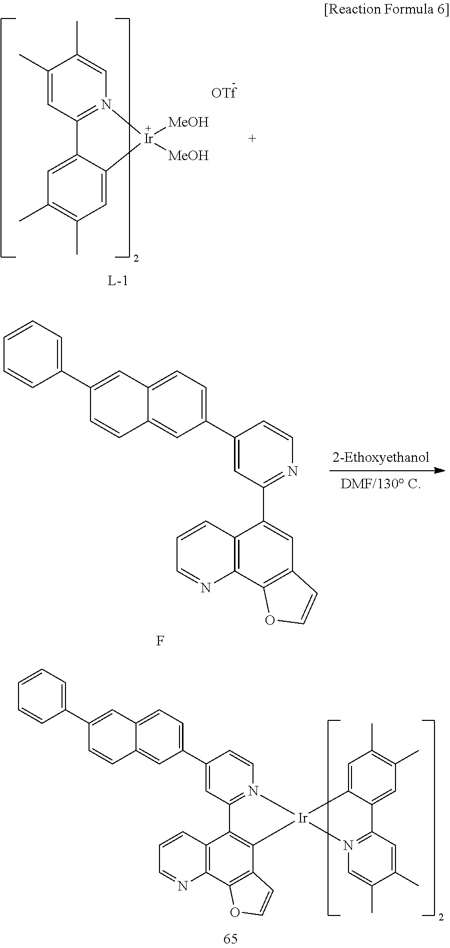

The iridium precursor compound L-1 (1.2 g, 1.5 mmol) and ligand precursor F (1.3 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 65 (0.4 g, 25%).

### Synthesis Example 7: Synthesis of Compound 123

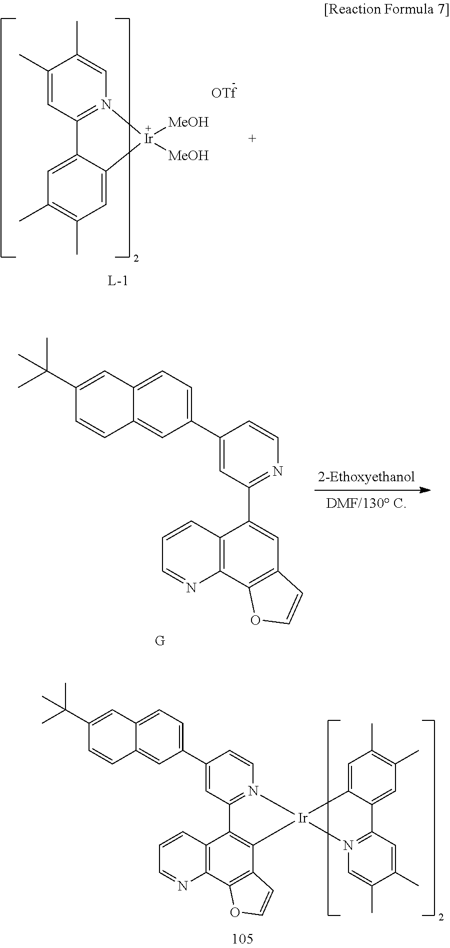

The iridium precursor compound L-1 (1.2 g, 1.6 mmol) and ligand precursor G (1.3 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 105 (0.4 g, 25%).

### Synthesis Example 8: Synthesis of Compound 123

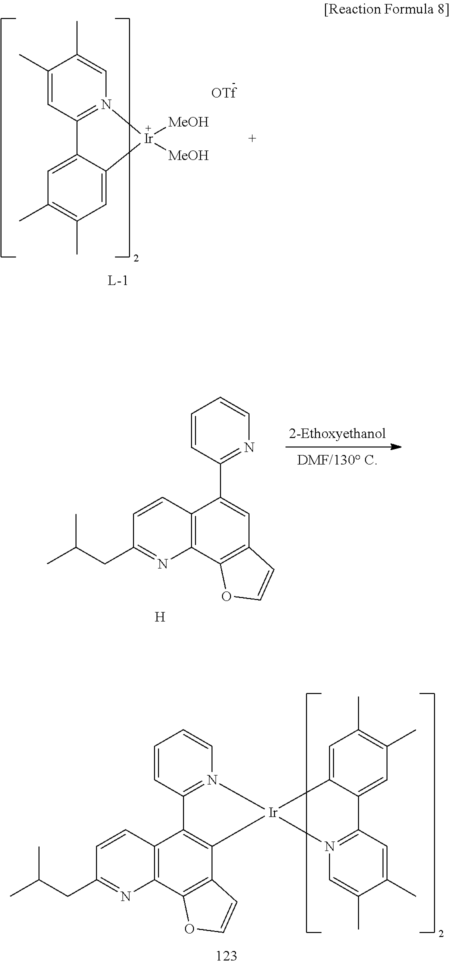

The iridium precursor compound L-1 (1.2 g, 1.5 mmol) and ligand precursor H (1.0 g, 3.1 mmol) dissolved in a mixed solvent of 2-ethoxyethanol (50 ml) and DMF (50 ml) were put into a 250 ml round bottom flask under nitrogen atmosphere, then the solution was heated with stirring at 130° C. for 24 hours. After the reaction was complete, the solution was cooled to room temperature, organic layer was extracted with dichloromethane and distilled water, and anhydrous magnesium sulfate was added to the organic layer to remove water. The organic layer was filtered, and the filtrate was subjected to reduced pressure to obtain a crude product. The crude product was purified with column chromatography (eluent: ethyl acetate:hexane=50:50) to give Compound 123 (0.4 g, 27%).

### Example 1 (Ex. 1): Fabrication of OLED

An organic light emitting diode where Compound 5 of Synthesis Example 1 as dopant, Compound PH1 of Chemical Formula 10 as a first host (P-type host), and Compound NH1 of Chemical Formula 12 as a second host (N-type host) were applied to an emitting material layer, was fabricated. A glass substrate onto which ITO (50 nm) was coated as a thin film was washed and ultrasonically cleaned with solvents such as isopropyl alcohol, acetone and dried at 100° C. oven. The substrate was transferred to a vacuum chamber for depositing other layers and an emissive layer and a cathode were deposited as the following order:

A hole injection layer (HIL, HAT-CN, 7 nm thickness); a hole transport layer (HTL, NPB, 78 nm thickness); an electron blocking layer (EBL, TAPC, 15 nm thickness); an emitting material layer (EML, PH1 (47.5 wt. %), NH1 (47.5 wt. %), Compound 5 (5 wt. %), 30 nm thickness); a hole blocking layer (HBL, B3PYMPM, 10 nm thickness); an electron transport layer (ETL, TPBi, 25 nm thickness); an electron injection layer (EIL, LiF, 1 nm thickness); and a cathode (Al, 100 nm thickness).

The fabricated OLED was encapsulated with glass and then transferred from the deposition chamber to a dry box in order to form a film. And then, the OLED was encapsulated with UV-cured epoxy resin and water getter. The structures of hole injecting material, hole transporting material, electron blocking material, luminescent host, hole blocking material and electron transporting material are illustrated in the following:

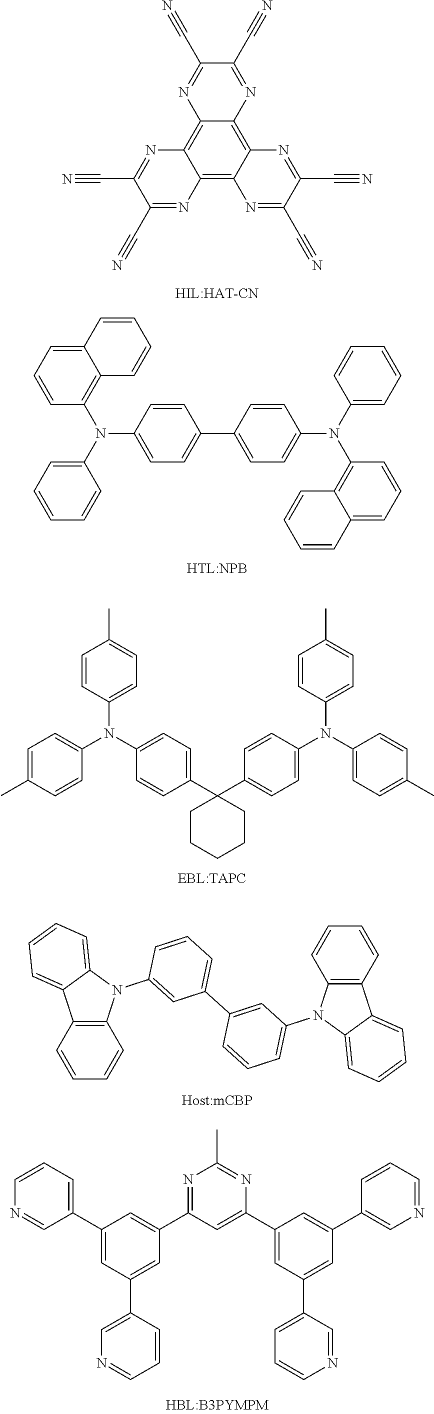

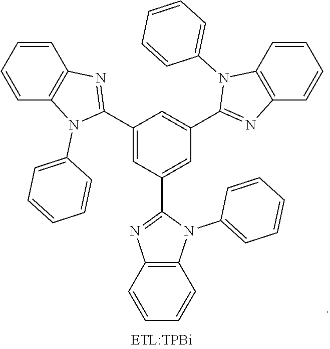 [SMILES: c1ccc(-n2c(-c3cc(-c4nc5ccccc5n4-c4ccccc4)cc(-c4nc5ccccc5n4-c4ccccc4)c3)nc3ccccc32)cc1]

### Examples 2-6 (Ex. 2-6): Fabrication of OLEDs

An OLED was fabricated using the same procedure and the same material as Example 1, except that each of Compound NH17 (Ex. 2), Compound NH23 (Ex. 3), Compound NH35 (Ex. 4), Compound NH53 (Ex. 5), and Compound NH65 (Ex. 6) of Chemical Formula 12, instead of Compound NH1, was used as the second host in the EML, respectively.

### Example 7 (Ex. 7): Fabrication of OLED

An OLED was fabricated using the same procedure and the same material as Example 1, except that Compound PH9 of Chemical Formula 10, instead of Compound PH1, as the first host in the EML.

### Examples 8-12 (Ex. 8-12): Fabrication of OLEDs

An OLED was fabricated using the same procedure and the same material as Example 7, except that each of Compound NH17 (Ex. 8), Compound NH23 (Ex. 9), Compound NH35 (Ex. 10), Compound NH53 (Ex. 11), and Compound NH65 (Ex. 12) of Chemical Formula 12, instead of Compound NH1, was used as the second host in the EML, respectively.

### Example 13 (Ex. 13): Fabrication of OLED

An OLED was fabricated using the same procedure and the same material as Example 1, except that Compound PH17 of Chemical Formula 10, instead of Compound PH1, as the first host in the EML.

### Examples 14-18 (Ex. 14-18): Fabrication of OLEDs

An OLED was fabricated using the same procedure and the same material as Example 13, except that each of Compound NH17 (Ex. 14), Compound NH23 (Ex. 15), Compound NH35 (Ex. 16), Compound NH53 (Ex. 17), and Compound NH65 (Ex. 18) of Chemical Formula 12, instead of Compound NH1, was used as the second host in the EML, respectively.

### Comparative Example 1 (Ref. 1): Fabrication of OLED

An OLED was fabricated using the same procedure and the same material as Example 1, except that the luminous materials in the EML mas modified to a single host mCBP (95 wt. %) and the Compound 5 (5 wt. %).

### Experimental Example 1: Measurement of Luminous Properties of OLEDs

Each of the OLEDs, having 9 mm² of emission area, fabricated in Examples 1 to 18 and Comparative Example 1 was connected to an external power source and then luminous properties for all the OLEDs were evaluated using a constant current source (KEITHLEY) and a photometer PR650 at room temperature. In particular, driving voltage (V, relative value), External quantum efficiency (EQE, relative value) and time period (LT₉₅, relative value) at which the luminance was reduced to 95% from initial luminance was measured at a current density 10 mA/cm². The measurement results are indicated in the following Table 1.

TABLE 1
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 1 | 5 | mCBP | | 100 | 100 | 100 |
| Ex. 1 | 5 | PH1 | NH1 | 95 | 114 | 119 |
| Ex. 2 | 5 | PH1 | NH17 | 96 | 111 | 118 |
| Ex. 3 | 5 | PH1 | NH23 | 96 | 113 | 112 |
| Ex. 4 | 5 | PH1 | NH35 | 95 | 112 | 113 |
| Ex. 5 | 5 | PH1 | NH53 | 97 | 106 | 110 |
| Ex. 6 | 5 | PH1 | NH65 | 96 | 115 | 117 |
| Ex. 7 | 5 | PH9 | NH1 | 96 | 116 | 116 |
| Ex. 8 | 5 | PH9 | NH17 | 97 | 112 | 115 |
| Ex. 9 | 5 | PH9 | NH23 | 97 | 114 | 110 |
| Ex. 10 | 5 | PH9 | NH35 | 97 | 112 | 111 |
| Ex. 11 | 5 | PH9 | NH53 | 98 | 107 | 110 |
| Ex. 12 | 5 | PH9 | NH65 | 97 | 113 | 114 |
| Ex. 13 | 5 | PH17 | NH1 | 97 | 108 | 115 |
| Ex. 14 | 5 | PH17 | NH17 | 97 | 105 | 114 |
| Ex. 15 | 5 | PH17 | NH23 | 97 | 106 | 112 |
| Ex. 16 | 5 | PH17 | NH35 | 96 | 106 | 112 |
| Ex. 17 | 5 | PH17 | NH53 | 97 | 103 | 108 |
| Ex. 18 | 5 | PH17 | NH65 | 97 | 106 | 112 |

### Example 19 (Ex. 19): Fabrication of OLED

An OLED was fabricated using the same procedure and the same material as Example 1, except that Compound PH33 of Chemical Formula 10, instead of Compound PH1, as the first host in the EML.

### Examples 20-24 (Ex. 20-24): Fabrication of OLEDs

An OLED was fabricated using the same procedure and the same material as Example 19, except that each of Compound NH17 (Ex. 20), Compound NH23 (Ex. 21), Compound NH35 (Ex. 22), Compound NH53 (Ex. 23), and Compound NH65 (Ex. 24) of Chemical Formula 12, instead of Compound NH1, was used as the second host in the EML, respectively.

### Example 25 (Ex. 25): Fabrication of OLED

An OLED was fabricated using the same procedure and the same material as Example 1, except that Compound PH49 of Chemical Formula 10, instead of Compound PH1, as the first host in the EML.

### Examples 26-30 (Ex. 26-30): Fabrication of OLEDs

An OLED was fabricated using the same procedure and the same material as Example 25, except that each of Compound NH17 (Ex. 26), Compound NH23 (Ex. 27), Compound NH35 (Ex. 28), Compound NH53 (Ex. 29), and Compound NH65 (Ex. 30) of Chemical Formula 12, instead of Compound NH1, was used as the second host in the EML, respectively.

### Example 31 (Ex. 31): Fabrication of OLED

An OLED was fabricated using the same procedure and the same material as Example 1, except that Compound PH65 of Chemical Formula 10, instead of Compound PH1, as the first host in the EML.

### Examples 32-36 (Ex. 32-36): Fabrication of OLEDs

An OLED was fabricated using the same procedure and the same material as Example 31, except that each of Compound NH17 (Ex. 32), Compound NH23 (Ex. 33), Compound NH35 (Ex. 34), Compound NH53 (Ex. 35), and Compound NH65 (Ex. 36) of Chemical Formula 12, instead of Compound NH1, was used as the second host in the EML, respectively.

### Experimental Example 2: Measurement of Luminous Properties of OLEDs

The optical property of the OLEDs fabricated in Examples 19 to 36 and Comparative Example 1 was measured as Experimental Example 1. The measurement results are indicated in the following Table 2.

TABLE 2
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 1 | 5 | mCBP | | 100 | 100 | 100 |
| Ex. 19 | 5 | PH33 | NH1 | 97 | 110 | 112 |
| Ex. 20 | 5 | PH33 | NH17 | 98 | 107 | 110 |
| Ex. 21 | 5 | PH33 | NH23 | 98 | 107 | 110 |
| Ex. 22 | 5 | PH33 | NH35 | 97 | 108 | 109 |
| Ex. 23 | 5 | PH33 | NH53 | 98 | 105 | 105 |
| Ex. 24 | 5 | PH33 | NH65 | 97 | 108 | 110 |
| Ex. 25 | 5 | PH49 | NH1 | 98 | 109 | 118 |
| Ex. 26 | 5 | PH49 | NH17 | 99 | 107 | 118 |
| Ex. 27 | 5 | PH49 | NH23 | 98 | 108 | 115 |
| Ex. 28 | 5 | PH49 | NH35 | 97 | 108 | 116 |
| Ex. 29 | 5 | PH49 | NH53 | 99 | 104 | 111 |
| Ex. 30 | 5 | PH49 | NH65 | 98 | 107 | 115 |
| Ex. 31 | 5 | PH65 | NH1 | 97 | 110 | 124 |
| Ex. 32 | 5 | PH65 | NH17 | 98 | 106 | 122 |
| Ex. 33 | 5 | PH65 | NH23 | 98 | 109 | 115 |
| Ex. 34 | 5 | PH65 | NH35 | 95 | 107 | 117 |
| Ex. 35 | 5 | PH65 | NH53 | 98 | 104 | 115 |
| Ex. 36 | 5 | PH65 | NH65 | 98 | 108 | 120 |

### Example 37 (Ex. 37): Fabrication of OLED

An OLED was fabricated using the same procedure and the same material as Example 1, except that Compound 26 of Synthesis Example 3, instead of Compound 5, as the dopant in the EML.

### Examples 38-42 (Ex. 38-42): Fabrication of OLEDs

An OLED was fabricated using the same procedure and the same material as Example 37, except that each of Compound NH17 (Ex. 38), Compound NH23 (Ex. 39), Compound NH35 (Ex. 40), Compound NH53 (Ex. 41), and Compound NH65 (Ex. 42) of Chemical Formula 12, instead of Compound NH1, was used as the second host in the EML, respectively.

### Example 43 (Ex. 43): Fabrication of OLED

An OLED was fabricated using the same procedure and the same material as Example 37, except that Compound PH9 of Chemical Formula 10, instead of Compound PH1, as the first host in the EML.

### Examples 44-48 (Ex. 44-48): Fabrication of OLEDs

An OLED was fabricated using the same procedure and the same material as Example 43, except that each of Compound NH17 (Ex. 44), Compound NH23 (Ex. 45), Compound NH35 (Ex. 46), Compound NH53 (Ex. 47), and Compound NH65 (Ex. 48) of Chemical Formula 12, instead of Compound NH1, was used as the second host in the EML, respectively.

### Example 49 (Ex. 49): Fabrication of OLED

An OLED was fabricated using the same procedure and the same material as Example 37, except that Compound PH17 of Chemical Formula 10, instead of Compound PH1, as the first host in the EML.

### Examples 50-54 (Ex. 50-54): Fabrication of OLEDs

An OLED was fabricated using the same procedure and the same material as Example 49, except that each of Compound NH17 (Ex. 50), Compound NH23 (Ex. 51), Compound NH35 (Ex. 52), Compound NH53 (Ex. 53), and Compound NH65 (Ex. 54) of Chemical Formula 12, instead of Compound NH1, was used as the second host in the EML, respectively.

### Comparative Example 2 (Ref. 2): Fabrication of OLED

An OLED was fabricated using the same procedure and the same material as Example 37, except that the luminous materials in the EML mas modified to a single host mCBP (95 wt. %) and the Compound 5 (5 wt. %).

### Experimental Example 3: Measurement of Luminous Properties of OLEDs

The optical properties of the OLEDs fabricated in Examples 37 to 54 and Comparative Example 2 were measured as presented in Experimental Example 1. The measurement results are indicated in the following Table 3.

TABLE 3
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 2 | 26 | mCBP | | 100 | 100 | 100 |
| Ex. 37 | 26 | PH1 | NH1 | 97 | 116 | 116 |
| Ex. 38 | 26 | PH1 | NH17 | 97 | 113 | 115 |
| Ex. 39 | 26 | PH1 | NH23 | 96 | 114 | 108 |
| Ex. 40 | 26 | PH1 | NH35 | 95 | 113 | 110 |
| Ex. 41 | 26 | PH1 | NH53 | 98 | 108 | 109 |
| Ex. 42 | 26 | PH1 | NH65 | 97 | 114 | 111 |
| Ex. 43 | 26 | PH9 | NH1 | 98 | 118 | 113 |
| Ex. 44 | 26 | PH9 | NH17 | 97 | 114 | 111 |
| Ex. 45 | 26 | PH9 | NH23 | 96 | 116 | 105 |
| Ex. 46 | 26 | PH9 | NH35 | 96 | 114 | 107 |
| Ex. 47 | 26 | PH9 | NH53 | 98 | 109 | 108 |
| Ex. 48 | 26 | PH9 | NH65 | 97 | 114 | 109 |
| Ex. 49 | 26 | PH17 | NH1 | 97 | 110 | 111 |
| Ex. 50 | 26 | PH17 | NH17 | 98 | 107 | 110 |
| Ex. 51 | 26 | PH17 | NH23 | 97 | 109 | 109 |
| Ex. 52 | 26 | PH17 | NH35 | 96 | 108 | 108 |
| Ex. 53 | 26 | PH17 | NH53 | 98 | 104 | 107 |
| Ex. 54 | 26 | PH17 | NH65 | 97 | 108 | 108 |

### Example 55 (Ex. 55): Fabrication of OLED

An OLED was fabricated using the same procedure and the same material as Example 37, except that Compound PH33 of Chemical Formula 10, instead of Compound PH1, as the first host in the EML.

### Examples 56-60 (Ex. 56-60): Fabrication of OLEDs

An OLED was fabricated using the same procedure and the same material as Example 55, except that each of Compound NH17 (Ex. 56), Compound NH23 (Ex. 57), Compound NH35 (Ex. 58), Compound NH53 (Ex. 59), and Compound NH65 (Ex. 60) of Chemical Formula 12, instead of Compound NH1, was used as the second host in the EML, respectively.

### Example 61 (Ex. 61): Fabrication of OLED

An OLED was fabricated using the same procedure and the same material as Example 37, except that Compound PH49 of Chemical Formula 10, instead of Compound PH1, as the first host in the EML.

### Examples 62-66 (Ex. 62-66): Fabrication of OLEDs

An OLED was fabricated using the same procedure and the same material as Example 61, except that each of Compound NH17 (Ex. 62), Compound NH23 (Ex. 63), Compound NH35 (Ex. 64), Compound NH53 (Ex. 65), and Compound NH65 (Ex. 66) of Chemical Formula 12, instead of Compound NH1, was used as the second host in the EML, respectively.

### Example 67 (Ex. 67): Fabrication of OLED

An OLED was fabricated using the same procedure and the same material as Example 37, except that Compound PH65 of Chemical Formula 10, instead of Compound PH1, as the first host in the EML.

### Examples 68-72 (Ex. 68-72): Fabrication of OLEDs

An OLED was fabricated using the same procedure and the same material as Example 67, except that each of Compound NH17 (Ex. 68), Compound NH23 (Ex. 69), Compound NH35 (Ex. 70), Compound NH53 (Ex. 71), and Compound NH65 (Ex. 72) of Chemical Formula 12, instead of Compound NH1, was used as the second host in the EML, respectively.

### Experimental Example 4: Measurement of Luminous Properties of OLEDs

The optical property of the OLEDs fabricated in Examples 55 to 72 and Comparative Example 2 was measured as Experimental Example 1. The measurement results are indicated in the following Table 4.

TABLE 4
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 2 | 26 | mCBP | | 100 | 100 | 100 |
| Ex. 55 | 26 | PH33 | NH1 | 97 | 112 | 108 |
| Ex. 56 | 26 | PH33 | NH17 | 97 | 108 | 108 |
| Ex. 57 | 26 | PH33 | NH23 | 97 | 111 | 109 |
| Ex. 58 | 26 | PH33 | NH35 | 97 | 109 | 107 |
| Ex. 59 | 26 | PH33 | NH53 | 98 | 107 | 107 |
| Ex. 60 | 26 | PH33 | NH65 | 98 | 109 | 106 |
| Ex. 61 | 26 | PH49 | NH1 | 98 | 112 | 115 |
| Ex. 62 | 26 | PH49 | NH17 | 98 | 109 | 114 |
| Ex. 63 | 26 | PH49 | NH23 | 97 | 110 | 110 |
| Ex. 64 | 26 | PH49 | NH35 | 95 | 109 | 109 |
| Ex. 65 | 26 | PH49 | NH53 | 97 | 105 | 108 |
| Ex. 66 | 26 | PH49 | NH65 | 98 | 109 | 112 |
| Ex. 67 | 26 | PH65 | NH1 | 96 | 112 | 120 |
| Ex. 68 | 26 | PH65 | NH17 | 98 | 108 | 118 |
| Ex. 69 | 26 | PH65 | NH23 | 96 | 110 | 111 |
| Ex. 70 | 26 | PH65 | NH35 | 96 | 110 | 112 |
| Ex. 71 | 26 | PH65 | NH53 | 98 | 105 | 112 |
| Ex. 72 | 26 | PH65 | NH65 | 97 | 109 | 117 |

### Example 73 (Ex. 73): Fabrication of OLED

An OLED was fabricated using the same procedure and the same material as Example 1, except that Compound 105 of Synthesis Example 7, instead of Compound 5, as the dopant in the EML.

### Examples 74-78 (Ex. 74-78): Fabrication of OLEDs

An OLED was fabricated using the same procedure and the same material as Example 73, except that each of Compound NH17 (Ex. 74), Compound NH23 (Ex. 75), Compound NH35 (Ex. 76), Compound NH53 (Ex. 77), and Compound NH65 (Ex. 78) of Chemical Formula 12, instead of Compound NH1, was used as the second host in the EML, respectively.

### Example 79 (Ex. 79): Fabrication of OLED

An OLED was fabricated using the same procedure and the same material as Example 73, except that Compound PH9 of Chemical Formula 10, instead of Compound PH1, as the first host in the EML.

### Examples 80-84 (Ex. 80-84): Fabrication of OLEDs

An OLED was fabricated using the same procedure and the same material as Example 79, except that each of Compound NH17 (Ex. 80), Compound NH23 (Ex. 81), Compound NH35 (Ex. 82), Compound NH53 (Ex. 83), and Compound NH65 (Ex. 84) of Chemical Formula 12, instead of Compound NH1, was used as the second host in the EML, respectively.

### Example 85 (Ex. 85): Fabrication of OLED

An OLED was fabricated using the same procedure and the same material as Example 73, except that Compound PH17 of Chemical Formula 10, instead of Compound PH1, as the first host in the EML.

### Examples 86-90 (Ex. 86-90): Fabrication of OLEDs

An OLED was fabricated using the same procedure and the same material as Example 85, except that each of Compound NH17 (Ex. 86), Compound NH23 (Ex. 87), Compound NH35 (Ex. 88), Compound NH53 (Ex. 89), and Compound NH65 (Ex. 90) of Chemical Formula 12, instead of Compound NH1, was used as the second host in the EML, respectively.

### Comparative Example 3 (Ref. 3): Fabrication of OLED

An OLED was fabricated using the same procedure and the same material as Example 73, except that the luminous materials in the EML mas modified to a single host mCBP (95 wt. %) and the Compound 5 (5 wt. %).

### Experimental Example 5: Measurement of Luminous Properties of OLEDs

The optical properties of the OLEDs fabricated in Examples 73 to 90 and Comparative Example 3 were measured as presented in Experimental Example 1. The measurement results are indicated in the following Table 5.

TABLE 5
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 3 | 105 | mCBP | | 100 | 100 | 100 |
| Ex. 73 | 105 | PH1 | NH1 | 93 | 113 | 120 |
| Ex. 74 | 105 | PH1 | NH17 | 94 | 112 | 120 |
| Ex. 75 | 105 | PH1 | NH23 | 94 | 112 | 117 |
| Ex. 76 | 105 | PH1 | NH35 | 93 | 112 | 115 |
| Ex. 77 | 105 | PH1 | NH53 | 94 | 106 | 111 |
| Ex. 78 | 105 | PH1 | NH65 | 93 | 108 | 116 |
| Ex. 79 | 105 | PH9 | NH1 | 94 | 113 | 117 |
| Ex. 80 | 105 | PH9 | NH17 | 95 | 112 | 116 |
| Ex. 81 | 105 | PH9 | NH23 | 94 | 112 | 115 |
| Ex. 82 | 105 | PH9 | NH35 | 93 | 111 | 114 |
| Ex. 83 | 105 | PH9 | NH53 | 95 | 108 | 109 |
| Ex. 84 | 105 | PH9 | NH65 | 94 | 109 | 112 |
| Ex. 85 | 105 | PH17 | NH1 | 95 | 109 | 116 |
| Ex. 86 | 105 | PH17 | NH17 | 96 | 106 | 114 |
| Ex. 87 | 105 | PH17 | NH23 | 95 | 107 | 113 |
| Ex. 88 | 105 | PH17 | NH35 | 95 | 106 | 113 |
| Ex. 89 | 105 | PH17 | NH53 | 96 | 103 | 108 |
| Ex. 90 | 105 | PH17 | NH65 | 96 | 107 | 111 |

### Example 91 (Ex. 91): Fabrication of OLED

An OLED was fabricated using the same procedure and the same material as Example 73, except that Compound PH33 of Chemical Formula 10, instead of Compound PH1, as the first host in the EML.

### Examples 92-96 (Ex. 92-96): Fabrication of OLEDs

An OLED was fabricated using the same procedure and the same material as Example 91, except that each of Compound NH17 (Ex. 92), Compound NH23 (Ex. 93), Compound NH35 (Ex. 94), Compound NH53 (Ex. 95), and Compound NH65 (Ex. 96) of Chemical Formula 12, instead of Compound NH1, was used as the second host in the EML, respectively.

### Example 97 (Ex. 97): Fabrication of OLED

An OLED was fabricated using the same procedure and the same material as Example 73, except that Compound PH49 of Chemical Formula 10, instead of Compound PH1, as the first host in the EML.

### Examples 98-102 (Ex. 98-102): Fabrication of OLEDs

An OLED was fabricated using the same procedure and the same material as Example 97, except that each of Compound NH17 (Ex. 98), Compound NH23 (Ex. 99), Compound NH35 (Ex. 100), Compound NH53 (Ex. 101), and Compound NH65 (Ex. 102) of Chemical Formula 12, instead of Compound NH1, was used as the second host in the EML, respectively.

### Example 103 (Ex. 103): Fabrication of OLED

An OLED was fabricated using the same procedure and the same material as Example 73, except that Compound PH65 of Chemical Formula 10, instead of Compound PH1, as the first host in the EML.

### Examples 104-108 (Ex. 104-108): Fabrication of OLEDs

An OLED was fabricated using the same procedure and the same material as Example 103, except that each of Compound NH17 (Ex. 104), Compound NH23 (Ex. 105), Compound NH35 (Ex. 106), Compound NH53 (Ex. 107), and Compound NH65 (Ex. 108) of Chemical Formula 12, instead of Compound NH1, was used as the second host in the EML, respectively.

### Experimental Example 6: Measurement of Luminous Properties of OLEDs

The optical properties of the OLEDs fabricated in Examples 91 to 108 and Comparative Example 3 were measured as presented in Experimental Example 1. The measurement results are indicated in the following Table 6.

TABLE 6
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 3 | 105 | CBP | | 100 | 100 | 100 |
| Ex. 91 | 105 | PH33 | NH1 | 96 | 113 | 112 |
| Ex. 92 | 105 | PH33 | NH17 | 96 | 108 | 110 |
| Ex. 93 | 105 | PH33 | NH23 | 95 | 107 | 113 |
| Ex. 94 | 105 | PH33 | NH35 | 96 | 107 | 111 |
| Ex. 95 | 105 | PH33 | NH53 | 96 | 105 | 105 |
| Ex. 96 | 105 | PH33 | NH65 | 97 | 109 | 106 |
| Ex. 97 | 105 | PH49 | NH1 | 95 | 110 | 119 |
| Ex. 98 | 105 | PH49 | NH17 | 95 | 108 | 117 |
| Ex. 99 | 105 | PH49 | NH23 | 93 | 106 | 116 |
| Ex. 100 | 105 | PH49 | NH35 | 93 | 106 | 115 |
| Ex. 101 | 105 | PH49 | NH53 | 95 | 105 | 112 |
| Ex. 102 | 105 | PH49 | NH65 | 95 | 107 | 115 |
| Ex. 103 | 105 | PH65 | NH1 | 96 | 112 | 127 |
| Ex. 104 | 105 | PH65 | NH17 | 95 | 107 | 123 |
| Ex. 105 | 105 | PH65 | NH23 | 95 | 107 | 118 |
| Ex. 106 | 105 | PH65 | NH35 | 94 | 106 | 117 |
| Ex. 107 | 105 | PH65 | NH53 | 96 | 103 | 119 |
| Ex. 108 | 105 | PH65 | NH65 | 96 | 109 | 123 |

### Example 109 (Ex. 109): Fabrication of OLED

An OLED was fabricated using the same procedure and the same material as Example 1, except that Compound 65 of Synthesis Example 6, instead of Compound 5, as the dopant in the EML.

### Examples 110-114 (Ex. 110-114): Fabrication of OLEDs

An OLED was fabricated using the same procedure and the same material as Example 109, except that each of Compound NH17 (Ex. 110), Compound NH23 (Ex. 111), Compound NH35 (Ex. 112), Compound NH53 (Ex. 113), and Compound NH65 (Ex. 114) of Chemical Formula 12, instead of Compound NH1, was used as the second host in the EML, respectively.

### Example 115 (Ex. 115): Fabrication of OLED

An OLED was fabricated using the same procedure and the same material as Example 109, except that Compound PH9 of Chemical Formula 10, instead of Compound PH1, as the first host in the EML.

### Examples 116-120 (Ex. 116-120): Fabrication of OLEDs

An OLED was fabricated using the same procedure and the same material as Example 115, except that each of Compound NH17 (Ex. 116), Compound NH23 (Ex. 117), Compound NH35 (Ex. 118), Compound NH53 (Ex. 119), and Compound NH65 (Ex. 120) of Chemical Formula 12, instead of Compound NH1, was used as the second host in the EML, respectively.

### Example 121 (Ex. 121): Fabrication of OLED

An OLED was fabricated using the same procedure and the same material as Example 109, except that Compound PH17 of Chemical Formula 10, instead of Compound PH1, as the first host in the EML.

### Examples 122-126 (Ex. 122-126): Fabrication of OLEDs

An OLED was fabricated using the same procedure and the same material as Example 121, except that each of Compound NH17 (Ex. 122), Compound NH23 (Ex. 123), Compound NH35 (Ex. 124), Compound NH53 (Ex. 125), and Compound NH65 (Ex. 126) of Chemical Formula 12, instead of Compound NH1, was used as the second host in the EML, respectively.

### Comparative Example 4 (Ref. 4): Fabrication of OLED

An OLED was fabricated using the same procedure and the same material as Example 109, except that the luminous materials in the EML mas modified to a single host mCBP (95 wt. %) and the Compound 5 (5 wt. %).

### Experimental Example 5: Measurement of Luminous Properties of OLEDs

The optical property of the OLEDs fabricated in Examples 109 to 126 and Comparative Example 4 was measured as Experimental Example 1. The measurement results are indicated in the following Table 7.

TABLE 7
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 4 | 65 | CBP | | 100 | 100 | 100 |
| Ex. 109 | 65 | PH1 | NH1 | 91 | 116 | 122 |
| Ex. 110 | 65 | PH1 | NH17 | 92 | 115 | 122 |
| Ex. 111 | 65 | PH1 | NH23 | 92 | 115 | 119 |
| Ex. 112 | 65 | PH1 | NH35 | 91 | 115 | 117 |
| Ex. 113 | 65 | PH1 | NH53 | 93 | 109 | 115 |
| Ex. 114 | 65 | PH1 | NH65 | 91 | 113 | 118 |
| Ex. 115 | 65 | PH9 | NH1 | 93 | 117 | 118 |
| Ex. 116 | 65 | PH9 | NH17 | 93 | 115 | 116 |
| Ex. 117 | 65 | PH9 | NH23 | 94 | 116 | 115 |
| Ex. 118 | 65 | PH9 | NH35 | 92 | 117 | 112 |
| Ex. 119 | 65 | PH9 | NH53 | 93 | 110 | 111 |
| Ex. 120 | 65 | PH9 | NH65 | 93 | 114 | 114 |
| Ex. 121 | 65 | PH17 | NH1 | 93 | 112 | 118 |
| Ex. 122 | 65 | PH17 | NH17 | 94 | 109 | 116 |
| Ex. 123 | 65 | PH17 | NH23 | 93 | 110 | 115 |
| Ex. 124 | 65 | PH17 | NH35 | 93 | 109 | 115 |
| Ex. 125 | 65 | PH17 | NH53 | 94 | 105 | 111 |
| Ex. 126 | 65 | PH17 | NH65 | 93 | 110 | 113 |

### Example 127 (Ex. 127): Fabrication of OLED

An OLED was fabricated using the same procedure and the same material as Example 109, except that Compound PH33 of Chemical Formula 10, instead of Compound PH1, as the first host in the EML.

### Examples 128-132 (Ex. 128-132): Fabrication of OLEDs

An OLED was fabricated using the same procedure and the same material as Example 127, except that each of Compound NH17 (Ex. 128), Compound NH23 (Ex. 129), Compound NH35 (Ex. 130), Compound NH53 (Ex. 131), and Compound NH65 (Ex. 132) of Chemical Formula 12, instead of Compound NH1, was used as the second host in the EML, respectively.

### Example 133 (Ex. 133): Fabrication of OLED

An OLED was fabricated using the same procedure and the same material as Example 109, except that Compound PH49 of Chemical Formula 10, instead of Compound PH1, as the first host in the EML.

### Examples 134-138 (Ex. 134-138): Fabrication of OLEDs

An OLED was fabricated using the same procedure and the same material as Example 133, except that each of Compound NH17 (Ex. 134), Compound NH23 (Ex. 135), Compound NH35 (Ex. 136), Compound NH53 (Ex. 137), and Compound NH65 (Ex. 138) of Chemical Formula 12, instead of Compound NH1, was used as the second host in the EML, respectively.

### Example 139 (Ex. 139): Fabrication of OLED

An OLED was fabricated using the same procedure and the same material as Example 109, except that Compound PH65 of Chemical Formula 10, instead of Compound PH1, as the first host in the EML.

### Examples 140-144 (Ex. 140-144): Fabrication of OLEDs

An OLED was fabricated using the same procedure and the same material as Example 139, except that each of Compound NH17 (Ex. 140), Compound NH23 (Ex. 141), Compound NH35 (Ex. 142), Compound NH53 (Ex. 143), and Compound NH65 (Ex. 144) of Chemical Formula 12, instead of Compound NH1, was used as the second host in the EML, respectively.

### Experimental Example 8: Measurement of Luminous Properties of OLEDs

The optical property of the OLEDs fabricated in Examples 127 to 144 and Comparative Example 4 was measured as Experimental Example 1. The measurement results are indicated in the following Table 8.

TABLE 8
Luminous Properties of OLED

| | EML | | | V (%, | EQE (%, | LT95 (%, |
|---|---|---|---|---|---|---|
| Sample | Dopant | Host | | Relative) | Relative) | Relative) |
| Ref. 4 | 65 | CBP | | 100 | 100 | 100 |
| Ex. 127 | 65 | PH33 | NH1 | 94 | 114 | 115 |
| Ex. 128 | 65 | PH33 | NH17 | 95 | 111 | 112 |
| Ex. 129 | 65 | PH33 | NH23 | 95 | 110 | 110 |
| Ex. 130 | 65 | PH33 | NH35 | 94 | 112 | 111 |
| Ex. 131 | 65 | PH33 | NH53 | 95 | 108 | 108 |
| Ex. 132 | 65 | PH33 | NH65 | 94 | 112 | 109 |
| Ex. 133 | 65 | PH49 | NH1 | 93 | 113 | 121 |
| Ex. 134 | 65 | PH49 | NH17 | 93 | 111 | 119 |
| Ex. 135 | 65 | PH49 | NH23 | 91 | 109 | 118 |
| Ex. 136 | 65 | PH49 | NH35 | 91 | 109 | 117 |
| Ex. 137 | 65 | PH49 | NH53 | 93 | 106 | 112 |
| Ex. 138 | 65 | PH49 | NH65 | 93 | 110 | 119 |
| Ex. 139 | 65 | PH65 | NH1 | 94 | 116 | 129 |
| Ex. 140 | 65 | PH65 | NH17 | 93 | 110 | 125 |
| Ex. 141 | 65 | PH65 | NH23 | 93 | 109 | 122 |
| Ex. 142 | 65 | PH65 | NH35 | 94 | 109 | 120 |
| Ex. 143 | 65 | PH65 | NH53 | 93 | 105 | 118 |
| Ex. 144 | 65 | PH65 | NH65 | 94 | 110 | 121 |

Summing up the results of Tables 1 to 8, as compared to the OLEDs fabricated in the Comparative Examples 1 to 4, where mCBP as a single host was applied into the emitting material layer, in the OLED where the organometallic compound as the dopant, the amine-containing compound with a phenanthrenyl moiety as the first host and the triazine-containing compound as the second host are applied into the emitting material layer, the driving voltage was lowered by maximally 9%, and EQE and LT₉₅ were improved by maximally 17% and 29%, respectively.

The results above show that the organometallic compound as the dopant, the amine-containing compound with the phenanthrenyl moiety as the first host and the triazine-containing compound as the second host introduced into the emitting material layer can make an OLED with reducing driving voltage and improving significantly luminous efficiency and luminous lifespan.

It will be apparent to those skilled in the art that various modifications and variations may be made in the present disclosure without departing from the scope of the disclosure. Thus, it is intended that the present disclosure cover the modifications and variations of the present disclosure provided they come within the scope of the appended claims.

What is claimed is:

1. An organic light emitting diode comprising:
a first electrode;
a second electrode facing the first electrode; and
an emissive layer disposed between the first and second electrodes and comprising at least one emitting material layer,
wherein the at least one emitting material layer comprises a first compound and a second compound,
wherein the first compound comprises an organometallic compound having the structure of Chemical Formula 1:
Ir(L_{A})ₘ(L_{B})ₙ, [Chemical Formula 1]
wherein:
L_{A} is a ligand having the structure of Chemical Formula 2: 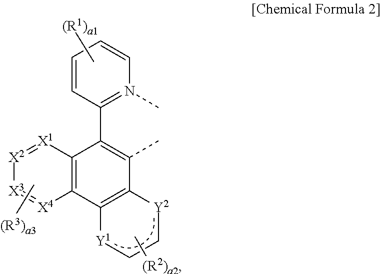
wherein:
each of X¹ to X⁴ is independently CR³ or N, wherein at least one of X¹ to X⁴ is CR³;
one of Y¹ and Y² is a single bond and another of Y¹ and Y² is CR⁴R⁵, NR⁴, O or S;
each of R¹ to R⁵ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R¹ is identical to or different from each other when a1 is 2, 3, or 4, wherein each R² is identical to or different from each other when a2 is 2, and wherein each R³ is identical to or different from each other when a3 is 2, 3 or 4, or
optionally,
two adjacent R¹ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a1 is 2, 3, or 4, and/or
two adjacent R² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a2 is 2,
two adjacent R³ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when a3 is 2, 3 or 4, and/or
R⁴ and R⁵ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring;
each of a1 and a3 is independently 0, 1, 2, 3, or 4;
a2 is 0, 1, or 2,
L_{B} is an auxiliary ligand;
m is 1, 2 or 3;
n is 0, 1 or 2; and
m+n is 3; and
wherein the second compound includes an organic compound having the structure of Chemical Formula 8: 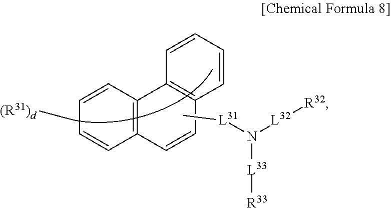
wherein:
each of R³¹ to R³³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R³¹ is identical to or different from each other when d is 2, 3, 4, 5, 6, 7, 8 or 9;
each of L³¹ and L³² is independently a single bond, an unsubstituted or substituted C₆-C₃₀ arylene group or an unsubstituted or substituted C₂-C₃₀ hetero arylene group; and
d is 0, 1, 2, 3, 4, 5, 6, 7, 8 or 9.

2. The organic light emitting diode of claim 1, wherein the at least one emitting material layer further comprises a third compound, and wherein the third compound comprises an organic compound having the following structure of Chemical Formula 11: 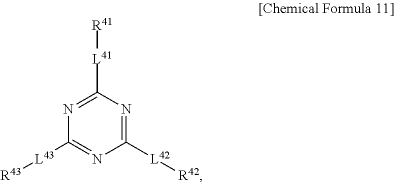
wherein:
each of R⁴¹ to R⁴³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group; and
each of L⁴¹ to L⁴³ is independently a single bond, an unsubstituted or substituted C₆-C₃₀ arylene group or an unsubstituted or substituted C₂-C₃₀ hetero arylene group.

3. The organic light emitting diode of claim 1, wherein the L_{A} in Chemical Formula 1 has the structure of Chemical Formula 3: 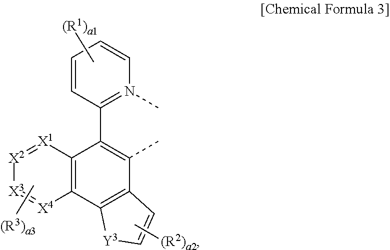
wherein:
Y³ is CR⁴R⁵, NR⁴, O or S; and
each of X¹ to X⁴, R¹ to R⁵, a1, a2 and a3 is as defined in Chemical Formula 2.

4. The organic light emitting diode of claim 1, wherein the L_{A} in Chemical Formula 1 has the structure of Chemical Formula 4: 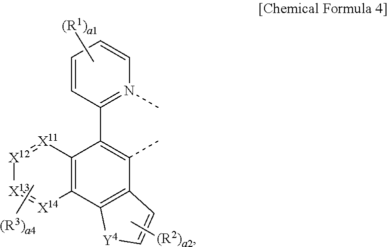
wherein:
each of X¹¹ to X¹⁴ is independently CR³ or N, wherein at least two of X¹¹ to X¹⁴ are CR³, and at least one of X¹¹ to X¹⁴ is N;
Y⁴ is NR⁴, O or S;
84 is 0, 1, 2, or 3; and
each of R¹ to R⁴, a1 and a2 is as defined in Chemical Formula 2.

5. The organic light emitting diode of claim 1, wherein the L_{A} in Chemical Formula 1 has the structure of Chemical Formula 5: 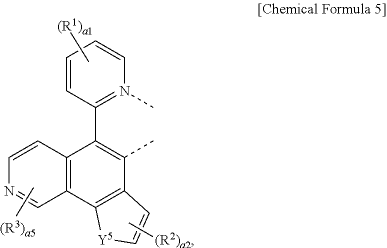
wherein:
Y⁵ is O or S;
a5 is 0, 1, 2 or 3; and
each of R¹ to R³, a1 and a2 is as defined in Chemical Formula 2.

6. The organic light emitting diode of claim 1, wherein each R¹ in Chemical Formula 2 is independently hydrogen, an unsubstituted or substituted C₁-C₂₀ alkyl group, an unsubstituted or substituted C₆-C₃₀ aryl group or an unsubstituted or substituted C₇-C₃₀ aralkyl group.

7. The organic light emitting diode of claim 1, wherein each of R² and R³ in Chemical Formula 2 is independently hydrogen, or an unsubstituted or substituted C₁-C₂₀ alkyl group.

8. The organic light emitting diode of claim 1, wherein one of X¹ to X⁴ is N and three of X¹ to X⁴ are CR³ in Chemical Formula 2.

9. The organic light emitting diode of claim 1, wherein Y¹ is O or S, and Y² is the single bond in Chemical Formula 2.

10. The organic light emitting diode of claim 1, wherein the L_{B} in Chemical Formula 1 has the structure of Chemical Formula 6A or Chemical Formula 6B: 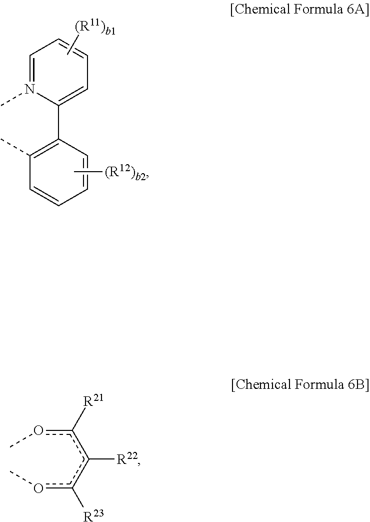
wherein:
each of R¹¹, R¹² and R²¹ to R²³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an unsubstituted or substituted C₃-C₃₀ hetero cycloalkyl group, an unsubstituted or substituted C₆-C₃₀ aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group, wherein each R¹¹ is identical to or different from each other when b1 is 2, 3 or 4, and wherein each R¹² is identical to or different from each other when b2 is 2, 3 or 4, or
optionally,
two adjacent R¹¹ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when b1 is 2, 3 or 4, and/or
two adjacent R¹² are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring when b2 is 2, 3 or 4, and/or
two adjacent groups among R²¹ to R²³ are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₂-C₂₀ hetero aromatic ring; and
each of b1 and b2 is independently 0, 1, 2, 3 or 4.

11. The organometallic compound of claim 1, wherein L_{A} in Chemical Formula 1 is chosen from:

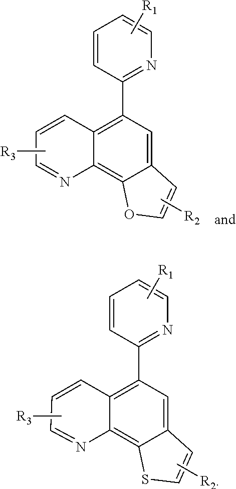

12. The organometallic compound of claim 1, wherein R¹ in Chemical Formula 1 is chosen from:
H, CH₃, C₂H₅,

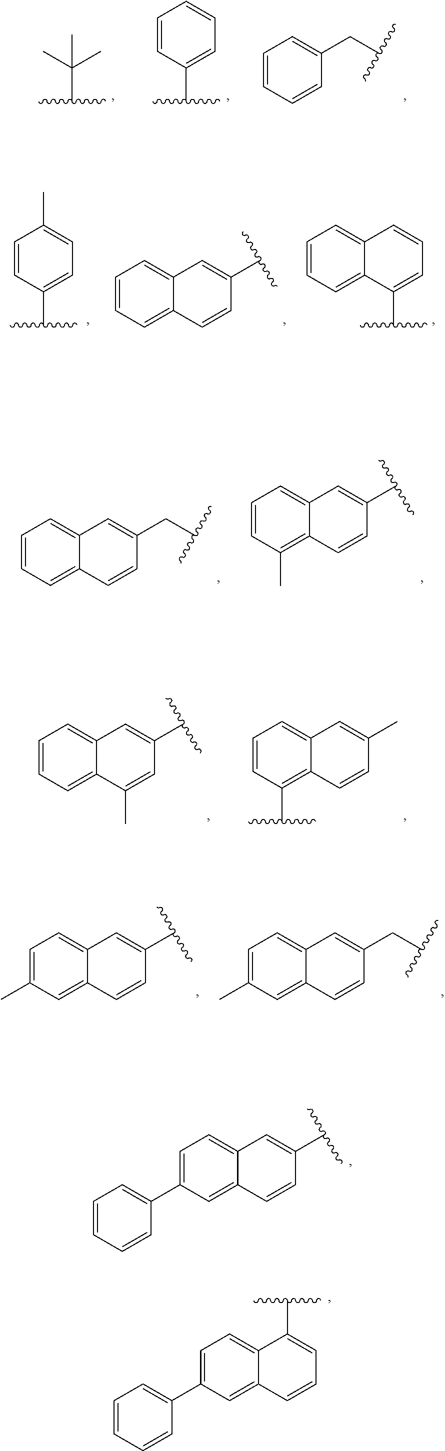

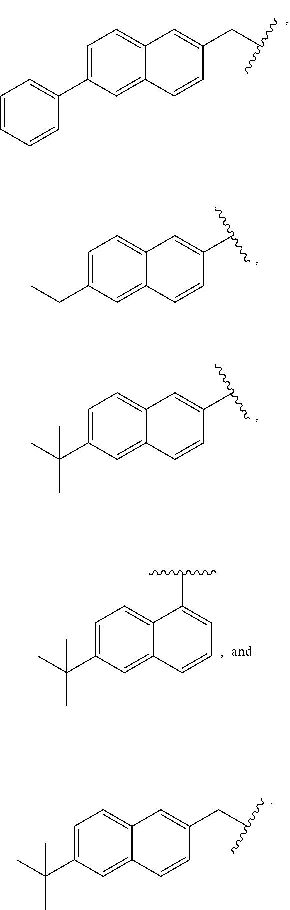

13. The organometallic compound of claim 1, wherein R² in Chemical Formula 1 is hydrogen.

14. The organometallic compound of claim 1, wherein Ra in Chemical Formula 1 is chosen from:
H, CH₃,

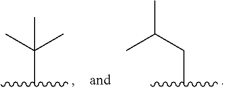

15. The organometallic compound of claim 1, wherein L_{B} in Chemical Formula 1 is chosen from:

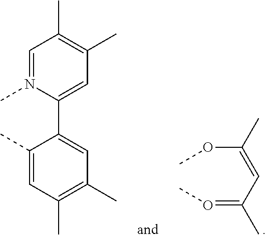

16. The organic light emitting diode of claim 11, wherein the first compound is at least one of:

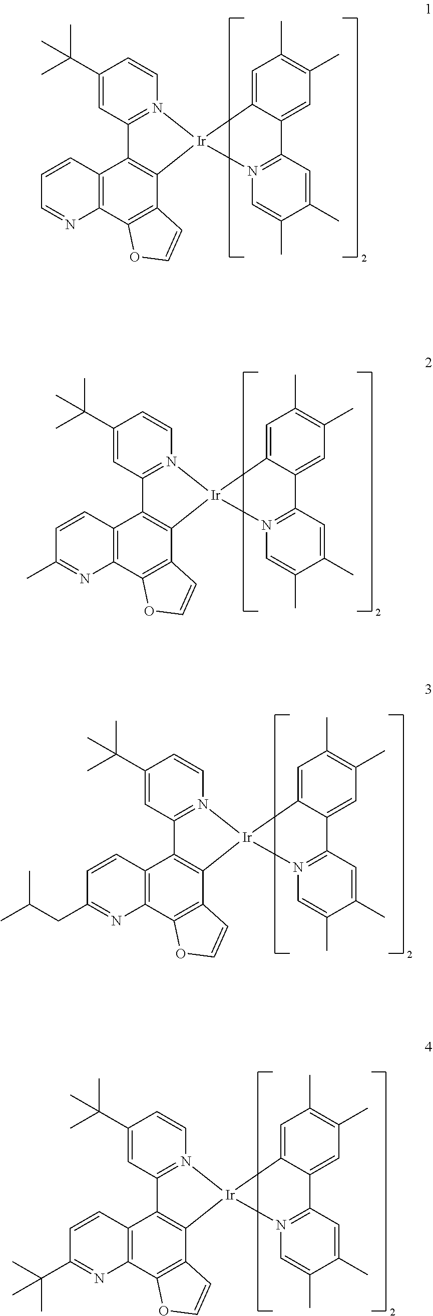

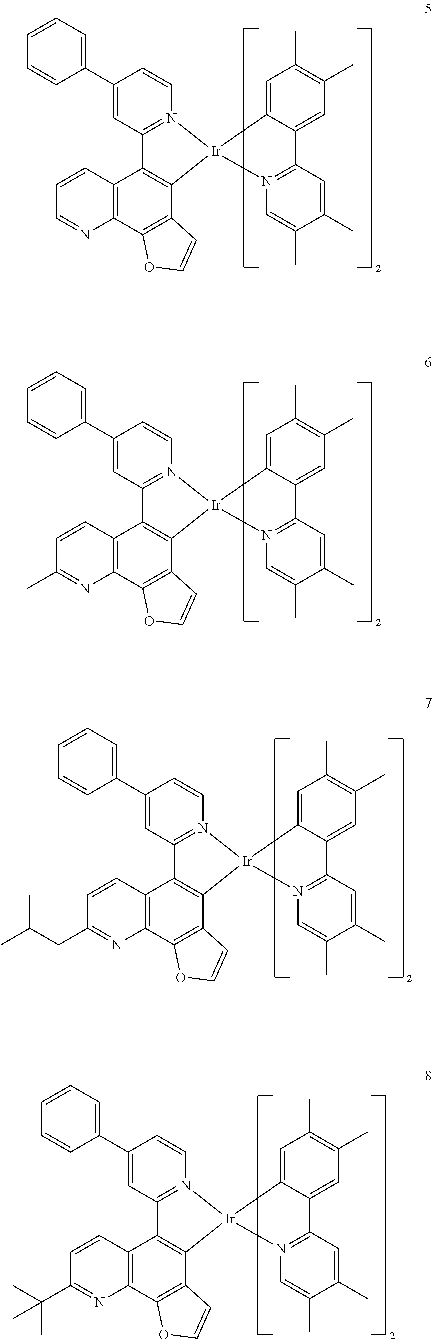

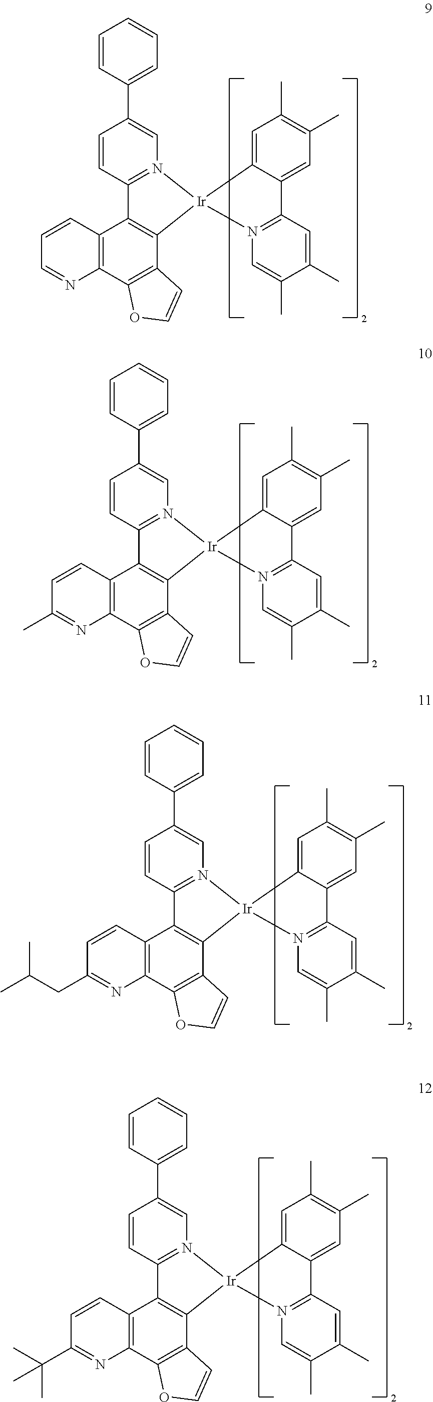

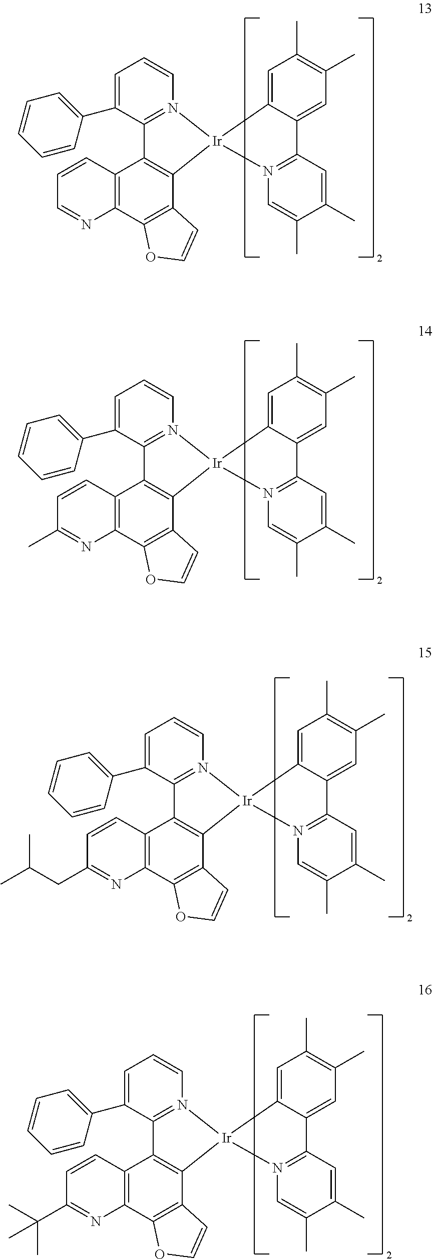

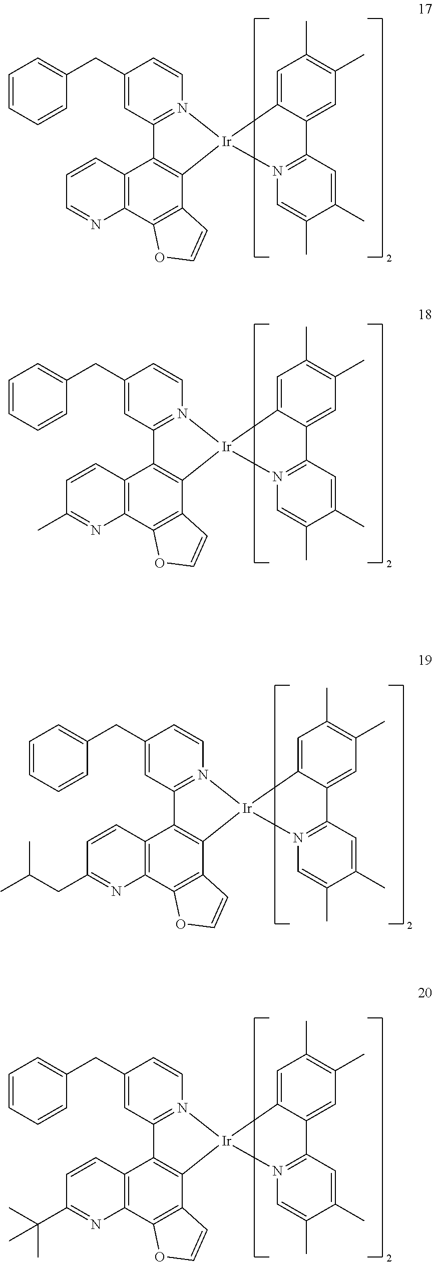

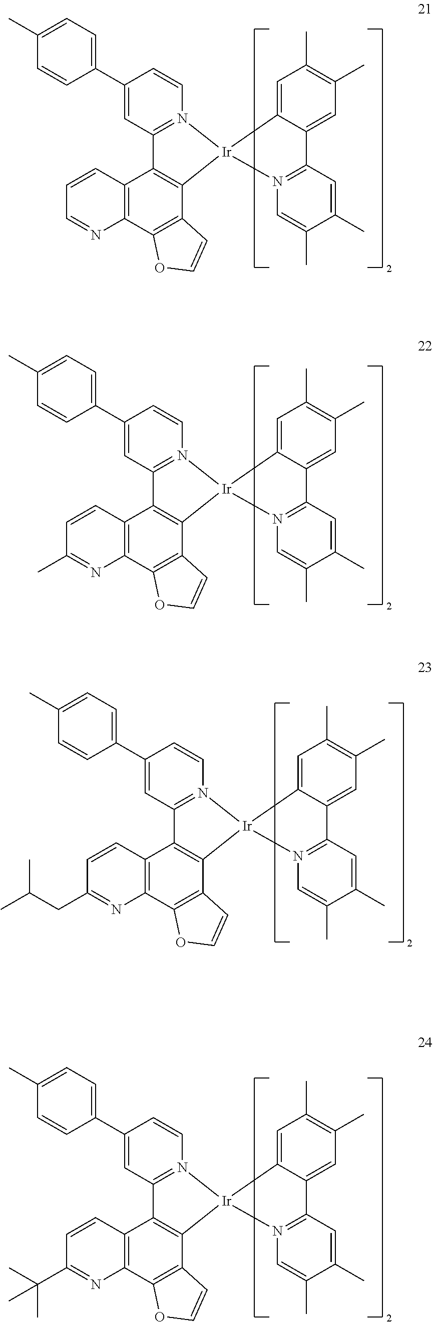

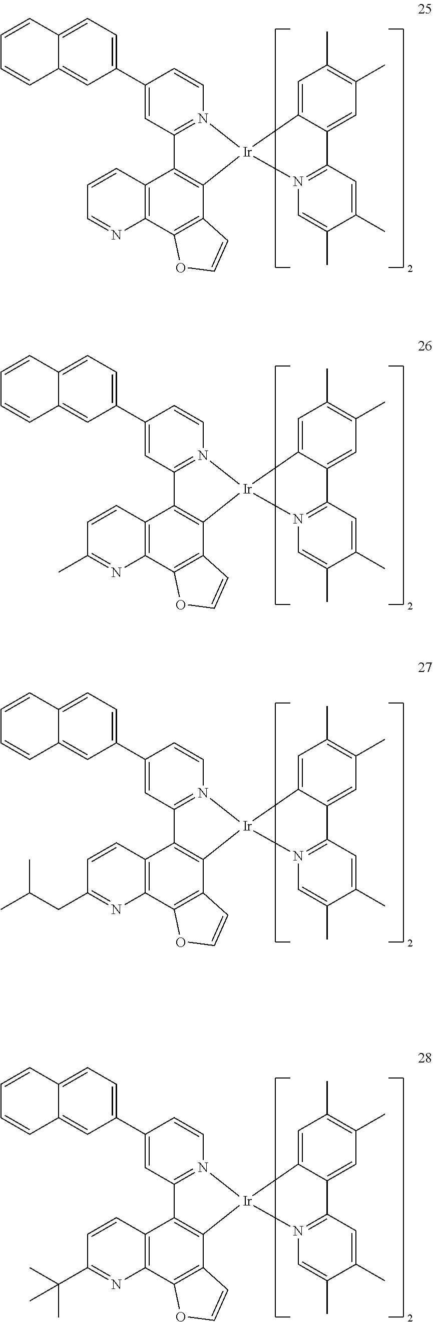

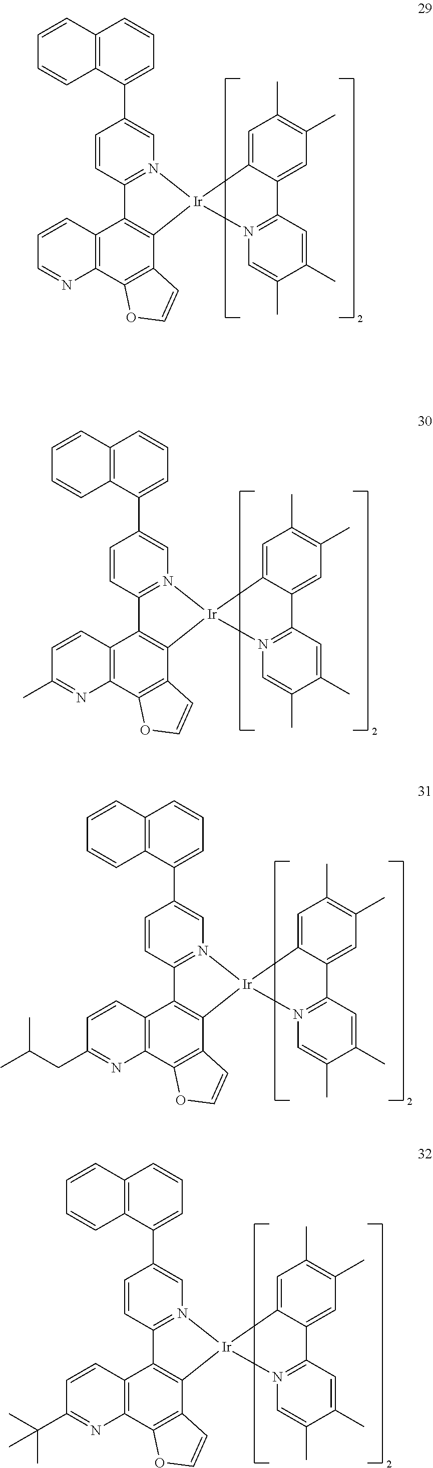

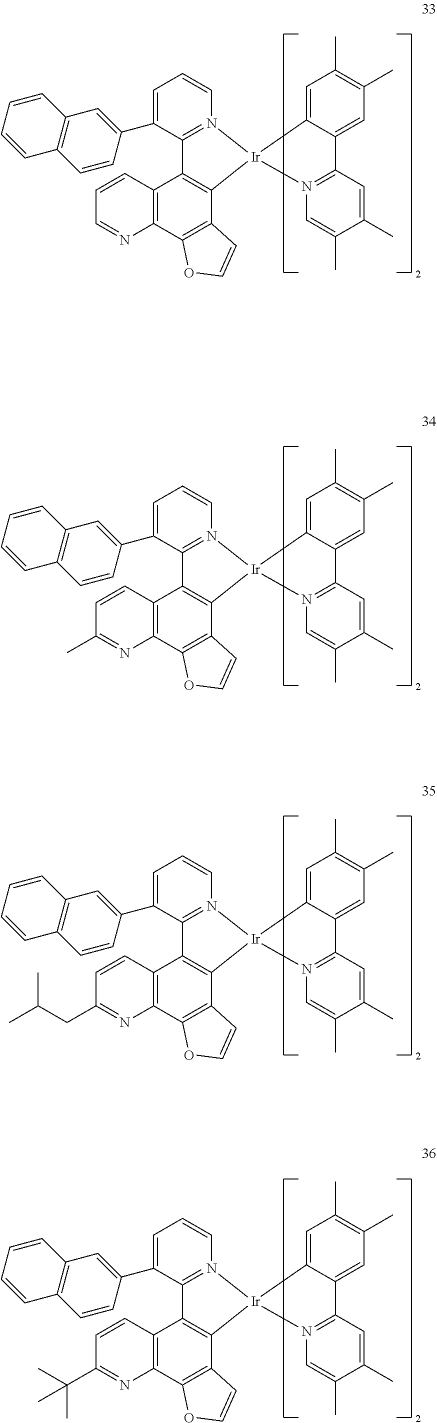

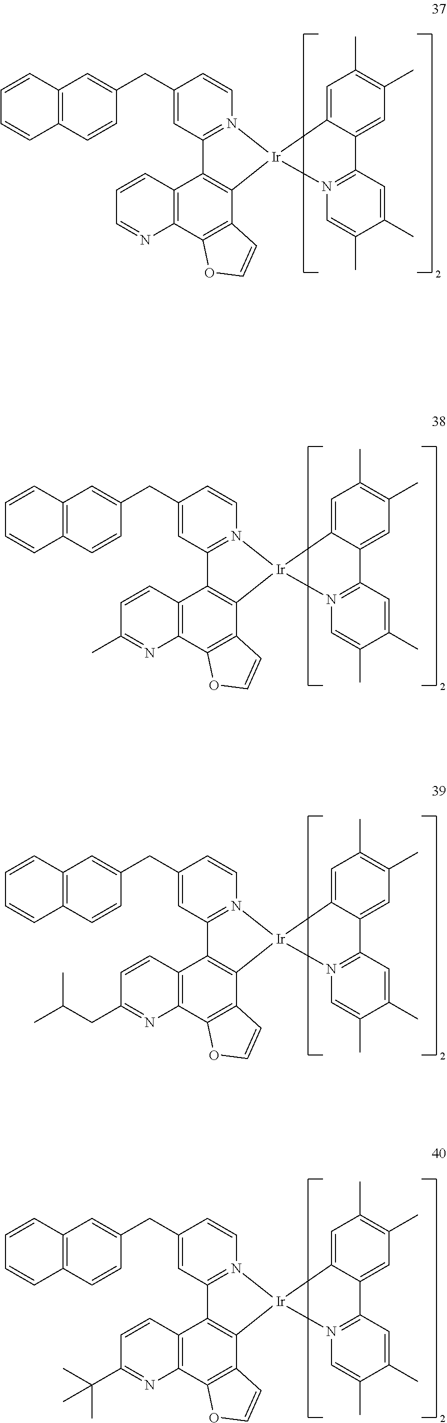

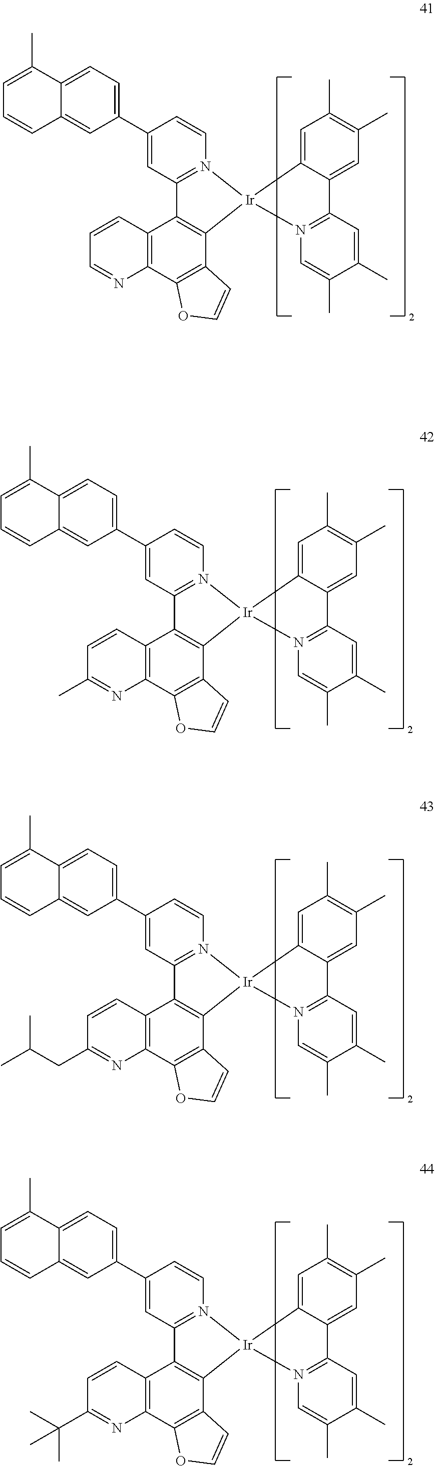

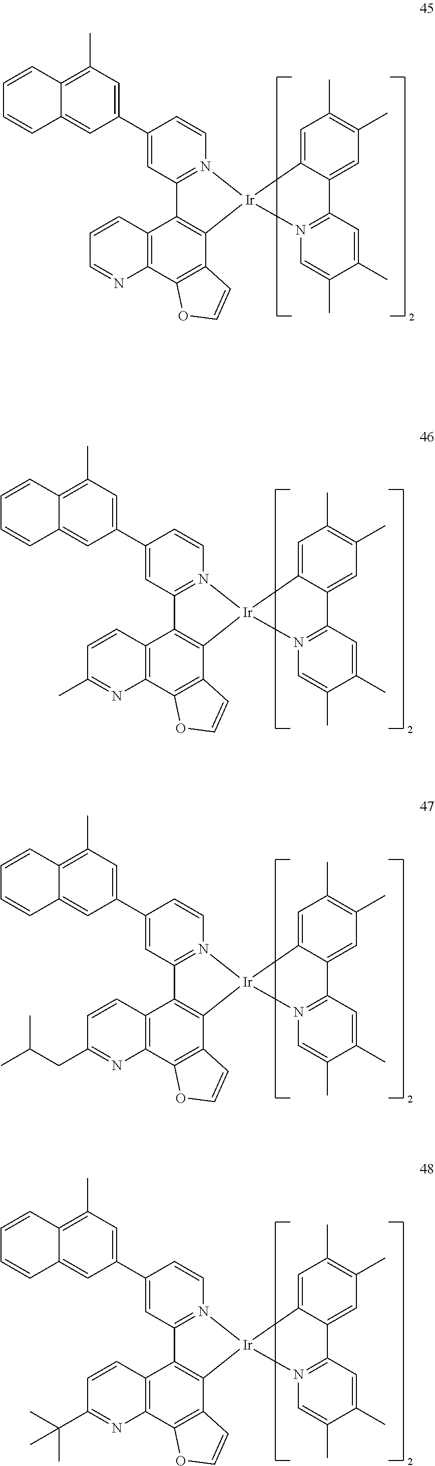

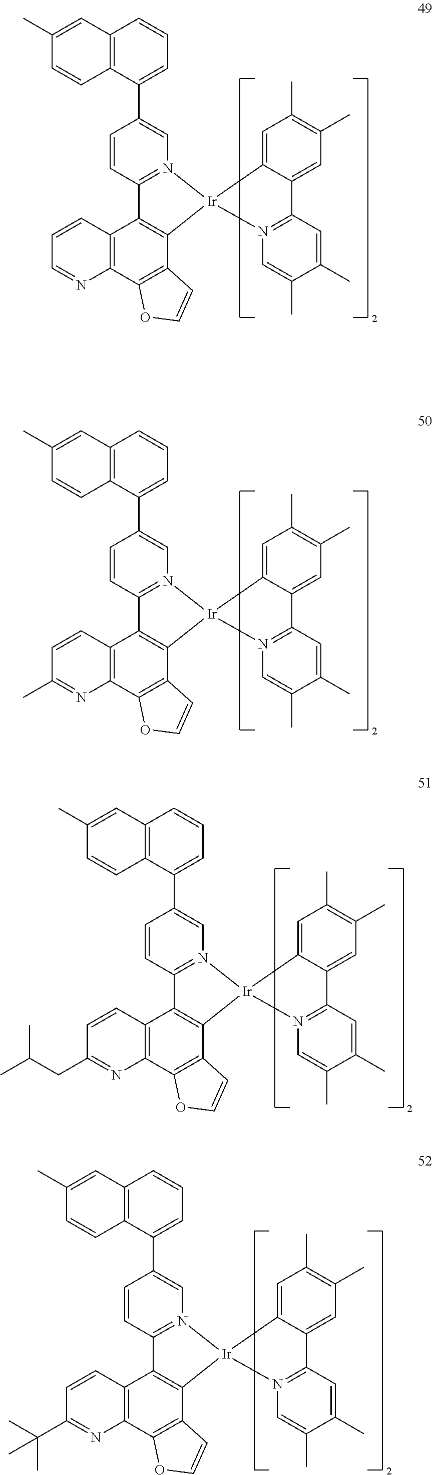

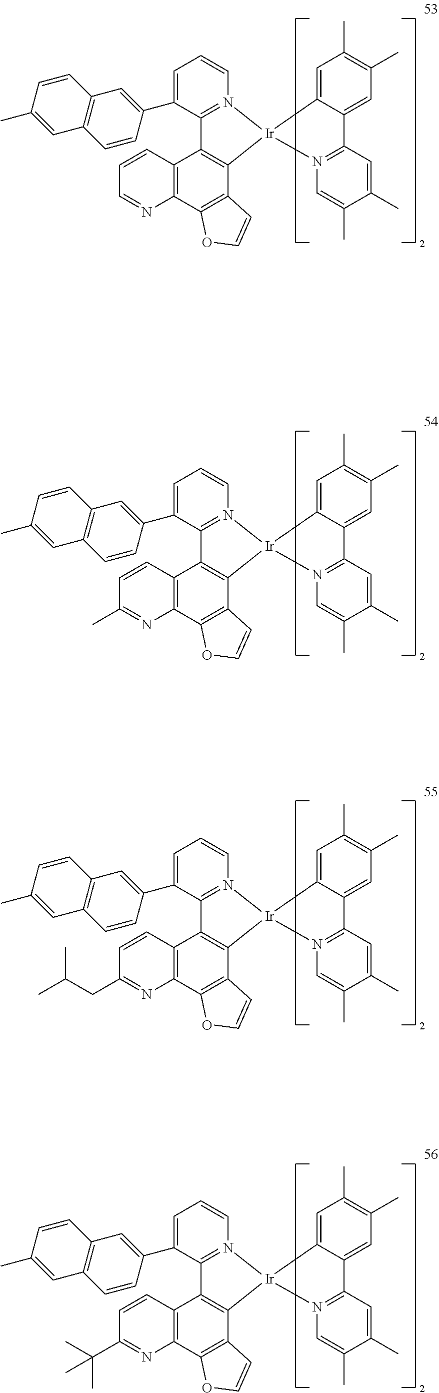

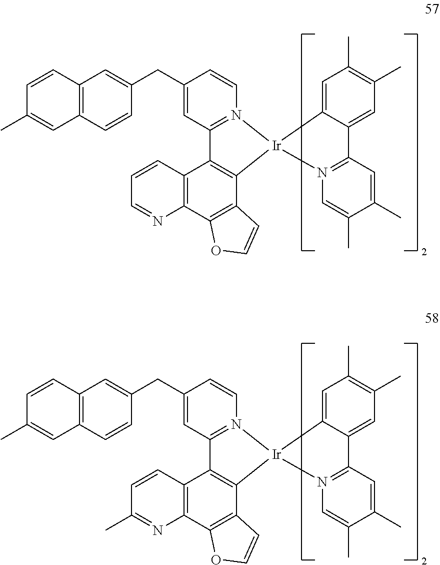

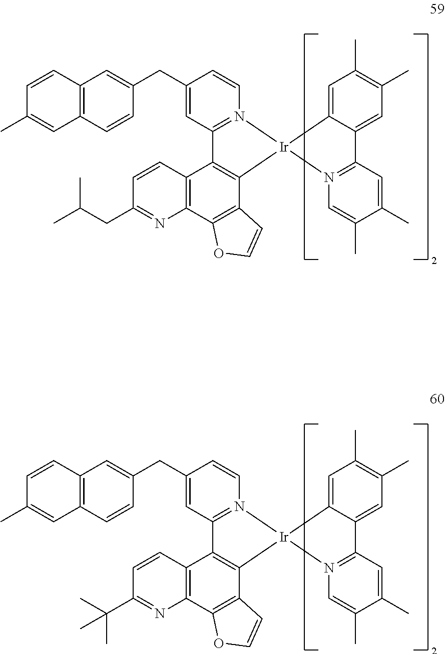

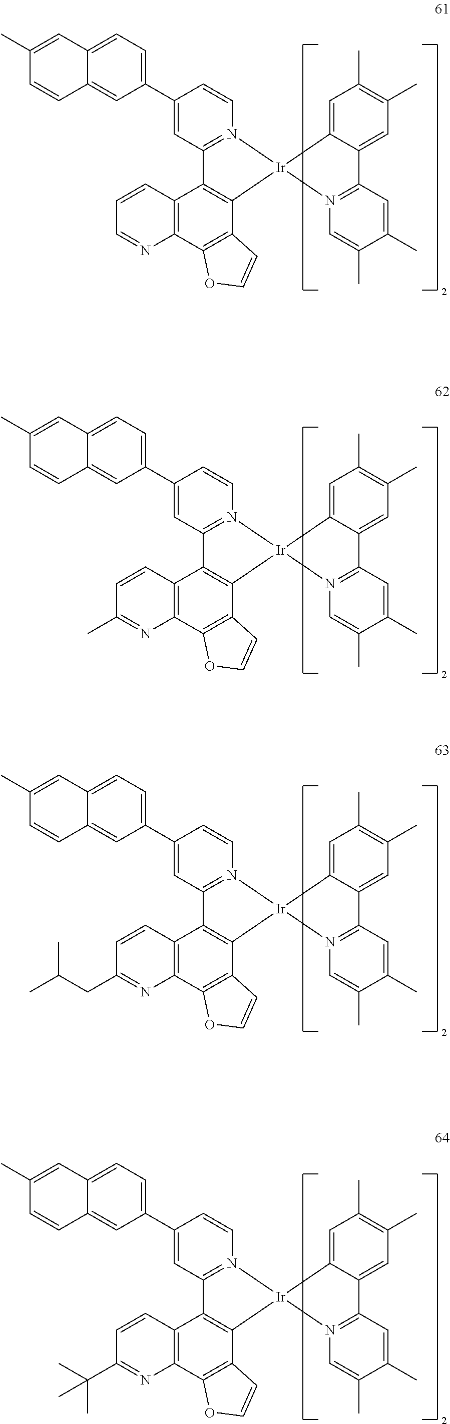

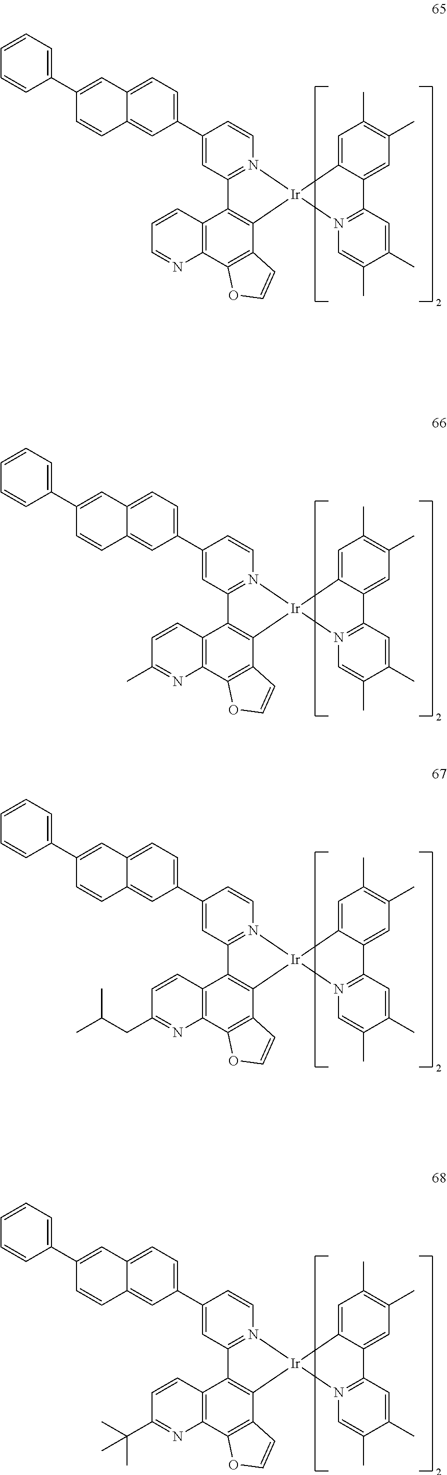

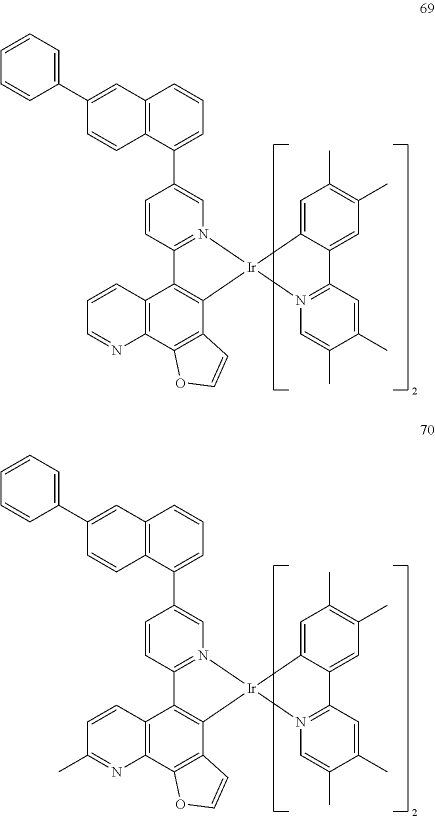

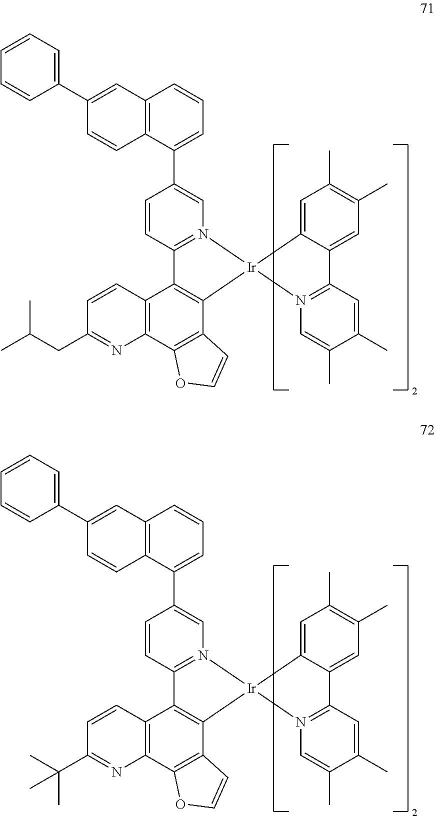

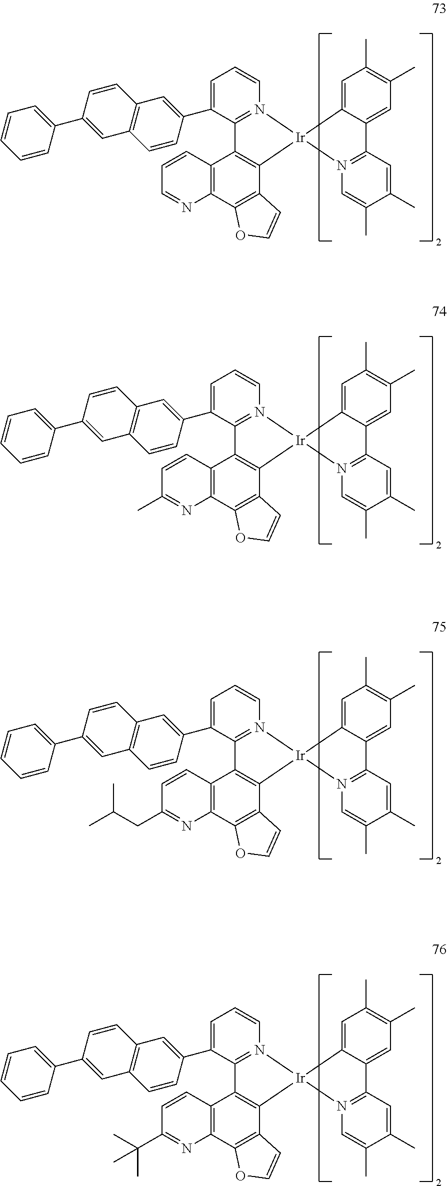

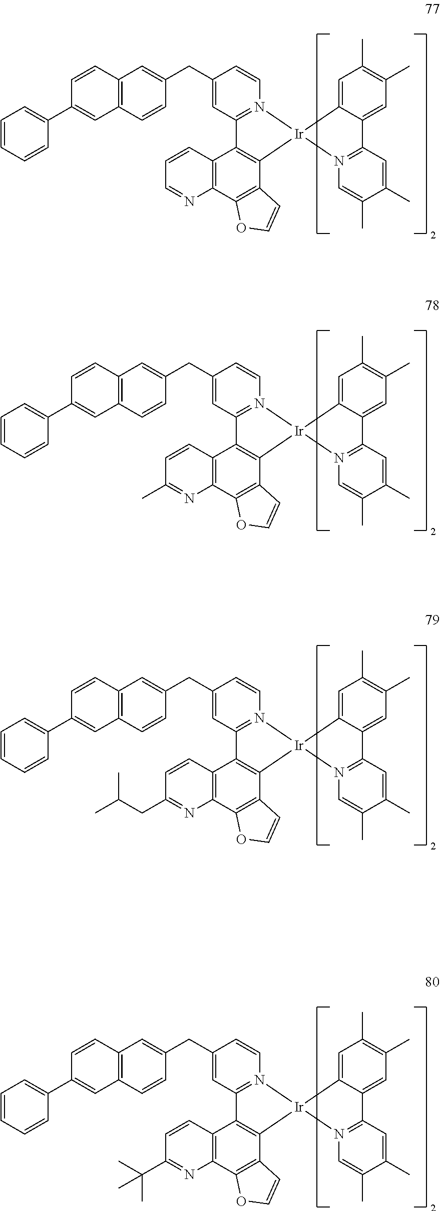

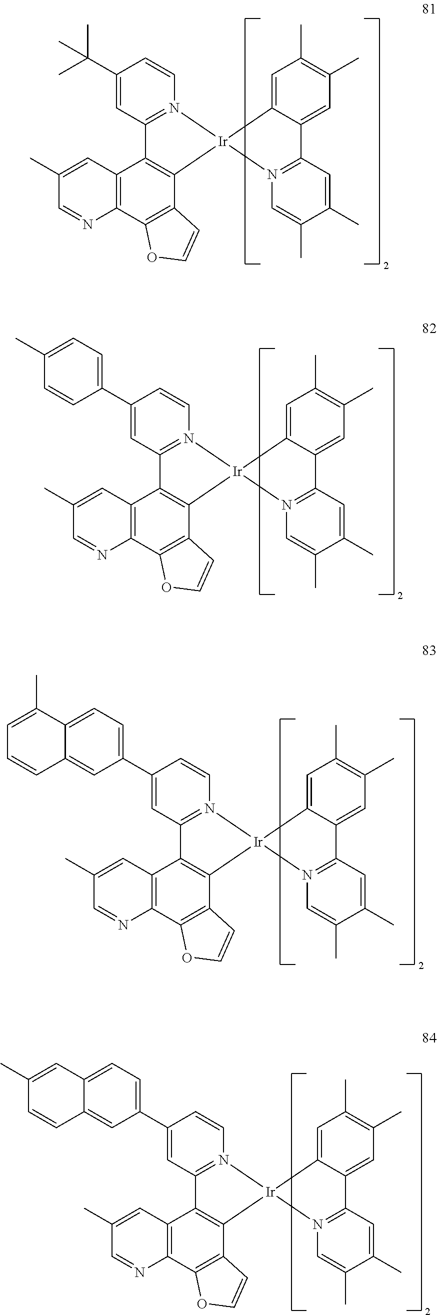

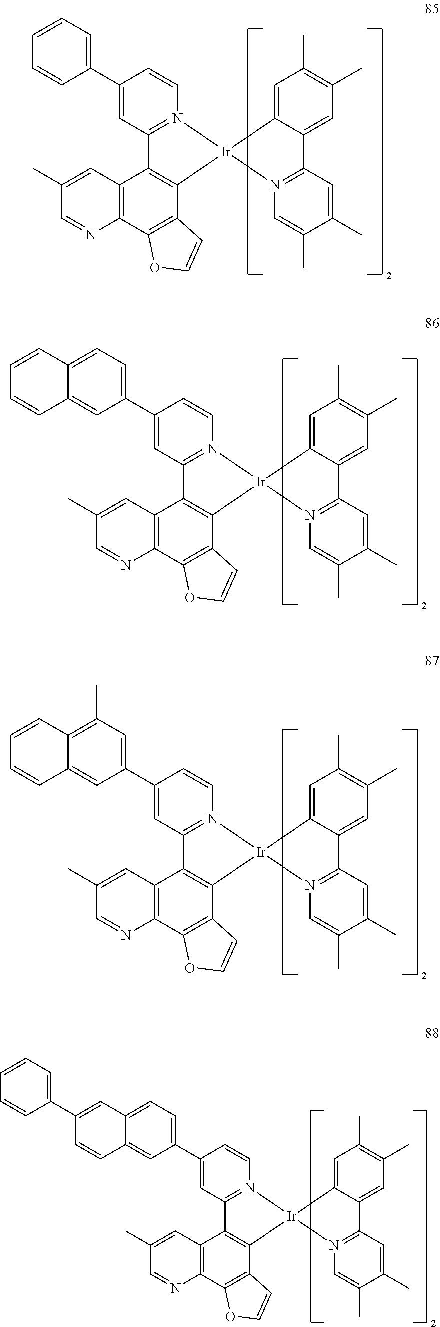

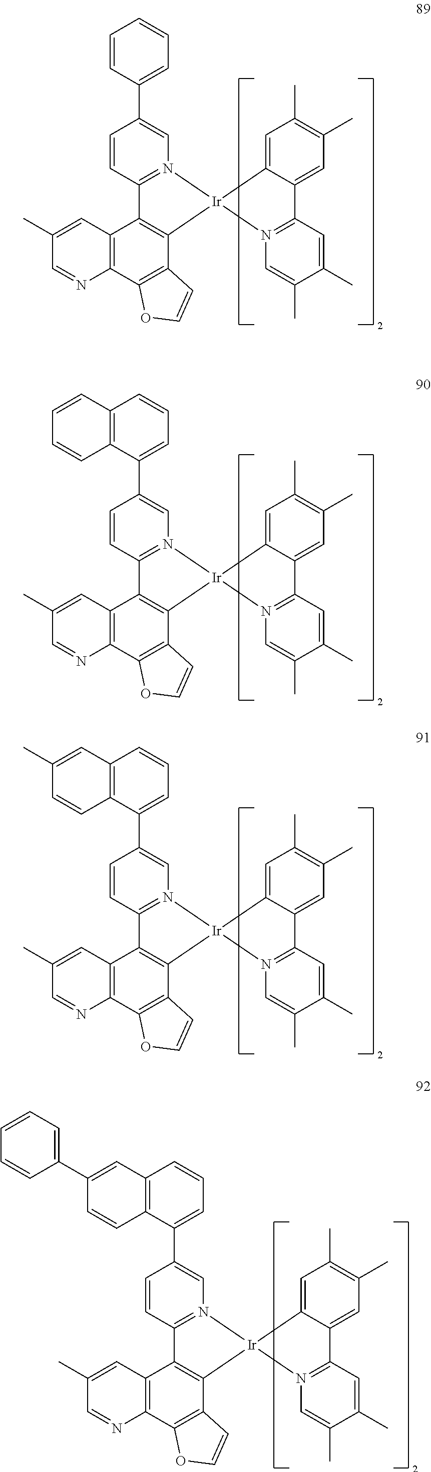

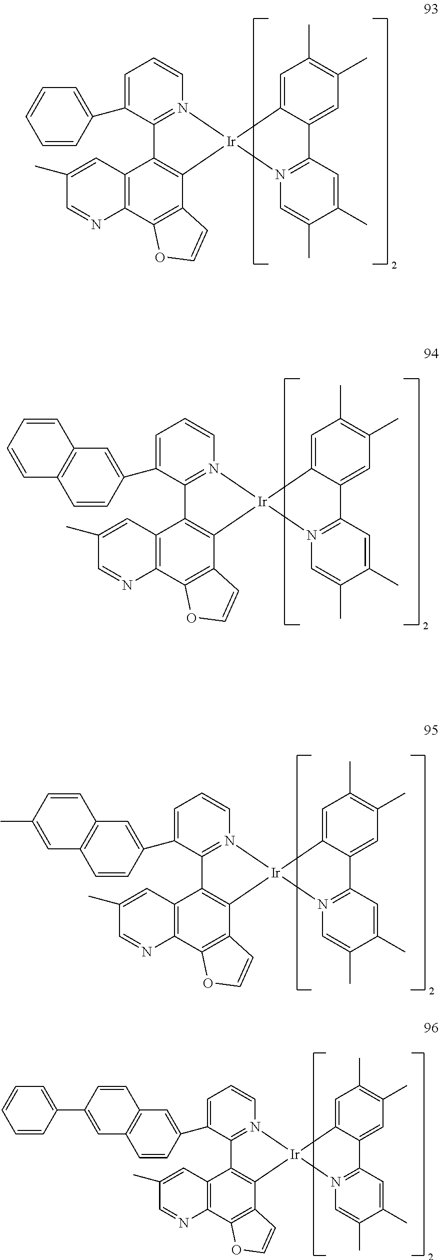

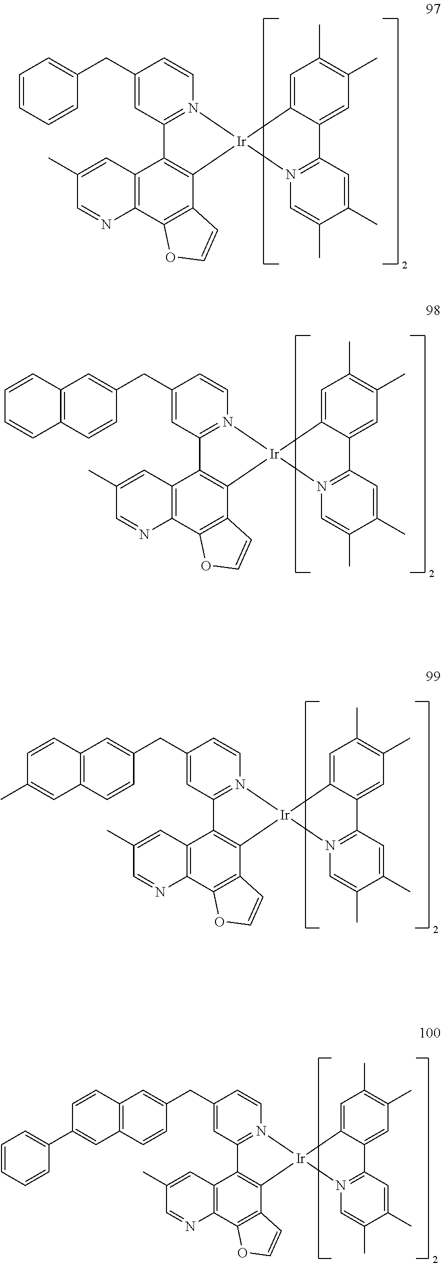

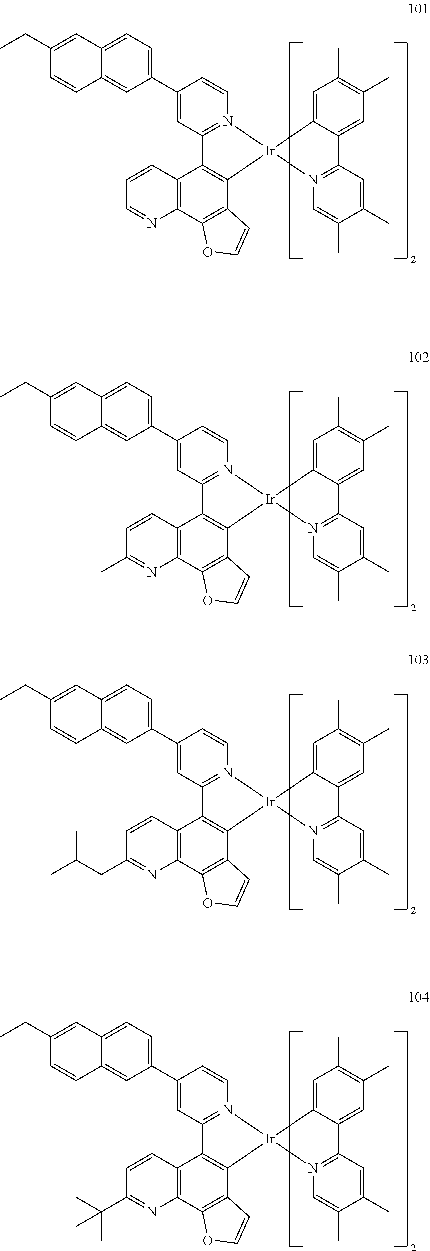

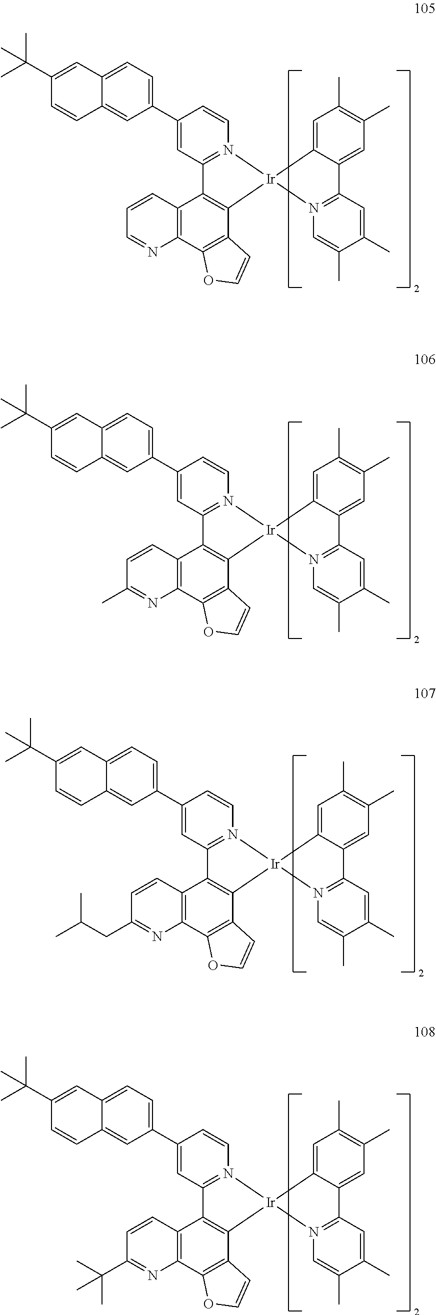

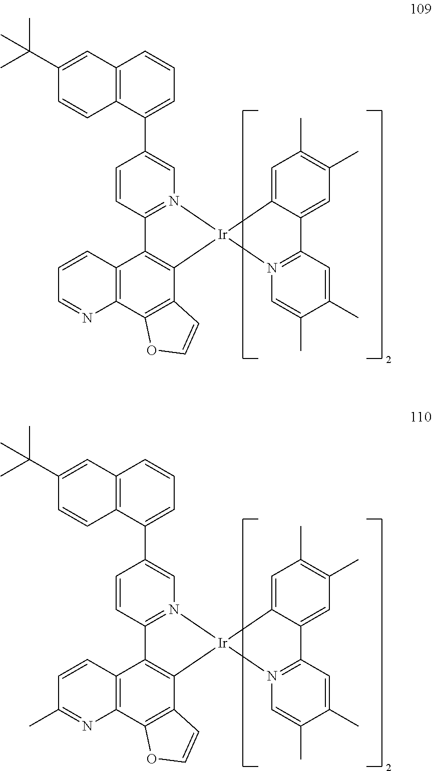

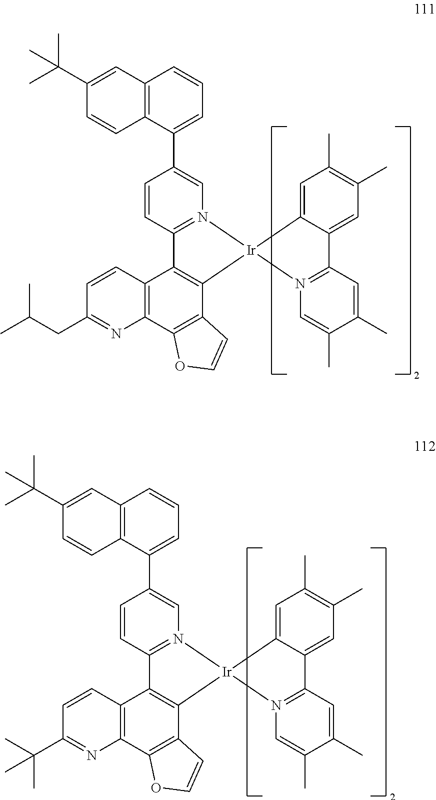

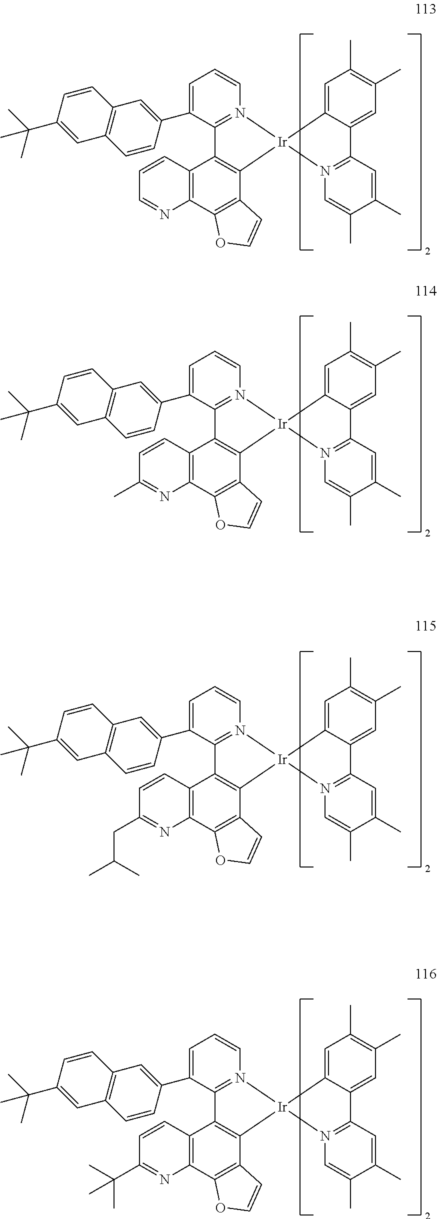

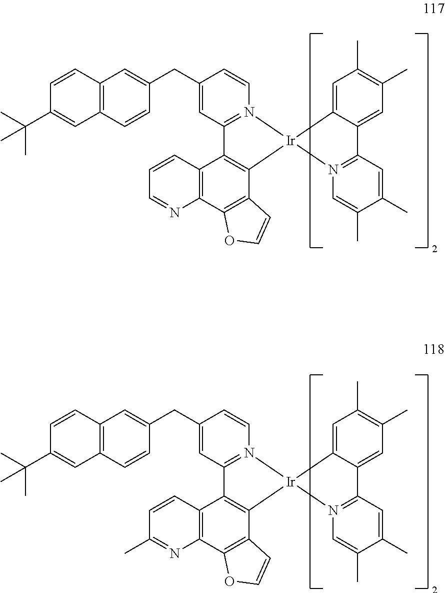

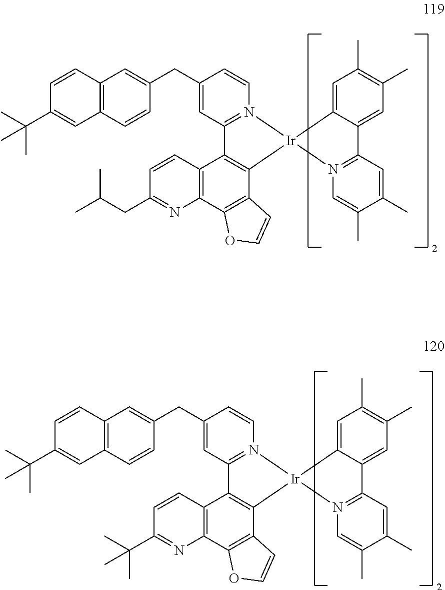

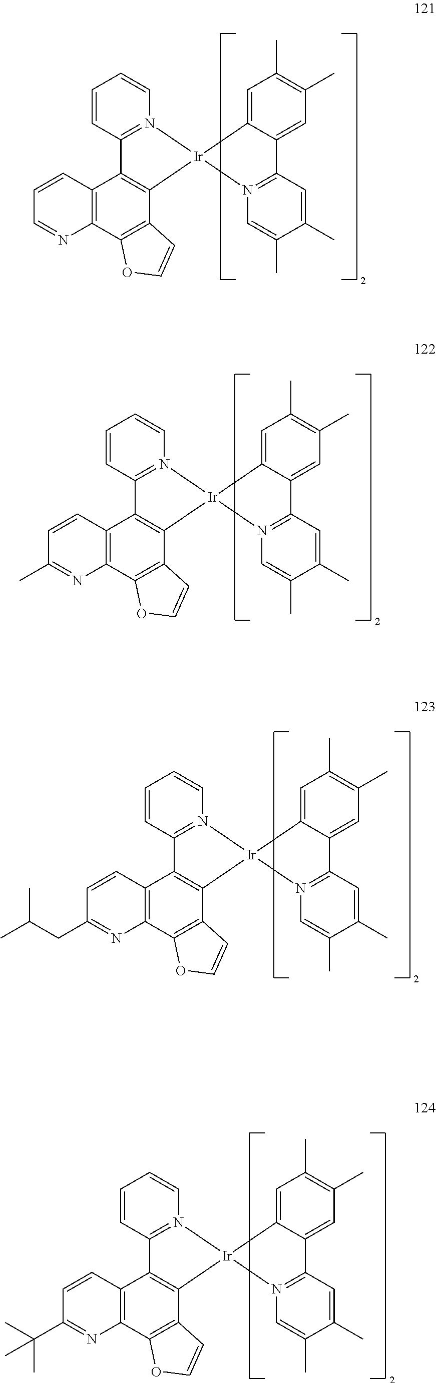

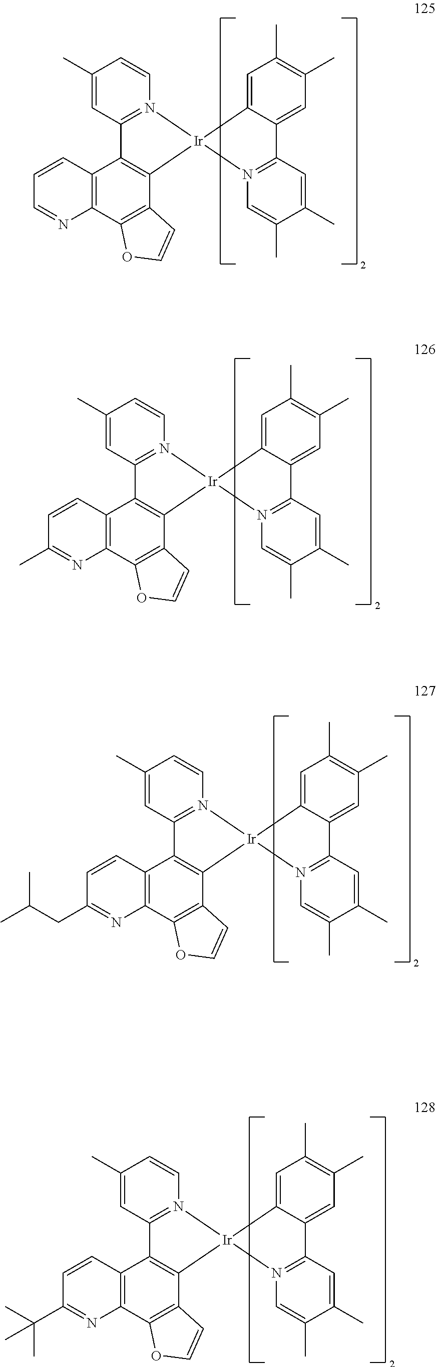

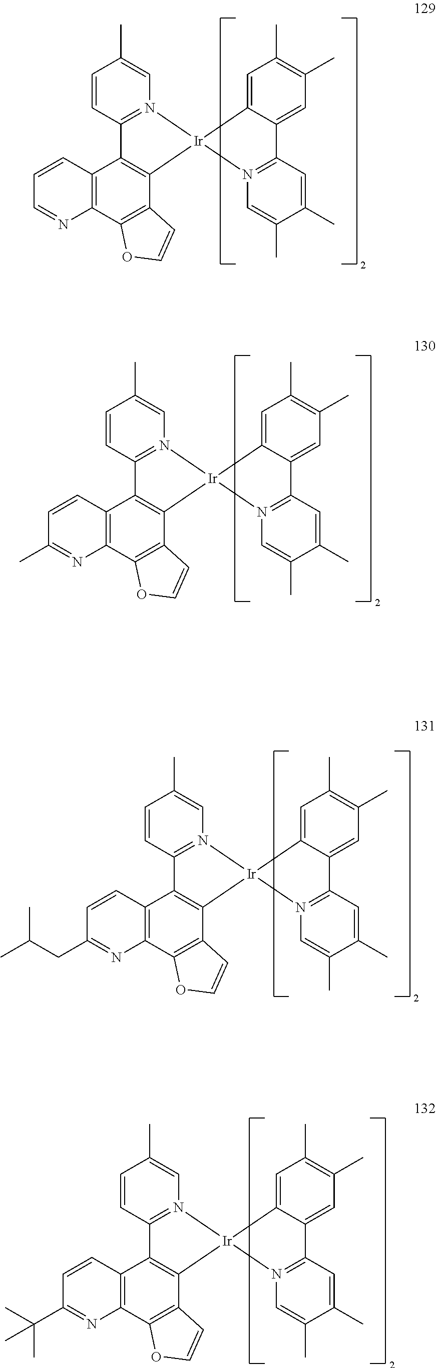

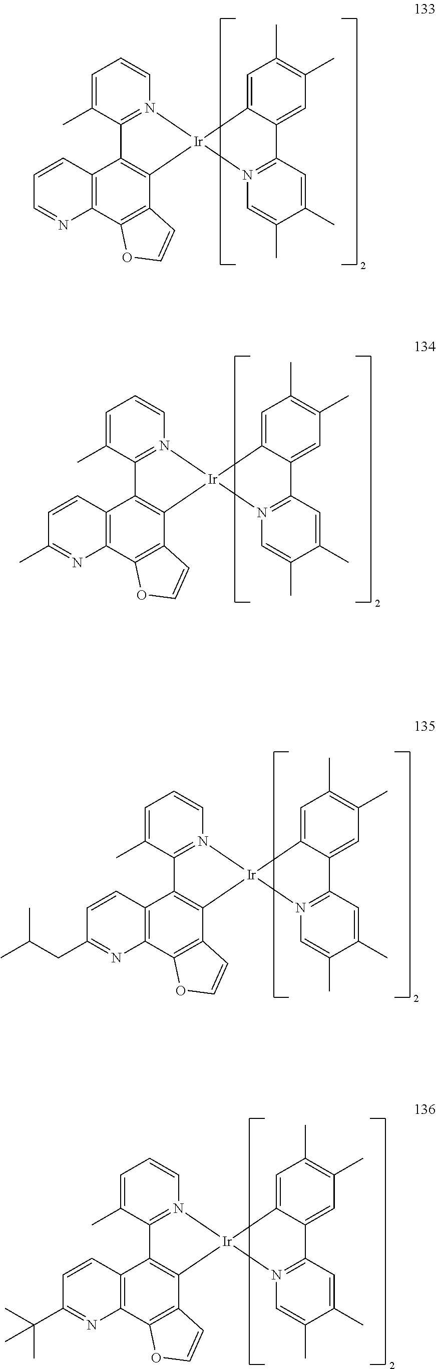

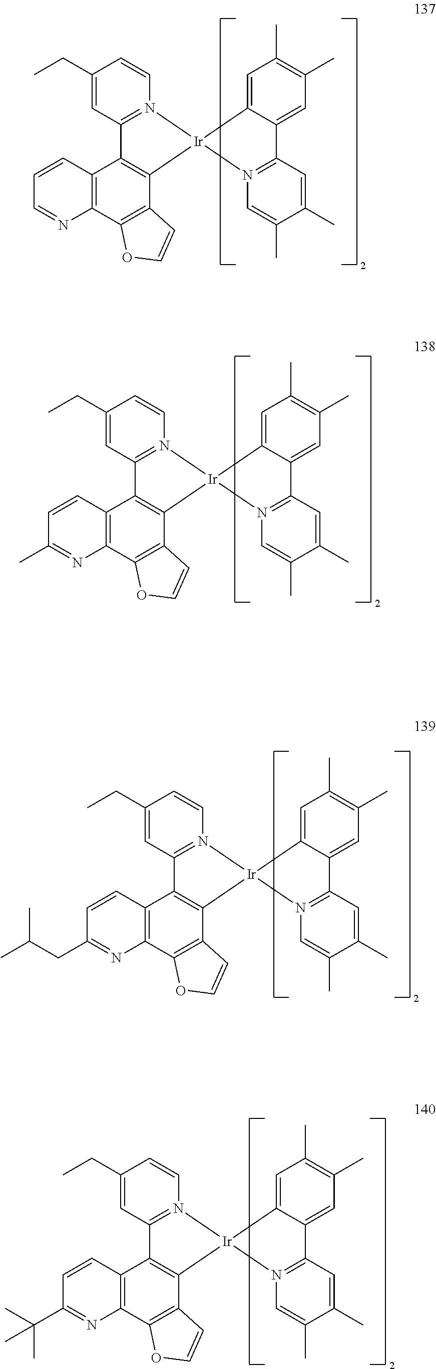

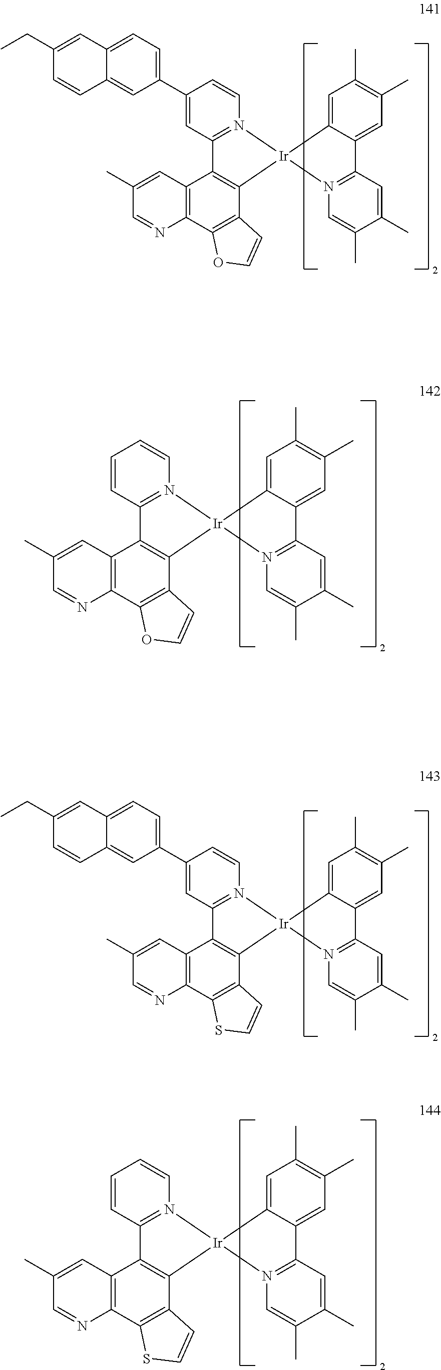

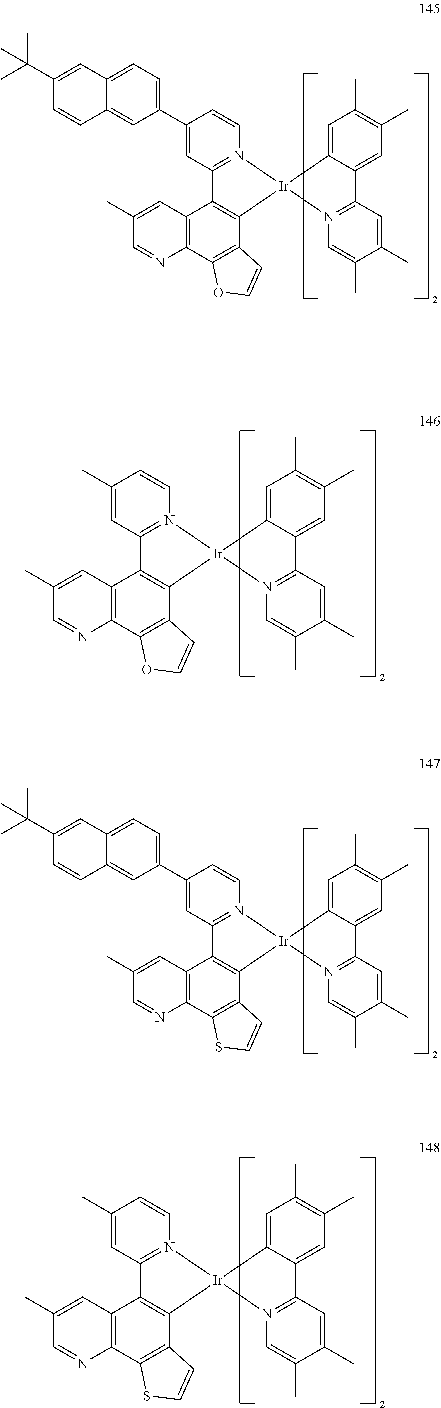

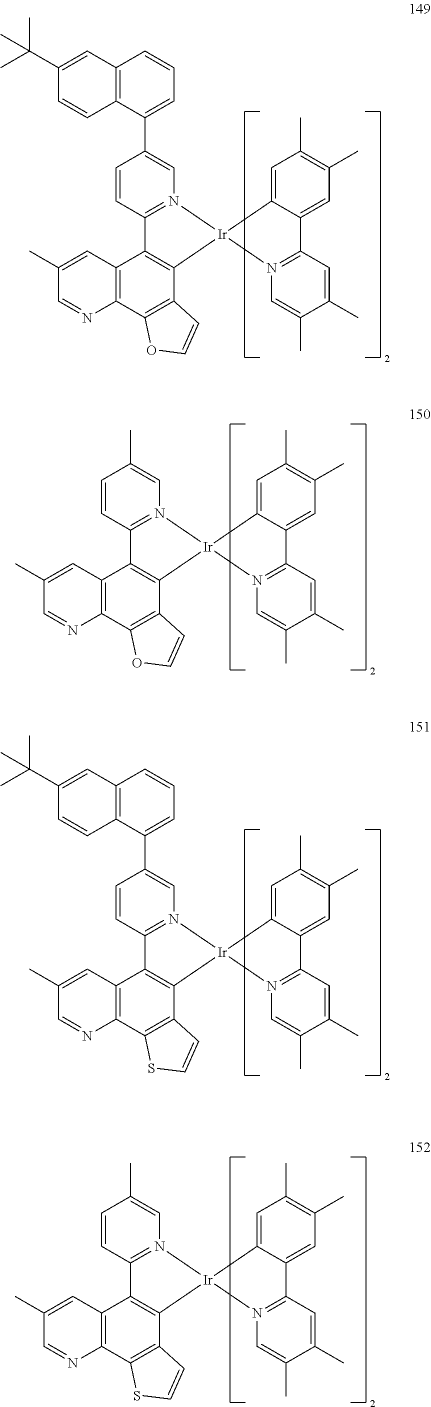

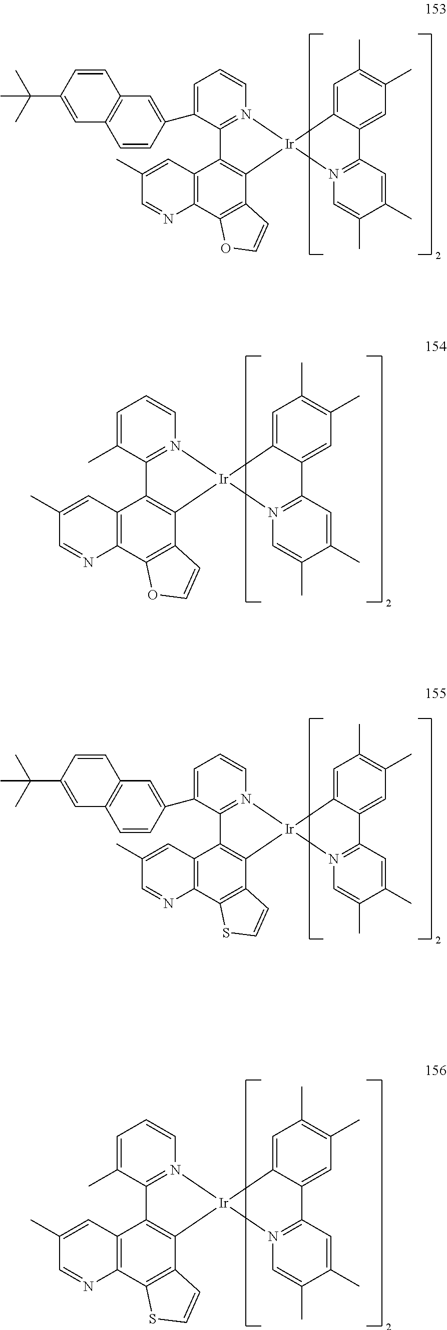

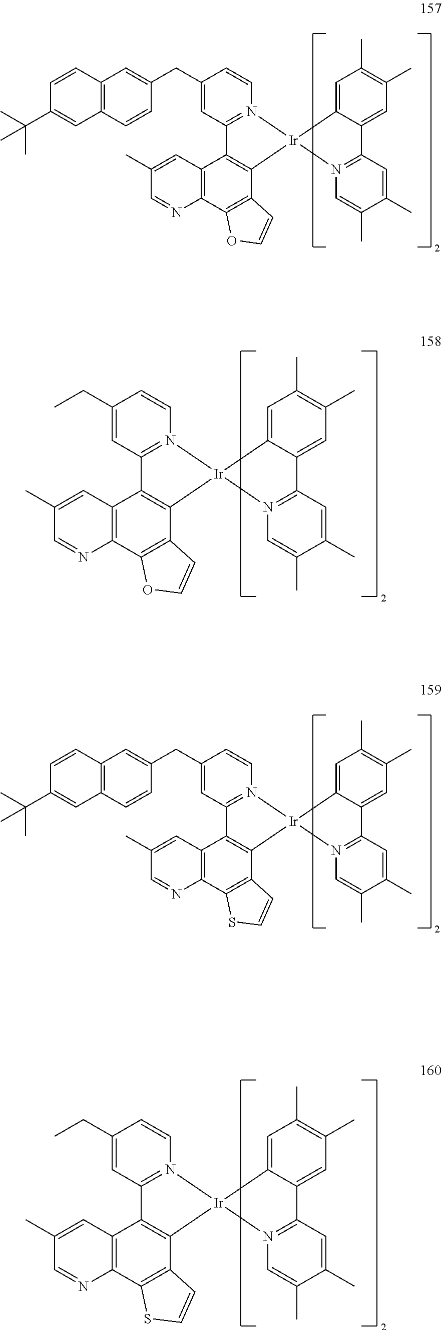

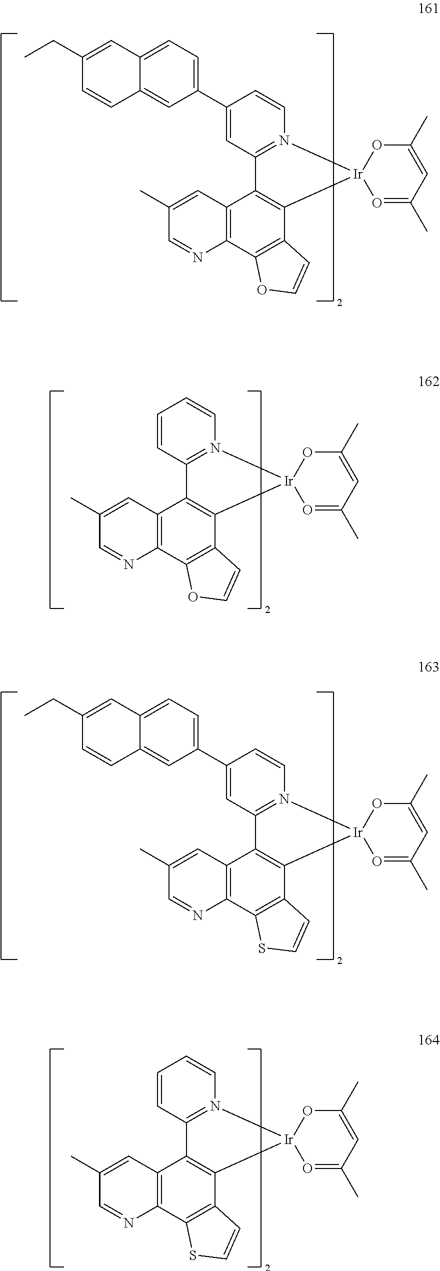

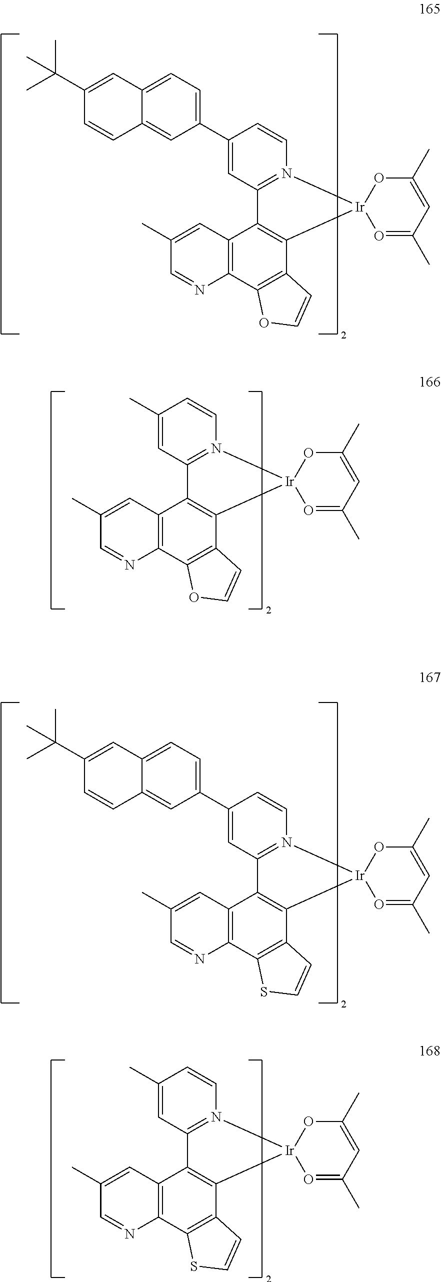

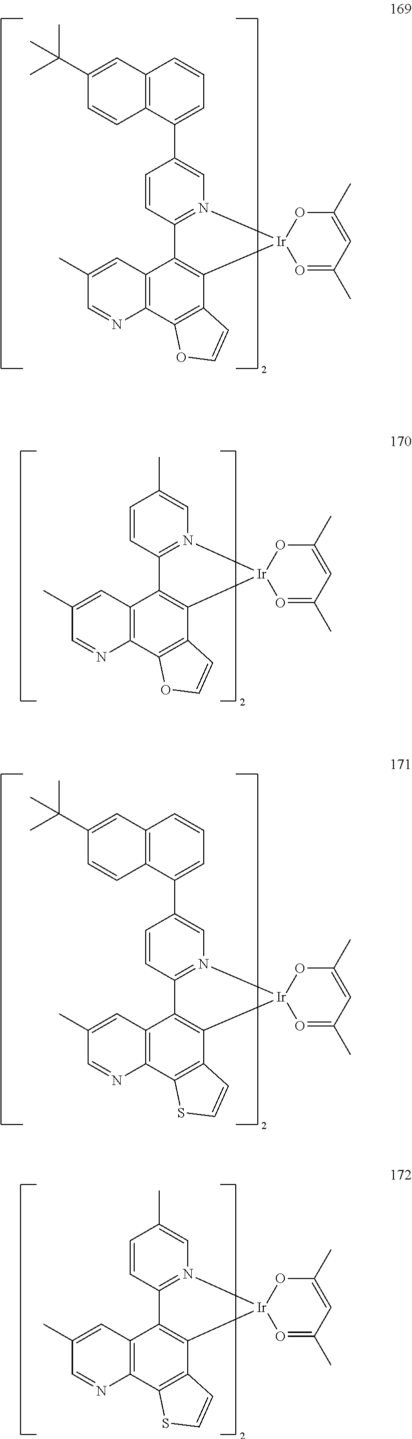

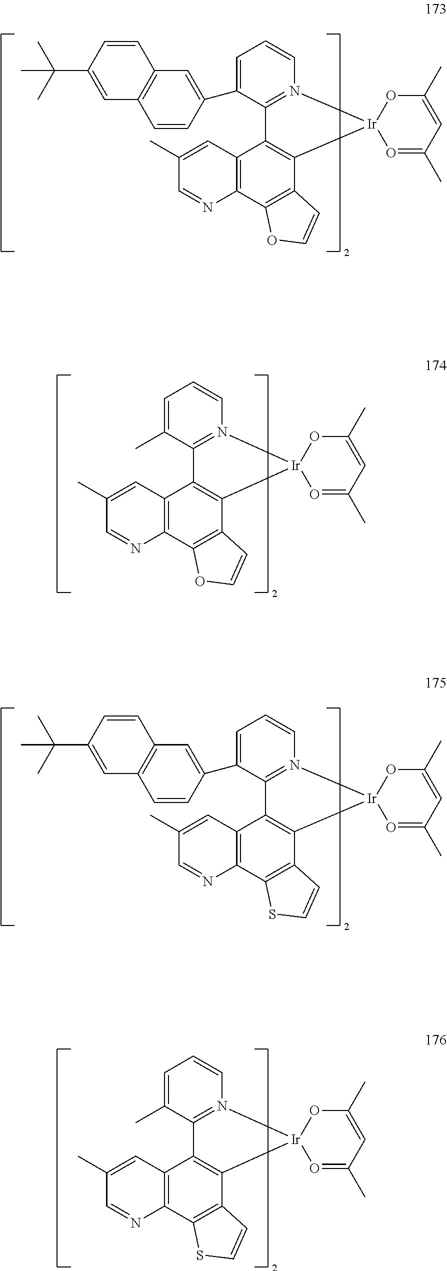

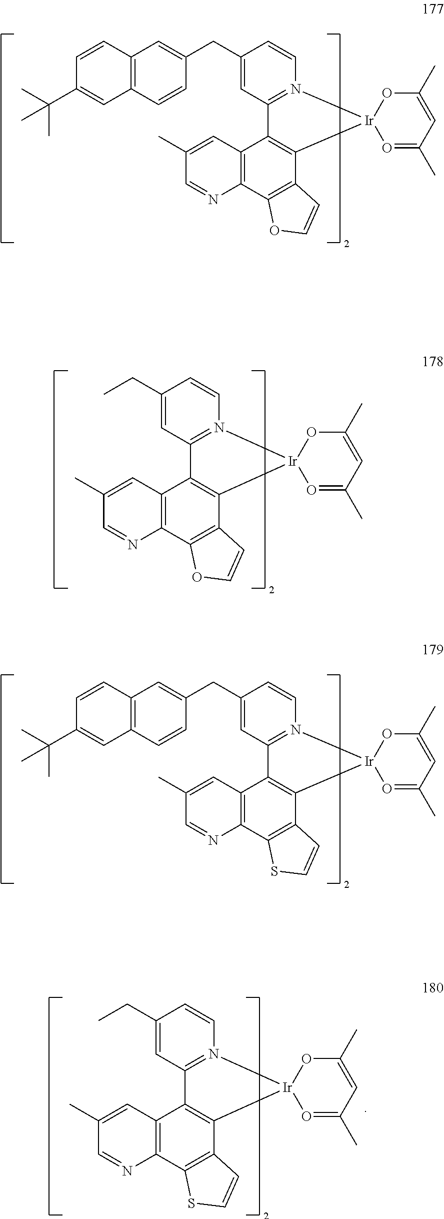

17. The organic light emitting diode, wherein the second compound has the structure of Chemical Formula 9: 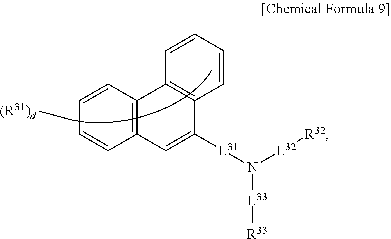
wherein each of R³¹ to R³³, L³¹ to L³³ and d as defined in Chemical Formula 8.

18. The organic light emitting diode of claim 1, wherein R³¹ is hydrogen or a C₁-C₁₀ alkyl group,
each of R³² and R³³ is independently selected from phenyl, biphenyl, terphenyl, naphthyl, phenanthrenyl, dibenzofuranyl and dibenzothiophenyl each of which is independently unsubstituted or substituted with at least one of C₁-C₁₀ alkyl and C₆-C₃₀ aryl, and
each of L³¹ to L³³ is independently a single bond, a phenylene group, a biphenylene group, a terphenylene group or a naphthylene group in Chemical Formula 8.

19. The organic light emitting diode of claim 17, wherein R³¹ is hydrogen.

20. The organic light emitting diode of claim 17, wherein R³² is chosen from:
H, CH₃,

[chemical structure]

21. The organic light emitting diode of claim 17, wherein R³³ is chosen from:

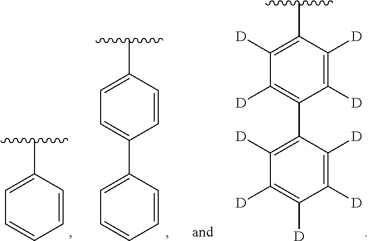

22. The organic light emitting diode of claim 17, wherein each of L³¹, L³², and L³³ is independently chosen from a single bond,

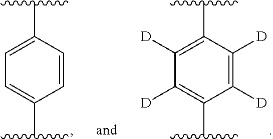 [SMILES: *c1ccc(*)cc1 ; *c1c([2H])c([2H])c(*)c([2H])c1[2H]]

23. The organic light emitting diode of claim 1, wherein the second compound is at least one of:

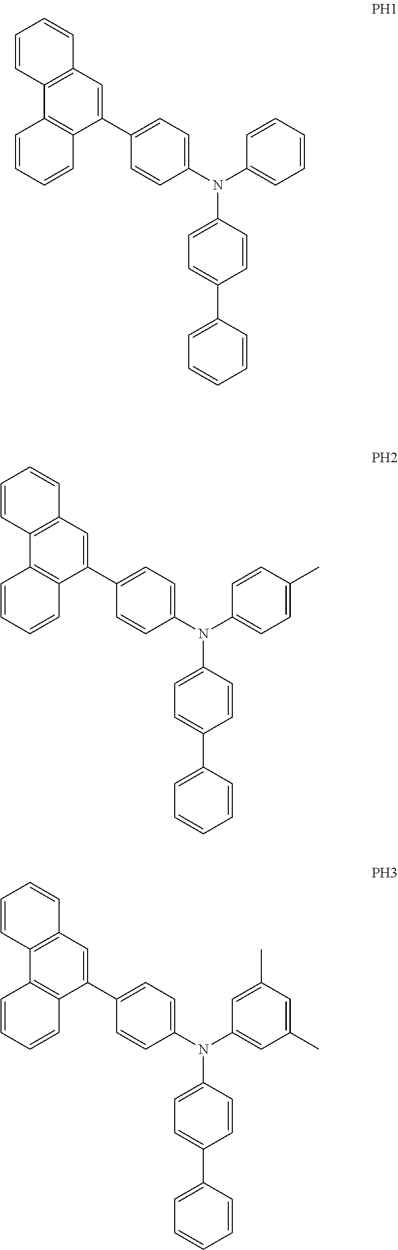 [SMILES: c1ccc(-c2ccc(N(c3ccccc3)c3ccc(-c4cc5ccccc5c5ccccc45)cc3)cc2)cc1 ; Cc1ccc(N(c2ccc(-c3ccccc3)cc2)c2ccc(-c3cc4ccccc4c4ccccc34)cc2)cc1 ; Cc1cc(C)cc(N(c2ccc(-c3ccccc3)cc2)c2ccc(-c3cc4ccccc4c4ccccc34)cc2)c1]

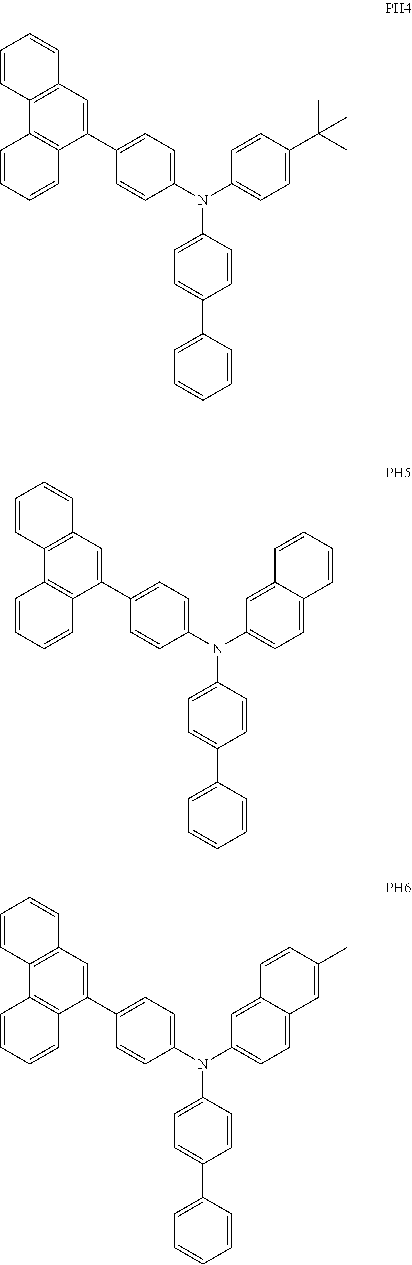 [SMILES: CC(C)(C)c1ccc(N(c2ccc(-c3ccccc3)cc2)c2ccc(-c3cc4ccccc4c4ccccc34)cc2)cc1 ; c1ccc(-c2ccc(N(c3ccc(-c4cc5ccccc5c5ccccc45)cc3)c3ccc4ccccc4c3)cc2)cc1 ; Cc1ccc2cc(N(c3ccc(-c4ccccc4)cc3)c3ccc(-c4cc5ccccc5c5ccccc45)cc3)ccc2c1]

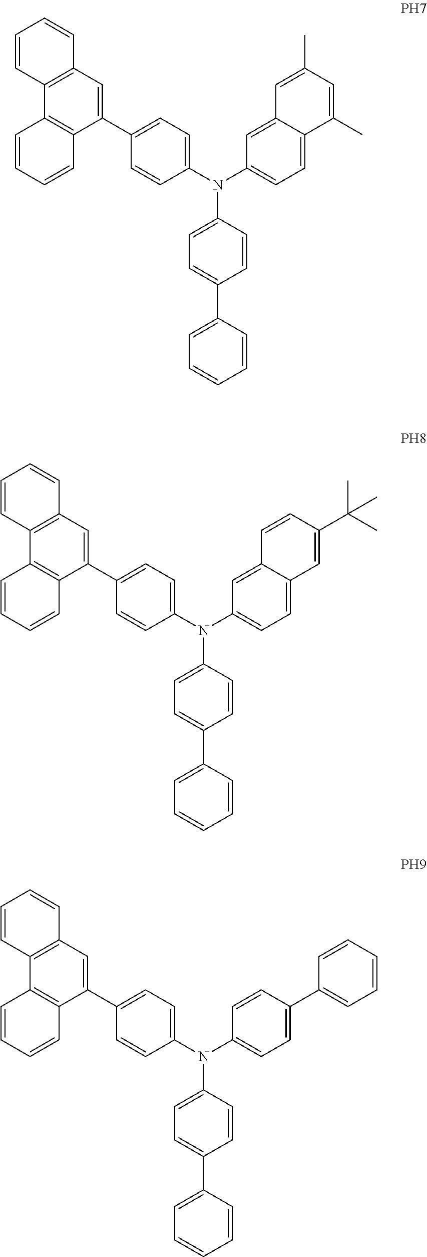 [SMILES: Cc1cc(C)c2ccc(N(c3ccc(-c4ccccc4)cc3)c3ccc(-c4cc5ccccc5c5ccccc45)cc3)cc2c1 ; CC(C)(C)c1ccc2cc(N(c3ccc(-c4ccccc4)cc3)c3ccc(-c4cc5ccccc5c5ccccc45)cc3)ccc2c1 ; c1ccc(-c2ccc(N(c3ccc(-c4ccccc4)cc3)c3ccc(-c4cc5ccccc5c5ccccc45)cc3)cc2)cc1]

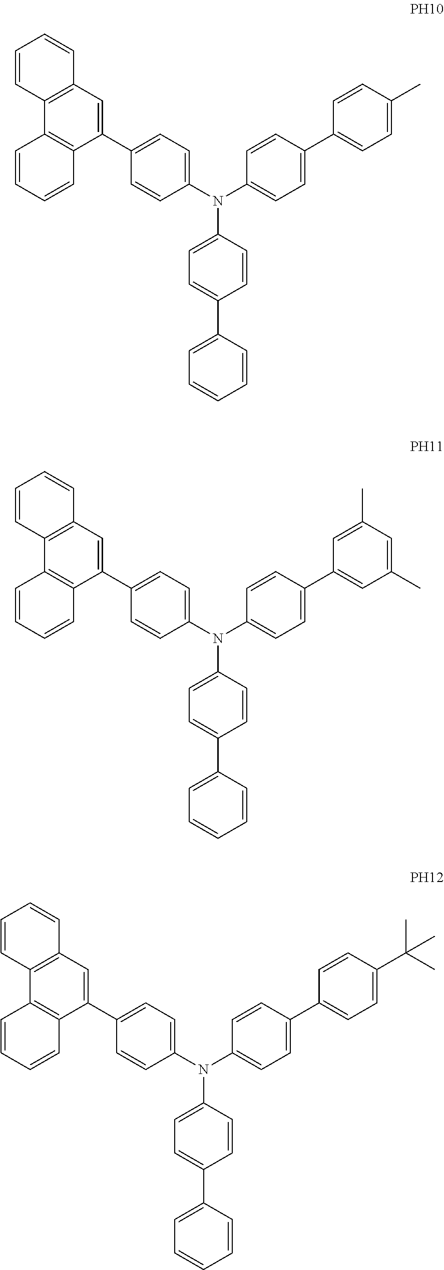 [SMILES: Cc1ccc(-c2ccc(N(c3ccc(-c4ccccc4)cc3)c3ccc(-c4cc5ccccc5c5ccccc45)cc3)cc2)cc1 ; Cc1cc(C)cc(-c2ccc(N(c3ccc(-c4ccccc4)cc3)c3ccc(-c4cc5ccccc5c5ccccc45)cc3)cc2)c1 ; CC(C)(C)c1ccc(-c2ccc(N(c3ccc(-c4ccccc4)cc3)c3ccc(-c4cc5ccccc5c5ccccc45)cc3)cc2)cc1]

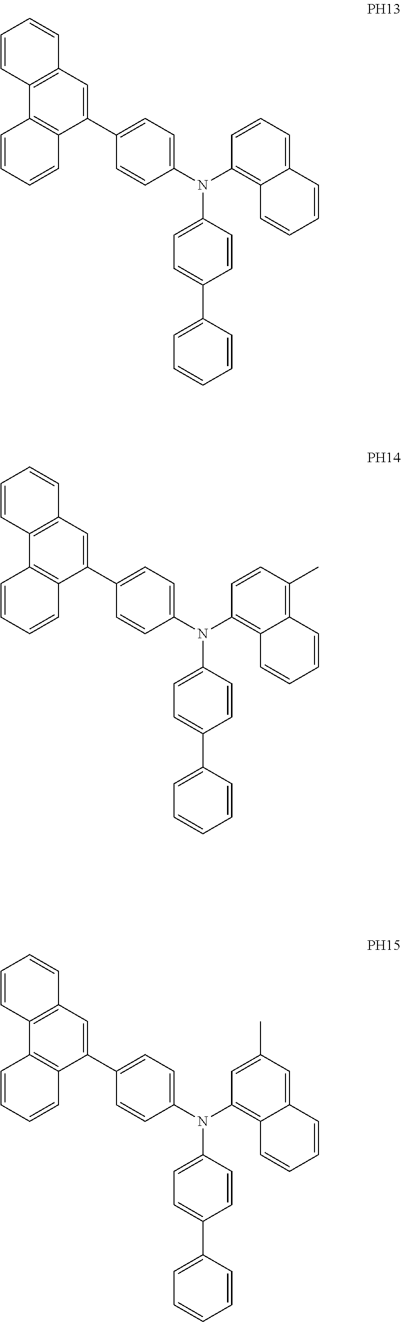 [SMILES: c1ccc(-c2ccc(N(c3ccc(-c4cc5ccccc5c5ccccc45)cc3)c3cccc4ccccc34)cc2)cc1 ; Cc1ccc(N(c2ccc(-c3ccccc3)cc2)c2ccc(-c3cc4ccccc4c4ccccc34)cc2)c2ccccc12 ; Cc1cc(N(c2ccc(-c3ccccc3)cc2)c2ccc(-c3cc4ccccc4c4ccccc34)cc2)c2ccccc2c1]

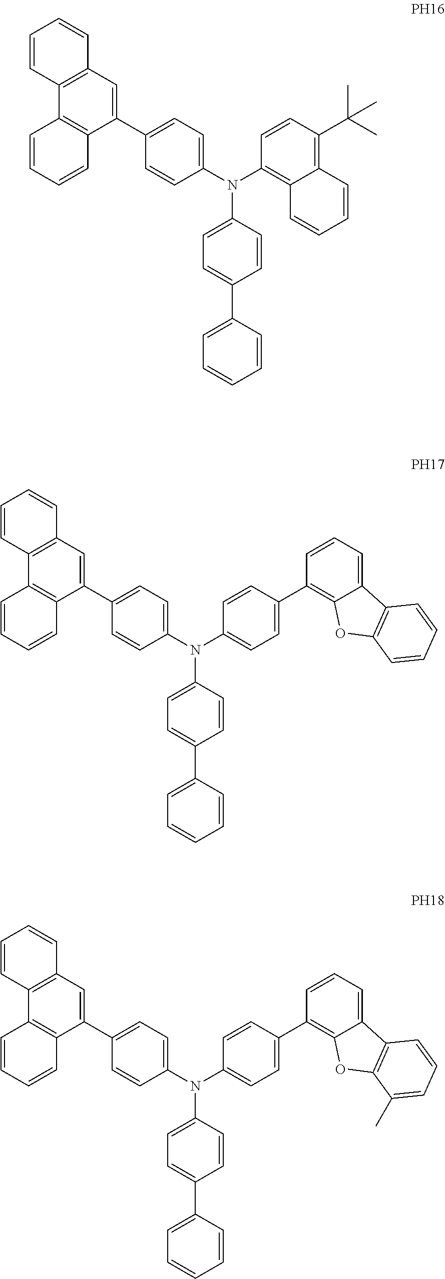 [SMILES: CC(C)(C)c1ccc(N(c2ccc(-c3ccccc3)cc2)c2ccc(-c3cc4ccccc4c4ccccc34)cc2)c2ccccc12 ; c1ccc(-c2ccc(N(c3ccc(-c4cc5ccccc5c5ccccc45)cc3)c3ccc(-c4cccc5c4oc4ccccc45)cc3)cc2)cc1 ; Cc1cccc2c1oc1c(-c3ccc(N(c4ccc(-c5ccccc5)cc4)c4ccc(-c5cc6ccccc6c6ccccc56)cc4)cc3)cccc12]

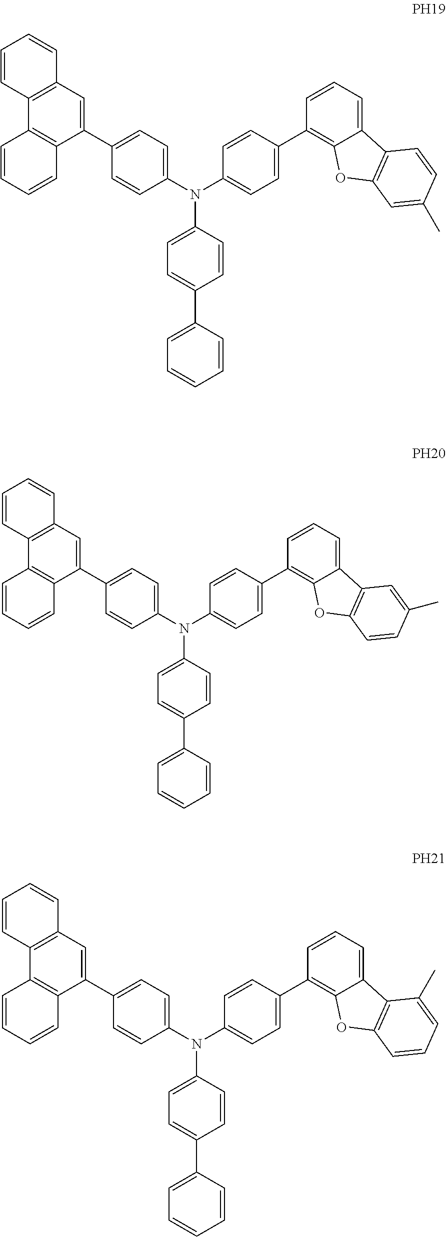 [SMILES: Cc1ccc2c(c1)oc1c(-c3ccc(N(c4ccc(-c5ccccc5)cc4)c4ccc(-c5cc6ccccc6c6ccccc56)cc4)cc3)cccc12 ; Cc1ccc2oc3c(-c4ccc(N(c5ccc(-c6ccccc6)cc5)c5ccc(-c6cc7ccccc7c7ccccc67)cc5)cc4)cccc3c2c1 ; Cc1cccc2oc3c(-c4ccc(N(c5ccc(-c6ccccc6)cc5)c5ccc(-c6cc7ccccc7c7ccccc67)cc5)cc4)cccc3c12]

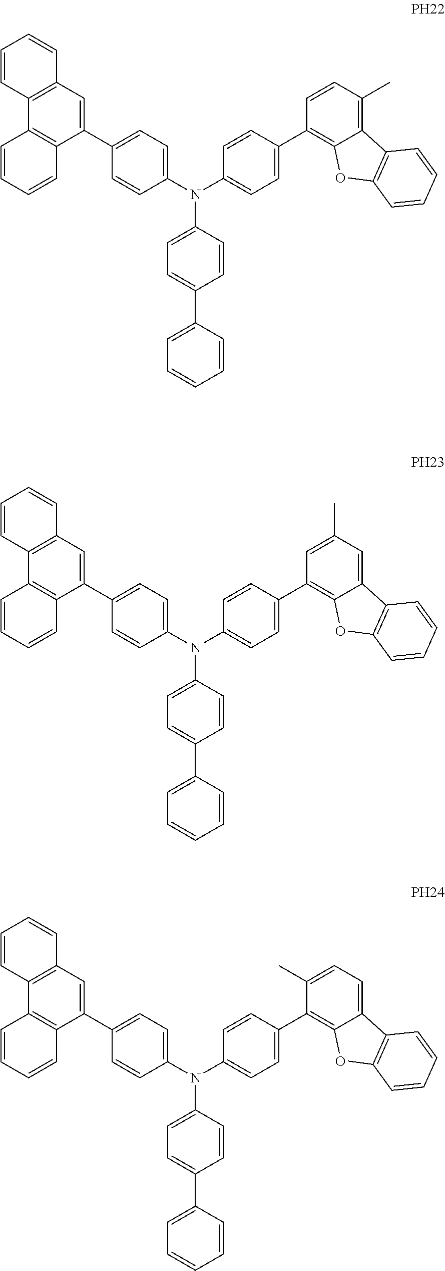 [SMILES: Cc1ccc(-c2ccc(N(c3ccc(-c4ccccc4)cc3)c3ccc(-c4cc5ccccc5c5ccccc45)cc3)cc2)c2oc3ccccc3c12 ; Cc1cc(-c2ccc(N(c3ccc(-c4ccccc4)cc3)c3ccc(-c4cc5ccccc5c5ccccc45)cc3)cc2)c2oc3ccccc3c2c1 ; Cc1ccc2c(oc3ccccc32)c1-c1ccc(N(c2ccc(-c3ccccc3)cc2)c2ccc(-c3cc4ccccc4c4ccccc34)cc2)cc1]

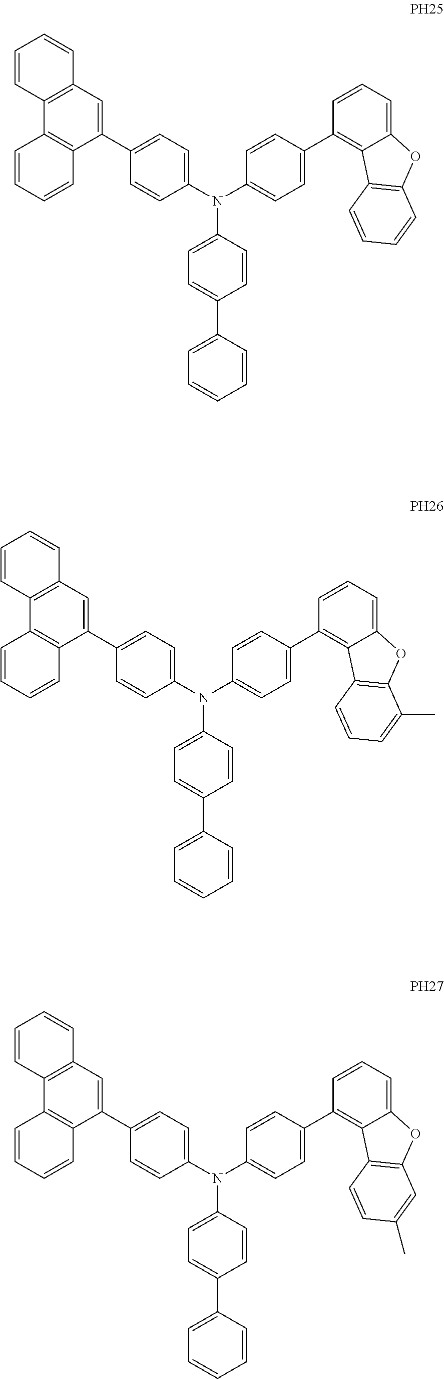 [SMILES: c1ccc(-c2ccc(N(c3ccc(-c4cc5ccccc5c5ccccc45)cc3)c3ccc(-c4cccc5oc6ccccc6c45)cc3)cc2)cc1 ; Cc1cccc2c1oc1cccc(-c3ccc(N(c4ccc(-c5ccccc5)cc4)c4ccc(-c5cc6ccccc6c6ccccc56)cc4)cc3)c12 ; Cc1ccc2c(c1)oc1cccc(-c3ccc(N(c4ccc(-c5ccccc5)cc4)c4ccc(-c5cc6ccccc6c6ccccc56)cc4)cc3)c12]

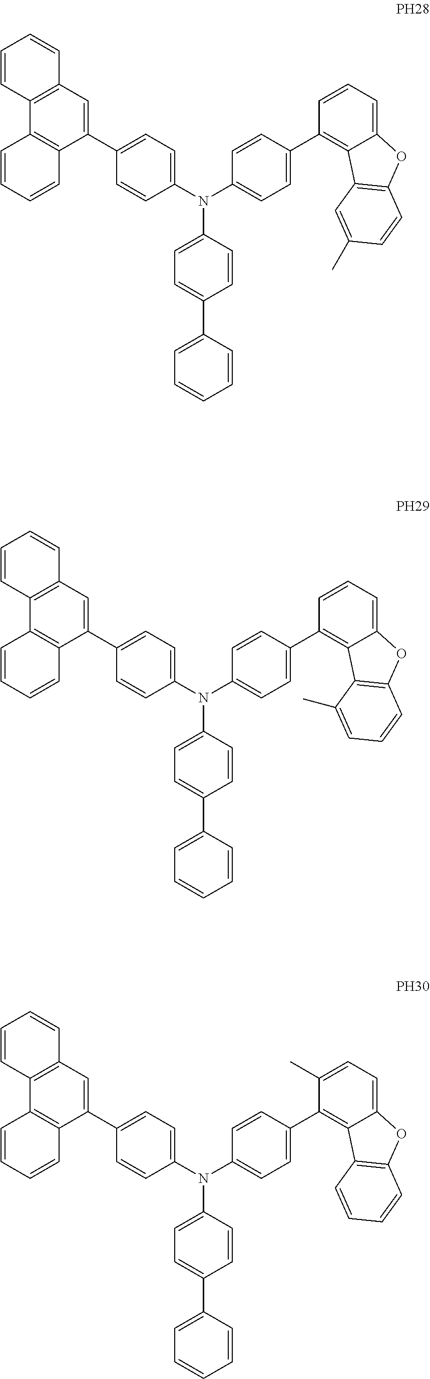 [SMILES: Cc1ccc2oc3cccc(-c4ccc(N(c5ccc(-c6ccccc6)cc5)c5ccc(-c6cc7ccccc7c7ccccc67)cc5)cc4)c3c2c1 ; Cc1cccc2oc3cccc(-c4ccc(N(c5ccc(-c6ccccc6)cc5)c5ccc(-c6cc7ccccc7c7ccccc67)cc5)cc4)c3c12 ; Cc1ccc2oc3ccccc3c2c1-c1ccc(N(c2ccc(-c3ccccc3)cc2)c2ccc(-c3cc4ccccc4c4ccccc34)cc2)cc1]

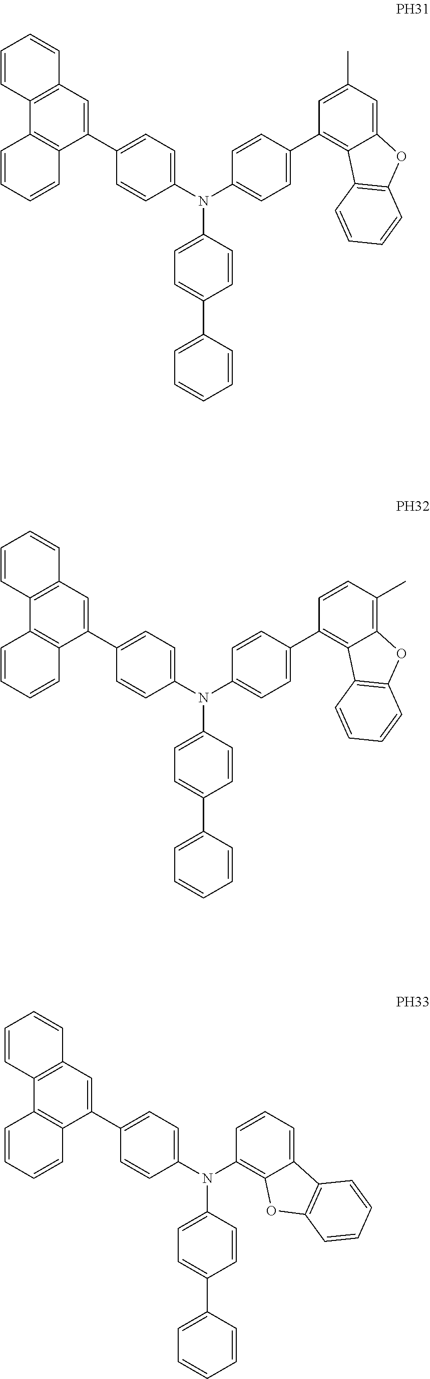 [SMILES: Cc1cc(-c2ccc(N(c3ccc(-c4ccccc4)cc3)c3ccc(-c4cc5ccccc5c5ccccc45)cc3)cc2)c2c(c1)oc1ccccc12 ; Cc1ccc(-c2ccc(N(c3ccc(-c4ccccc4)cc3)c3ccc(-c4cc5ccccc5c5ccccc45)cc3)cc2)c2c1oc1ccccc12 ; c1ccc(-c2ccc(N(c3ccc(-c4cc5ccccc5c5ccccc45)cc3)c3cccc4c3oc3ccccc34)cc2)cc1]

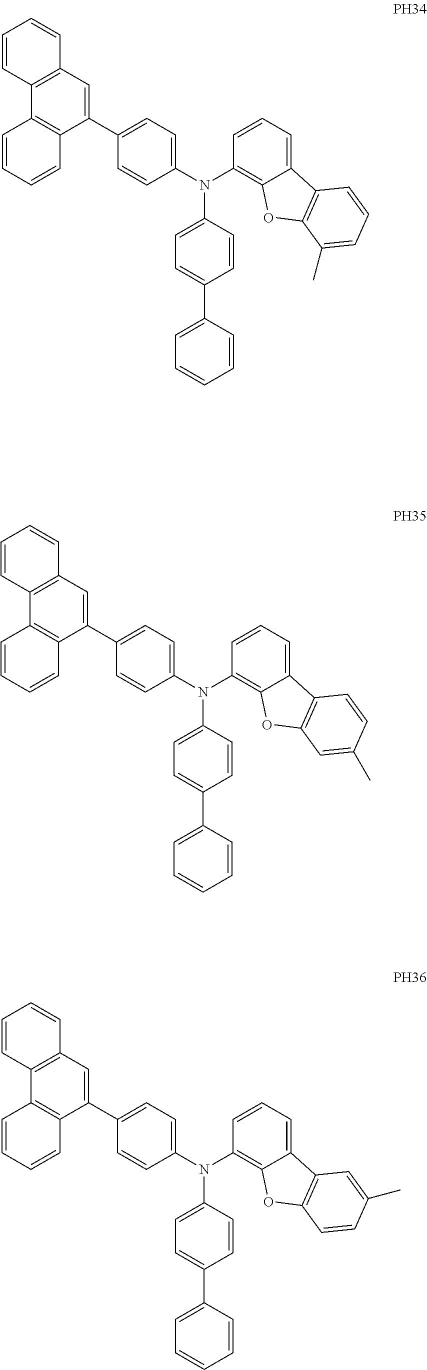 [SMILES: Cc1cccc2c1oc1c(N(c3ccc(-c4ccccc4)cc3)c3ccc(-c4cc5ccccc5c5ccccc45)cc3)cccc12 ; Cc1ccc2c(c1)oc1c(N(c3ccc(-c4ccccc4)cc3)c3ccc(-c4cc5ccccc5c5ccccc45)cc3)cccc12 ; Cc1ccc2oc3c(N(c4ccc(-c5ccccc5)cc4)c4ccc(-c5cc6ccccc6c6ccccc56)cc4)cccc3c2c1]

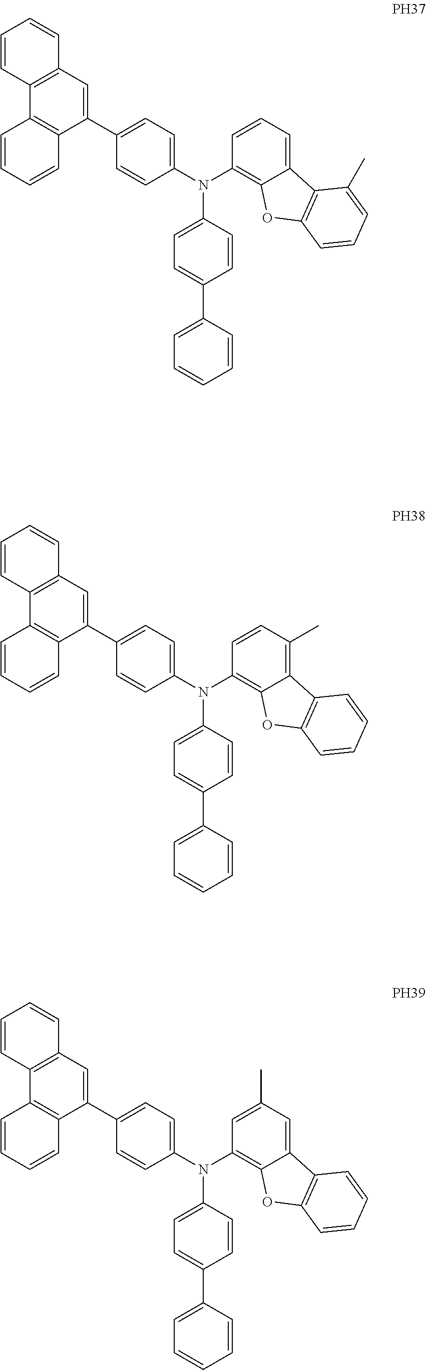 [SMILES: Cc1cccc2oc3c(N(c4ccc(-c5ccccc5)cc4)c4ccc(-c5cc6ccccc6c6ccccc56)cc4)cccc3c12 ; Cc1ccc(N(c2ccc(-c3ccccc3)cc2)c2ccc(-c3cc4ccccc4c4ccccc34)cc2)c2oc3ccccc3c12 ; Cc1cc(N(c2ccc(-c3ccccc3)cc2)c2ccc(-c3cc4ccccc4c4ccccc34)cc2)c2oc3ccccc3c2c1]

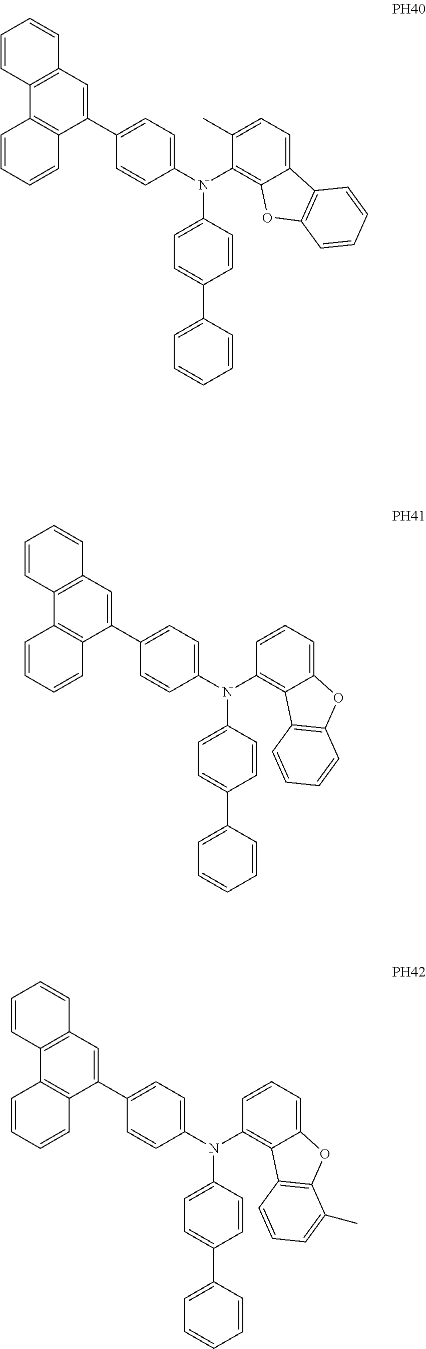 [SMILES: Cc1ccc2c(oc3ccccc32)c1N(c1ccc(-c2ccccc2)cc1)c1ccc(-c2cc3ccccc3c3ccccc23)cc1 ; c1ccc(-c2ccc(N(c3ccc(-c4cc5ccccc5c5ccccc45)cc3)c3cccc4oc5ccccc5c34)cc2)cc1 ; Cc1cccc2c1oc1cccc(N(c3ccc(-c4ccccc4)cc3)c3ccc(-c4cc5ccccc5c5ccccc45)cc3)c12]

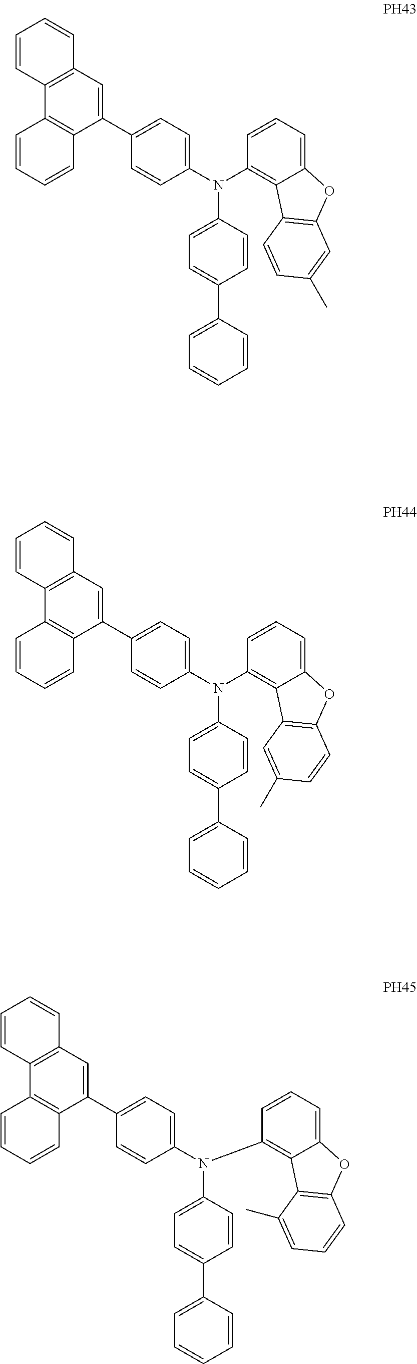 [SMILES: Cc1ccc2c(c1)oc1cccc(N(c3ccc(-c4ccccc4)cc3)c3ccc(-c4cc5ccccc5c5ccccc45)cc3)c12 ; Cc1ccc2oc3cccc(N(c4ccc(-c5ccccc5)cc4)c4ccc(-c5cc6ccccc6c6ccccc56)cc4)c3c2c1 ; Cc1cccc2oc3cccc(N(c4ccc(-c5ccccc5)cc4)c4ccc(-c5cc6ccccc6c6ccccc56)cc4)c3c12]

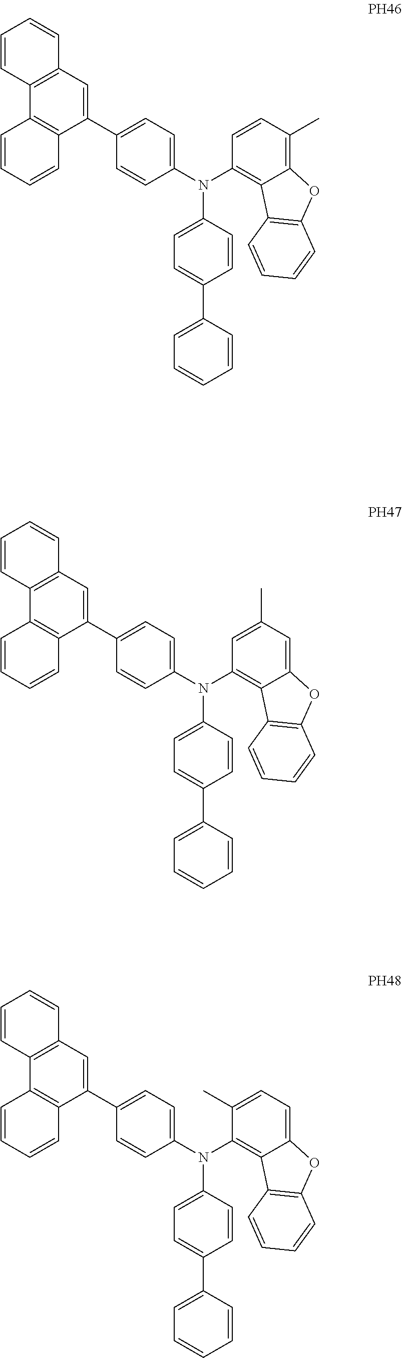 [SMILES: Cc1ccc(N(c2ccc(-c3ccccc3)cc2)c2ccc(-c3cc4ccccc4c4ccccc34)cc2)c2c1oc1ccccc12 ; Cc1cc(N(c2ccc(-c3ccccc3)cc2)c2ccc(-c3cc4ccccc4c4ccccc34)cc2)c2c(c1)oc1ccccc12 ; Cc1ccc2oc3ccccc3c2c1N(c1ccc(-c2ccccc2)cc1)c1ccc(-c2cc3ccccc3c3ccccc23)cc1]

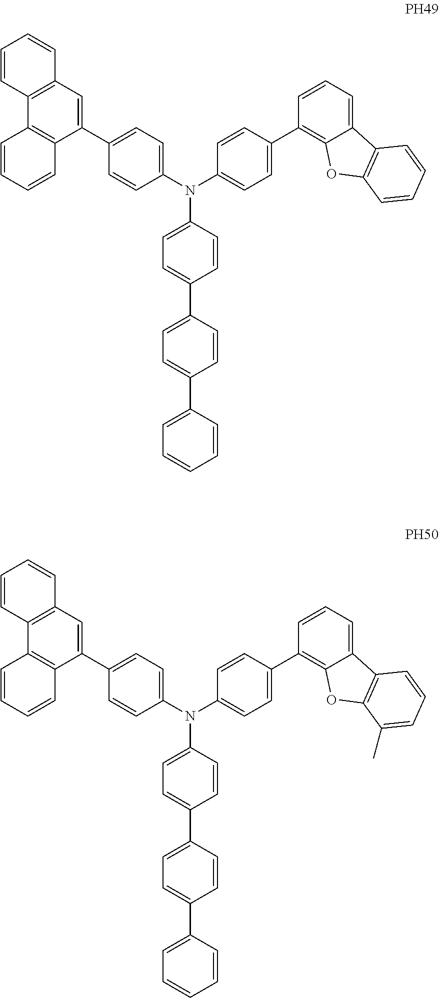 [SMILES: c1ccc(-c2ccc(-c3ccc(N(c4ccc(-c5cc6ccccc6c6ccccc56)cc4)c4ccc(-c5cccc6c5oc5ccccc56)cc4)cc3)cc2)cc1 ; Cc1cccc2c1oc1c(-c3ccc(N(c4ccc(-c5ccc(-c6ccccc6)cc5)cc4)c4ccc(-c5cc6ccccc6c6ccccc56)cc4)cc3)cccc12]

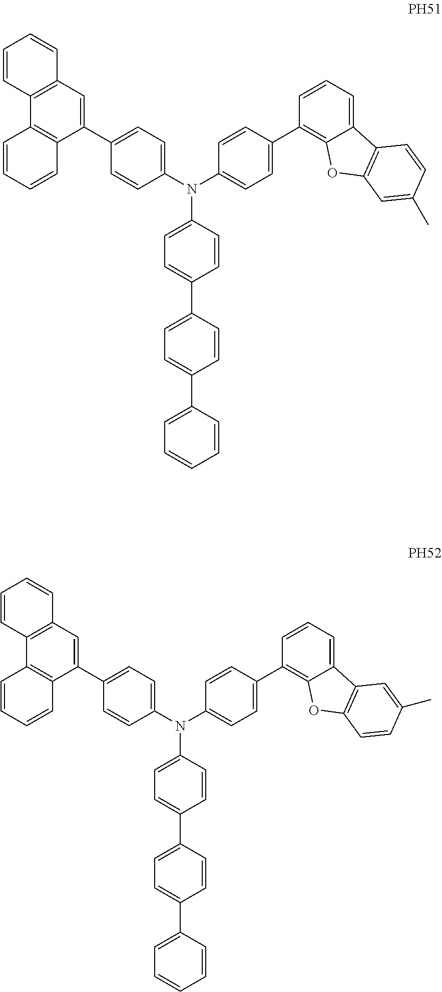 [SMILES: Cc1ccc2c(c1)oc1c(-c3ccc(N(c4ccc(-c5ccc(-c6ccccc6)cc5)cc4)c4ccc(-c5cc6ccccc6c6ccccc56)cc4)cc3)cccc12 ; Cc1ccc2oc3c(-c4ccc(N(c5ccc(-c6ccc(-c7ccccc7)cc6)cc5)c5ccc(-c6cc7ccccc7c7ccccc67)cc5)cc4)cccc3c2c1]

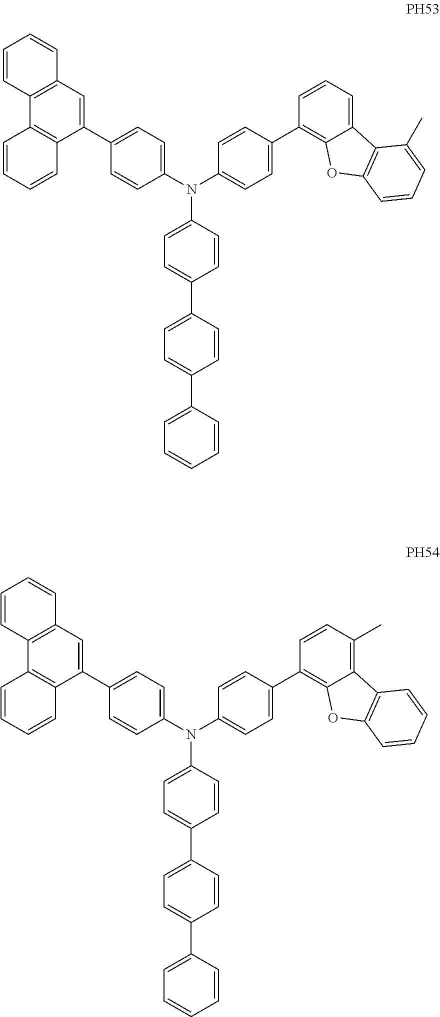 [SMILES: Cc1cccc2oc3c(-c4ccc(N(c5ccc(-c6ccc(-c7ccccc7)cc6)cc5)c5ccc(-c6cc7ccccc7c7ccccc67)cc5)cc4)cccc3c12 ; Cc1ccc(-c2ccc(N(c3ccc(-c4ccc(-c5ccccc5)cc4)cc3)c3ccc(-c4cc5ccccc5c5ccccc45)cc3)cc2)c2oc3ccccc3c12]

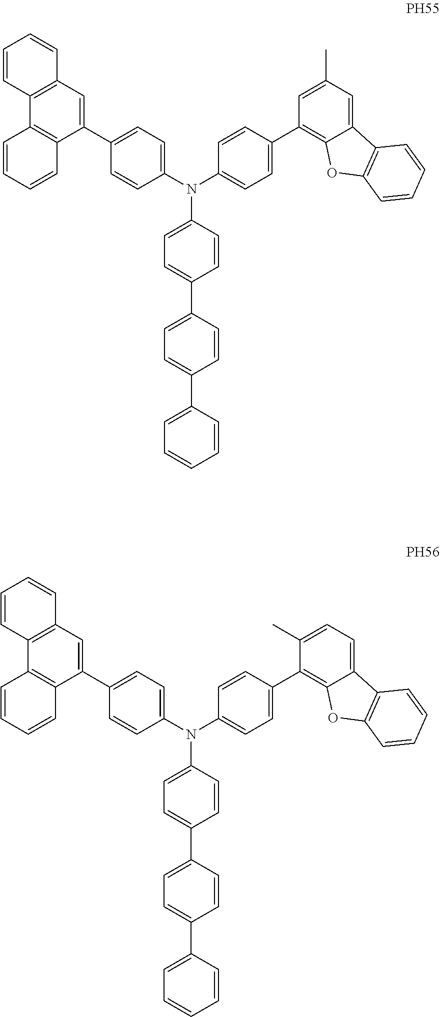 [SMILES: Cc1cc(-c2ccc(N(c3ccc(-c4ccc(-c5ccccc5)cc4)cc3)c3ccc(-c4cc5ccccc5c5ccccc45)cc3)cc2)c2oc3ccccc3c2c1 ; Cc1ccc2c(oc3ccccc32)c1-c1ccc(N(c2ccc(-c3ccc(-c4ccccc4)cc3)cc2)c2ccc(-c3cc4ccccc4c4ccccc34)cc2)cc1]

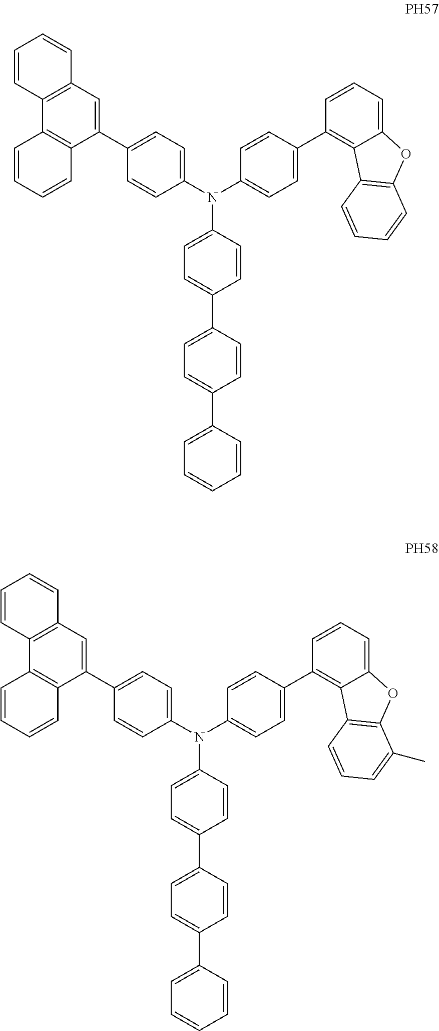 [SMILES: c1ccc(-c2ccc(-c3ccc(N(c4ccc(-c5cc6ccccc6c6ccccc56)cc4)c4ccc(-c5cccc6oc7ccccc7c56)cc4)cc3)cc2)cc1 ; Cc1cccc2c1oc1cccc(-c3ccc(N(c4ccc(-c5ccc(-c6ccccc6)cc5)cc4)c4ccc(-c5cc6ccccc6c6ccccc56)cc4)cc3)c12]

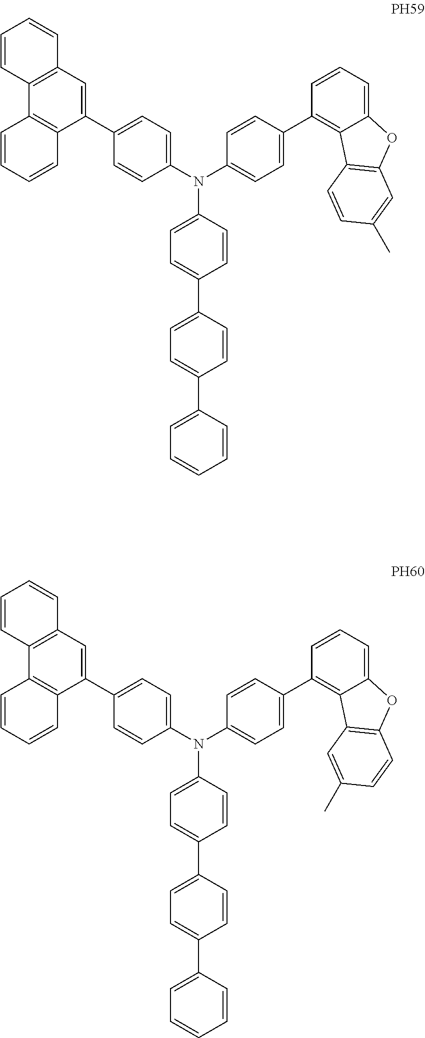 [SMILES: Cc1ccc2c(c1)oc1cccc(-c3ccc(N(c4ccc(-c5ccc(-c6ccccc6)cc5)cc4)c4ccc(-c5cc6ccccc6c6ccccc56)cc4)cc3)c12 ; Cc1ccc2oc3cccc(-c4ccc(N(c5ccc(-c6ccc(-c7ccccc7)cc6)cc5)c5ccc(-c6cc7ccccc7c7ccccc67)cc5)cc4)c3c2c1]

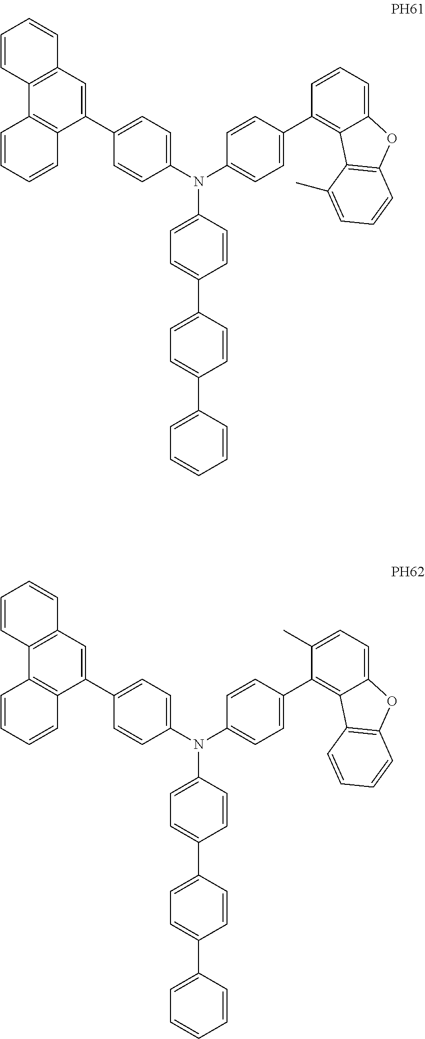 [SMILES: Cc1cccc2oc3cccc(-c4ccc(N(c5ccc(-c6ccc(-c7ccccc7)cc6)cc5)c5ccc(-c6cc7ccccc7c7ccccc67)cc5)cc4)c3c12 ; Cc1ccc2oc3ccccc3c2c1-c1ccc(N(c2ccc(-c3ccc(-c4ccccc4)cc3)cc2)c2ccc(-c3cc4ccccc4c4ccccc34)cc2)cc1]

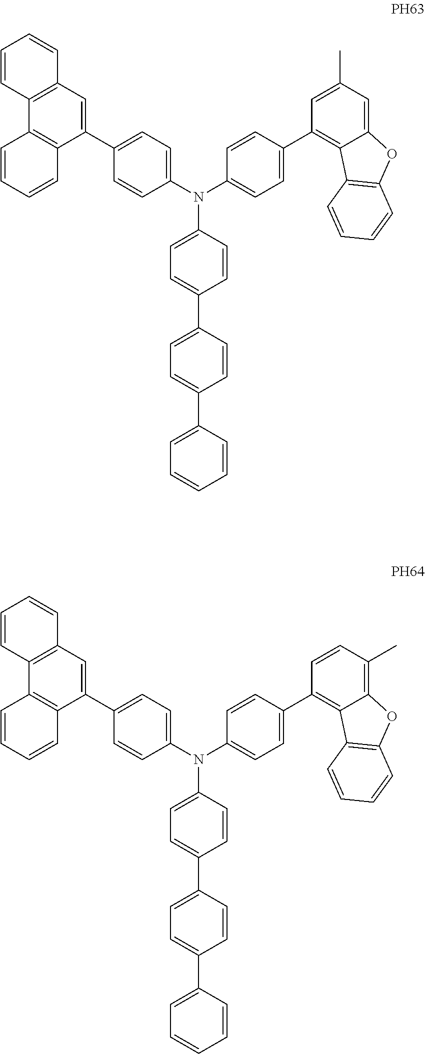 [SMILES: Cc1cc(-c2ccc(N(c3ccc(-c4ccc(-c5ccccc5)cc4)cc3)c3ccc(-c4cc5ccccc5c5ccccc45)cc3)cc2)c2c(c1)oc1ccccc12 ; Cc1ccc(-c2ccc(N(c3ccc(-c4ccc(-c5ccccc5)cc4)cc3)c3ccc(-c4cc5ccccc5c5ccccc45)cc3)cc2)c2c1oc1ccccc12]

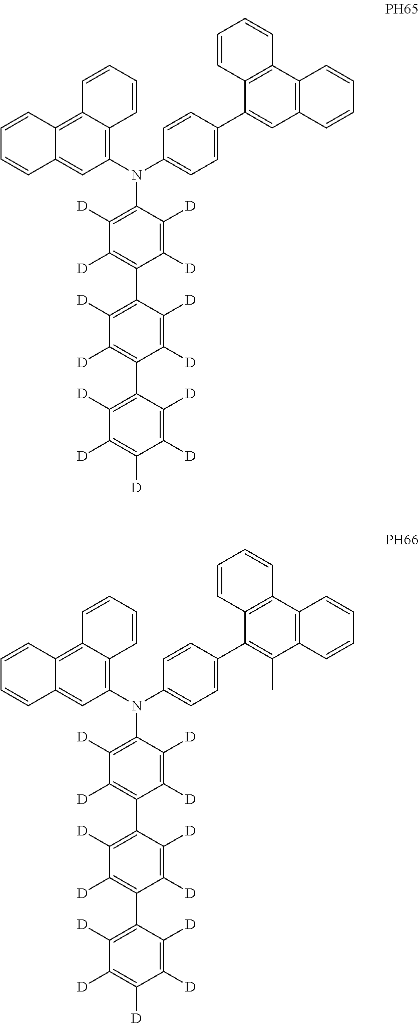 [SMILES: [2H]c1c([2H])c([2H])c(-c2c([2H])c([2H])c(-c3c([2H])c([2H])c(N(c4ccc(-c5cc6ccccc6c6ccccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5c(C)c6ccccc6c6ccccc56)cc4)c4cc5ccccc5c5ccccc45)c([2H])c3[2H])c([2H])c2[2H])c([2H])c1[2H]]

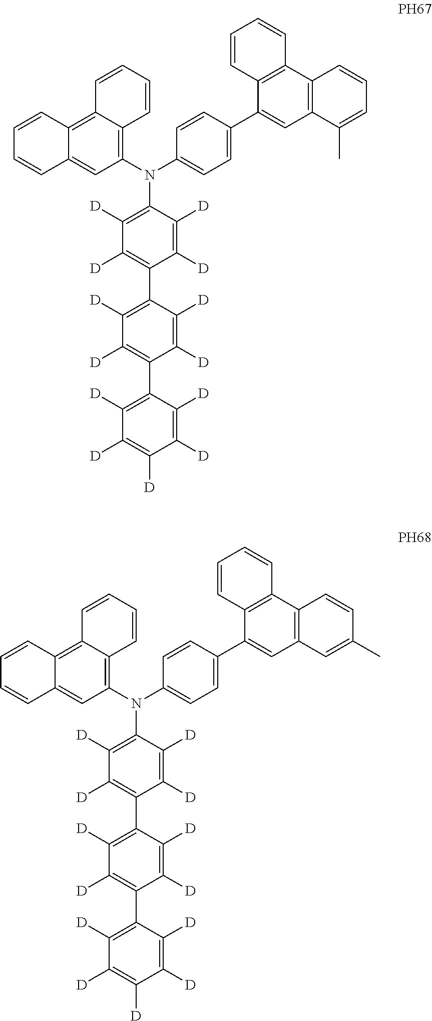 [SMILES: [2H]c1c([2H])c([2H])c(-c2c([2H])c([2H])c(-c3c([2H])c([2H])c(N(c4ccc(-c5cc6c(C)cccc6c6ccccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5cc6cc(C)ccc6c6ccccc56)cc4)c4cc5ccccc5c5ccccc45)c([2H])c3[2H])c([2H])c2[2H])c([2H])c1[2H]]

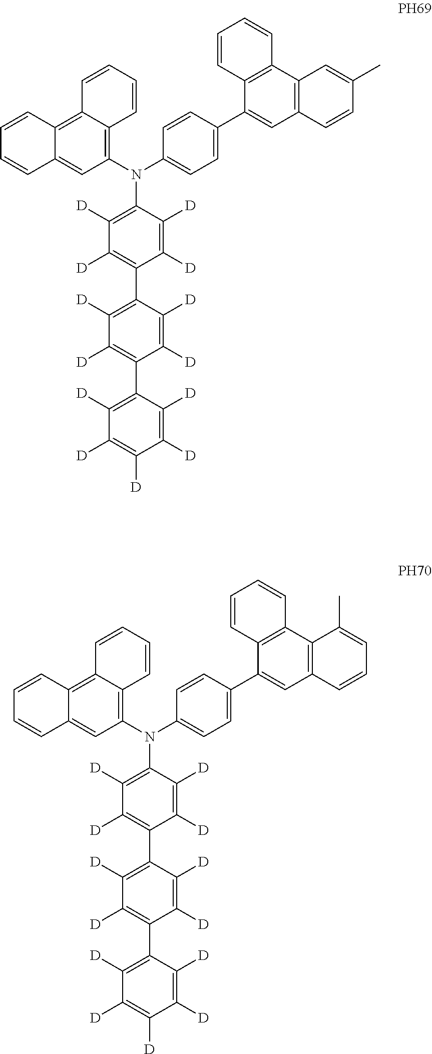 [SMILES: [2H]c1c([2H])c([2H])c(-c2c([2H])c([2H])c(-c3c([2H])c([2H])c(N(c4ccc(-c5cc6ccc(C)cc6c6ccccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5cc6cccc(C)c6c6ccccc56)cc4)c4cc5ccccc5c5ccccc45)c([2H])c3[2H])c([2H])c2[2H])c([2H])c1[2H]]

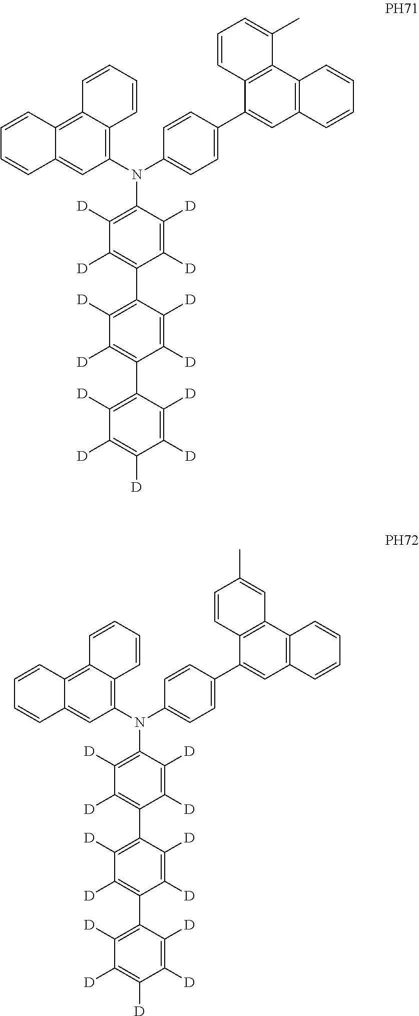 [SMILES: [2H]c1c([2H])c([2H])c(-c2c([2H])c([2H])c(-c3c([2H])c([2H])c(N(c4ccc(-c5cc6ccccc6c6c(C)cccc56)cc4)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4ccc(-c5cc6ccccc6c6cc(C)ccc56)cc4)c4cc5ccccc5c5ccccc45)c([2H])c3[2H])c([2H])c2[2H])c([2H])c1[2H]]

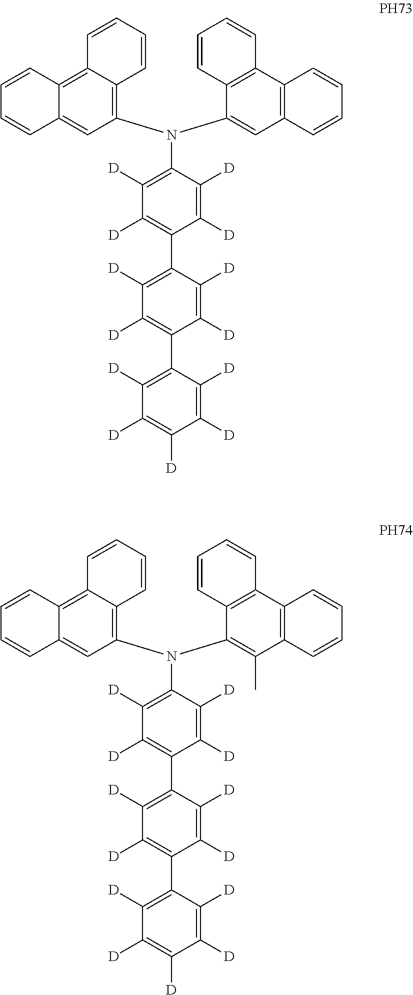 [SMILES: [2H]c1c([2H])c([2H])c(-c2c([2H])c([2H])c(-c3c([2H])c([2H])c(N(c4cc5ccccc5c5ccccc45)c4cc5ccccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4c(C)c5ccccc5c5ccccc45)c([2H])c3[2H])c([2H])c2[2H])c([2H])c1[2H]]

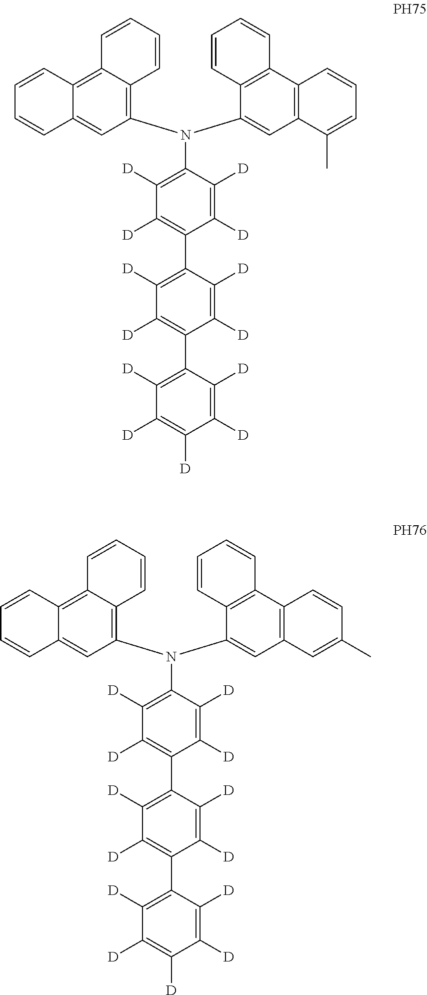 [SMILES: [2H]c1c([2H])c([2H])c(-c2c([2H])c([2H])c(-c3c([2H])c([2H])c(N(c4cc5ccccc5c5ccccc45)c4cc5c(C)cccc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4cc5cc(C)ccc5c5ccccc45)c([2H])c3[2H])c([2H])c2[2H])c([2H])c1[2H]]

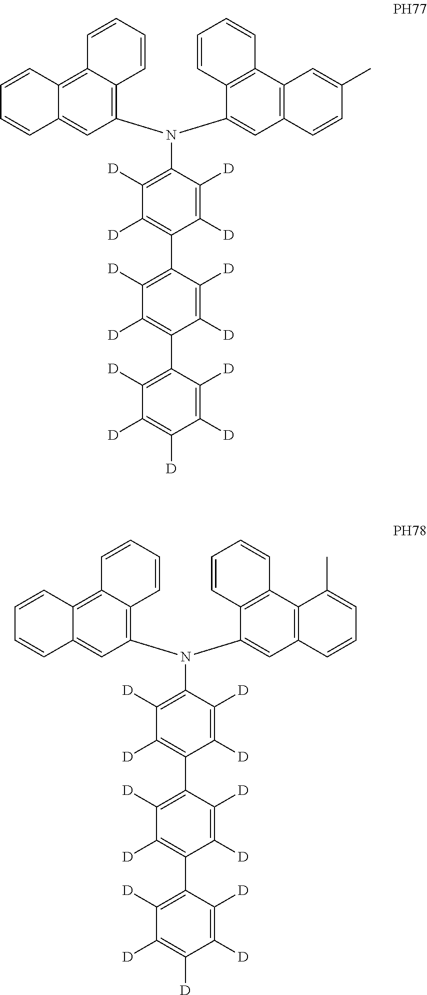 [SMILES: [2H]c1c([2H])c([2H])c(-c2c([2H])c([2H])c(-c3c([2H])c([2H])c(N(c4cc5ccccc5c5ccccc45)c4cc5ccc(C)cc5c5ccccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4cc5cccc(C)c5c5ccccc45)c([2H])c3[2H])c([2H])c2[2H])c([2H])c1[2H]]

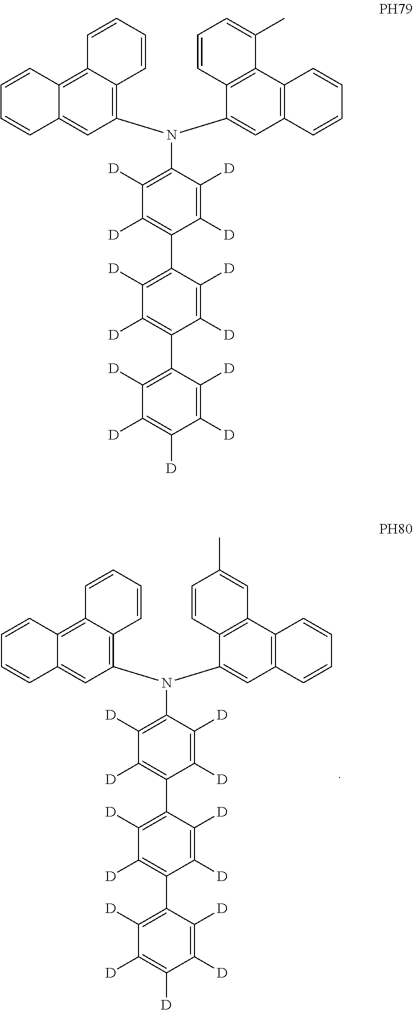 [SMILES: [2H]c1c([2H])c([2H])c(-c2c([2H])c([2H])c(-c3c([2H])c([2H])c(N(c4cc5ccccc5c5ccccc45)c4cc5ccccc5c5c(C)cccc45)c([2H])c3[2H])c([2H])c2[2H])c([2H])c1[2H] ; [2H]c1c([2H])c([2H])c(-c2c([2H])c([2H])c(-c3c([2H])c([2H])c(N(c4cc5ccccc5c5ccccc45)c4cc5ccccc5c5cc(C)ccc45)c([2H])c3[2H])c([2H])c2[2H])c([2H])c1[2H]]

24. The organic light emitting diode of claim 2, wherein R⁴¹ is selected from phenyl, naphthyl, dibenzofuranyl and dibenzothiophenyl each of which is independently unsubstituted or substituted with at least one of C₁-C₁₀ alkyl and C₆-C₂₀ aryl,
each of R⁴² and R⁴³ is independently selected from phenyl, biphenyl, terphenyl and naphthyl each of which is independently unsubstituted or substituted with at least one of C₁-C₁₀ alkyl and C₆-C₂₀ aryl, and
each of L⁴¹ to L⁴³ is independently a single bond, a phenylene group, a biphenylene group, a terphenylene group or a naphthylene group in Chemical Formula 11.

25. The organic light emitting diode of claim 2, wherein the third compound is at least one of:

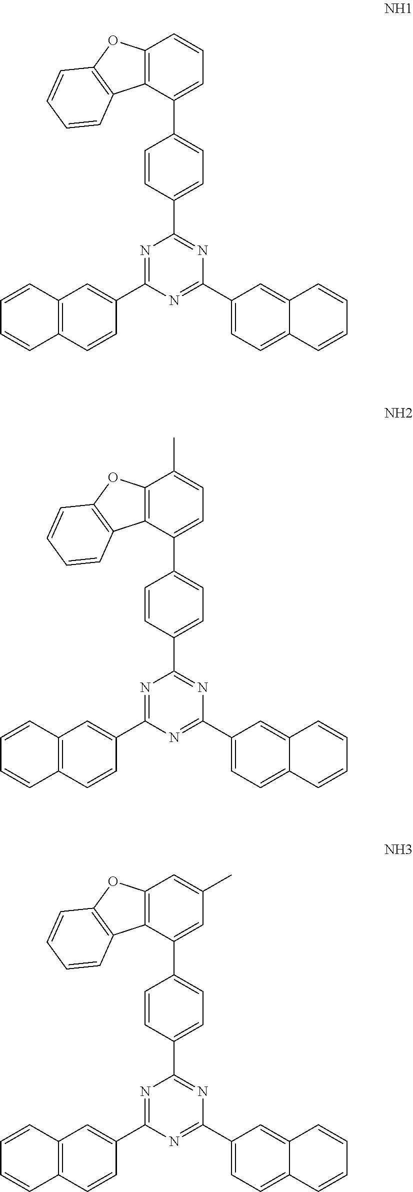 [SMILES: c1ccc2cc(-c3nc(-c4ccc(-c5cccc6oc7ccccc7c56)cc4)nc(-c4ccc5ccccc5c4)n3)ccc2c1 ; Cc1ccc(-c2ccc(-c3nc(-c4ccc5ccccc5c4)nc(-c4ccc5ccccc5c4)n3)cc2)c2c1oc1ccccc12 ; Cc1cc(-c2ccc(-c3nc(-c4ccc5ccccc5c4)nc(-c4ccc5ccccc5c4)n3)cc2)c2c(c1)oc1ccccc12]

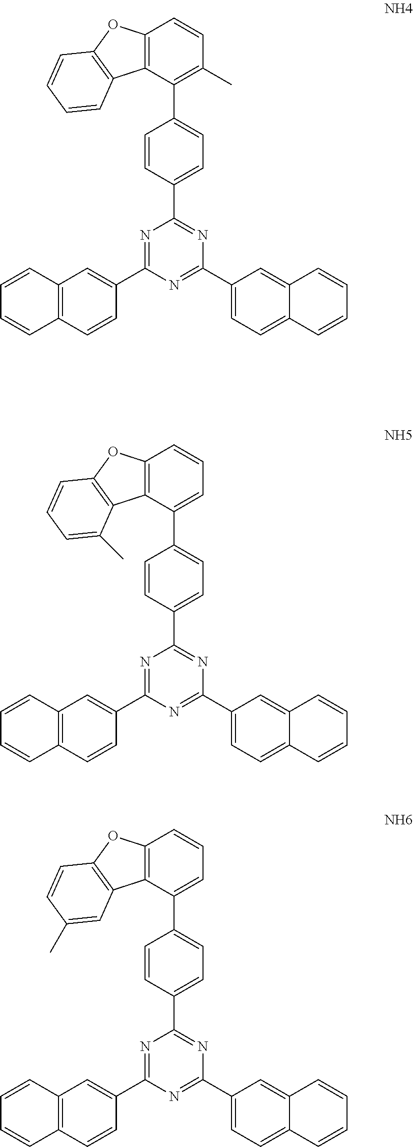 [SMILES: Cc1ccc2oc3ccccc3c2c1-c1ccc(-c2nc(-c3ccc4ccccc4c3)nc(-c3ccc4ccccc4c3)n2)cc1 ; Cc1cccc2oc3cccc(-c4ccc(-c5nc(-c6ccc7ccccc7c6)nc(-c6ccc7ccccc7c6)n5)cc4)c3c12 ; Cc1ccc2oc3cccc(-c4ccc(-c5nc(-c6ccc7ccccc7c6)nc(-c6ccc7ccccc7c6)n5)cc4)c3c2c1]

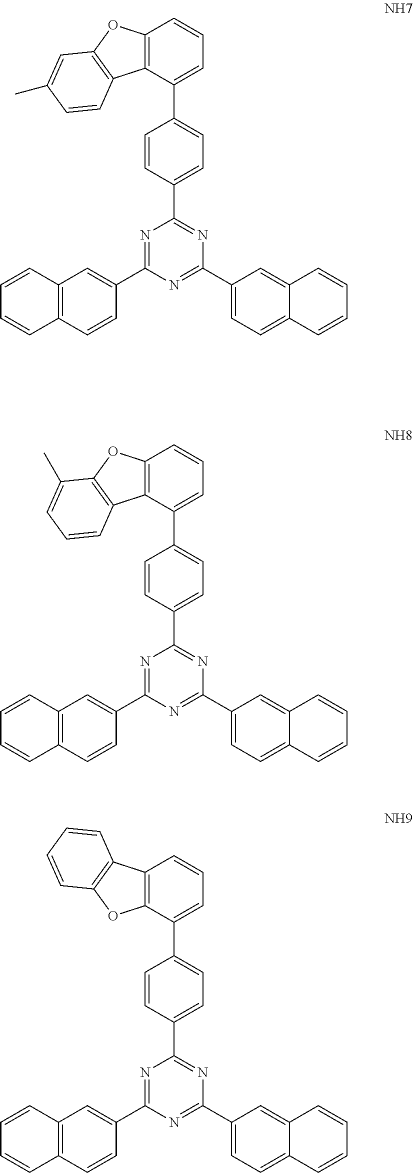 [SMILES: Cc1ccc2c(c1)oc1cccc(-c3ccc(-c4nc(-c5ccc6ccccc6c5)nc(-c5ccc6ccccc6c5)n4)cc3)c12 ; Cc1cccc2c1oc1cccc(-c3ccc(-c4nc(-c5ccc6ccccc6c5)nc(-c5ccc6ccccc6c5)n4)cc3)c12 ; c1ccc2cc(-c3nc(-c4ccc(-c5cccc6c5oc5ccccc56)cc4)nc(-c4ccc5ccccc5c4)n3)ccc2c1]

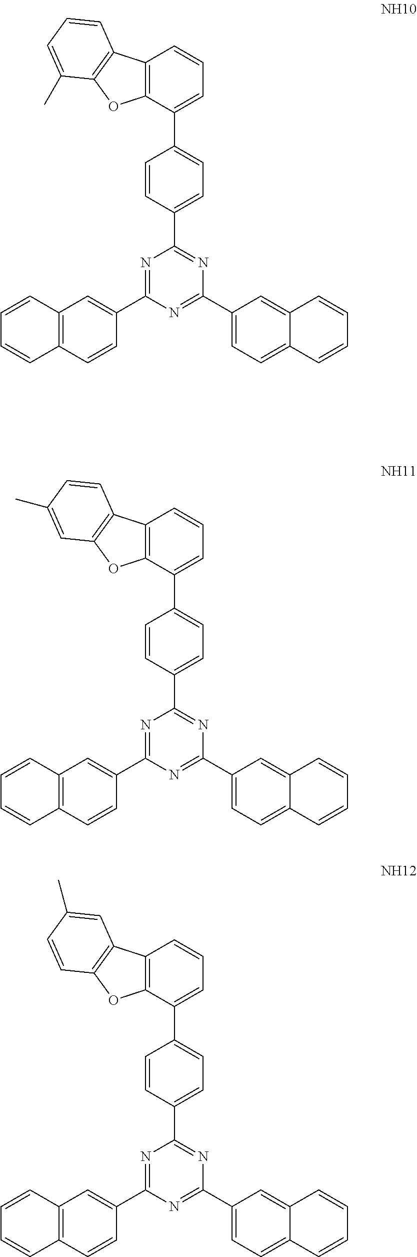 [SMILES: Cc1cccc2c1oc1c(-c3ccc(-c4nc(-c5ccc6ccccc6c5)nc(-c5ccc6ccccc6c5)n4)cc3)cccc12 ; Cc1ccc2c(c1)oc1c(-c3ccc(-c4nc(-c5ccc6ccccc6c5)nc(-c5ccc6ccccc6c5)n4)cc3)cccc12 ; Cc1ccc2oc3c(-c4ccc(-c5nc(-c6ccc7ccccc7c6)nc(-c6ccc7ccccc7c6)n5)cc4)cccc3c2c1]

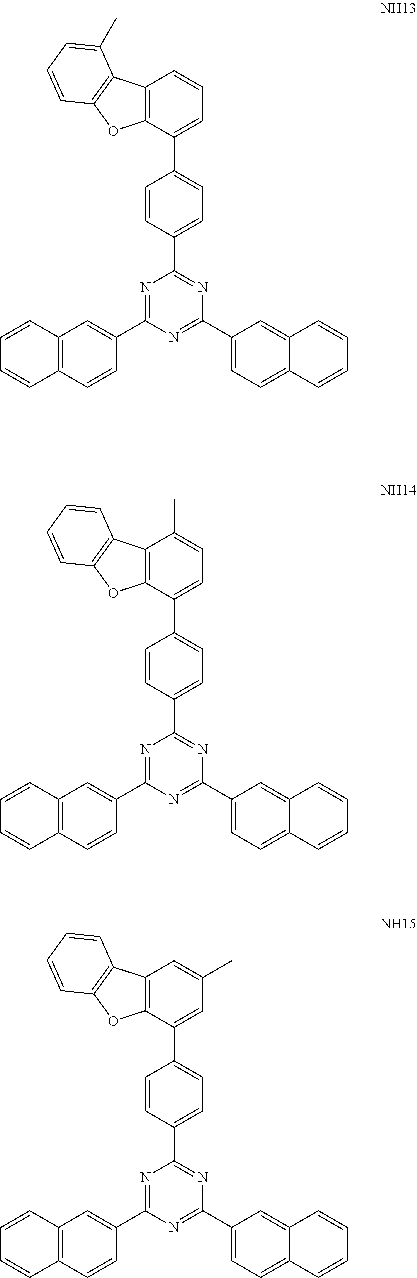 [SMILES: Cc1cccc2oc3c(-c4ccc(-c5nc(-c6ccc7ccccc7c6)nc(-c6ccc7ccccc7c6)n5)cc4)cccc3c12 ; Cc1ccc(-c2ccc(-c3nc(-c4ccc5ccccc5c4)nc(-c4ccc5ccccc5c4)n3)cc2)c2oc3ccccc3c12 ; Cc1cc(-c2ccc(-c3nc(-c4ccc5ccccc5c4)nc(-c4ccc5ccccc5c4)n3)cc2)c2oc3ccccc3c2c1]

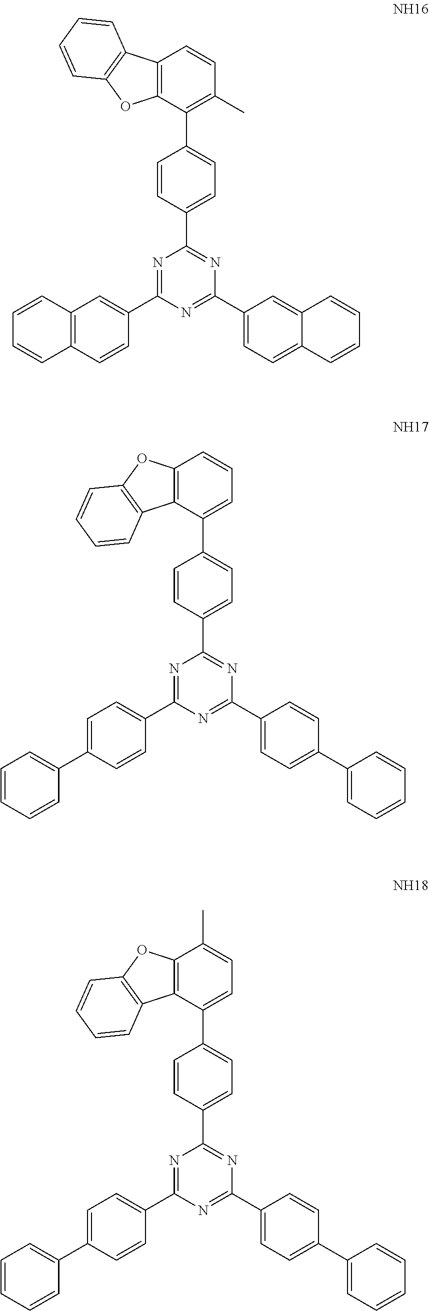 [SMILES: Cc1ccc2c(oc3ccccc32)c1-c1ccc(-c2nc(-c3ccc4ccccc4c3)nc(-c3ccc4ccccc4c3)n2)cc1 ; c1ccc(-c2ccc(-c3nc(-c4ccc(-c5ccccc5)cc4)nc(-c4ccc(-c5cccc6oc7ccccc7c56)cc4)n3)cc2)cc1 ; Cc1ccc(-c2ccc(-c3nc(-c4ccc(-c5ccccc5)cc4)nc(-c4ccc(-c5ccccc5)cc4)n3)cc2)c2c1oc1ccccc12]

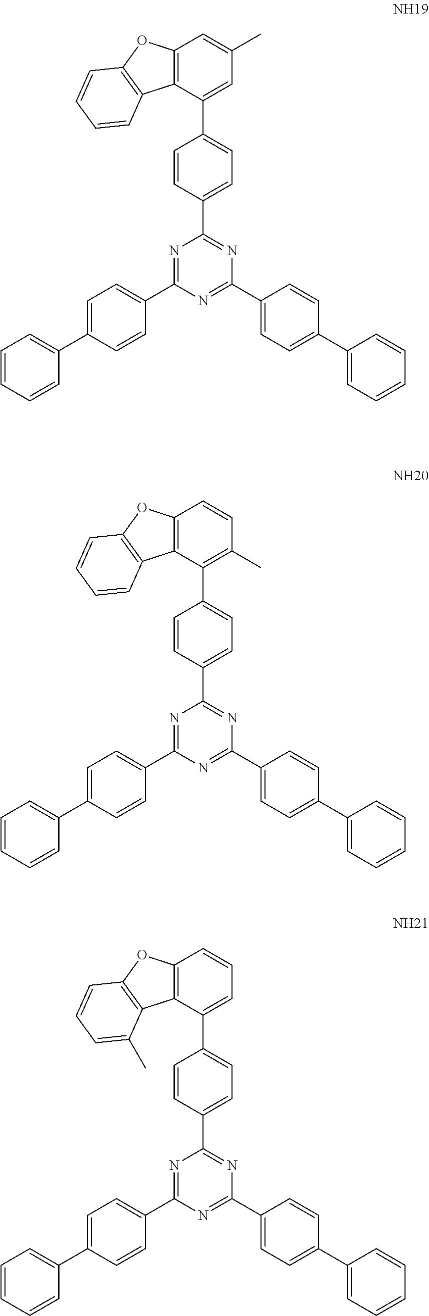 [SMILES: Cc1cc(-c2ccc(-c3nc(-c4ccc(-c5ccccc5)cc4)nc(-c4ccc(-c5ccccc5)cc4)n3)cc2)c2c(c1)oc1ccccc12 ; Cc1ccc2oc3ccccc3c2c1-c1ccc(-c2nc(-c3ccc(-c4ccccc4)cc3)nc(-c3ccc(-c4ccccc4)cc3)n2)cc1 ; Cc1cccc2oc3cccc(-c4ccc(-c5nc(-c6ccc(-c7ccccc7)cc6)nc(-c6ccc(-c7ccccc7)cc6)n5)cc4)c3c12]

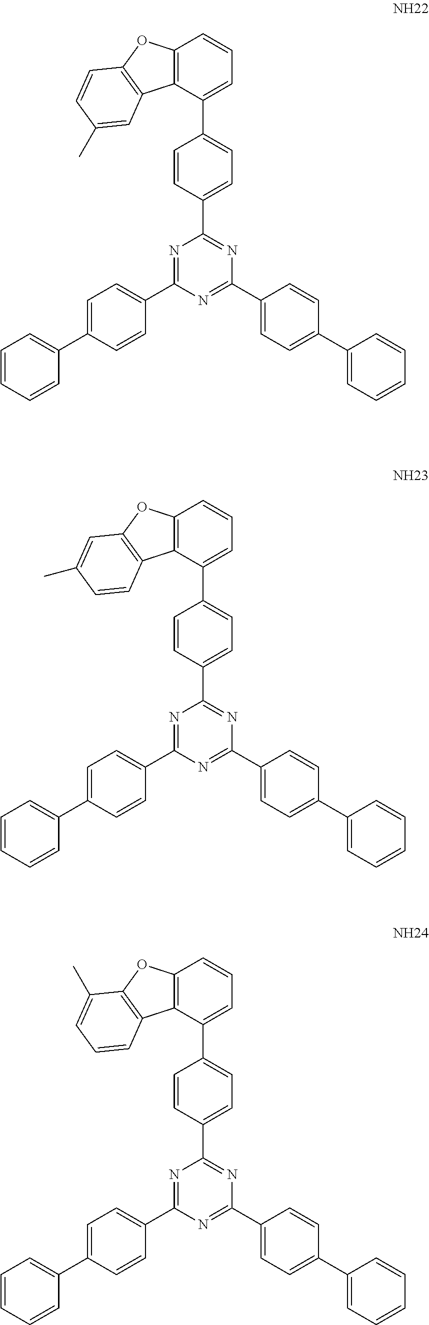 [SMILES: Cc1ccc2oc3cccc(-c4ccc(-c5nc(-c6ccc(-c7ccccc7)cc6)nc(-c6ccc(-c7ccccc7)cc6)n5)cc4)c3c2c1 ; Cc1ccc2c(c1)oc1cccc(-c3ccc(-c4nc(-c5ccc(-c6ccccc6)cc5)nc(-c5ccc(-c6ccccc6)cc5)n4)cc3)c12 ; Cc1cccc2c1oc1cccc(-c3ccc(-c4nc(-c5ccc(-c6ccccc6)cc5)nc(-c5ccc(-c6ccccc6)cc5)n4)cc3)c12]

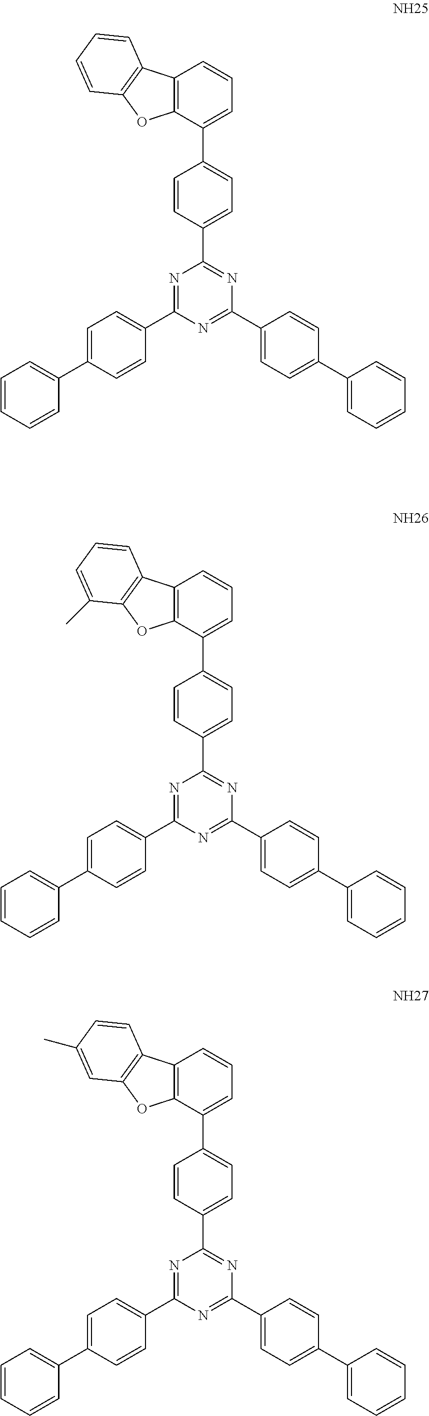 [SMILES: c1ccc(-c2ccc(-c3nc(-c4ccc(-c5ccccc5)cc4)nc(-c4ccc(-c5cccc6c5oc5ccccc56)cc4)n3)cc2)cc1 ; Cc1cccc2c1oc1c(-c3ccc(-c4nc(-c5ccc(-c6ccccc6)cc5)nc(-c5ccc(-c6ccccc6)cc5)n4)cc3)cccc12 ; Cc1ccc2c(c1)oc1c(-c3ccc(-c4nc(-c5ccc(-c6ccccc6)cc5)nc(-c5ccc(-c6ccccc6)cc5)n4)cc3)cccc12]

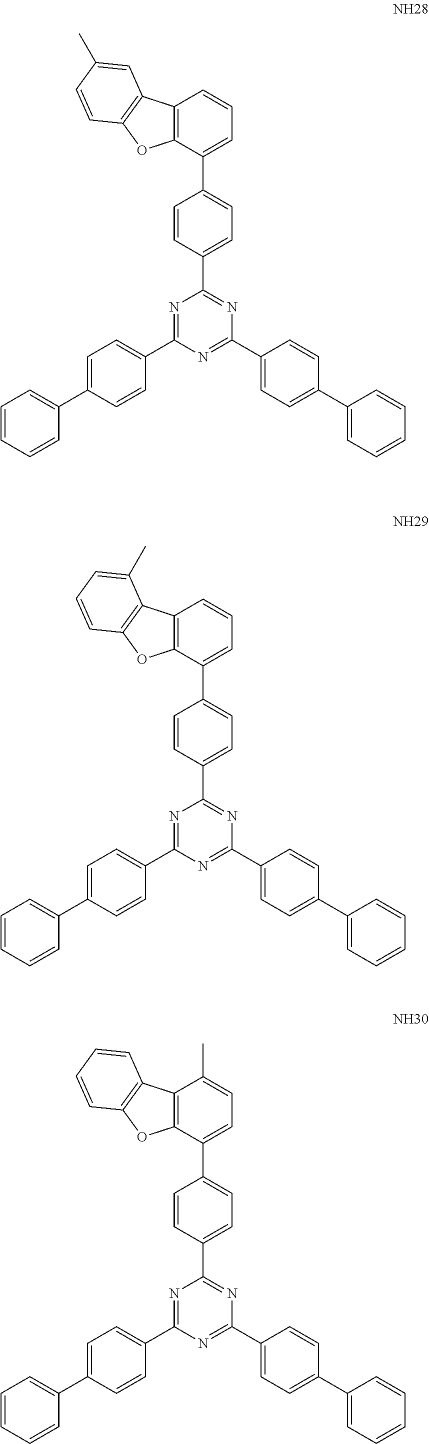 [SMILES: Cc1ccc2oc3c(-c4ccc(-c5nc(-c6ccc(-c7ccccc7)cc6)nc(-c6ccc(-c7ccccc7)cc6)n5)cc4)cccc3c2c1 ; Cc1cccc2oc3c(-c4ccc(-c5nc(-c6ccc(-c7ccccc7)cc6)nc(-c6ccc(-c7ccccc7)cc6)n5)cc4)cccc3c12 ; Cc1ccc(-c2ccc(-c3nc(-c4ccc(-c5ccccc5)cc4)nc(-c4ccc(-c5ccccc5)cc4)n3)cc2)c2oc3ccccc3c12]

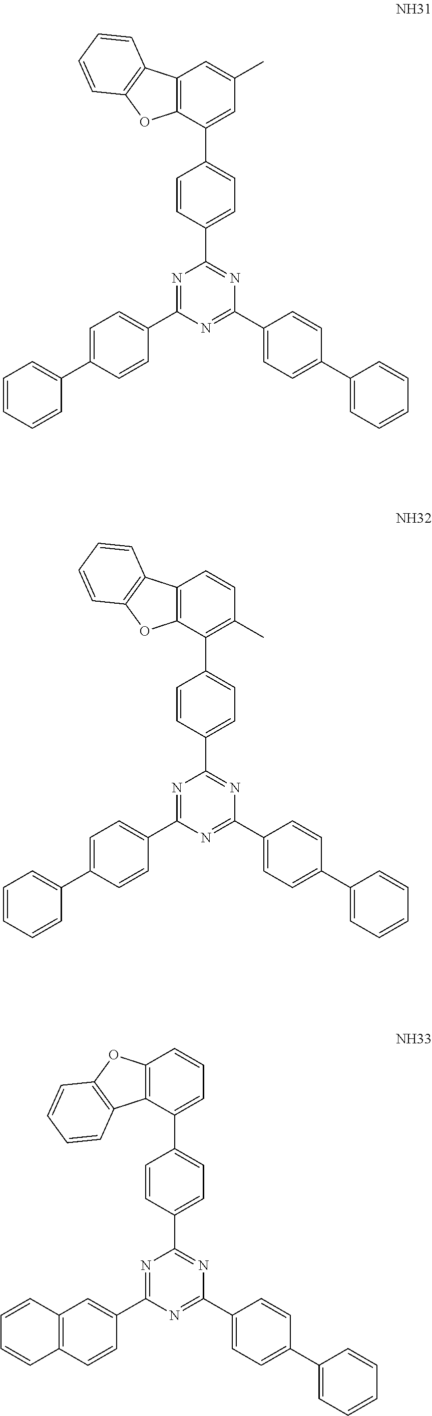 [SMILES: Cc1cc(-c2ccc(-c3nc(-c4ccc(-c5ccccc5)cc4)nc(-c4ccc(-c5ccccc5)cc4)n3)cc2)c2oc3ccccc3c2c1 ; Cc1ccc2c(oc3ccccc32)c1-c1ccc(-c2nc(-c3ccc(-c4ccccc4)cc3)nc(-c3ccc(-c4ccccc4)cc3)n2)cc1 ; c1ccc(-c2ccc(-c3nc(-c4ccc(-c5cccc6oc7ccccc7c56)cc4)nc(-c4ccc5ccccc5c4)n3)cc2)cc1]

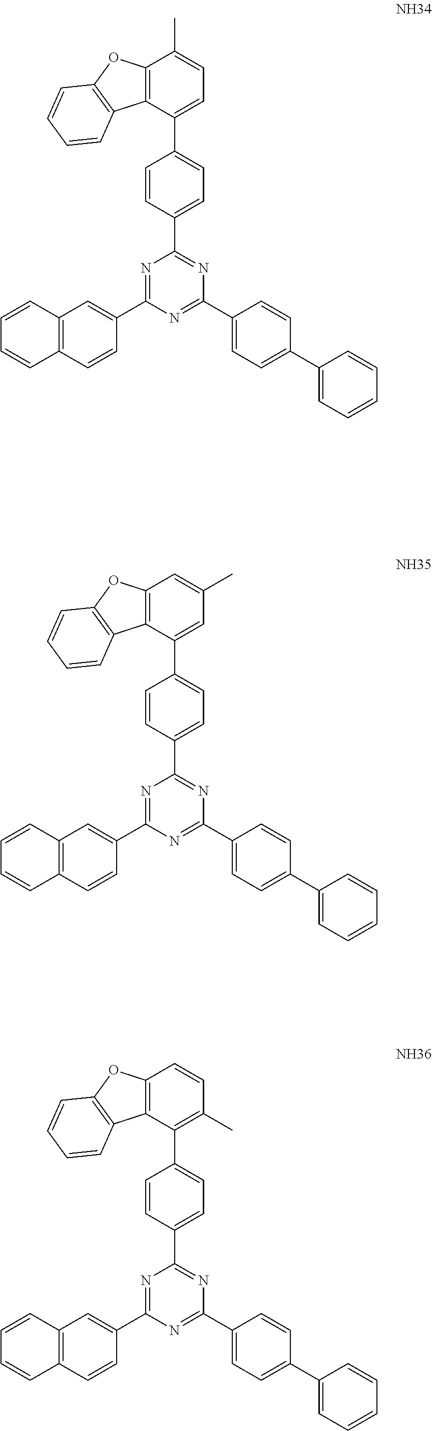 [SMILES: Cc1ccc(-c2ccc(-c3nc(-c4ccc(-c5ccccc5)cc4)nc(-c4ccc5ccccc5c4)n3)cc2)c2c1oc1ccccc12 ; Cc1cc(-c2ccc(-c3nc(-c4ccc(-c5ccccc5)cc4)nc(-c4ccc5ccccc5c4)n3)cc2)c2c(c1)oc1ccccc12 ; Cc1ccc2oc3ccccc3c2c1-c1ccc(-c2nc(-c3ccc(-c4ccccc4)cc3)nc(-c3ccc4ccccc4c3)n2)cc1]

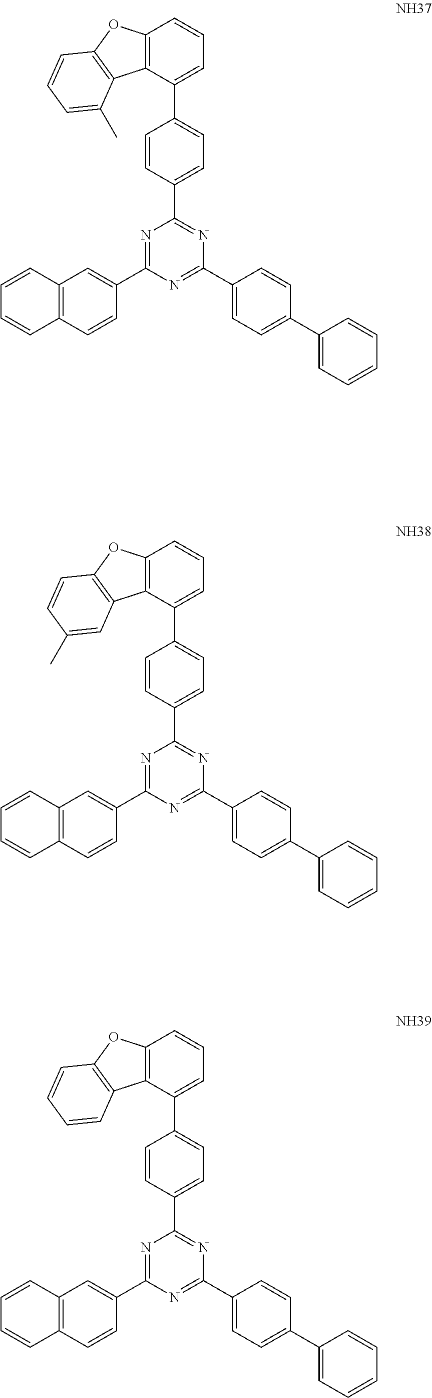 [SMILES: Cc1cccc2oc3cccc(-c4ccc(-c5nc(-c6ccc(-c7ccccc7)cc6)nc(-c6ccc7ccccc7c6)n5)cc4)c3c12 ; Cc1ccc2oc3cccc(-c4ccc(-c5nc(-c6ccc(-c7ccccc7)cc6)nc(-c6ccc7ccccc7c6)n5)cc4)c3c2c1 ; c1ccc(-c2ccc(-c3nc(-c4ccc(-c5cccc6oc7ccccc7c56)cc4)nc(-c4ccc5ccccc5c4)n3)cc2)cc1]

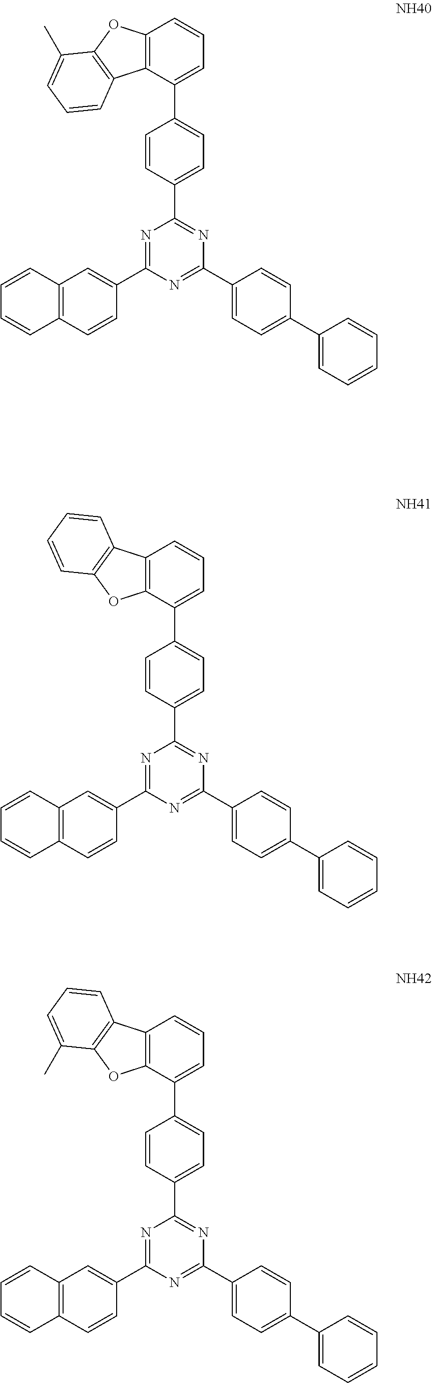 [SMILES: Cc1cccc2c1oc1cccc(-c3ccc(-c4nc(-c5ccc(-c6ccccc6)cc5)nc(-c5ccc6ccccc6c5)n4)cc3)c12 ; c1ccc(-c2ccc(-c3nc(-c4ccc(-c5cccc6c5oc5ccccc56)cc4)nc(-c4ccc5ccccc5c4)n3)cc2)cc1 ; Cc1cccc2c1oc1c(-c3ccc(-c4nc(-c5ccc(-c6ccccc6)cc5)nc(-c5ccc6ccccc6c5)n4)cc3)cccc12]

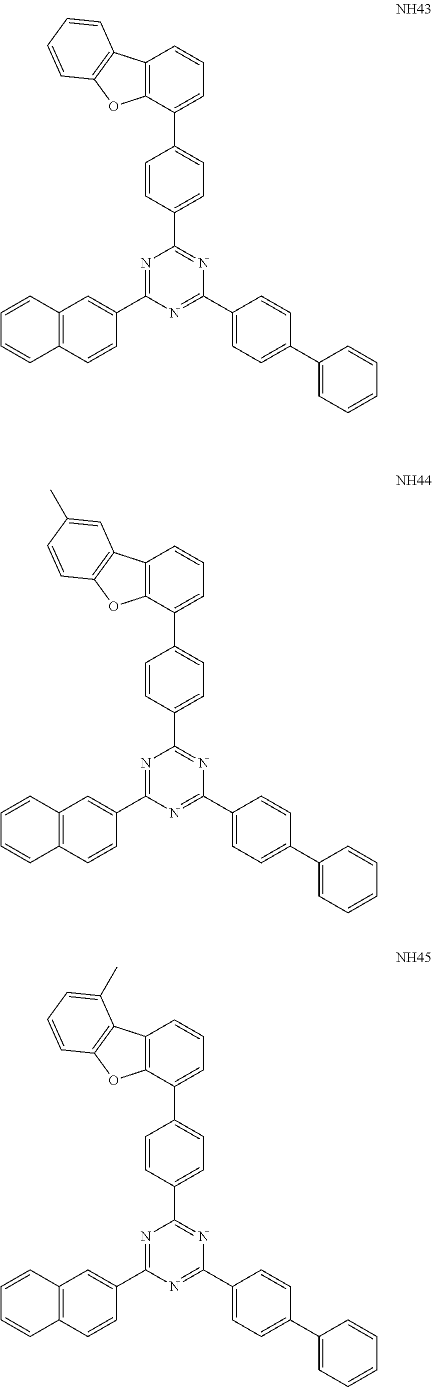 [SMILES: c1ccc(-c2ccc(-c3nc(-c4ccc(-c5cccc6c5oc5ccccc56)cc4)nc(-c4ccc5ccccc5c4)n3)cc2)cc1 ; Cc1ccc2oc3c(-c4ccc(-c5nc(-c6ccc(-c7ccccc7)cc6)nc(-c6ccc7ccccc7c6)n5)cc4)cccc3c2c1 ; Cc1cccc2oc3c(-c4ccc(-c5nc(-c6ccc(-c7ccccc7)cc6)nc(-c6ccc7ccccc7c6)n5)cc4)cccc3c12]

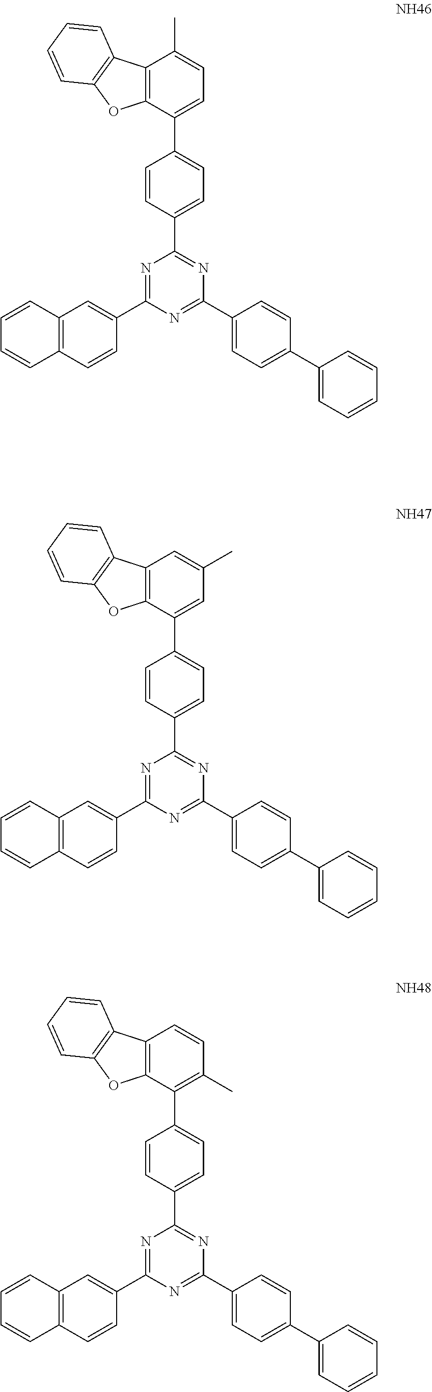 [SMILES: Cc1ccc(-c2ccc(-c3nc(-c4ccc(-c5ccccc5)cc4)nc(-c4ccc5ccccc5c4)n3)cc2)c2oc3ccccc3c12 ; Cc1cc(-c2ccc(-c3nc(-c4ccc(-c5ccccc5)cc4)nc(-c4ccc5ccccc5c4)n3)cc2)c2oc3ccccc3c2c1 ; Cc1ccc2c(oc3ccccc32)c1-c1ccc(-c2nc(-c3ccc(-c4ccccc4)cc3)nc(-c3ccc4ccccc4c3)n2)cc1]

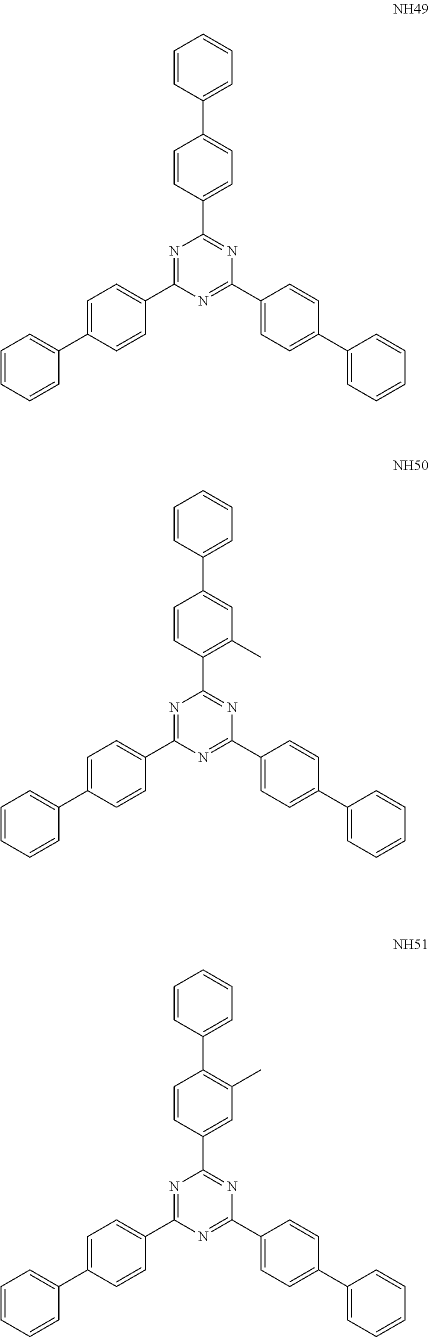 [SMILES: c1ccc(-c2ccc(-c3nc(-c4ccc(-c5ccccc5)cc4)nc(-c4ccc(-c5ccccc5)cc4)n3)cc2)cc1 ; Cc1cc(-c2ccccc2)ccc1-c1nc(-c2ccc(-c3ccccc3)cc2)nc(-c2ccc(-c3ccccc3)cc2)n1 ; Cc1cc(-c2nc(-c3ccc(-c4ccccc4)cc3)nc(-c3ccc(-c4ccccc4)cc3)n2)ccc1-c1ccccc1]

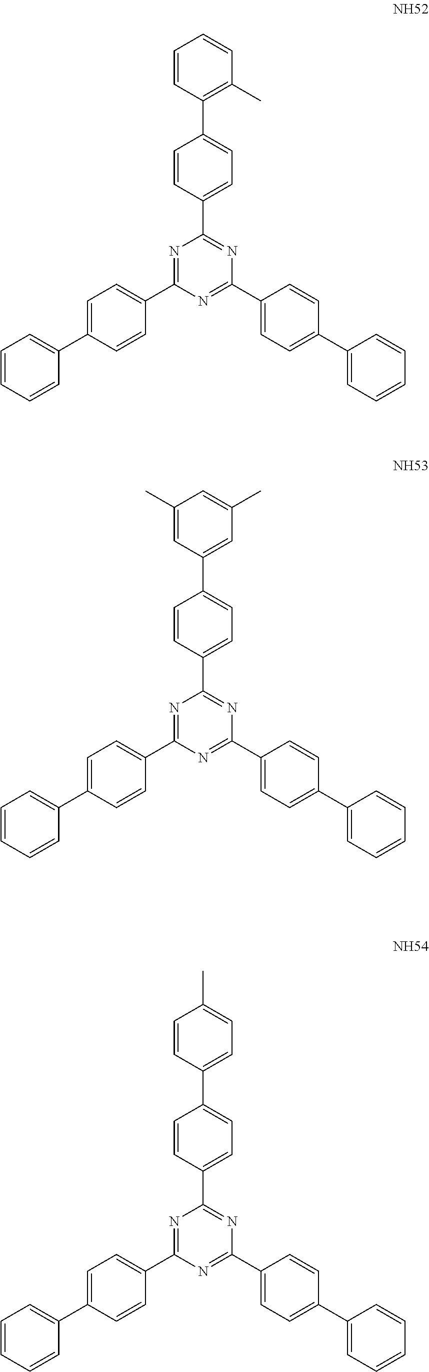 [SMILES: Cc1ccccc1-c1ccc(-c2nc(-c3ccc(-c4ccccc4)cc3)nc(-c3ccc(-c4ccccc4)cc3)n2)cc1 ; Cc1cc(C)cc(-c2ccc(-c3nc(-c4ccc(-c5ccccc5)cc4)nc(-c4ccc(-c5ccccc5)cc4)n3)cc2)c1 ; Cc1ccc(-c2ccc(-c3nc(-c4ccc(-c5ccccc5)cc4)nc(-c4ccc(-c5ccccc5)cc4)n3)cc2)cc1]

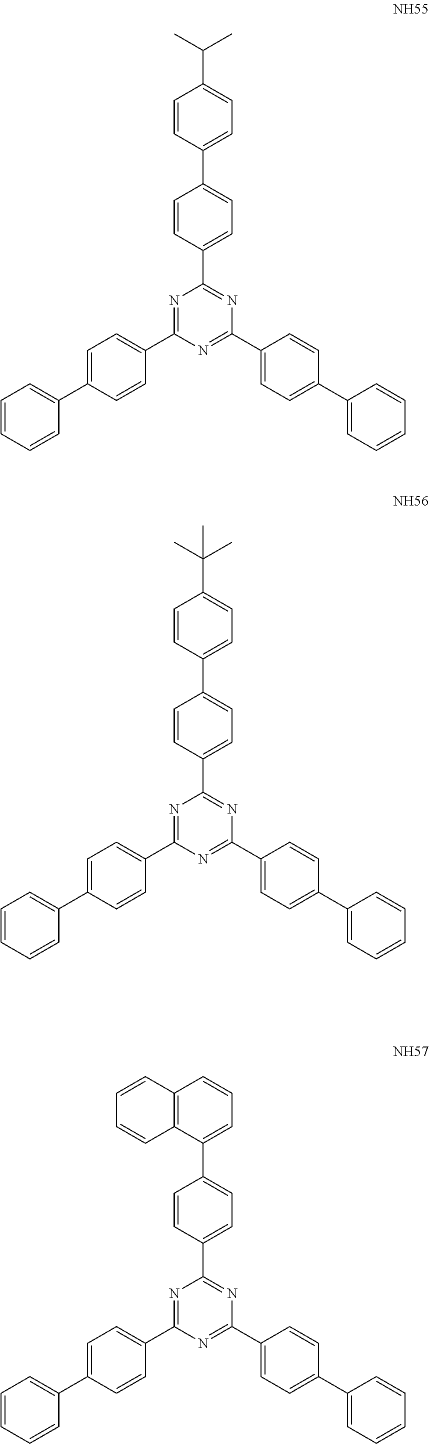 [SMILES: CC(C)c1ccc(-c2ccc(-c3nc(-c4ccc(-c5ccccc5)cc4)nc(-c4ccc(-c5ccccc5)cc4)n3)cc2)cc1 ; CC(C)(C)c1ccc(-c2ccc(-c3nc(-c4ccc(-c5ccccc5)cc4)nc(-c4ccc(-c5ccccc5)cc4)n3)cc2)cc1 ; c1ccc(-c2ccc(-c3nc(-c4ccc(-c5ccccc5)cc4)nc(-c4ccc(-c5cccc6ccccc56)cc4)n3)cc2)cc1]

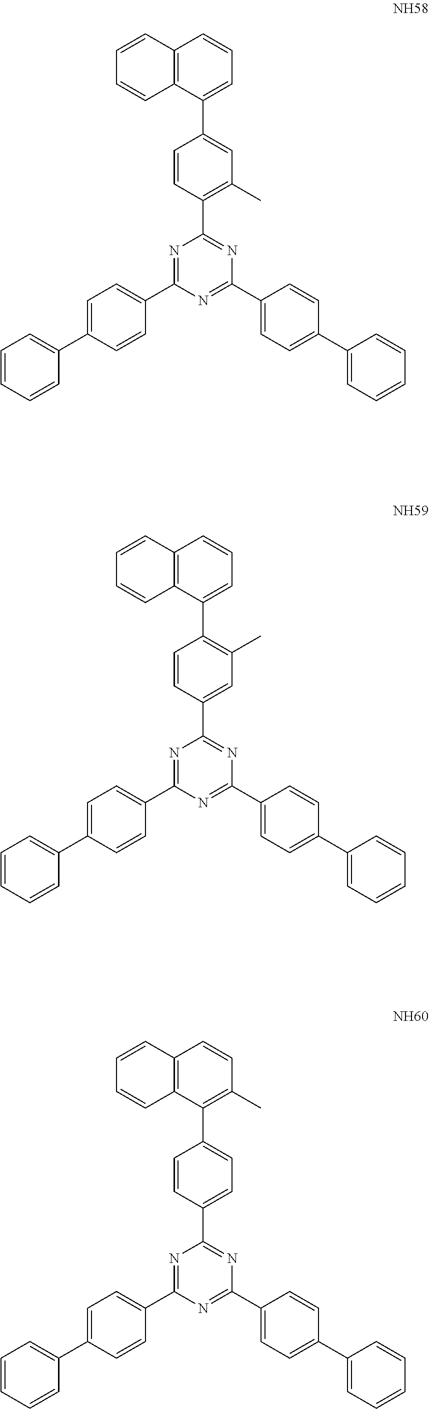 [SMILES: Cc1cc(-c2cccc3ccccc23)ccc1-c1nc(-c2ccc(-c3ccccc3)cc2)nc(-c2ccc(-c3ccccc3)cc2)n1 ; Cc1cc(-c2nc(-c3ccc(-c4ccccc4)cc3)nc(-c3ccc(-c4ccccc4)cc3)n2)ccc1-c1cccc2ccccc12 ; Cc1ccc2ccccc2c1-c1ccc(-c2nc(-c3ccc(-c4ccccc4)cc3)nc(-c3ccc(-c4ccccc4)cc3)n2)cc1]

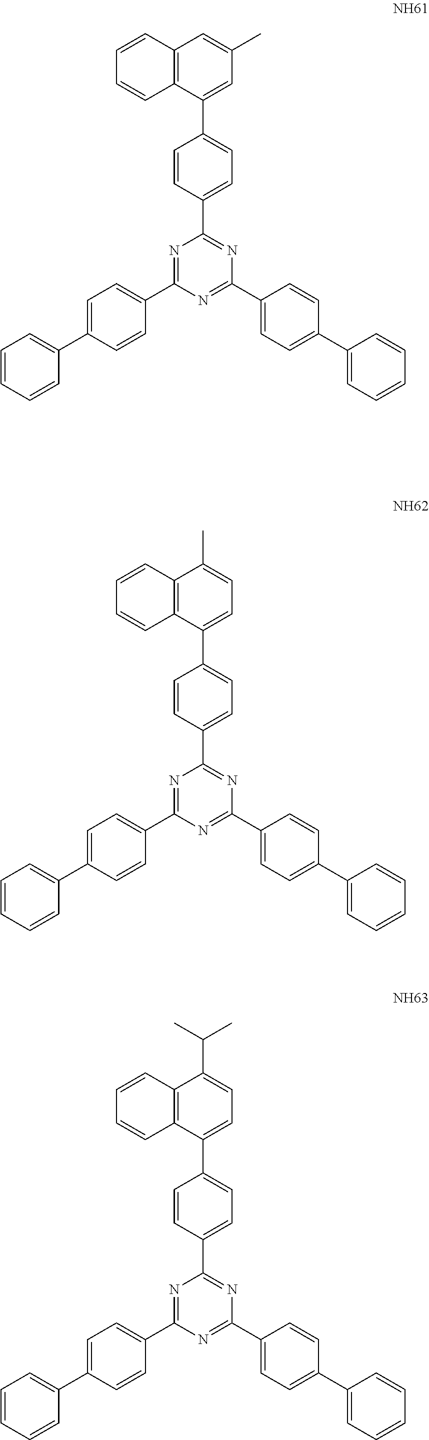 [SMILES: Cc1cc(-c2ccc(-c3nc(-c4ccc(-c5ccccc5)cc4)nc(-c4ccc(-c5ccccc5)cc4)n3)cc2)c2ccccc2c1 ; Cc1ccc(-c2ccc(-c3nc(-c4ccc(-c5ccccc5)cc4)nc(-c4ccc(-c5ccccc5)cc4)n3)cc2)c2ccccc12 ; CC(C)c1ccc(-c2ccc(-c3nc(-c4ccc(-c5ccccc5)cc4)nc(-c4ccc(-c5ccccc5)cc4)n3)cc2)c2ccccc12]

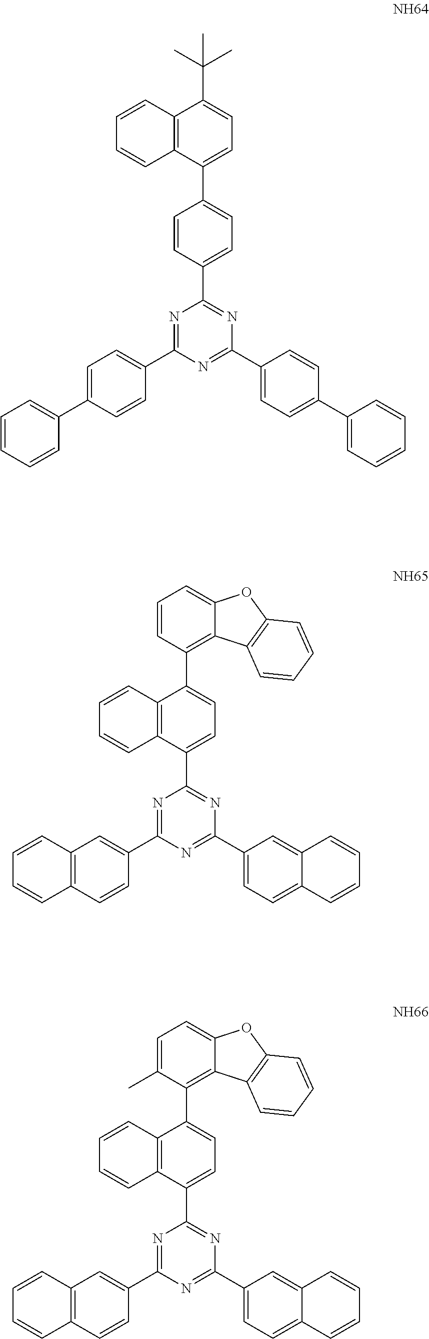 [SMILES: CC(C)(C)c1ccc(-c2ccc(-c3nc(-c4ccc(-c5ccccc5)cc4)nc(-c4ccc(-c5ccccc5)cc4)n3)cc2)c2ccccc12 ; c1ccc2cc(-c3nc(-c4ccc5ccccc5c4)nc(-c4ccc(-c5cccc6oc7ccccc7c56)c5ccccc45)n3)ccc2c1 ; Cc1ccc2oc3ccccc3c2c1-c1ccc(-c2nc(-c3ccc4ccccc4c3)nc(-c3ccc4ccccc4c3)n2)c2ccccc12]

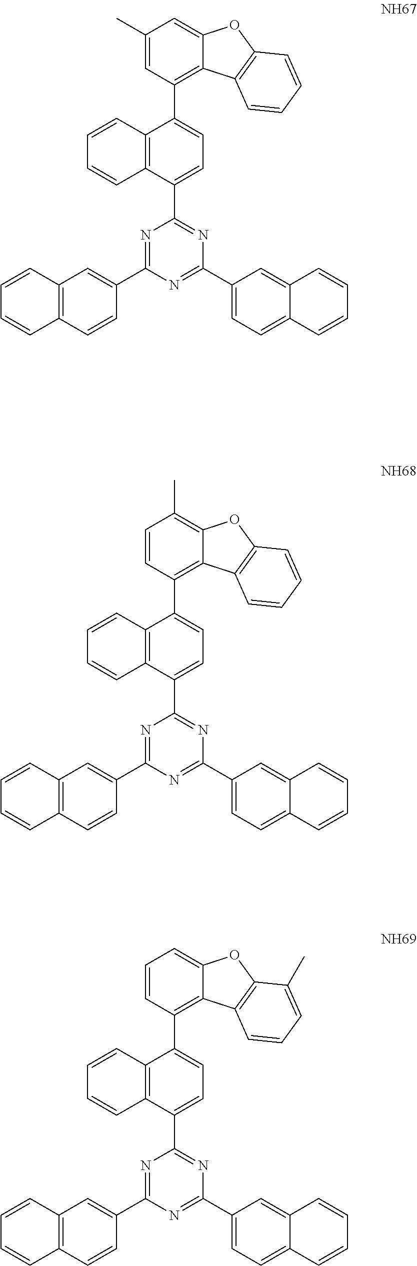 [SMILES: Cc1cc(-c2ccc(-c3nc(-c4ccc5ccccc5c4)nc(-c4ccc5ccccc5c4)n3)c3ccccc23)c2c(c1)oc1ccccc12 ; Cc1ccc(-c2ccc(-c3nc(-c4ccc5ccccc5c4)nc(-c4ccc5ccccc5c4)n3)c3ccccc23)c2c1oc1ccccc12 ; Cc1cccc2c1oc1cccc(-c3ccc(-c4nc(-c5ccc6ccccc6c5)nc(-c5ccc6ccccc6c5)n4)c4ccccc34)c12]

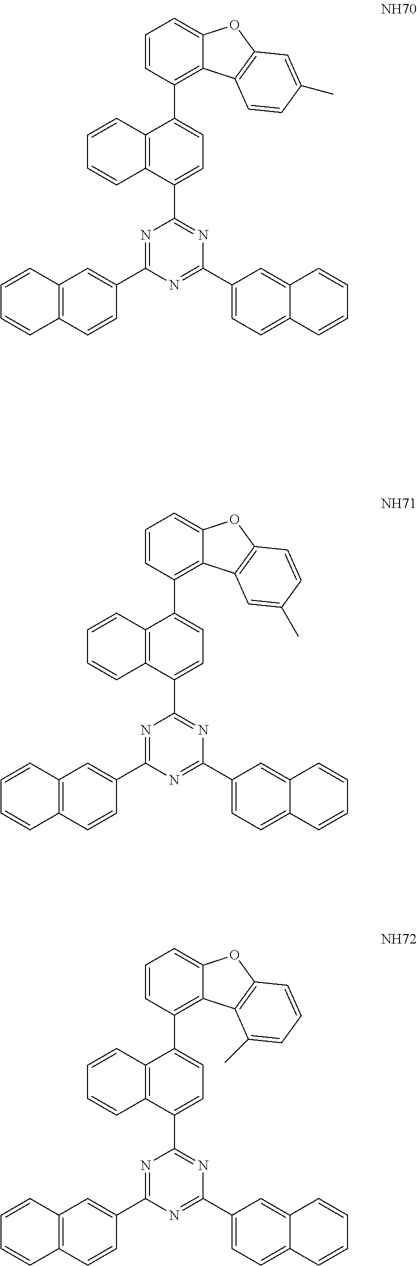 [SMILES: Cc1ccc2c(c1)oc1cccc(-c3ccc(-c4nc(-c5ccc6ccccc6c5)nc(-c5ccc6ccccc6c5)n4)c4ccccc34)c12 ; Cc1ccc2oc3cccc(-c4ccc(-c5nc(-c6ccc7ccccc7c6)nc(-c6ccc7ccccc7c6)n5)c5ccccc45)c3c2c1 ; Cc1cccc2oc3cccc(-c4ccc(-c5nc(-c6ccc7ccccc7c6)nc(-c6ccc7ccccc7c6)n5)c5ccccc45)c3c12]

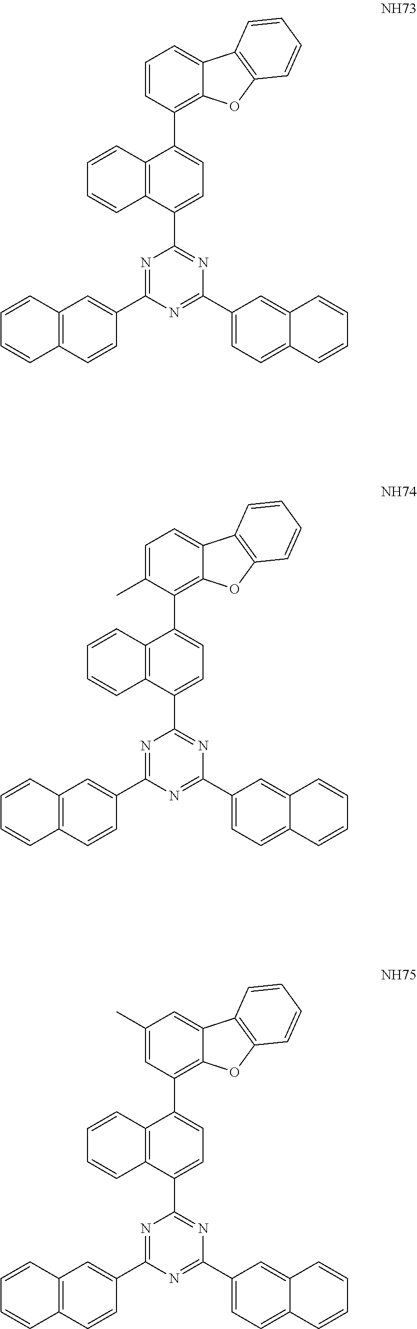 [SMILES: c1ccc2cc(-c3nc(-c4ccc5ccccc5c4)nc(-c4ccc(-c5cccc6c5oc5ccccc56)c5ccccc45)n3)ccc2c1 ; Cc1ccc2c(oc3ccccc32)c1-c1ccc(-c2nc(-c3ccc4ccccc4c3)nc(-c3ccc4ccccc4c3)n2)c2ccccc12 ; Cc1cc(-c2ccc(-c3nc(-c4ccc5ccccc5c4)nc(-c4ccc5ccccc5c4)n3)c3ccccc23)c2oc3ccccc3c2c1]

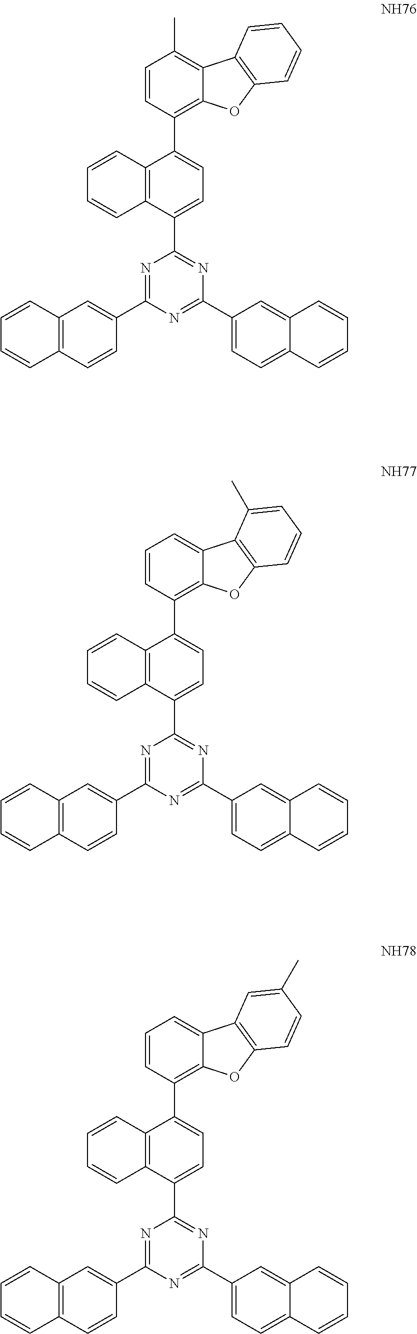 [SMILES: Cc1ccc(-c2ccc(-c3nc(-c4ccc5ccccc5c4)nc(-c4ccc5ccccc5c4)n3)c3ccccc23)c2oc3ccccc3c12 ; Cc1cccc2oc3c(-c4ccc(-c5nc(-c6ccc7ccccc7c6)nc(-c6ccc7ccccc7c6)n5)c5ccccc45)cccc3c12 ; Cc1ccc2oc3c(-c4ccc(-c5nc(-c6ccc7ccccc7c6)nc(-c6ccc7ccccc7c6)n5)c5ccccc45)cccc3c2c1]

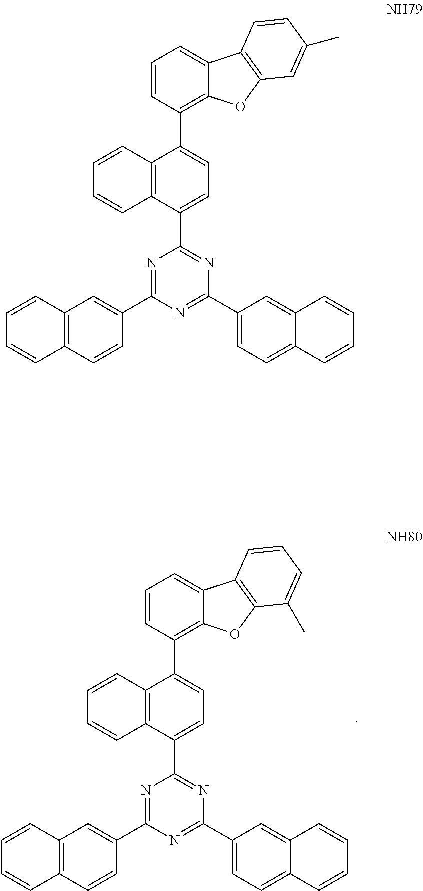 [SMILES: Cc1ccc2c(c1)oc1c(-c3ccc(-c4nc(-c5ccc6ccccc6c5)nc(-c5ccc6ccccc6c5)n4)c4ccccc34)cccc12 ; Cc1cccc2c1oc1c(-c3ccc(-c4nc(-c5ccc6ccccc6c5)nc(-c5ccc6ccccc6c5)n4)c4ccccc34)cccc12]

26. The organic light emitting diode of claim 1, wherein the emissive layer comprises:
a first emitting part disposed between the first and second electrodes and comprising a first emitting material layer;
a second emitting part disposed between the first emitting part and the second electrode and comprising a second emitting material layer; and
a first charge generation layer disposed between the first emitting part and the second emitting part, and
wherein at least one of the first emitting material layer and the second emitting material layer comprises the first compound and the second compound.

27. The organic light emitting diode of claim 26, wherein the at least one of the first emitting material layer and the second emitting material layer further comprises a third compound, and wherein the third compound comprises an organic compound having the structure of Chemical Formula 11: 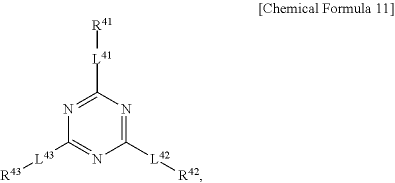
wherein:
each of R⁴¹ to R⁴³ is independently chosen from hydrogen, halogen, a hydroxyl group, a cyano group, a nitro group, an amino group, an amidino group, a hydrazine group, a hydrazone group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ cycloalkyl group, an aryl group, an unsubstituted or substituted C₂-C₃₀ hetero aryl group, an unsubstituted or substituted C₇-C₃₀ aralkyl group, an unsubstituted or substituted C₃-C₃₀ hetero aralkyl group, an unsubstituted or substituted C₆-C₃₀ aryloxy group, an unsubstituted or substituted C₂-C₃₀ hetero aryloxy group, an unsubstituted or substituted C₆-C₃₀ aryl amino group, an unsubstituted or substituted C₂-C₃₀ hetero aryl amino group, an unsubstituted or substituted C₆-C₃₀ aryl silyl group, and an unsubstituted or substituted C₂-C₃₀ hetero aryl silyl group; and
each of L⁴¹ to L⁴³ is independently a single bond, an unsubstituted or substituted C₆-C₃₀ arylene group or an unsubstituted or substituted C₂-C₃₀ hetero arylene group.

28. The organic light emitting diode of claim 26, wherein each of L⁴¹, L⁴², and L⁴³ is independently chosen from a single bond,

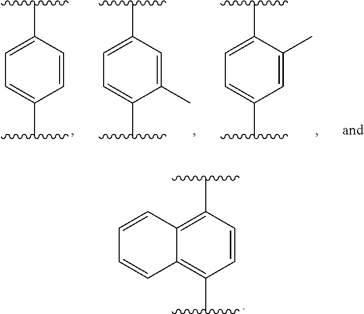

29. The organic light emitting diode of claim 26, wherein R⁴¹ is chosen from:

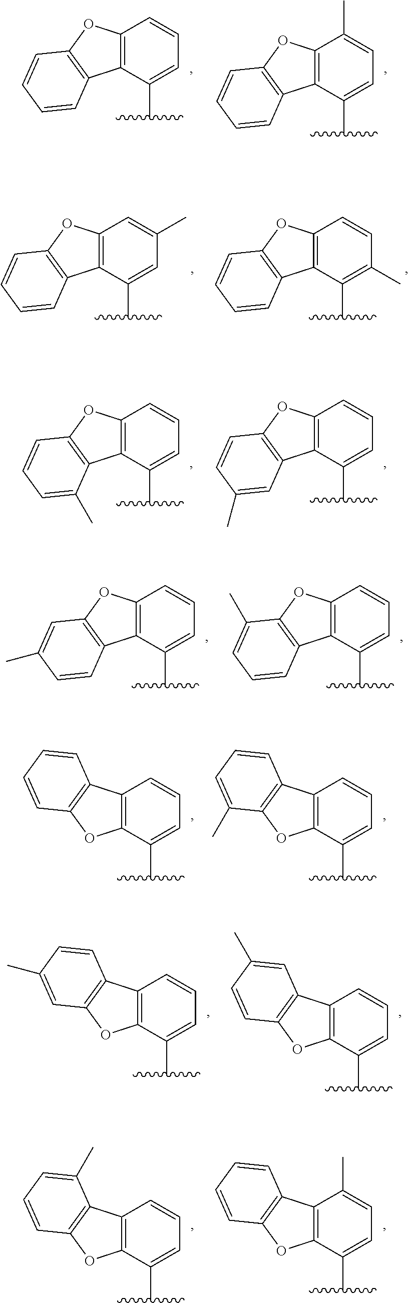

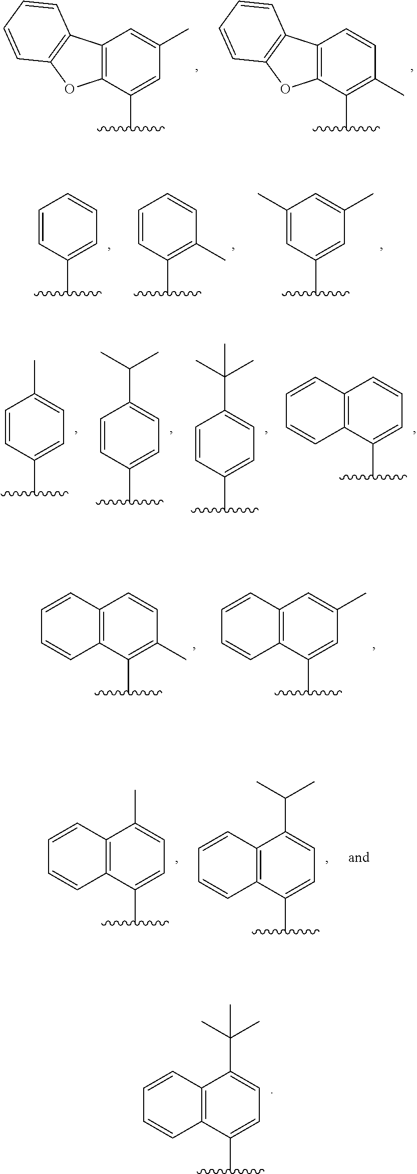

30. The organic light emitting diode of claim 26, wherein each of R⁴² and R⁴³ is independently chosen from:

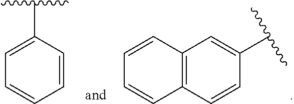 [SMILES: *c1ccccc1 ; *c1ccc2ccccc2c1]

31. The organic light emitting diode of claim 27, wherein the second emitting material layer comprises:
a first layer disposed between the first charge generation layer and the second electrode; and
a second layer disposed between the first layer and the second electrode, and
wherein one of the first layer and the second layer comprises the first compound, the second compound and the third compound.

32. The organic light emitting diode of claim 27, wherein the emissive layer further comprises:
a third emitting part disposed between the second emitting part and the second electrode and comprising a third emitting material layer; and
a second charge generation layer disposed between the second emitting part and the third emitting part.

33. The organic light emitting diode of claim 32, wherein the second emitting material layer comprises:
a first layer disposed between the first charge generation layer and the second electrode; and
a second layer disposed between the first layer and the second electrode, and
wherein one of the first layer and the second layer comprises the first compound, the second compound and the third compound.

34. An organic light emitting device comprising:
a substrate; and
the organic light emitting diode of claim 1 disposed over the substrate.
